(19) United States
(12) Patent Application Publication
(10) Pub. No.: US 2015/0218441 A1
(43) Pub. Date: Aug. 6, 2015

(54) NOVEL COMBINATION OF A HOST COMPOUND AND A DOPANT COMPOUND AND AN ORGANIC ELECTROLUMINESCENCE DEVICE COMPRISING THE SAME

(71) Applicant: Rohm and Haas Electronic Mateirals Korea Ltd., Cheonan (KR)

(72) Inventors: Young-Jun Cho, Seongnam (KR); So-Young Jung, Hwaseong (KR); Hyun-Ju Kang, Gwangmyeong (KR); Bong-Ok Kim, Seoul (KR); Chi-Sik Kim, Hwaseong (KR); Hyun Kim, Suwon (KR); Nam-Kyun Kim, Yongin (KR); Hyuck-Joo Kwon, Cheonan (KR); Kyung-Joo Lee, Seoul (KR); Hyo-Nim Shin, Seongnam (KR); Seok-Keun Yoon, Suwon (KR)

(21) Appl. No.: 14/426,169

(22) PCT Filed: Mar. 13, 2014
(86) PCT No.: PCT/KR2013/008021

§ 371 Date: Mar. 5, 2015

(30) Foreign Application Priority Data
Sep. 7, 2012 (KR) 10-2012-0099580

(51) Int. Cl. C09K 11/02; C09K 11/06; H01L 51/00

(52) U.S. Cl. CPC C09K 11/025; H01L 51/0085; H01L 51/0072; H01L 51/0067; H01L 51/0071; H01L 51/0094; H01L 51/0074; H01L 51/0073; H01L 51/0054; H01L 51/0052; C09K 11/06; H01L 51/5036

(57) ABSTRACT

The present invention relates to a specific combination of a dopant compound and a host compound, and an organic electroluminescent device comprising the same. The organic electroluminescent device of the present invention emits yellow-green light; lowers the driving voltage of the device by improving the current characteristic of the device; and improves power efficiency and operational lifespan.

### TECHNICAL FIELD

The present invention relates to a novel combination of a host compound and a dopant compound and an organic electroluminescence device comprising the same.

### BACKGROUND ART

An electroluminescent (EL) device is a self-light-emitting device which has advantages in that it provides a wider viewing angle, a greater contrast ratio, and a faster response time compared to LCDs. An organic EL device was first developed by Eastman Kodak, by using small aromatic diamine molecules, and aluminum complexes as materials for forming a light-emitting layer [Appl. Phys. Lett. 51, 913, 1987].

The most important factor determining luminous efficiency in an organic EL device is the light-emitting material. The electroluminescent material includes a host material and a dopant material for purposes of functionality. Typically, a device that has very superior electroluminescent properties is known to have a structure in which a host is doped with a dopant to form an electroluminescent layer. Recently, the development of an organic EL device having high efficiency and long lifespan is being urgently called for. Particularly, taking into consideration the electroluminescent properties required of medium to large OLED panels, the development of materials very superior to conventional electroluminescent materials is urgent. In order to achieve such, a host material which functions as the solvent in a solid phase and plays a role in transferring energy should be of high purity and must have a molecular weight appropriate to enabling vacuum deposition. Also, the glass transition temperature and heat decomposition temperature should be high to ensure thermal stability, and high electrochemical stability is required to attain a long lifespan, and the formation of an amorphous thin film should become simple, and the force of adhesion to materials of other adjacent layers must be good but interlayer migration should not occur.

Until now, fluorescent materials have been widely used as a light-emitting material. However, in view of electroluminescent mechanisms, developing phosphorescent materials is one of the best methods to theoretically enhance luminous efficiency by four (4) times. Iridium(III) complexes have been widely known as dopant compounds of phosphorescent substances, including bis(2-(2′-benzothienyl)-pyridinato-N,C3′)iridium(acetylacetonate)[(acac)Ir(btp)₂], tris(2-phenylpyridine)iridium [Ir(ppy)₃] and bis(4,6-difluorophenylpyridinato-N,C2)picolinato iridium [Firpic] as red, green and blue materials, respectively. Until now, 4,4′-N,N′-dicarbazol-biphenyl (CBP) was the most widely known host material for phosphorescent substances. Further, an organic EL device of high efficiency using bathocuproine (BCP) and aluminum(III)bis(2-methyl-8-quinolinate)(4-phenylphenolate) (BAlq) for a hole blocking layer is also known.

However, there were problems affecting power efficiency, operational life span, and luminous efficiency, when applying a light-emitting material comprising conventional dopant and host compounds to an organic EL device. Further, there were difficulties with obtaining a yellow-green light emitting luminous material having excellent performance.

Korean Patent Appln. Laying-Open No. KR 10-2012-0012431 A discloses combinations of iridium complex dopant compounds, and various host compounds. However, this reference does not disclose a luminous material emitting yellow-green light.

The present inventors found that a specific combination of a luminous material containing a dopant compound and a host compound emits yellow-green light, and is suitable for manufacturing organic EL devices having high color purity, high luminance, and a long lifespan.

### DISCLOSURE OF THE INVENTION

### Problems to be Solved

The objective of the present invention is to provide a novel combination of a dopant compound and a host compound, and an organic electroluminescent device comprising the same which lowers the driving voltage of the device by improving the current characteristic of the device; improves power efficiency and operational lifespan; and emits yellow-green light.

### Solution to Problems

In order to achieve said purposes, the present invention provides a combination of one or more dopant compounds represented by the following formula 1, and one or more host compounds represented by the following formula 2:

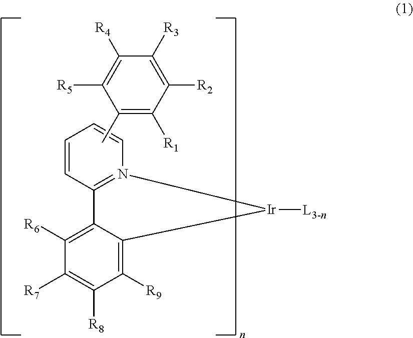

wherein

L is selected from the following structures:

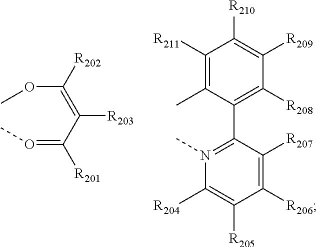

R₁ to R₉ each independently represent hydrogen, deuterium, a halogen, a substituted or unsubstituted (C1-C30)alkyl, a substituted or unsubstituted (C3-C30)cycloalkyl, a cyano, or a substituted or unsubstituted (C1-C30)alkoxy;

R₂₀₁ to R₂₁₁ each independently represent hydrogen, deuterium, a halogen, a substituted or unsubstituted (C1-C30)alkyl, or a substituted or unsubstituted (C3-C30)cycloalkyl; and

n represents an integer of 1 to 3;

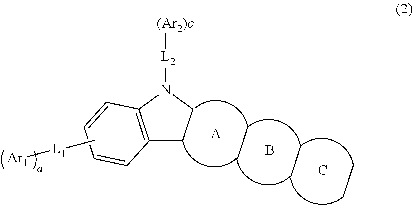

wherein

ring A and ring C each independently represent an aromatic ring represented by the following formula 1a;

ring B represents a 5-membered ring represented by the following formula 1b;

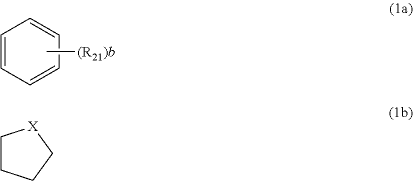

L₁ and L₂ each independently represent a single bond, a substituted or unsubstituted (C6-C30)arylene, or a substituted or unsubstituted 5- to 30-membered heteroarylene;

Ar₁ and Ar₂ each independently represent hydrogen, deuterium, a halogen, a cyano, a nitro, a hydroxyl, a substituted or unsubstituted (C1-C30)alkyl, a substituted or unsubstituted (C1-C30)alkoxy, a substituted or unsubstituted (C3-C30)cycloalkyl, a substituted or unsubstituted (C6-C30)aryl, a substituted or unsubstituted tri(C1-C30)alkylsilyl, a substituted or unsubstituted tri(C6-C30)arylsilyl, or a substituted or unsubstituted 5- to 30-membered heteroaryl; or are linked to an adjacent substituent(s) to form a mono- or polycyclic, (C3-C30)alicyclic or aromatic ring whose carbon atom(s) may be replaced with at least one hetero atom selected from nitrogen, oxygen and sulfur;

R₂₁ represents hydrogen, deuterium, a halogen, a substituted or unsubstituted (C1-C30)alkyl, a substituted or unsubstituted (C6-C30)aryl, a substituted or unsubstituted 5- to 30-membered heteroaryl, —NR₁₁R₁₂—, —SiR₁₃R₁₄R₁₅—; or are linked to an adjacent substituent(s) to form a mono- or polycyclic, (C3-C30)alicyclic or aromatic ring whose carbon atom(s) may be replaced with at least one hetero atom selected from nitrogen, oxygen and sulfur;

X represents —O—, —S—, —N(R₂₂)—, —C(R₂₃R₂₄)— or —Si(R₂₅R₂₆)—;

R₁₁ to R₁₅ and R₂₂ to R₂₆ each independently represent hydrogen, deuterium, a halogen, a substituted or unsubstituted (C1-C30)alkyl, a substituted or unsubstituted (C6-C30)aryl, or a substituted or unsubstituted 5- to 30-membered heteroaryl; or are linked to an adjacent substituent(s) to form a mono- or polycyclic, (C3-C30)alicyclic or aromatic ring whose carbon atom(s) may be replaced with at least one hetero atom selected from nitrogen, oxygen and sulfur;

a and c each independently represent an integer of 0 to 4; where a or c is an integer of 2 or more, each of Ar₁, and each of Ar₂ are same or different; and

b represents an integer of 0 to 2; where b is 2, each of R₂₁ are same or different.

### Effects of the Invention

The organic electroluminescent device comprising the dopant and host combination of the present invention emits yellow-green light; lowers the driving voltage of the device by improving the current characteristic of the device; and improves power efficiency and operational lifespan.

### EMBODIMENTS OF THE INVENTION

Hereinafter, the present invention will be described in detail. However, the following description is intended to explain the invention, and is not meant in any way to restrict the scope of the invention.

The present invention relates to a combination of one or more dopant compounds represented by formula 1, and one or more host compounds represented by formula 2; and an organic electroluminescent device comprising the same.

The dopant compound represented by formula 1 is preferably represented by formula 3 or 4:

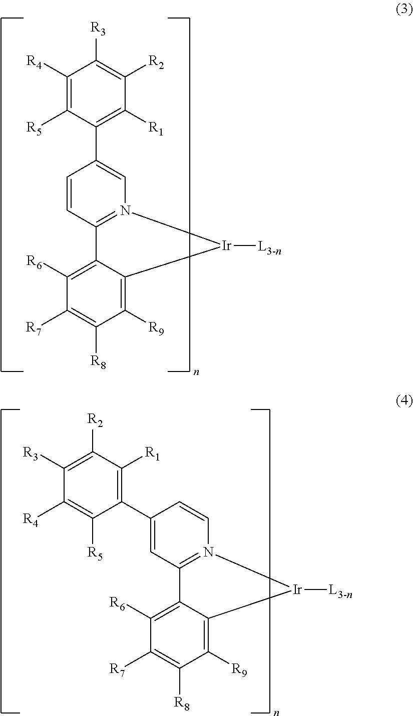

wherein R₁ to R₉, L, and n are as defined in formula 1.

In formulae 1, 3, and 4, R₁ to R₉ preferably each independently represent hydrogen, deuterium, a (C1-C10)alkyl unsubstituted or substituted with a halogen, an unsubstituted (C3-C7)cycloalkyl, or a (C1-C10)alkoxy unsubstituted or substituted with a halogen. R₂₀₁ to R₂₁₁ preferably each independently represent hydrogen, or an unsubstituted (C1-C10)alkyl.

The representative compounds of formula 1 include the following compounds, but are not limited thereto:

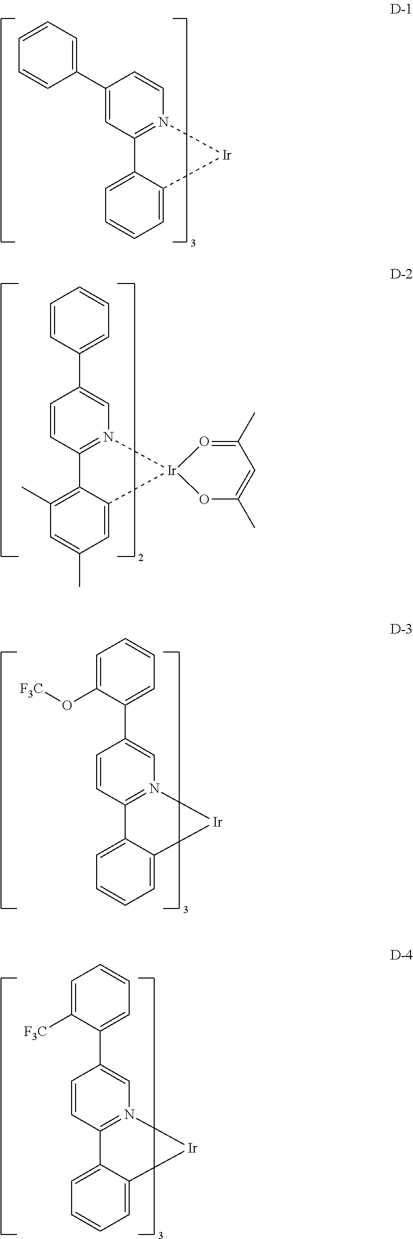

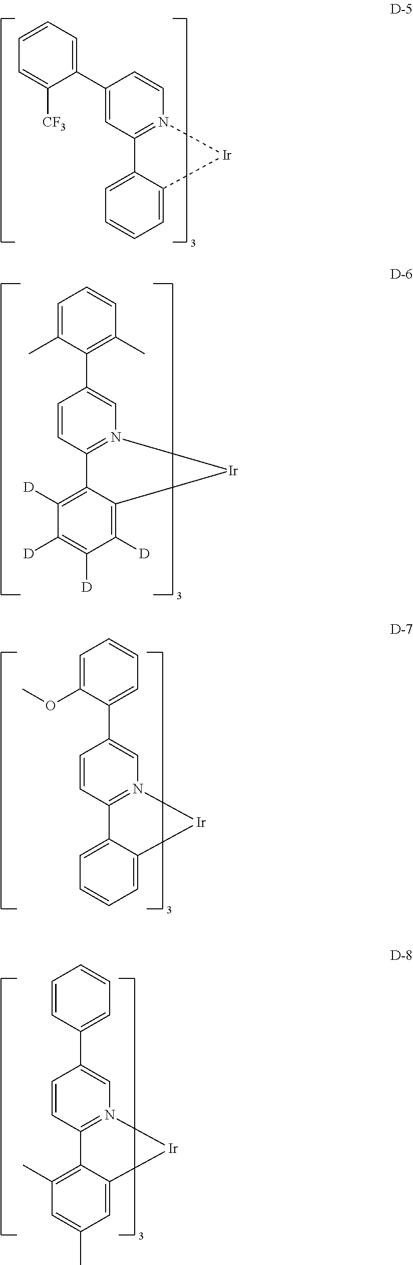

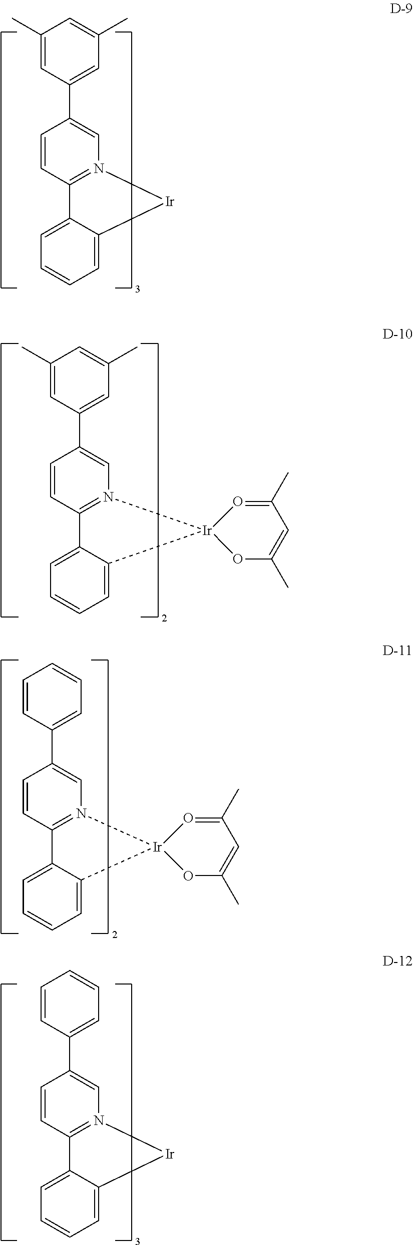

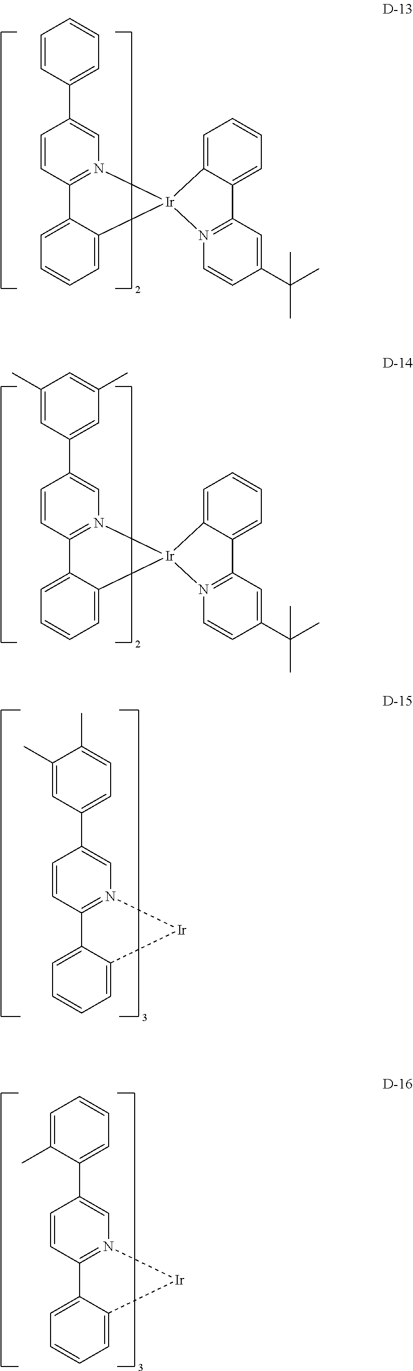

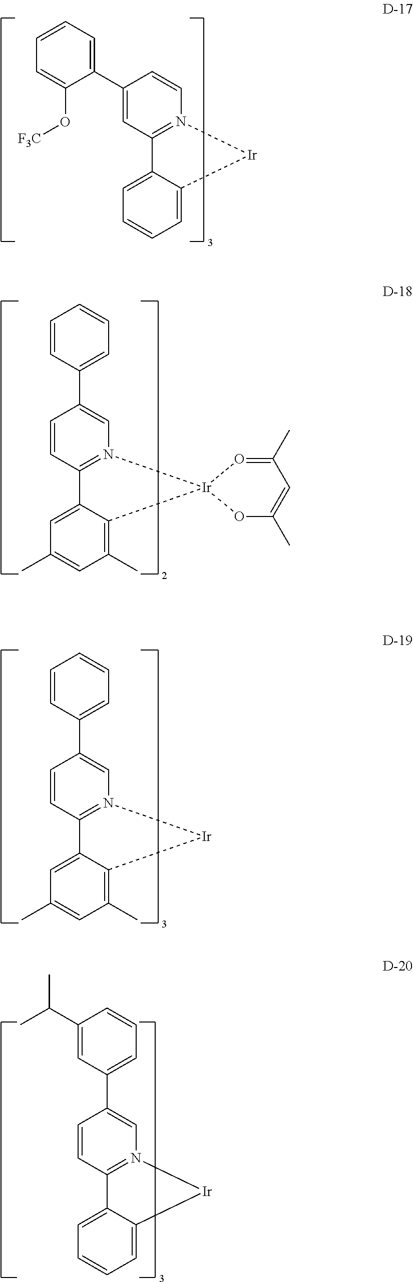

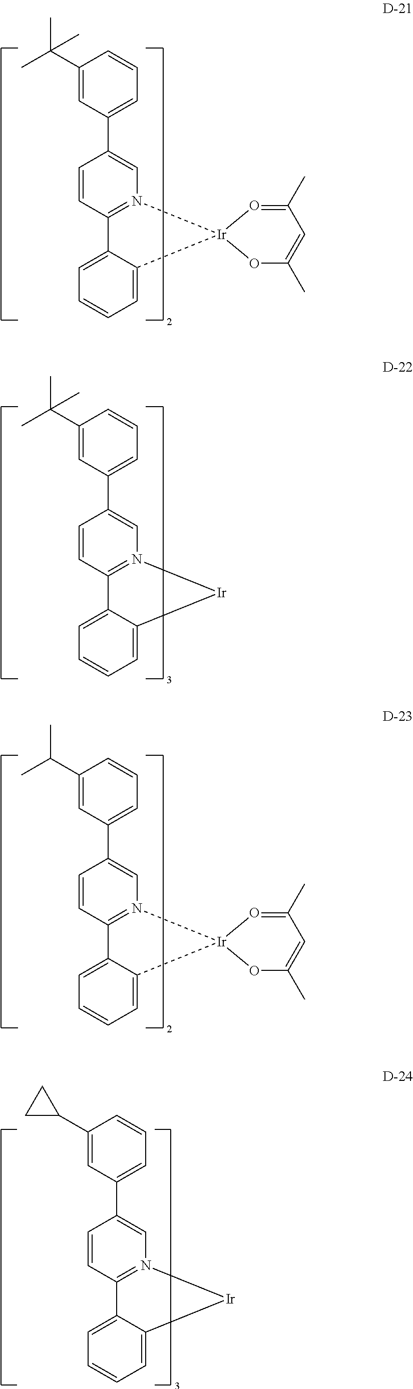

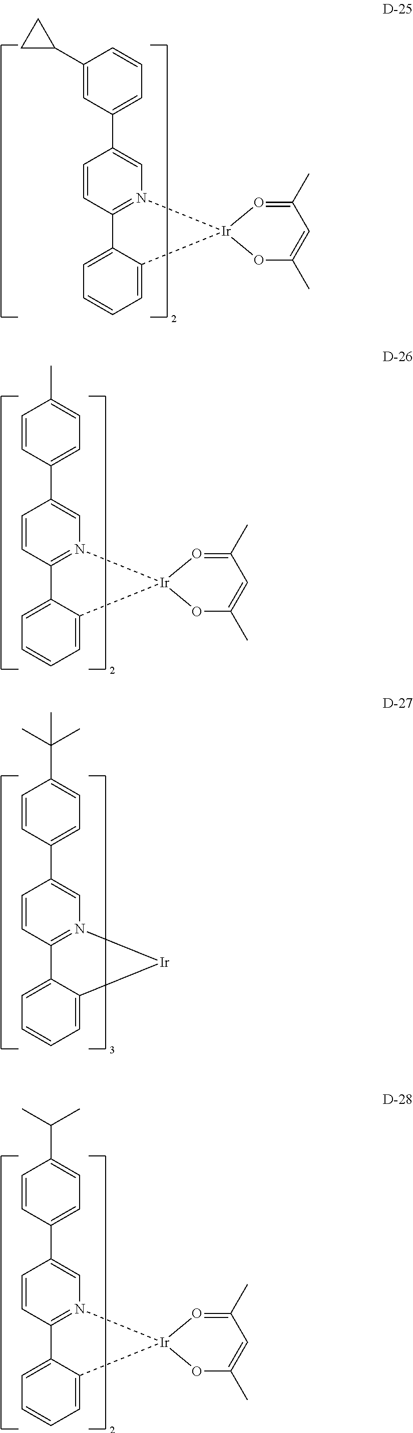

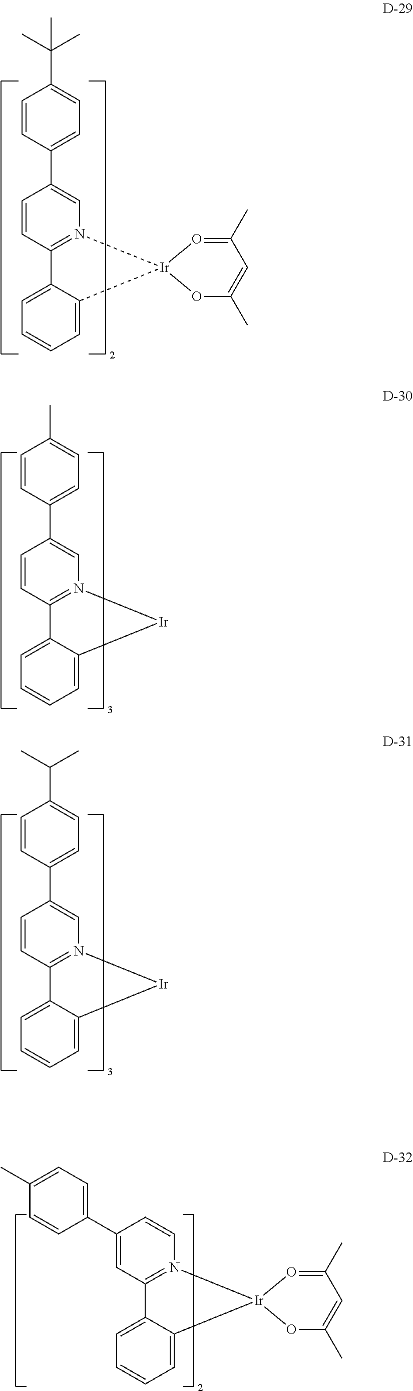

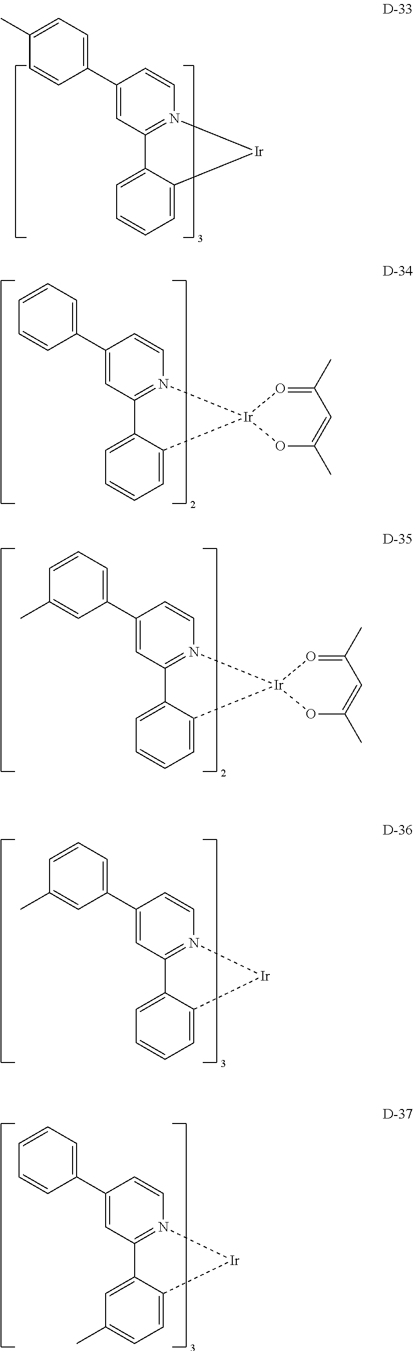

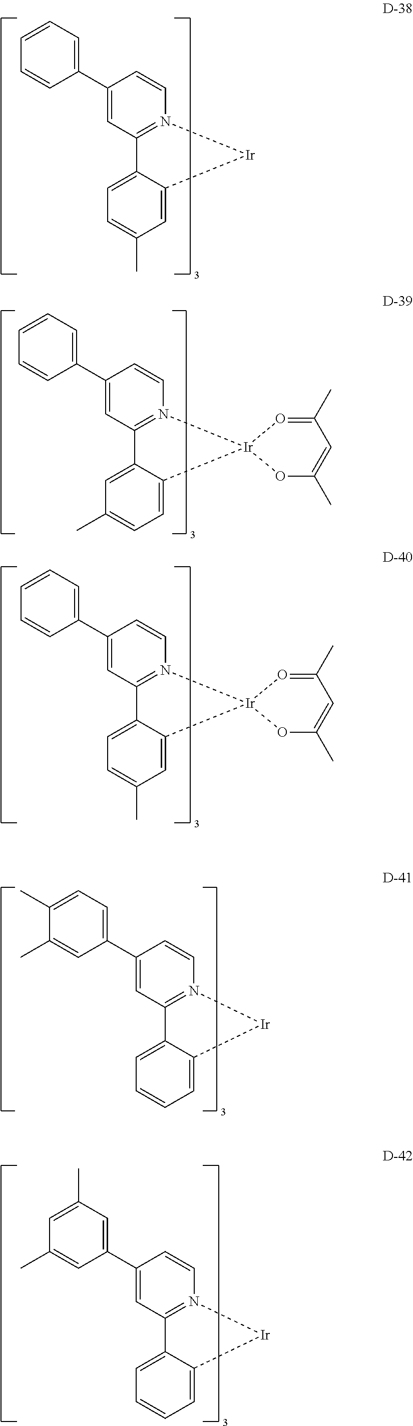

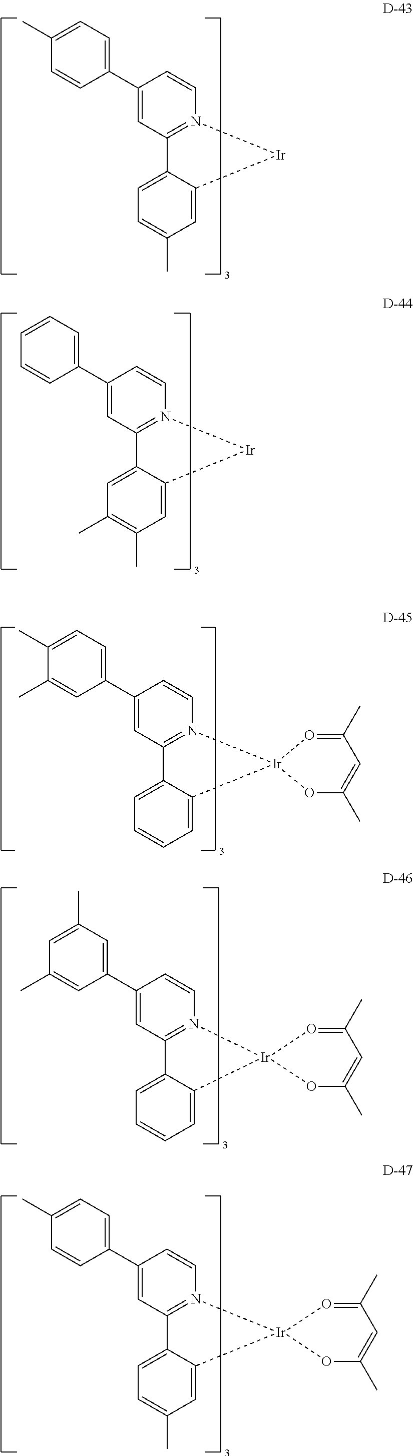

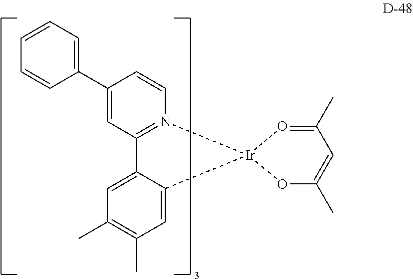

The host compound represented by formula 2 is preferably selected from formulae 5 to 10:

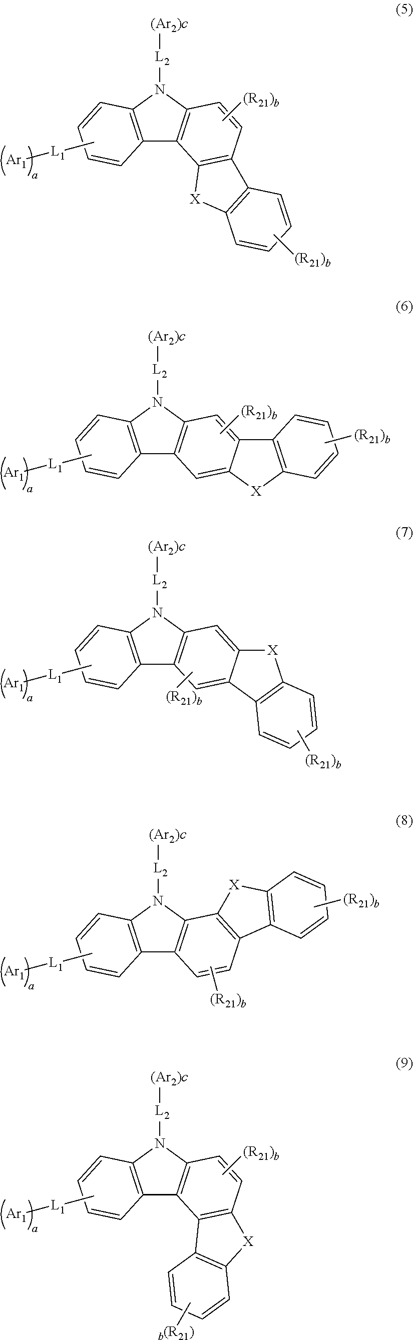

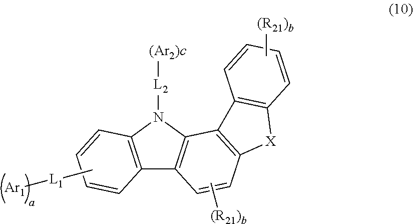

wherein L₁, L₂, Ar₁, Ar₂, R₂₁, X, a, b and c are as defined in formula 2.

In formulae 2, and 5 to 10, L₁ and L₂ each independently represent a single bond, a substituted or unsubstituted (C6-C30)arylene, or a substituted or unsubstituted 5- to 30-membered heteroarylene, preferably each independently represent a single bond, a substituted or unsubstituted (C6-C20)arylene, or a substituted or unsubstituted 5- to 22-membered heteroarylene, and more preferably each independently represent a single bond, a (C6-C20)arylene unsubstituted or substituted with a (C1-C6)alkyl, or an unsubstituted 5- to 22-membered heteroarylene.

Ar₁ and Ar₂ each independently represent hydrogen, deuterium, a halogen, a cyano, a nitro, a hydroxyl, a substituted or unsubstituted (C1-C30)alkyl, a substituted or unsubstituted (C1-C30)alkoxy, a substituted or unsubstituted (C3-C30)cycloalkyl, a substituted or unsubstituted (C6-C30)aryl, a substituted or unsubstituted tri(C1-C30)alkylsilyl, a substituted or unsubstituted tri(C6-C30)arylsilyl, or a substituted or unsubstituted 5- to 30-membered heteroaryl; or are linked to an adjacent substituent(s) to form a mono- or polycyclic, (C3-C30)alicyclic or aromatic ring whose carbon atom(s) may be replaced with at least one hetero atom selected from nitrogen, oxygen and sulfur, preferably each independently represent hydrogen, a substituted or unsubstituted (C1-C6)alkyl, a substituted or unsubstituted (C6-C20)aryl, a substituted or unsubstituted tri(C1-C6)alkylsilyl, a substituted or unsubstituted tri(C6-C12)arylsilyl, or a substituted or unsubstituted 5- to 22-membered heteroaryl, and more preferably each independently represent hydrogen; an unsubstituted (C1-C6)alkyl; a (C6-C20)aryl unsubstituted or substituted with a (C1-C6)alkyl or a (C6-C20)aryl; an unsubstituted tri(C1-C6)alkylsilyl; an unsubstituted tri(C6-C12)arylsilyl; or an unsubstituted 5- to 22-membered heteroaryl.

R₂₁ represents hydrogen, deuterium, a halogen, a substituted or unsubstituted (C1-C30)alkyl, a substituted or unsubstituted (C6-C30)aryl, a substituted or unsubstituted 5- to 30-membered heteroaryl, —NR₁₁R₁₂, —SiR₁₃R₁₄R₁₅; or are linked to an adjacent substituent(s) to form a mono- or polycyclic, (C3-C30)alicyclic or aromatic ring whose carbon atom(s) may be replaced with at least one hetero atom selected from nitrogen, oxygen and sulfur, preferably represents hydrogen, a substituted or unsubstituted (C6-C20)aryl, or a substituted or unsubstituted 5- to 22-membered heteroaryl, and more preferably represents hydrogen; an unsubstituted (C6-C20)aryl; or a 5- to 22-membered heteroaryl unsubstituted or substituted with a (C6-C20)aryl.

X represents —O—, —S—, —N(R₂₂)—, —C(R₂₃)(R₂₄)— or —Si(R₂₅)(R₂₆)—.

R₁₁ to R₁₅ and R₂₂ to R₂₆ each independently represent hydrogen, deuterium, a halogen, a substituted or unsubstituted (C1-C30)alkyl, a substituted or unsubstituted (C6-C30)aryl, or a substituted or unsubstituted 5- to 30-membered heteroaryl; or are linked to an adjacent substituent(s) to form a mono- or polycyclic, (C3-C30)alicyclic or aromatic ring whose carbon atom(s) may be replaced with at least one hetero atom selected from nitrogen, oxygen and sulfur, preferably each independently represent hydrogen, a substituted or unsubstituted (C1-C6)alkyl, a substituted or unsubstituted (C6-C20)aryl, or a substituted or unsubstituted 5- to 22-membered heteroaryl; or are linked to an adjacent substituent(s) to form a mono- or polycyclic, (C3-C30)alicyclic or aromatic ring, and more preferably each independently represent hydrogen; an unsubstituted (C1-C6)alkyl; an unsubstituted (C6-C20)aryl; a 5- to 22-membered heteroaryl unsubstituted or substituted with a (C6-C20)aryl; or are linked to an adjacent substituent(s) to form a mono- or polycyclic, (C3-C30)alicyclic or aromatic ring.

The representative compounds of formula 2 include the following compounds, but are not limited thereto:

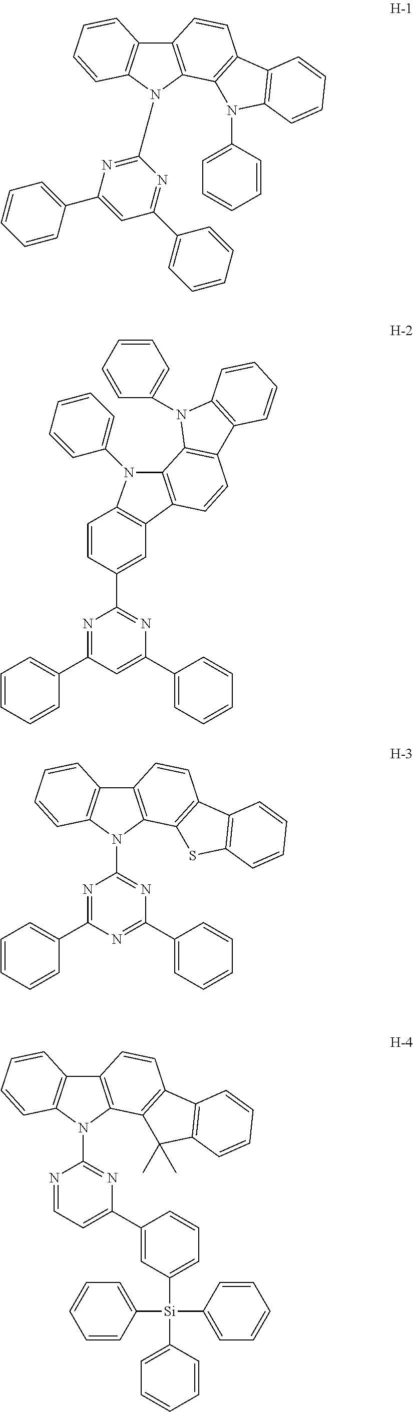 [SMILES: c1ccc(-c2cc(-c3ccccc3)nc(-n3c4ccccc4c4ccc5c6ccccc6n(-c6ccccc6)c5c43)n2)cc1 ; c1ccc(-c2cc(-c3ccccc3)nc(-c3ccc4c(c3)c3ccc5c6ccccc6n(-c6ccccc6)c5c3n4-c3ccccc3)n2)cc1 ; c1ccc(-c2nc(-c3ccccc3)nc(-n3c4ccccc4c4ccc5c6ccccc6sc5c43)n2)cc1 ; CC1(C)c2ccccc2-c2ccc3c4ccccc4n(-c4nccc(-c5cccc([Si](c6ccccc6)(c6ccccc6)c6ccccc6)c5)n4)c3c21]

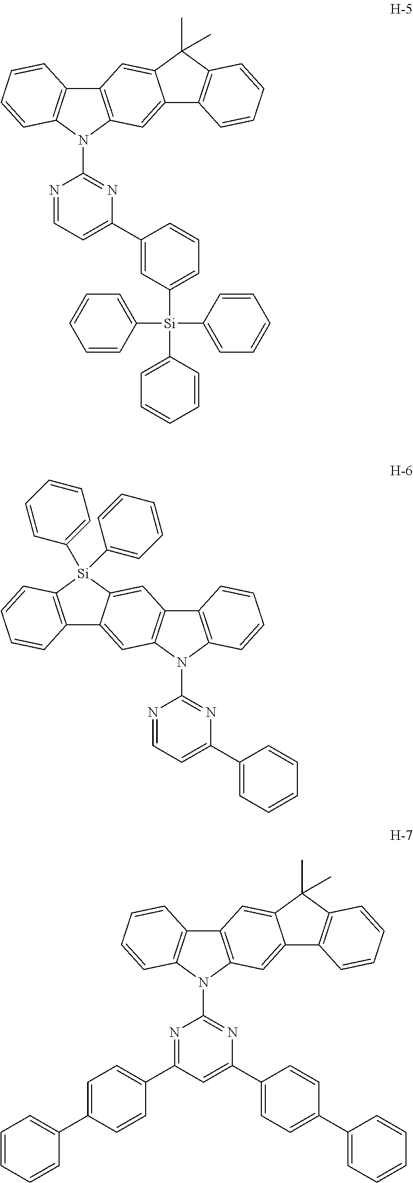 [SMILES: CC1(C)c2ccccc2-c2cc3c(cc21)c1ccccc1n3-c1nccc(-c2cccc([Si](c3ccccc3)(c3ccccc3)c3ccccc3)c2)n1 ; c1ccc(-c2ccnc(-n3c4ccccc4c4cc5c(cc43)-c3ccccc3[Si]5(c3ccccc3)c3ccccc3)n2)cc1 ; CC1(C)c2ccccc2-c2cc3c(cc21)c1ccccc1n3-c1nc(-c2ccc(-c3ccccc3)cc2)cc(-c2ccc(-c3ccccc3)cc2)n1]

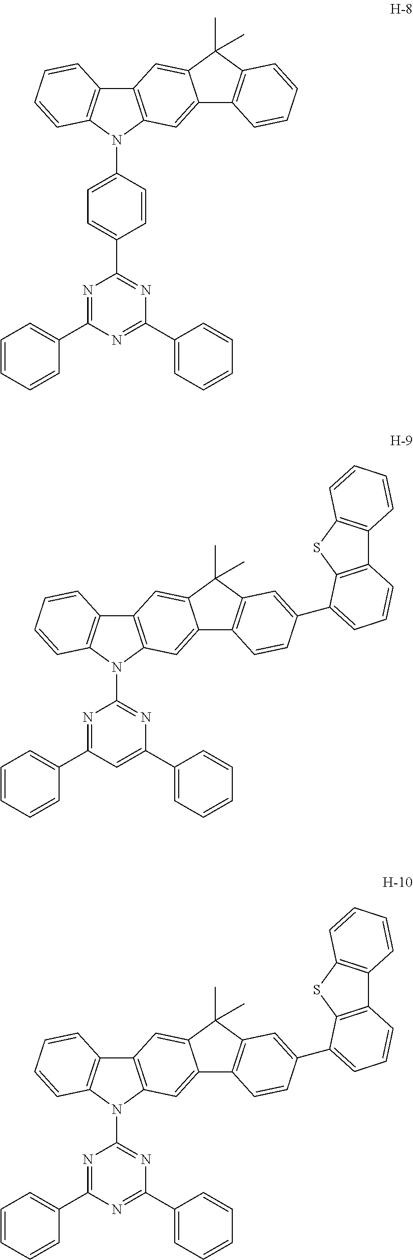 [SMILES: CC1(C)c2ccccc2-c2cc3c(cc21)c1ccccc1n3-c1ccc(-c2nc(-c3ccccc3)nc(-c3ccccc3)n2)cc1 ; CC1(C)c2cc(-c3cccc4c3sc3ccccc34)ccc2-c2cc3c(cc21)c1ccccc1n3-c1nc(-c2ccccc2)cc(-c2ccccc2)n1 ; CC1(C)c2cc(-c3cccc4c3sc3ccccc34)ccc2-c2cc3c(cc21)c1ccccc1n3-c1nc(-c2ccccc2)nc(-c2ccccc2)n1]

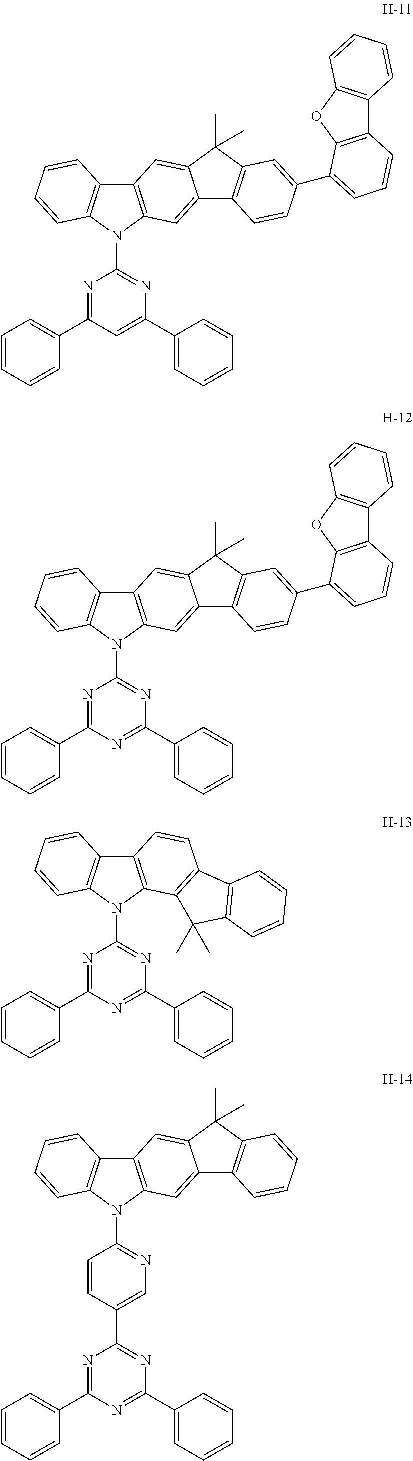

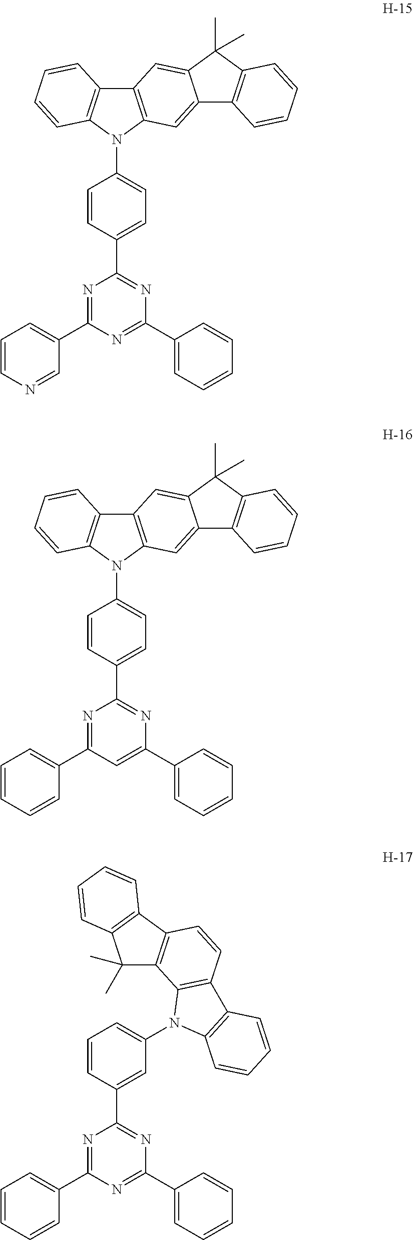 [SMILES: CC1(C)c2ccccc2-c2cc3c(cc21)c1ccccc1n3-c1ccc(-c2nc(-c3ccccc3)nc(-c3cccnc3)n2)cc1 ; CC1(C)c2ccccc2-c2cc3c(cc21)c1ccccc1n3-c1ccc(-c2nc(-c3ccccc3)cc(-c3ccccc3)n2)cc1 ; CC1(C)c2ccccc2-c2ccc3c4ccccc4n(-c4cccc(-c5nc(-c6ccccc6)nc(-c6ccccc6)n5)c4)c3c21]

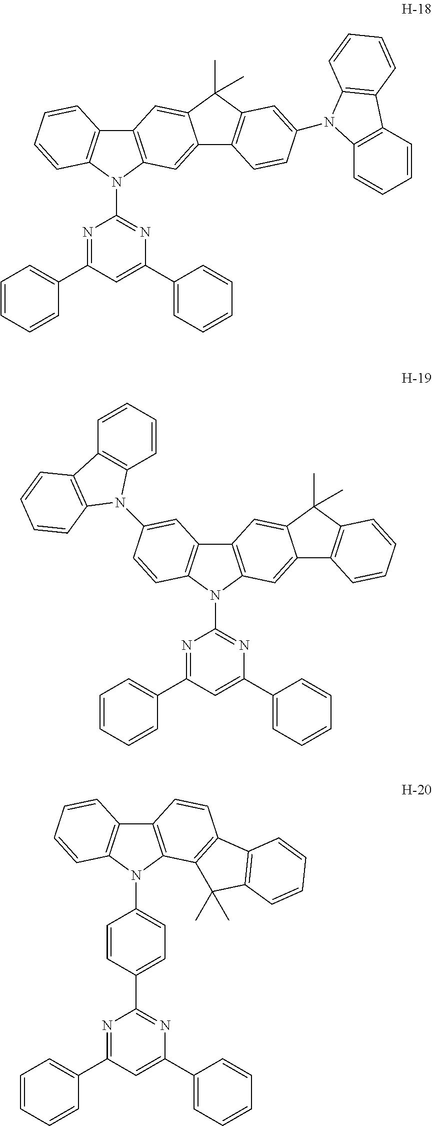 [SMILES: CC1(C)c2cc(-n3c4ccccc4c4ccccc43)ccc2-c2cc3c(cc21)c1ccccc1n3-c1nc(-c2ccccc2)cc(-c2ccccc2)n1 ; CC1(C)c2ccccc2-c2cc3c(cc21)c1cc(-n2c4ccccc4c4ccccc42)ccc1n3-c1nc(-c2ccccc2)cc(-c2ccccc2)n1 ; CC1(C)c2ccccc2-c2ccc3c4ccccc4n(-c4ccc(-c5nc(-c6ccccc6)cc(-c6ccccc6)n5)cc4)c3c21]

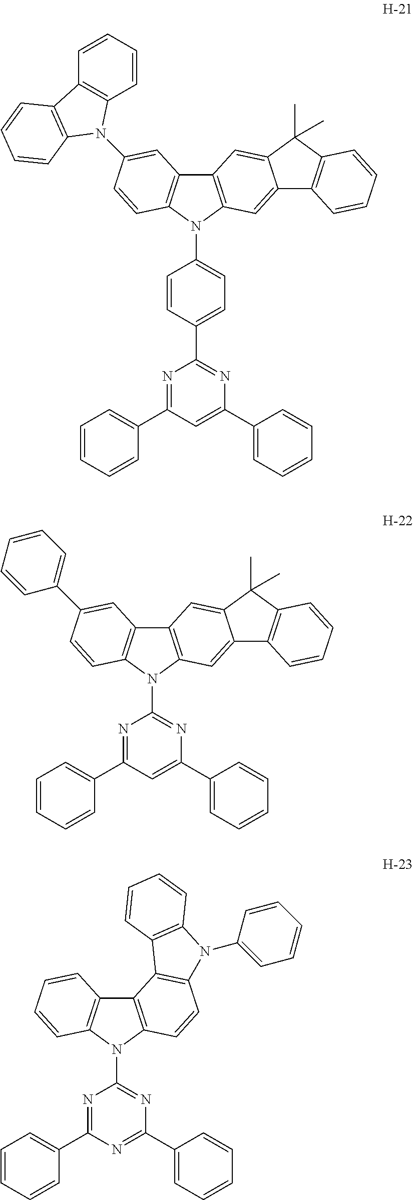 [SMILES: CC1(C)c2ccccc2-c2cc3c(cc21)c1cc(-n2c4ccccc4c4ccccc42)ccc1n3-c1ccc(-c2nc(-c3ccccc3)cc(-c3ccccc3)n2)cc1 ; CC1(C)c2ccccc2-c2cc3c(cc21)c1cc(-c2ccccc2)ccc1n3-c1nc(-c2ccccc2)cc(-c2ccccc2)n1 ; c1ccc(-c2nc(-c3ccccc3)nc(-n3c4ccccc4c4c5c6ccccc6n(-c6ccccc6)c5ccc43)n2)cc1]

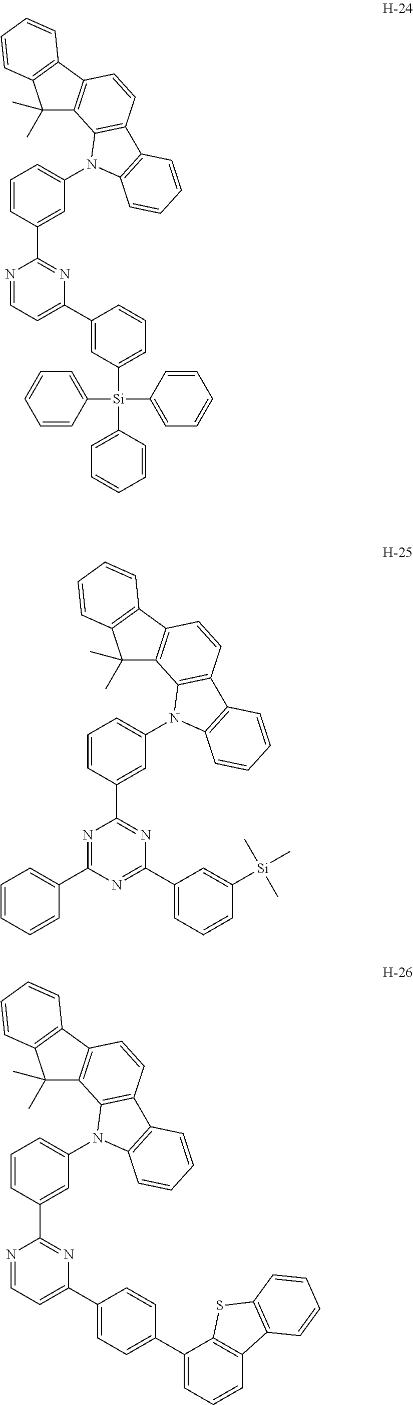 [SMILES: CC1(C)c2ccccc2-c2ccc3c4ccccc4n(-c4cccc(-c5nccc(-c6cccc([Si](c7ccccc7)(c7ccccc7)c7ccccc7)c6)n5)c4)c3c21 ; CC1(C)c2ccccc2-c2ccc3c4ccccc4n(-c4cccc(-c5nc(-c6ccccc6)nc(-c6cccc([Si](C)(C)C)c6)n5)c4)c3c21 ; CC1(C)c2ccccc2-c2ccc3c4ccccc4n(-c4cccc(-c5nccc(-c6ccc(-c7cccc8c7sc7ccccc78)cc6)n5)c4)c3c21]

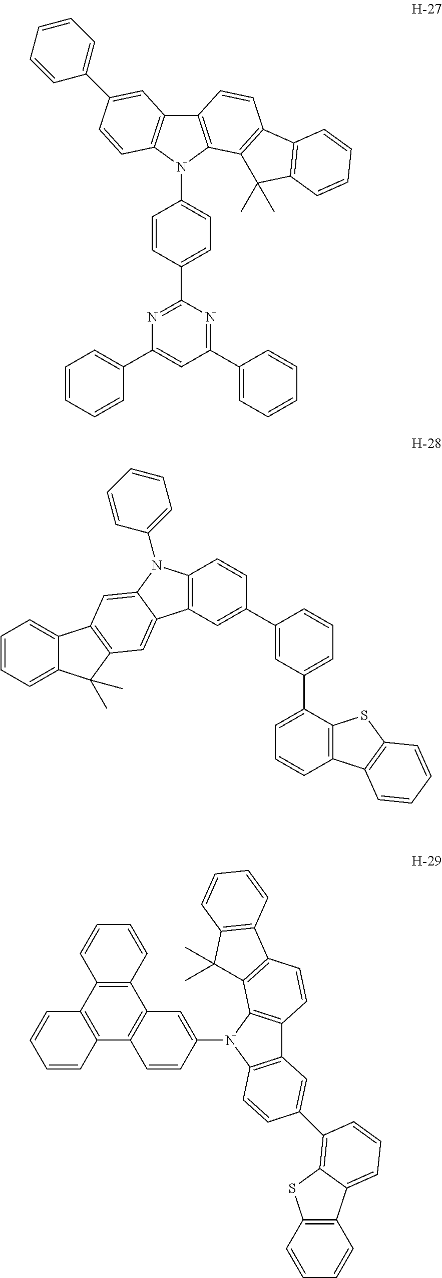 [SMILES: CC1(C)c2ccccc2-c2ccc3c4cc(-c5ccccc5)ccc4n(-c4ccc(-c5nc(-c6ccccc6)cc(-c6ccccc6)n5)cc4)c3c21 ; CC1(C)c2ccccc2-c2cc3c(cc21)c1cc(-c2cccc(-c4cccc5c4sc4ccccc45)c2)ccc1n3-c1ccccc1 ; CC1(C)c2ccccc2-c2ccc3c4cc(-c5cccc6c5sc5ccccc56)ccc4n(-c4ccc5c6ccccc6c6ccccc6c5c4)c3c21]

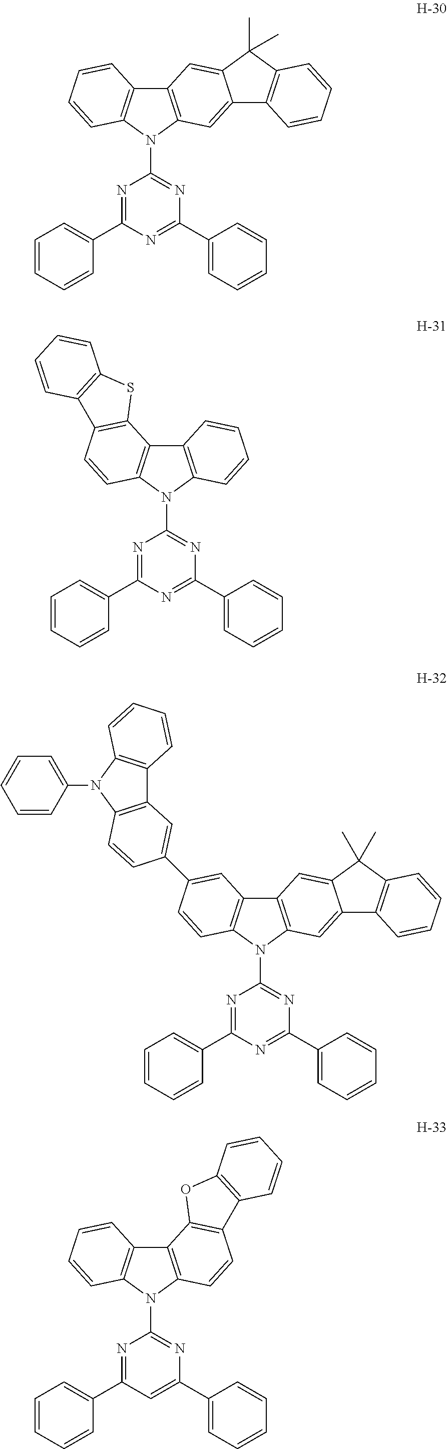

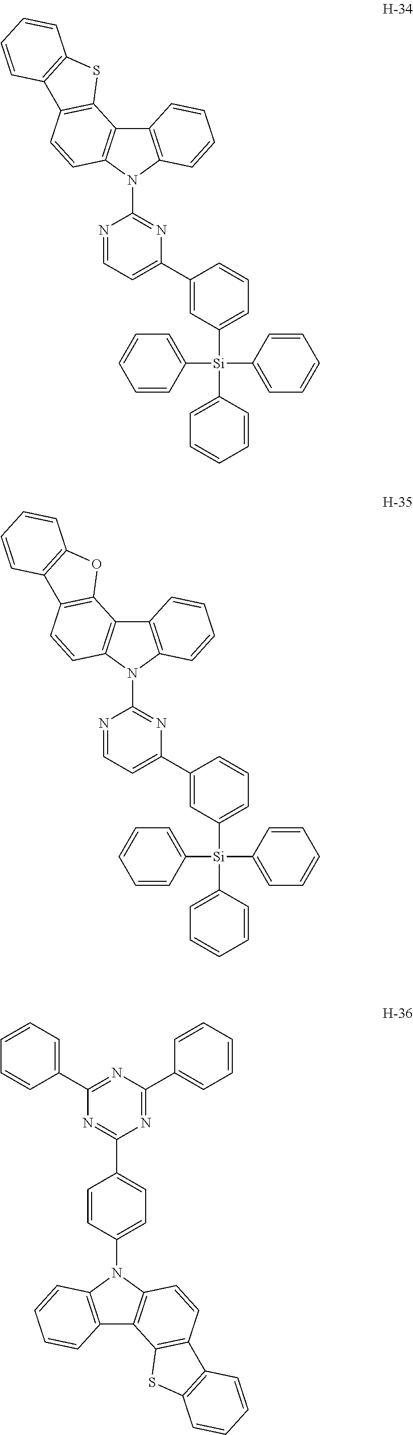 [SMILES: c1ccc([Si](c2ccccc2)(c2ccccc2)c2cccc(-c3ccnc(-n4c5ccccc5c5c6sc7ccccc7c6ccc54)n3)c2)cc1 ; c1ccc([Si](c2ccccc2)(c2ccccc2)c2cccc(-c3ccnc(-n4c5ccccc5c5c6oc7ccccc7c6ccc54)n3)c2)cc1 ; c1ccc(-c2nc(-c3ccccc3)nc(-c3ccc(-n4c5ccccc5c5c6sc7ccccc7c6ccc54)cc3)n2)cc1]

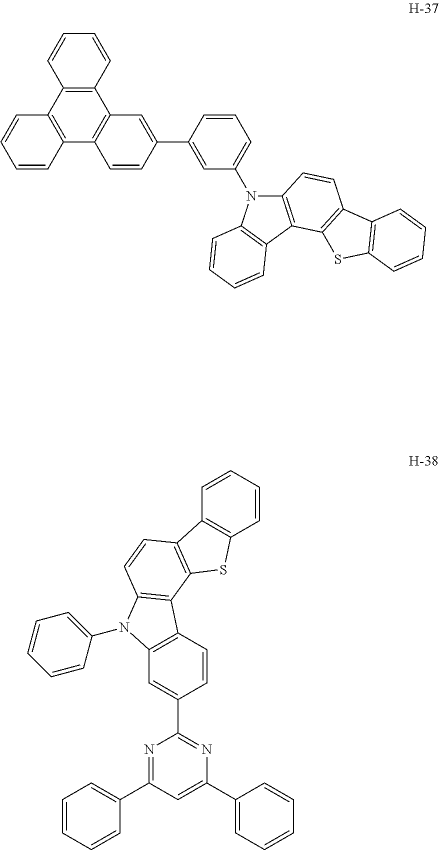 [SMILES: c1cc(-c2ccc3c4ccccc4c4ccccc4c3c2)cc(-n2c3ccccc3c3c4sc5ccccc5c4ccc32)c1 ; c1ccc(-c2cc(-c3ccccc3)nc(-c3ccc4c5c6sc7ccccc7c6ccc5n(-c5ccccc5)c4c3)n2)cc1]

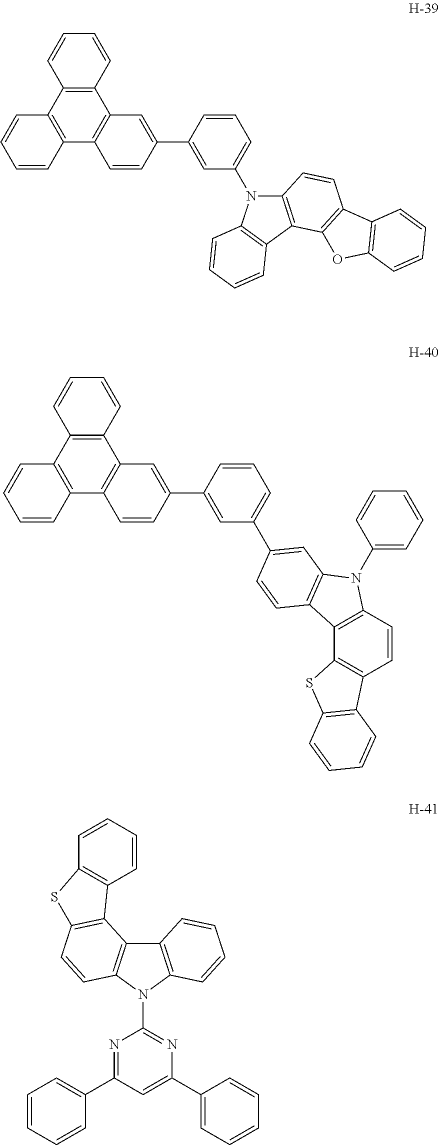 [SMILES: c1cc(-c2ccc3c4ccccc4c4ccccc4c3c2)cc(-n2c3ccccc3c3c4oc5ccccc5c4ccc32)c1 ; c1ccc(-n2c3cc(-c4cccc(-c5ccc6c7ccccc7c7ccccc7c6c5)c4)ccc3c3c4sc5ccccc5c4ccc32)cc1 ; c1ccc(-c2cc(-c3ccccc3)nc(-n3c4ccccc4c4c5c(ccc43)sc3ccccc35)n2)cc1]

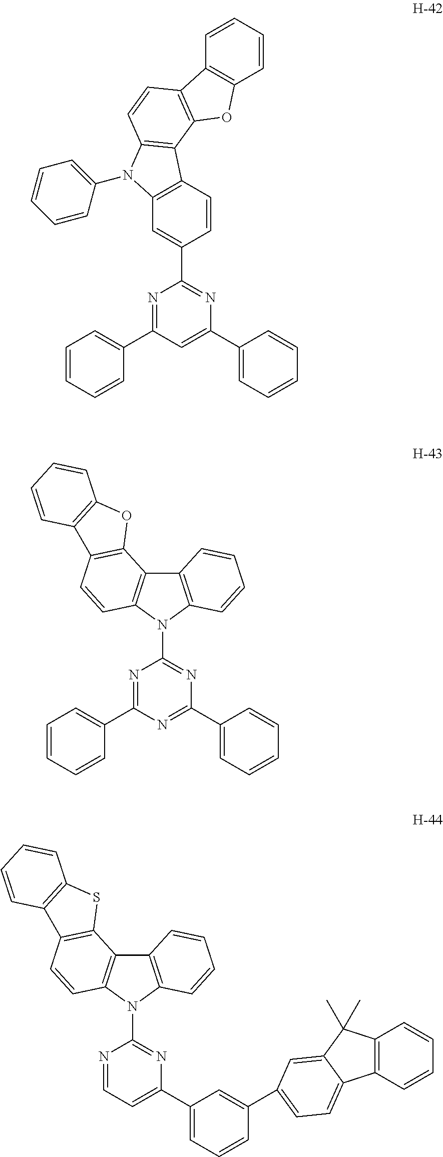 [SMILES: c1ccc(-c2cc(-c3ccccc3)nc(-c3ccc4c5c6oc7ccccc7c6ccc5n(-c5ccccc5)c4c3)n2)cc1 ; c1ccc(-c2nc(-c3ccccc3)nc(-n3c4ccccc4c4c5oc6ccccc6c5ccc43)n2)cc1 ; CC1(C)c2ccccc2-c2ccc(-c3cccc(-c4ccnc(-n5c6ccccc6c6c7sc8ccccc8c7ccc65)n4)c3)cc21]

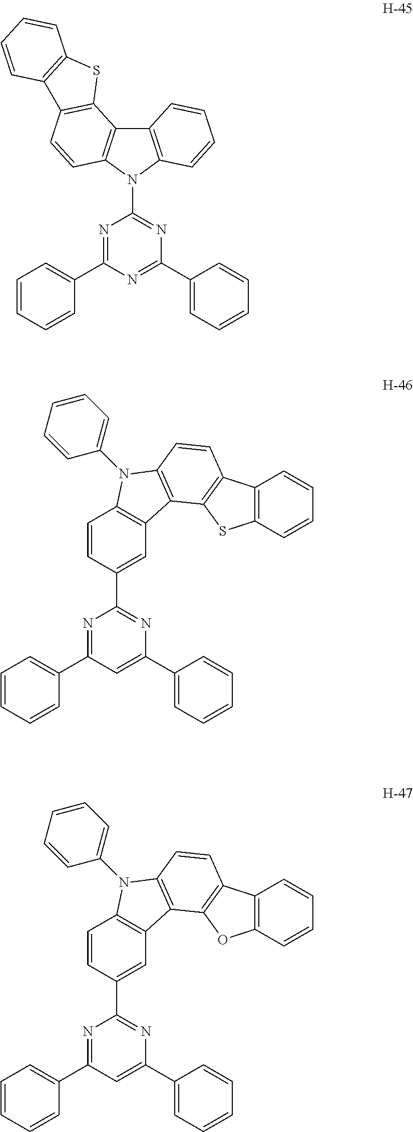 [SMILES: c1ccc(-c2nc(-c3ccccc3)nc(-n3c4ccccc4c4c5sc6ccccc6c5ccc43)n2)cc1 ; c1ccc(-c2cc(-c3ccccc3)nc(-c3ccc4c(c3)c3c5sc6ccccc6c5ccc3n4-c3ccccc3)n2)cc1 ; c1ccc(-c2cc(-c3ccccc3)nc(-c3ccc4c(c3)c3c5oc6ccccc6c5ccc3n4-c3ccccc3)n2)cc1]

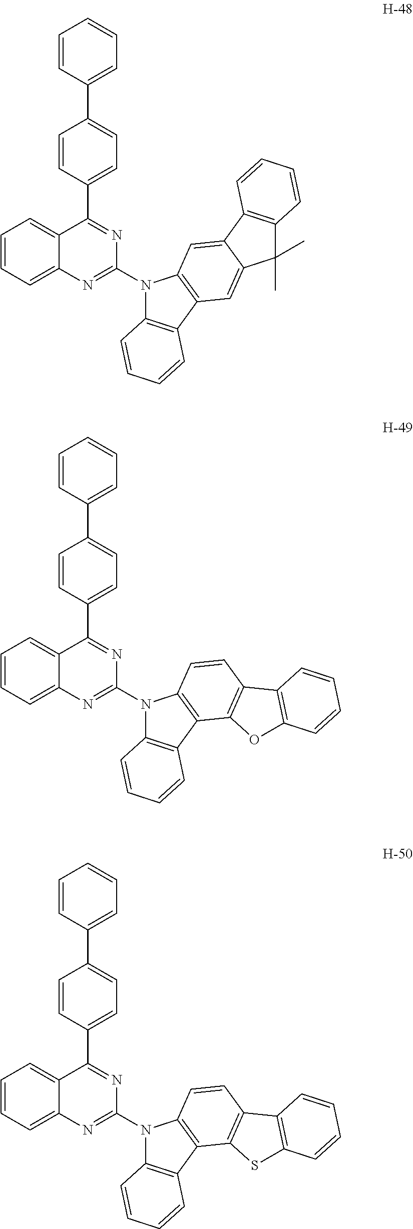 [SMILES: CC1(C)c2ccccc2-c2cc3c(cc21)c1ccccc1n3-c1nc(-c2ccc(-c3ccccc3)cc2)c2ccccc2n1 ; c1ccc(-c2ccc(-c3nc(-n4c5ccccc5c5c6oc7ccccc7c6ccc54)nc4ccccc34)cc2)cc1 ; c1ccc(-c2ccc(-c3nc(-n4c5ccccc5c5c6sc7ccccc7c6ccc54)nc4ccccc34)cc2)cc1]

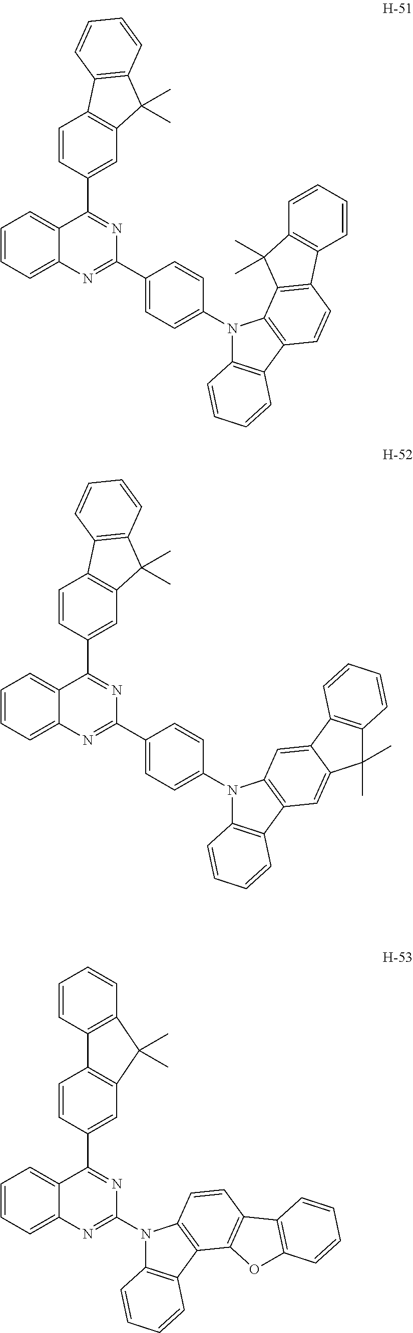 [SMILES: CC1(C)c2ccccc2-c2ccc(-c3nc(-c4ccc(-n5c6ccccc6c6ccc7c(c65)C(C)(C)c5ccccc5-7)cc4)nc4ccccc34)cc21 ; CC1(C)c2ccccc2-c2ccc(-c3nc(-c4ccc(-n5c6ccccc6c6cc7c(cc65)-c5ccccc5C7(C)C)cc4)nc4ccccc34)cc21 ; CC1(C)c2ccccc2-c2ccc(-c3nc(-n4c5ccccc5c5c6oc7ccccc7c6ccc54)nc4ccccc34)cc21]

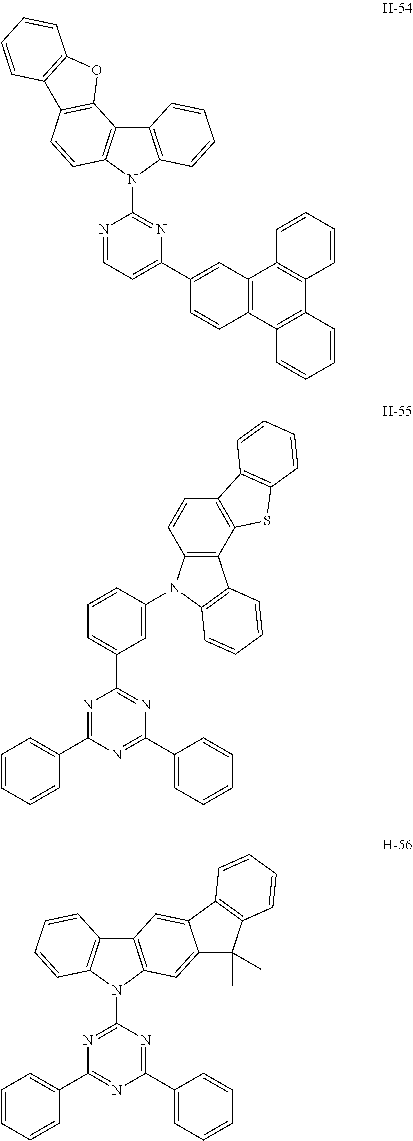 [SMILES: c1ccc2c(c1)oc1c2ccc2c1c1ccccc1n2-c1nccc(-c2ccc3c4ccccc4c4ccccc4c3c2)n1 ; c1ccc(-c2nc(-c3ccccc3)nc(-c3cccc(-n4c5ccccc5c5c6sc7ccccc7c6ccc54)c3)n2)cc1 ; CC1(C)c2ccccc2-c2cc3c4ccccc4n(-c4nc(-c5ccccc5)nc(-c5ccccc5)n4)c3cc21]

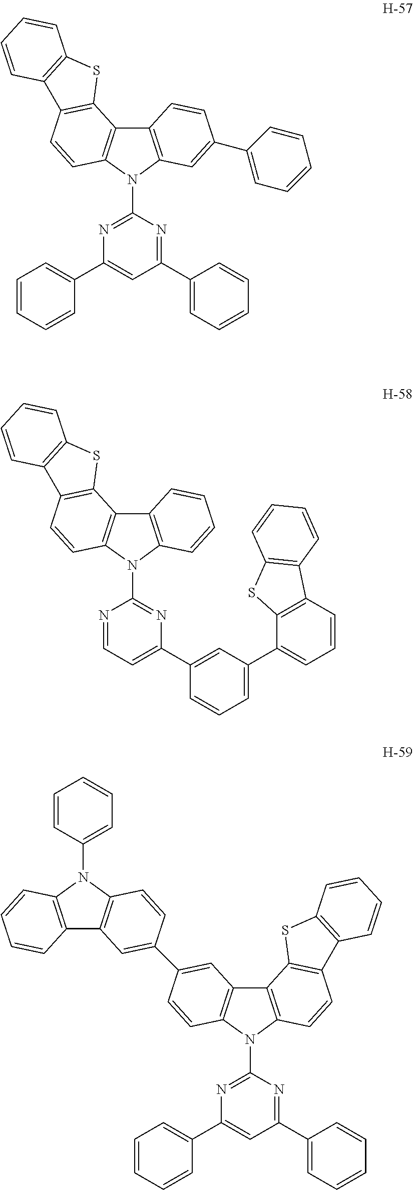 [SMILES: c1ccc(-c2ccc3c4c5sc6ccccc6c5ccc4n(-c4nc(-c5ccccc5)cc(-c5ccccc5)n4)c3c2)cc1 ; c1cc(-c2ccnc(-n3c4ccccc4c4c5sc6ccccc6c5ccc43)n2)cc(-c2cccc3c2sc2ccccc23)c1 ; c1ccc(-c2cc(-c3ccccc3)nc(-n3c4ccc(-c5ccc6c(c5)c5ccccc5n6-c5ccccc5)cc4c4c5sc6ccccc6c5ccc43)n2)cc1]

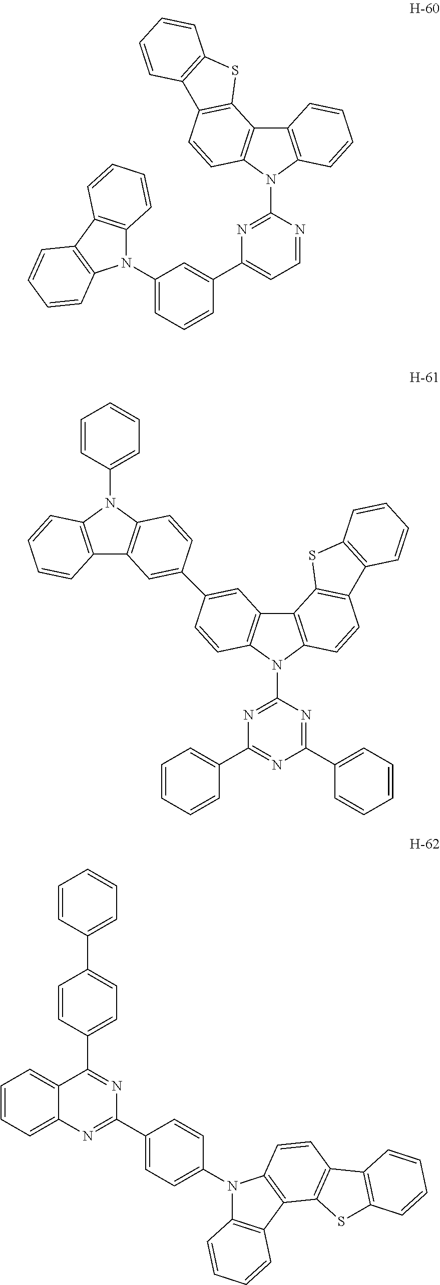 [SMILES: c1cc(-c2ccnc(-n3c4ccccc4c4c5sc6ccccc6c5ccc43)n2)cc(-n2c3ccccc3c3ccccc32)c1 ; c1ccc(-c2nc(-c3ccccc3)nc(-n3c4ccc(-c5ccc6c(c5)c5ccccc5n6-c5ccccc5)cc4c4c5sc6ccccc6c5ccc43)n2)cc1 ; c1ccc(-c2ccc(-c3nc(-c4ccc(-n5c6ccccc6c6c7sc8ccccc8c7ccc65)cc4)nc4ccccc34)cc2)cc1]

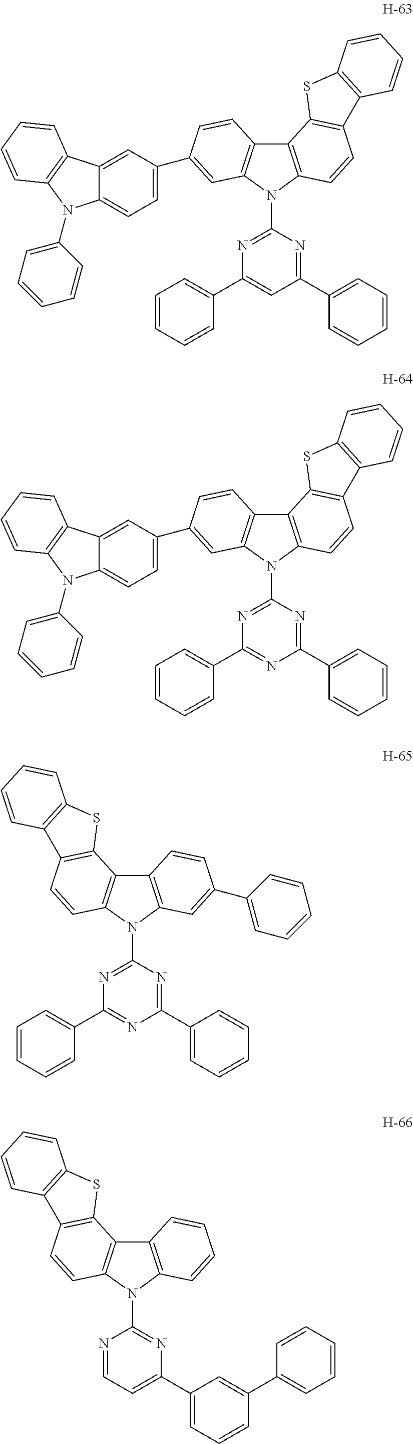 [SMILES: c1ccc(-c2cc(-c3ccccc3)nc(-n3c4cc(-c5ccc6c(c5)c5ccccc5n6-c5ccccc5)ccc4c4c5sc6ccccc6c5ccc43)n2)cc1 ; c1ccc(-c2nc(-c3ccccc3)nc(-n3c4cc(-c5ccc6c(c5)c5ccccc5n6-c5ccccc5)ccc4c4c5sc6ccccc6c5ccc43)n2)cc1 ; c1ccc(-c2ccc3c4c5sc6ccccc6c5ccc4n(-c4nc(-c5ccccc5)nc(-c5ccccc5)n4)c3c2)cc1 ; c1ccc(-c2cccc(-c3ccnc(-n4c5ccccc5c5c6sc7ccccc7c6ccc54)n3)c2)cc1]

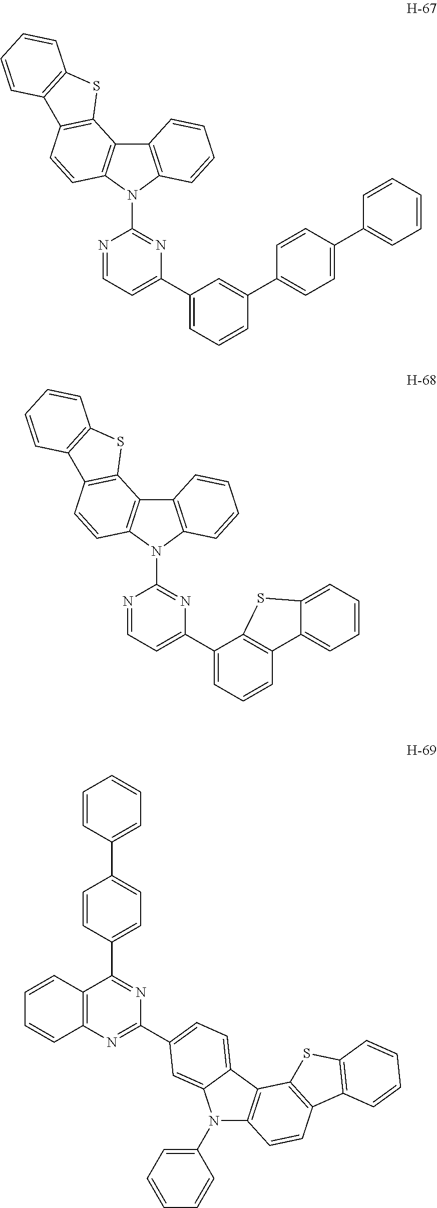 [SMILES: c1ccc(-c2ccc(-c3cccc(-c4ccnc(-n5c6ccccc6c6c7sc8ccccc8c7ccc65)n4)c3)cc2)cc1 ; c1ccc2c(c1)sc1c(-c3ccnc(-n4c5ccccc5c5c6sc7ccccc7c6ccc54)n3)cccc12 ; c1ccc(-c2ccc(-c3nc(-c4ccc5c6c7sc8ccccc8c7ccc6n(-c6ccccc6)c5c4)nc4ccccc34)cc2)cc1]

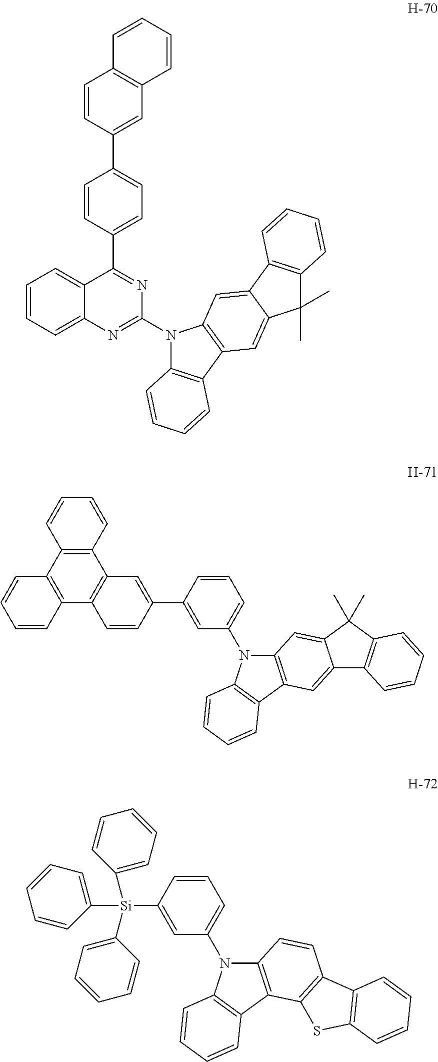 [SMILES: CC1(C)c2ccccc2-c2cc3c(cc21)c1ccccc1n3-c1nc(-c2ccc(-c3ccc4ccccc4c3)cc2)c2ccccc2n1 ; CC1(C)c2ccccc2-c2cc3c4ccccc4n(-c4cccc(-c5ccc6c7ccccc7c7ccccc7c6c5)c4)c3cc21 ; c1ccc([Si](c2ccccc2)(c2ccccc2)c2cccc(-n3c4ccccc4c4c5sc6ccccc6c5ccc43)c2)cc1]

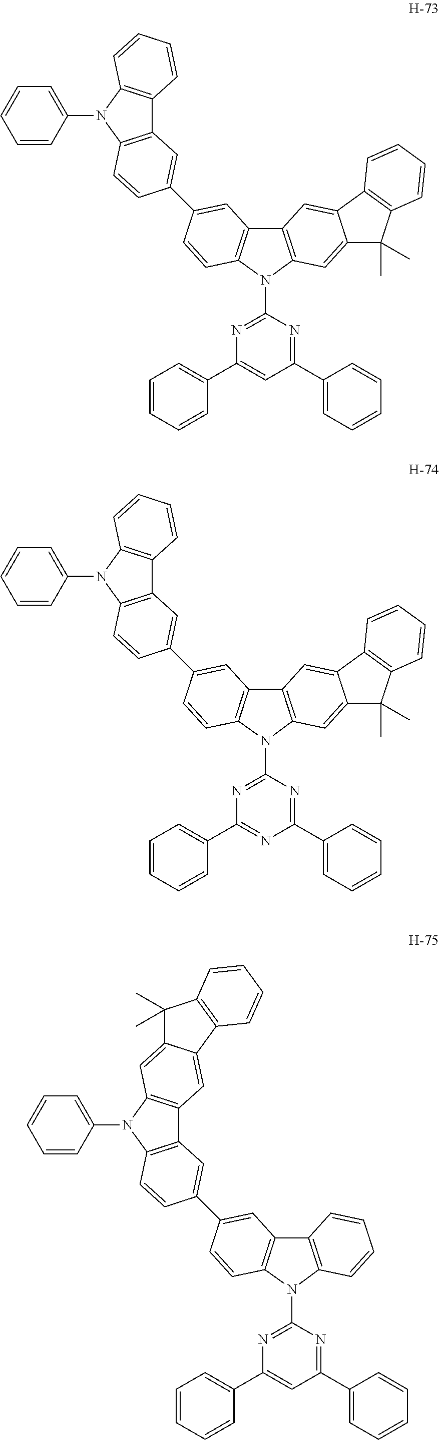 [SMILES: CC1(C)c2ccccc2-c2cc3c4cc(-c5ccc6c(c5)c5ccccc5n6-c5ccccc5)ccc4n(-c4nc(-c5ccccc5)cc(-c5ccccc5)n4)c3cc21 ; CC1(C)c2ccccc2-c2cc3c4cc(-c5ccc6c(c5)c5ccccc5n6-c5ccccc5)ccc4n(-c4nc(-c5ccccc5)nc(-c5ccccc5)n4)c3cc21 ; CC1(C)c2ccccc2-c2cc3c4cc(-c5ccc6c(c5)c5ccccc5n6-c5nc(-c6ccccc6)cc(-c6ccccc6)n5)ccc4n(-c4ccccc4)c3cc21]

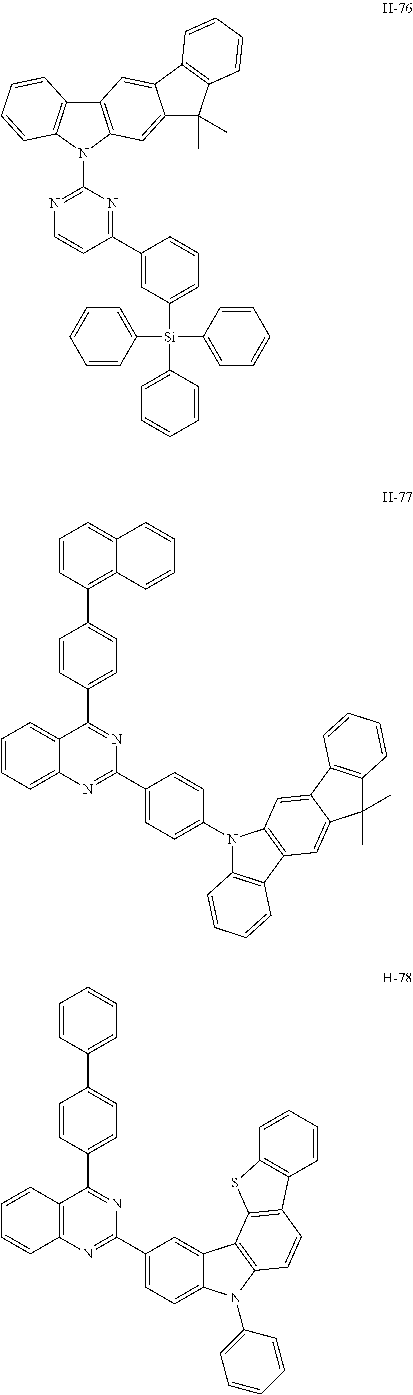 [SMILES: CC1(C)c2ccccc2-c2cc3c4ccccc4n(-c4nccc(-c5cccc([Si](c6ccccc6)(c6ccccc6)c6ccccc6)c5)n4)c3cc21 ; CC1(C)c2ccccc2-c2cc3c(cc21)c1ccccc1n3-c1ccc(-c2nc(-c3ccc(-c4cccc5ccccc45)cc3)c3ccccc3n2)cc1 ; c1ccc(-c2ccc(-c3nc(-c4ccc5c(c4)c4c6sc7ccccc7c6ccc4n5-c4ccccc4)nc4ccccc34)cc2)cc1]

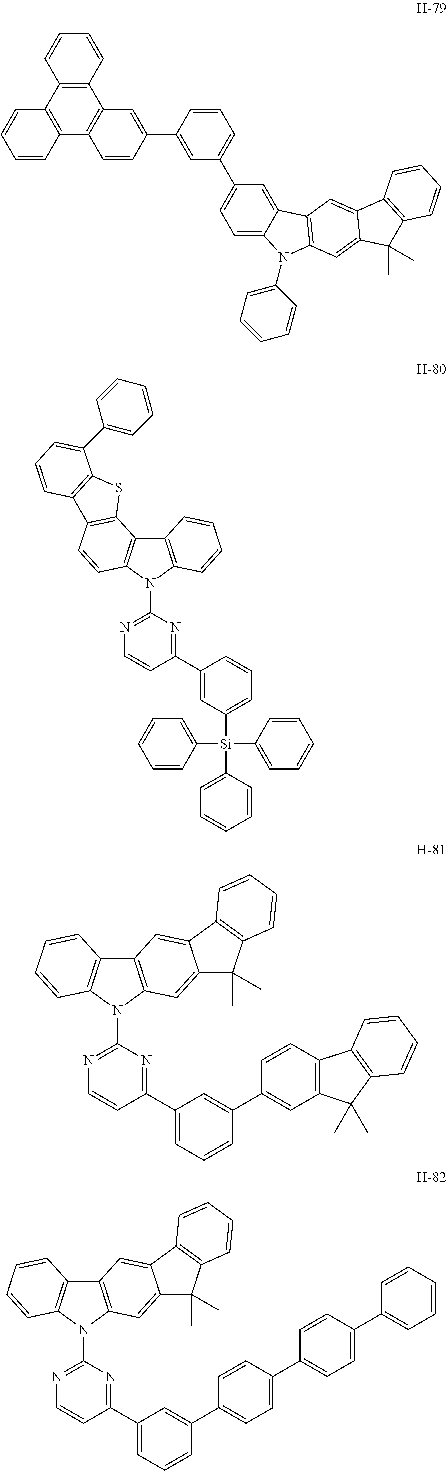 [SMILES: CC1(C)c2ccccc2-c2cc3c4cc(-c5cccc(-c6ccc7c8ccccc8c8ccccc8c7c6)c5)ccc4n(-c4ccccc4)c3cc21 ; c1ccc(-c2cccc3c2sc2c3ccc3c2c2ccccc2n3-c2nccc(-c3cccc([Si](c4ccccc4)(c4ccccc4)c4ccccc4)c3)n2)cc1 ; CC1(C)c2ccccc2-c2ccc(-c3cccc(-c4ccnc(-n5c6ccccc6c6cc7c(cc65)C(C)(C)c5ccccc5-7)n4)c3)cc21 ; CC1(C)c2ccccc2-c2cc3c4ccccc4n(-c4nccc(-c5cccc(-c6ccc(-c7ccc(-c8ccccc8)cc7)cc6)c5)n4)c3cc21]

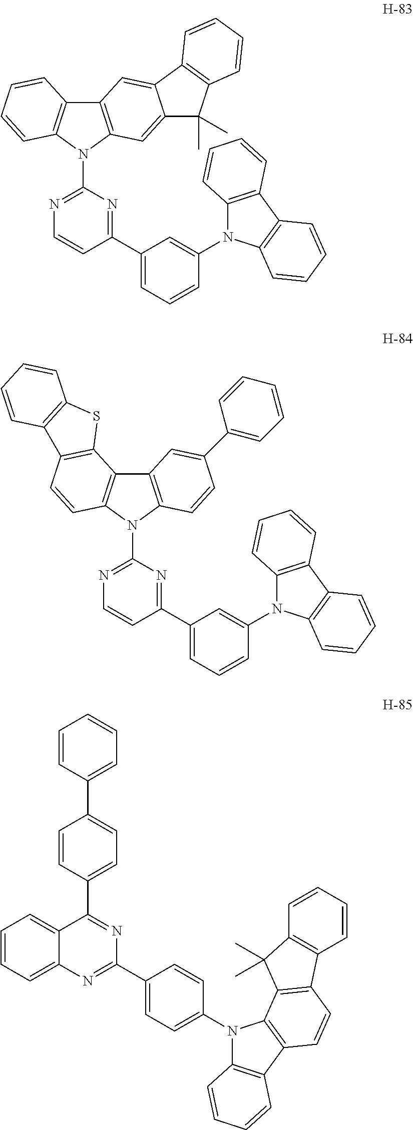 [SMILES: CC1(C)c2ccccc2-c2cc3c4ccccc4n(-c4nccc(-c5cccc(-n6c7ccccc7c7ccccc76)c5)n4)c3cc21 ; c1ccc(-c2ccc3c(c2)c2c4sc5ccccc5c4ccc2n3-c2nccc(-c3cccc(-n4c5ccccc5c5ccccc54)c3)n2)cc1 ; CC1(C)c2ccccc2-c2ccc3c4ccccc4n(-c4ccc(-c5nc(-c6ccc(-c7ccccc7)cc6)c6ccccc6n5)cc4)c3c21]

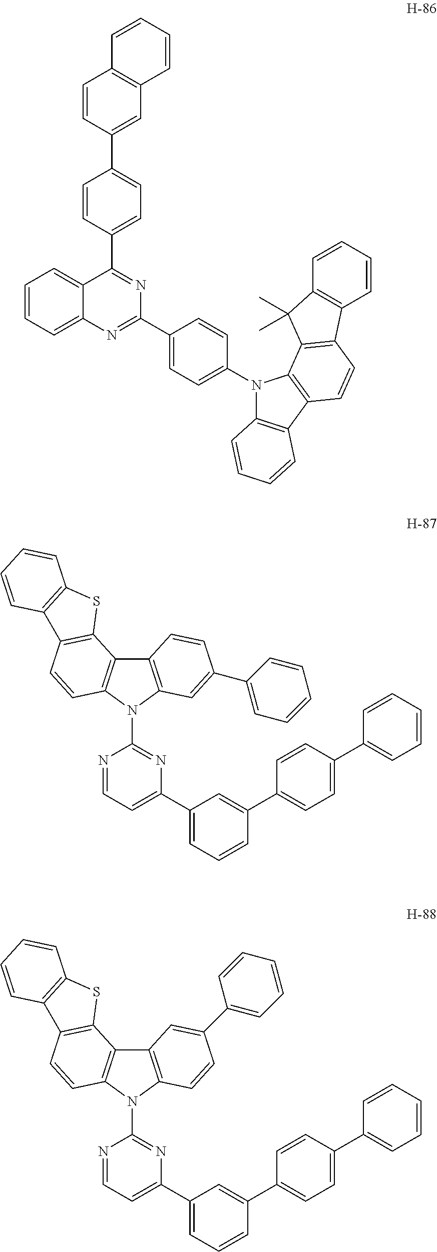 [SMILES: CC1(C)c2ccccc2-c2ccc3c4ccccc4n(-c4ccc(-c5nc(-c6ccc(-c7ccc8ccccc8c7)cc6)c6ccccc6n5)cc4)c3c21 ; c1ccc(-c2ccc(-c3cccc(-c4ccnc(-n5c6cc(-c7ccccc7)ccc6c6c7sc8ccccc8c7ccc65)n4)c3)cc2)cc1 ; c1ccc(-c2ccc(-c3cccc(-c4ccnc(-n5c6ccc(-c7ccccc7)cc6c6c7sc8ccccc8c7ccc65)n4)c3)cc2)cc1]

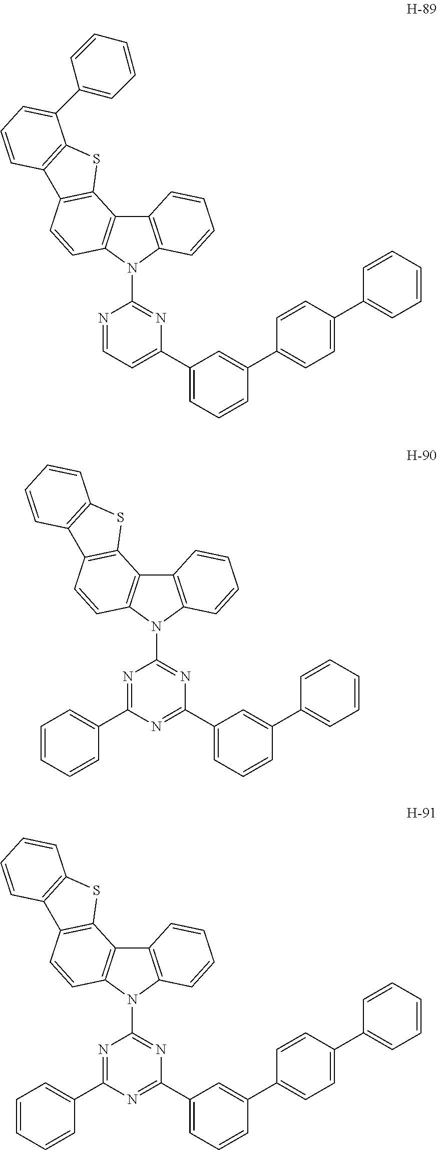 [SMILES: c1ccc(-c2ccc(-c3cccc(-c4ccnc(-n5c6ccccc6c6c7sc8c(-c9ccccc9)cccc8c7ccc65)n4)c3)cc2)cc1 ; c1ccc(-c2cccc(-c3nc(-c4ccccc4)nc(-n4c5ccccc5c5c6sc7ccccc7c6ccc54)n3)c2)cc1 ; c1ccc(-c2ccc(-c3cccc(-c4nc(-c5ccccc5)nc(-n5c6ccccc6c6c7sc8ccccc8c7ccc65)n4)c3)cc2)cc1]

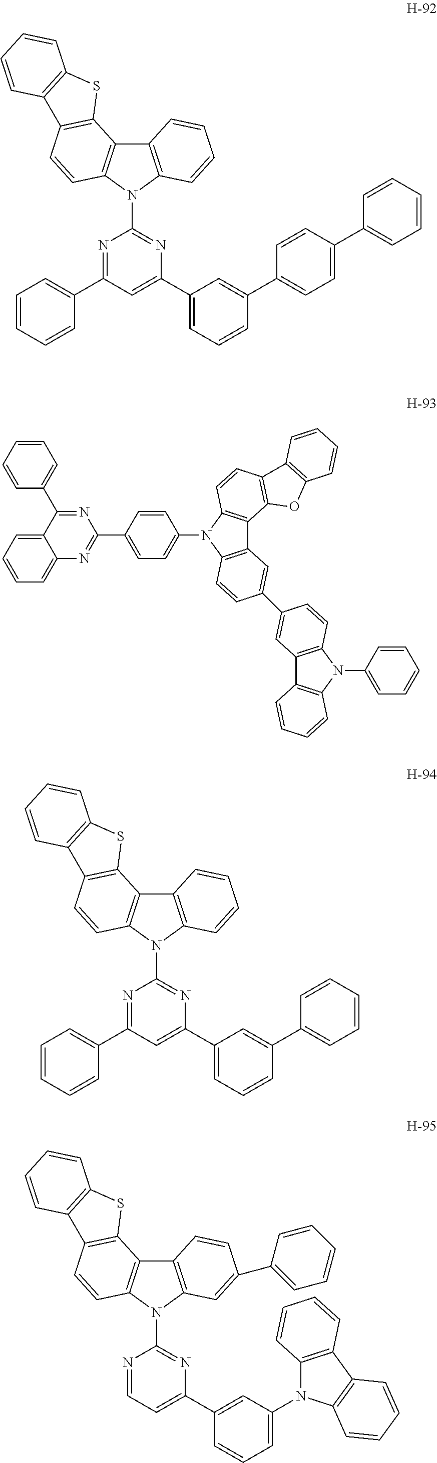 [SMILES: c1ccc(-c2ccc(-c3cccc(-c4cc(-c5ccccc5)nc(-n5c6ccccc6c6c7sc8ccccc8c7ccc65)n4)c3)cc2)cc1 ; c1ccc(-c2nc(-c3ccc(-n4c5ccc(-c6ccc7c(c6)c6ccccc6n7-c6ccccc6)cc5c5c6oc7ccccc7c6ccc54)cc3)nc3ccccc23)cc1 ; c1ccc(-c2cccc(-c3cc(-c4ccccc4)nc(-n4c5ccccc5c5c6sc7ccccc7c6ccc54)n3)c2)cc1 ; c1ccc(-c2ccc3c4c5sc6ccccc6c5ccc4n(-c4nccc(-c5cccc(-n6c7ccccc7c7ccccc76)c5)n4)c3c2)cc1]

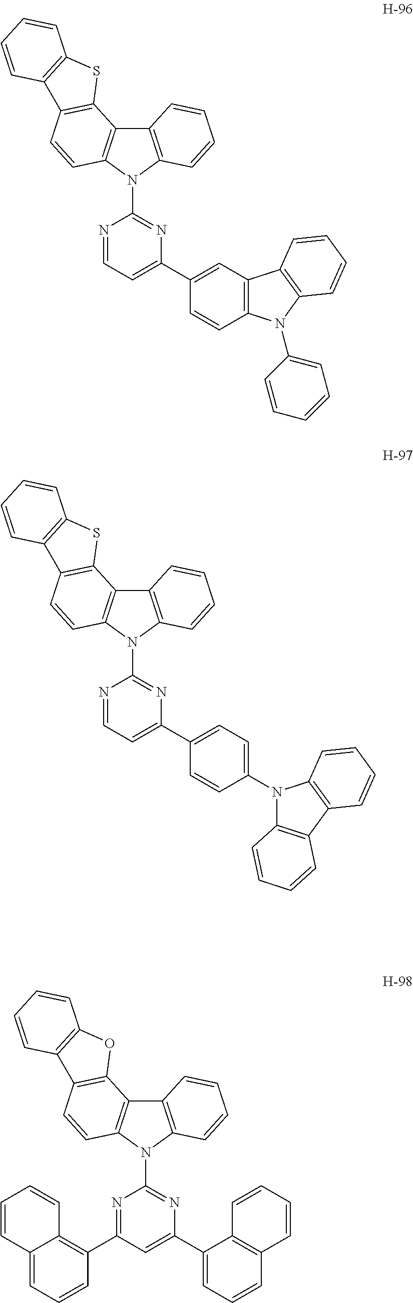 [SMILES: c1ccc(-n2c3ccccc3c3cc(-c4ccnc(-n5c6ccccc6c6c7sc8ccccc8c7ccc65)n4)ccc32)cc1 ; c1ccc2c(c1)sc1c2ccc2c1c1ccccc1n2-c1nccc(-c2ccc(-n3c4ccccc4c4ccccc43)cc2)n1 ; c1ccc2c(-c3cc(-c4cccc5ccccc45)nc(-n4c5ccccc5c5c6oc7ccccc7c6ccc54)n3)cccc2c1]

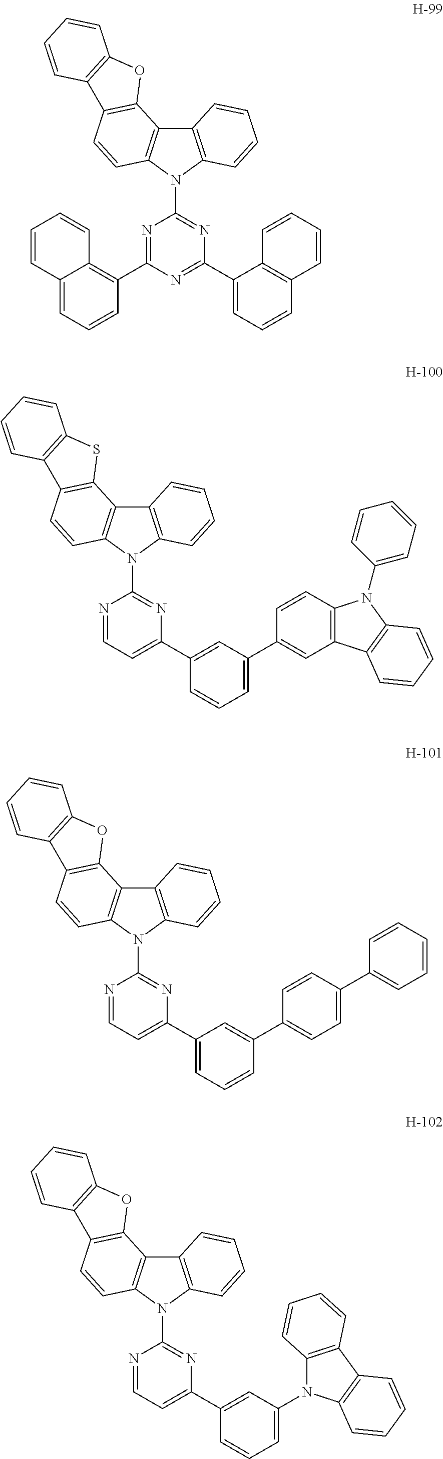 [SMILES: c1ccc2c(-c3nc(-c4cccc5ccccc45)nc(-n4c5ccccc5c5c6oc7ccccc7c6ccc54)n3)cccc2c1 ; c1ccc(-n2c3ccccc3c3cc(-c4cccc(-c5ccnc(-n6c7ccccc7c7c8sc9ccccc9c8ccc76)n5)c4)ccc32)cc1 ; c1ccc(-c2ccc(-c3cccc(-c4ccnc(-n5c6ccccc6c6c7oc8ccccc8c7ccc65)n4)c3)cc2)cc1 ; c1cc(-c2ccnc(-n3c4ccccc4c4c5oc6ccccc6c5ccc43)n2)cc(-n2c3ccccc3c3ccccc32)c1]

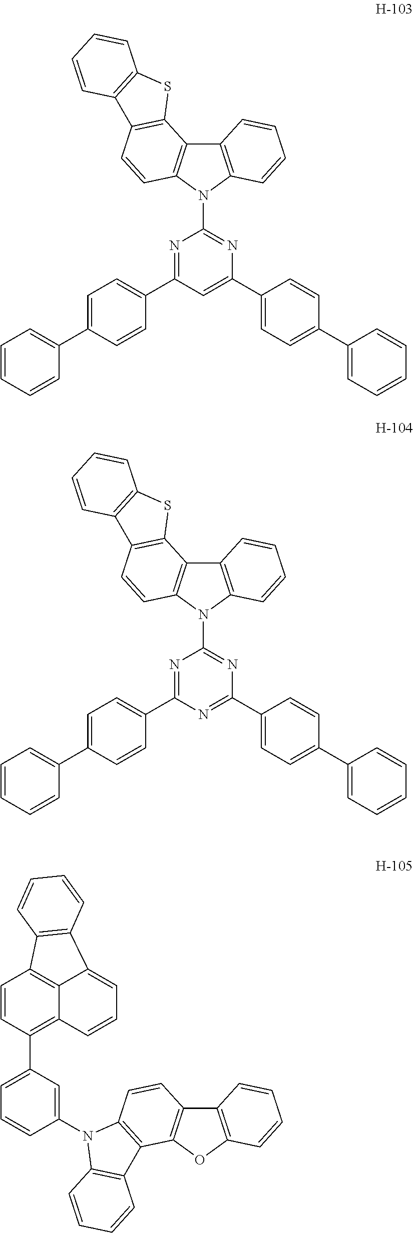 [SMILES: c1ccc(-c2ccc(-c3cc(-c4ccc(-c5ccccc5)cc4)nc(-n4c5ccccc5c5c6sc7ccccc7c6ccc54)n3)cc2)cc1 ; c1ccc(-c2ccc(-c3nc(-c4ccc(-c5ccccc5)cc4)nc(-n4c5ccccc5c5c6sc7ccccc7c6ccc54)n3)cc2)cc1 ; c1cc(-c2ccc3c4c(cccc24)-c2ccccc2-3)cc(-n2c3ccccc3c3c4oc5ccccc5c4ccc32)c1]

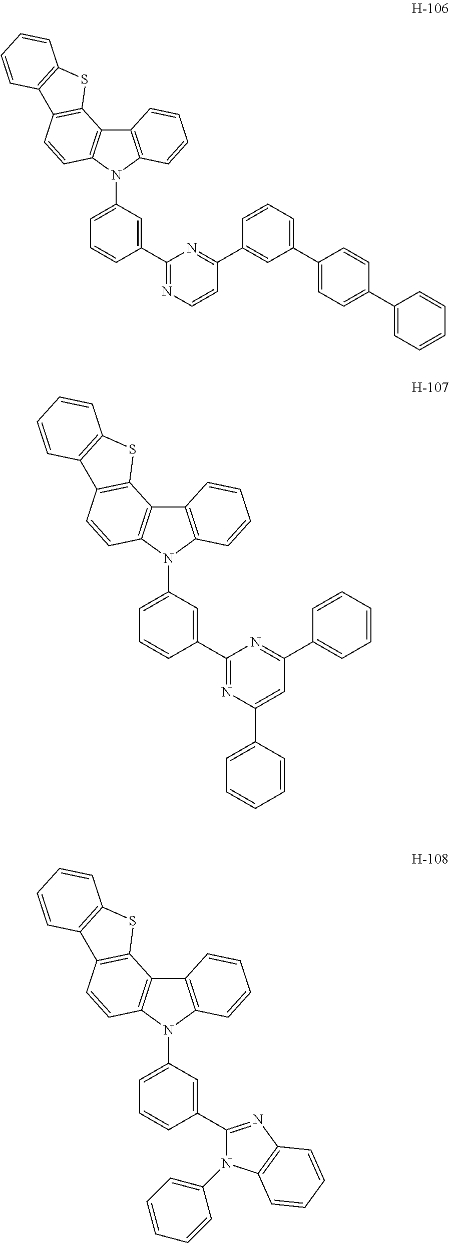 [SMILES: c1ccc(-c2ccc(-c3cccc(-c4ccnc(-c5cccc(-n6c7ccccc7c7c8sc9ccccc9c8ccc76)c5)n4)c3)cc2)cc1 ; c1ccc(-c2cc(-c3ccccc3)nc(-c3cccc(-n4c5ccccc5c5c6sc7ccccc7c6ccc54)c3)n2)cc1 ; c1ccc(-n2c(-c3cccc(-n4c5ccccc5c5c6sc7ccccc7c6ccc54)c3)nc3ccccc32)cc1]

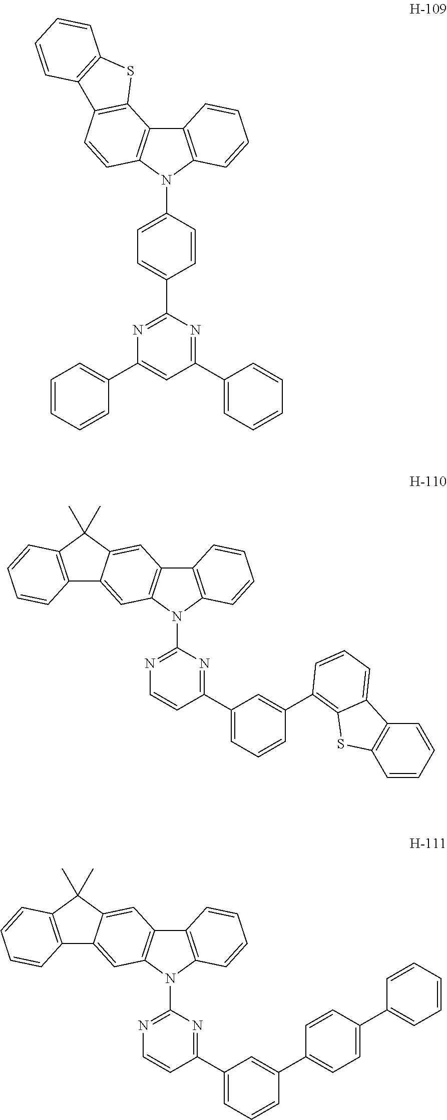 [SMILES: c1ccc(-c2cc(-c3ccccc3)nc(-c3ccc(-n4c5ccccc5c5c6sc7ccccc7c6ccc54)cc3)n2)cc1 ; CC1(C)c2ccccc2-c2cc3c(cc21)c1ccccc1n3-c1nccc(-c2cccc(-c3cccc4c3sc3ccccc34)c2)n1 ; CC1(C)c2ccccc2-c2cc3c(cc21)c1ccccc1n3-c1nccc(-c2cccc(-c3ccc(-c4ccccc4)cc3)c2)n1]

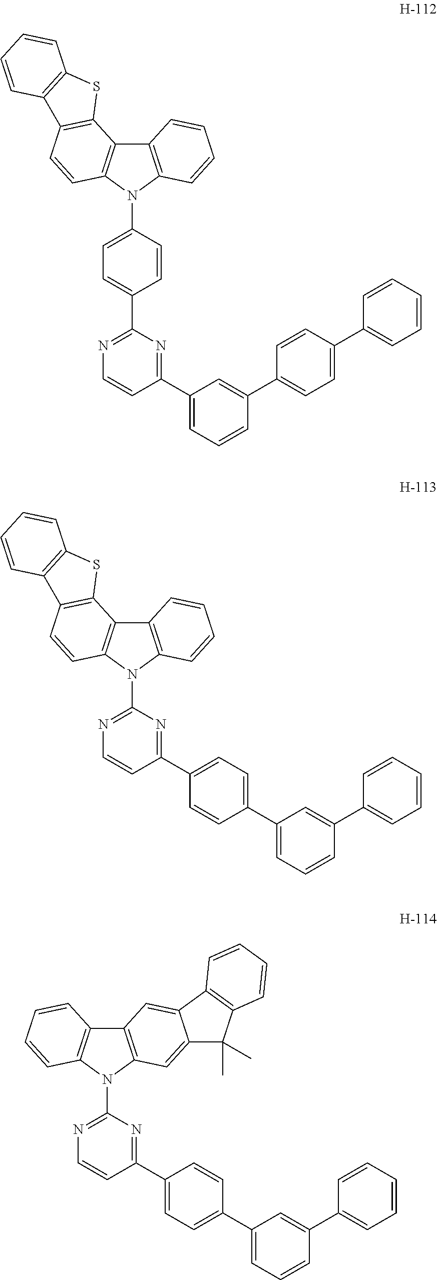 [SMILES: c1ccc(-c2ccc(-c3cccc(-c4ccnc(-c5ccc(-n6c7ccccc7c7c8sc9ccccc9c8ccc76)cc5)n4)c3)cc2)cc1 ; c1ccc(-c2cccc(-c3ccc(-c4ccnc(-n5c6ccccc6c6c7sc8ccccc8c7ccc65)n4)cc3)c2)cc1 ; CC1(C)c2ccccc2-c2cc3c4ccccc4n(-c4nccc(-c5ccc(-c6cccc(-c7ccccc7)c6)cc5)n4)c3cc21]

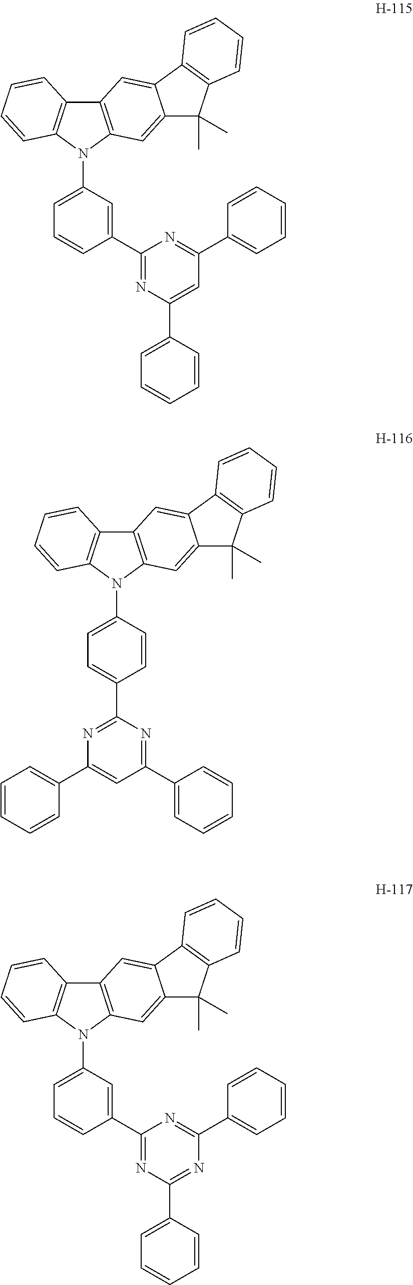 [SMILES: CC1(C)c2ccccc2-c2cc3c4ccccc4n(-c4cccc(-c5nc(-c6ccccc6)cc(-c6ccccc6)n5)c4)c3cc21 ; CC1(C)c2ccccc2-c2cc3c4ccccc4n(-c4ccc(-c5nc(-c6ccccc6)cc(-c6ccccc6)n5)cc4)c3cc21 ; CC1(C)c2ccccc2-c2cc3c4ccccc4n(-c4cccc(-c5nc(-c6ccccc6)nc(-c6ccccc6)n5)c4)c3cc21]

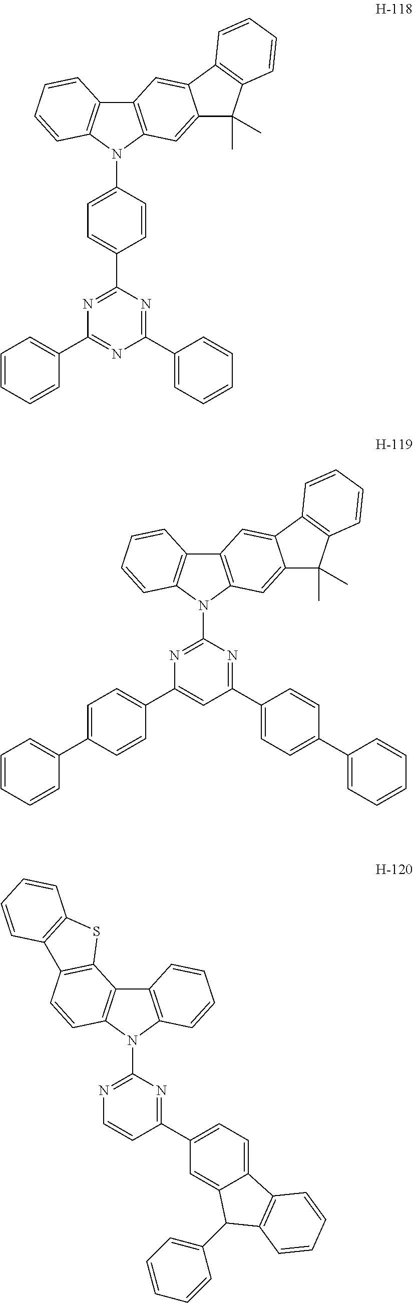 [SMILES: CC1(C)c2ccccc2-c2cc3c4ccccc4n(-c4ccc(-c5nc(-c6ccccc6)nc(-c6ccccc6)n5)cc4)c3cc21 ; CC1(C)c2ccccc2-c2cc3c4ccccc4n(-c4nc(-c5ccc(-c6ccccc6)cc5)cc(-c5ccc(-c6ccccc6)cc5)n4)c3cc21 ; c1ccc(C2c3ccccc3-c3ccc(-c4ccnc(-n5c6ccccc6c6c7sc8ccccc8c7ccc65)n4)cc32)cc1]

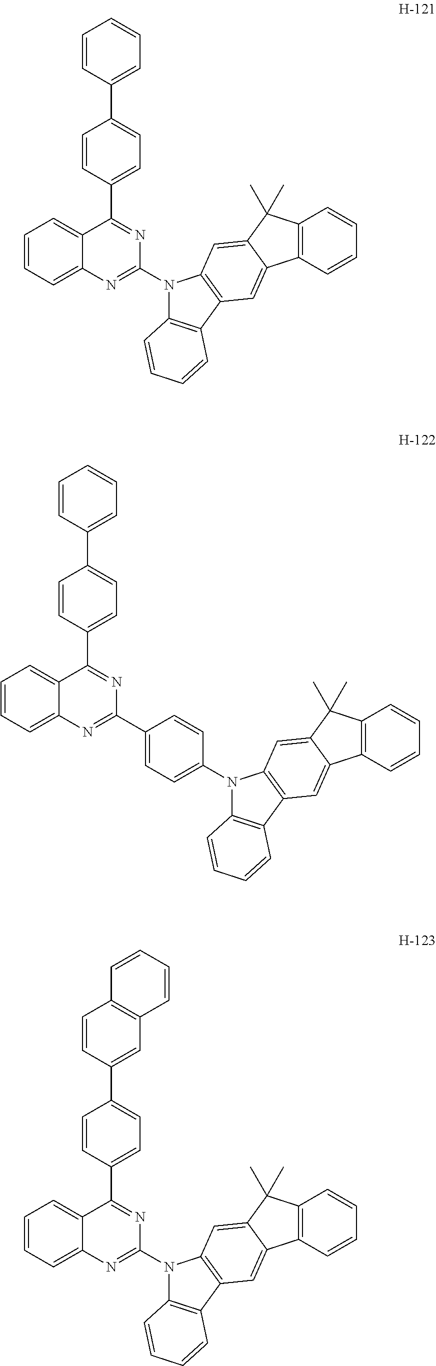 [SMILES: CC1(C)c2ccccc2-c2cc3c4ccccc4n(-c4nc(-c5ccc(-c6ccccc6)cc5)c5ccccc5n4)c3cc21 ; CC1(C)c2ccccc2-c2cc3c4ccccc4n(-c4ccc(-c5nc(-c6ccc(-c7ccccc7)cc6)c6ccccc6n5)cc4)c3cc21 ; CC1(C)c2ccccc2-c2cc3c4ccccc4n(-c4nc(-c5ccc(-c6ccc7ccccc7c6)cc5)c5ccccc5n4)c3cc21]

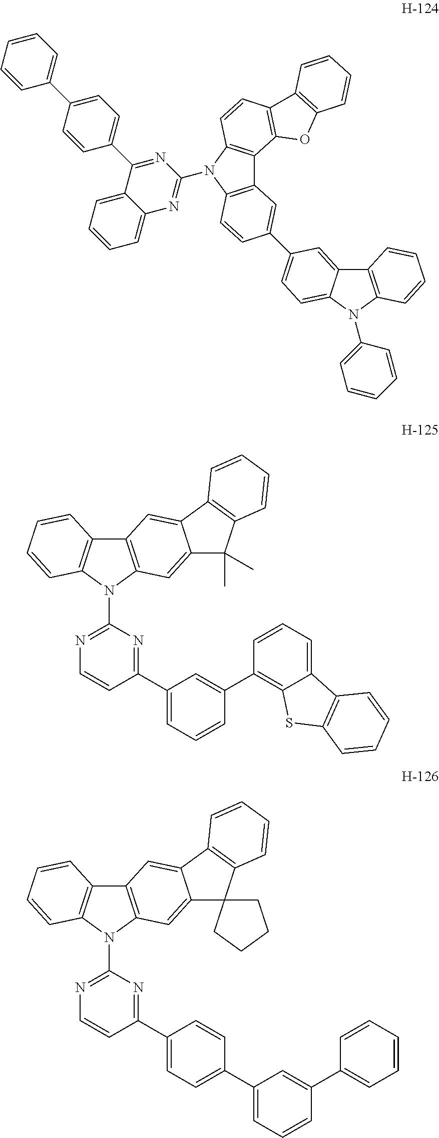 [SMILES: c1ccc(-c2ccc(-c3nc(-n4c5ccc(-c6ccc7c(c6)c6ccccc6n7-c6ccccc6)cc5c5c6oc7ccccc7c6ccc54)nc4ccccc34)cc2)cc1 ; CC1(C)c2ccccc2-c2cc3c4ccccc4n(-c4nccc(-c5cccc(-c6cccc7c6sc6ccccc67)c5)n4)c3cc21 ; c1ccc(-c2cccc(-c3ccc(-c4ccnc(-n5c6ccccc6c6cc7c(cc65)C5(CCCC5)c5ccccc5-7)n4)cc3)c2)cc1]

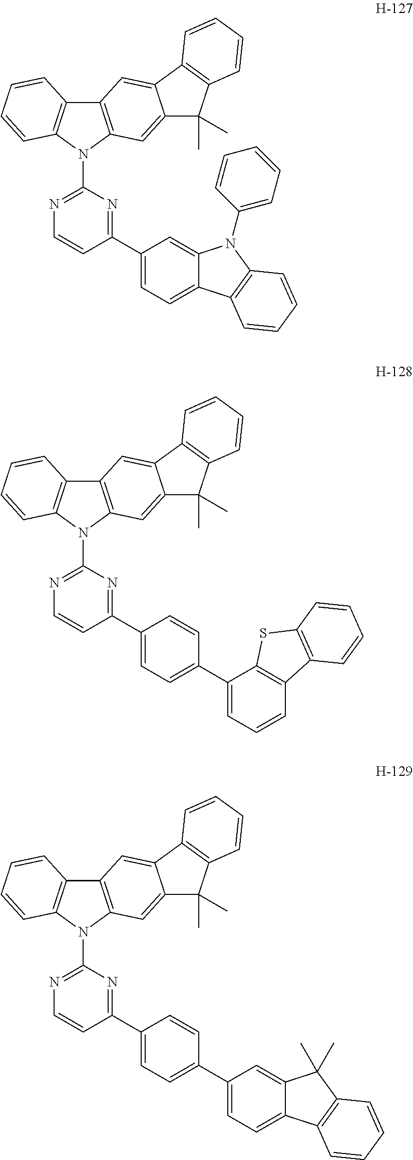 [SMILES: CC1(C)c2ccccc2-c2cc3c4ccccc4n(-c4nccc(-c5ccc6c7ccccc7n(-c7ccccc7)c6c5)n4)c3cc21 ; CC1(C)c2ccccc2-c2cc3c4ccccc4n(-c4nccc(-c5ccc(-c6cccc7c6sc6ccccc67)cc5)n4)c3cc21 ; CC1(C)c2ccccc2-c2ccc(-c3ccc(-c4ccnc(-n5c6ccccc6c6cc7c(cc65)C(C)(C)c5ccccc5-7)n4)cc3)cc21]

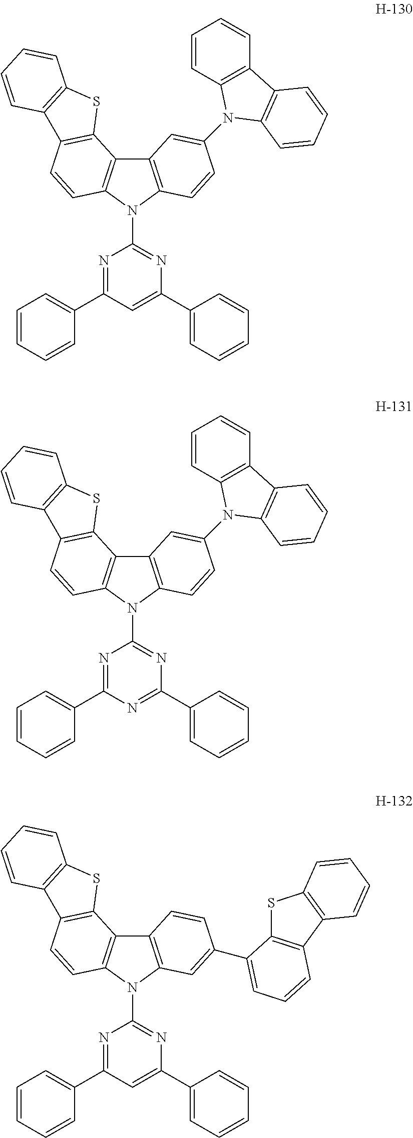 [SMILES: c1ccc(-c2cc(-c3ccccc3)nc(-n3c4ccc(-n5c6ccccc6c6ccccc65)cc4c4c5sc6ccccc6c5ccc43)n2)cc1 ; c1ccc(-c2nc(-c3ccccc3)nc(-n3c4ccc(-n5c6ccccc6c6ccccc65)cc4c4c5sc6ccccc6c5ccc43)n2)cc1 ; c1ccc(-c2cc(-c3ccccc3)nc(-n3c4cc(-c5cccc6c5sc5ccccc56)ccc4c4c5sc6ccccc6c5ccc43)n2)cc1]

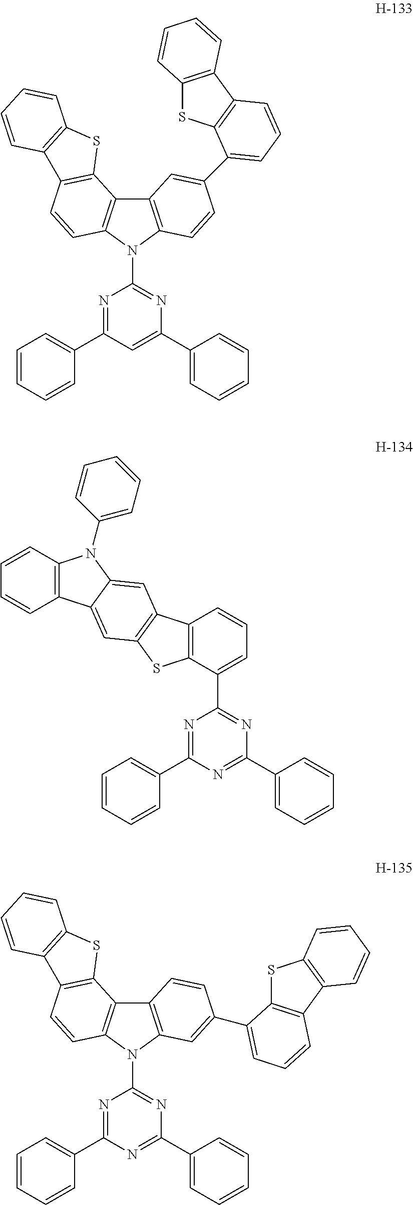 [SMILES: c1ccc(-c2cc(-c3ccccc3)nc(-n3c4ccc(-c5cccc6c5sc5ccccc56)cc4c4c5sc6ccccc6c5ccc43)n2)cc1 ; c1ccc(-c2nc(-c3ccccc3)nc(-c3cccc4c3sc3cc5c6ccccc6n(-c6ccccc6)c5cc34)n2)cc1 ; c1ccc(-c2nc(-c3ccccc3)nc(-n3c4cc(-c5cccc6c5sc5ccccc56)ccc4c4c5sc6ccccc6c5ccc43)n2)cc1]

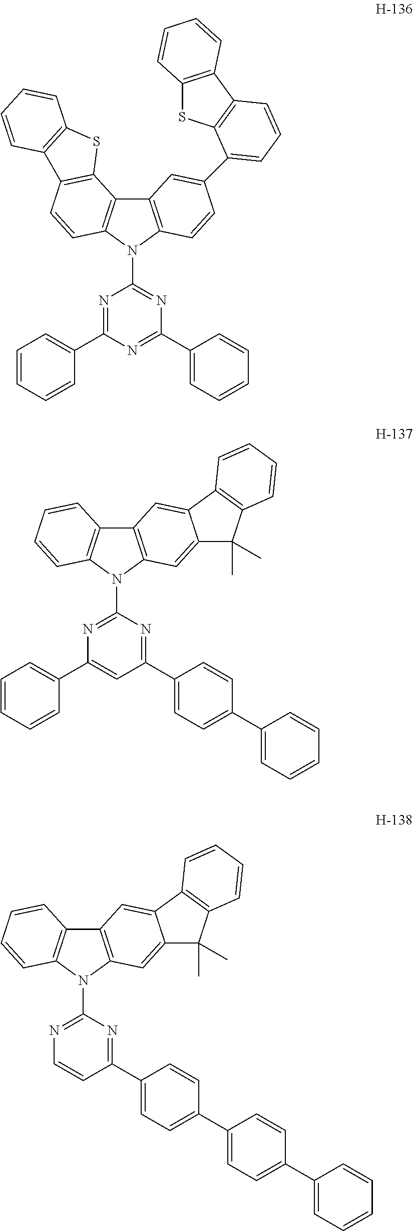 [SMILES: c1ccc(-c2nc(-c3ccccc3)nc(-n3c4ccc(-c5cccc6c5sc5ccccc56)cc4c4c5sc6ccccc6c5ccc43)n2)cc1 ; CC1(C)c2ccccc2-c2cc3c4ccccc4n(-c4nc(-c5ccccc5)cc(-c5ccc(-c6ccccc6)cc5)n4)c3cc21 ; CC1(C)c2ccccc2-c2cc3c4ccccc4n(-c4nccc(-c5ccc(-c6ccc(-c7ccccc7)cc6)cc5)n4)c3cc21]

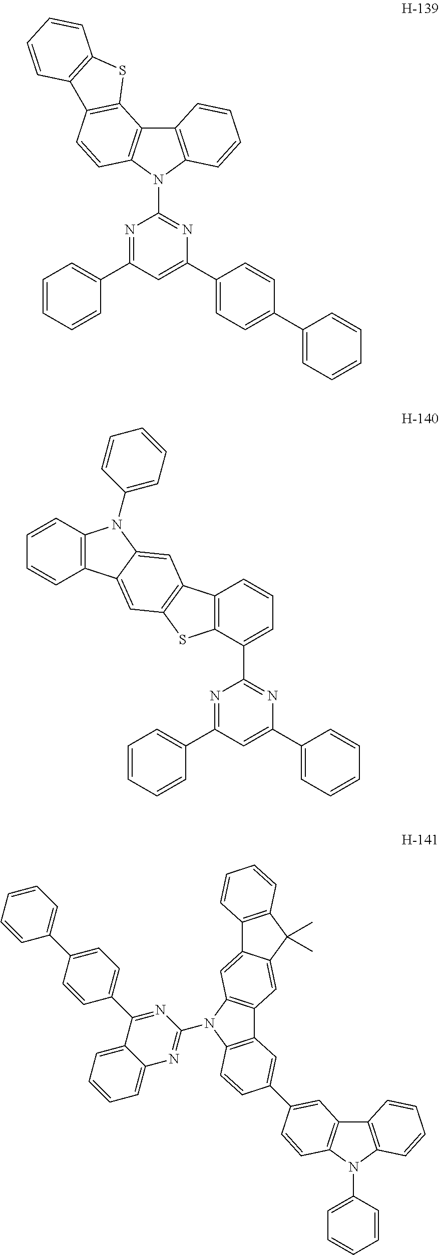 [SMILES: c1ccc(-c2ccc(-c3cc(-c4ccccc4)nc(-n4c5ccccc5c5c6sc7ccccc7c6ccc54)n3)cc2)cc1 ; c1ccc(-c2cc(-c3ccccc3)nc(-c3cccc4c3sc3cc5c6ccccc6n(-c6ccccc6)c5cc34)n2)cc1 ; CC1(C)c2ccccc2-c2cc3c(cc21)c1cc(-c2ccc4c(c2)c2ccccc2n4-c2ccccc2)ccc1n3-c1nc(-c2ccc(-c3ccccc3)cc2)c2ccccc2n1]

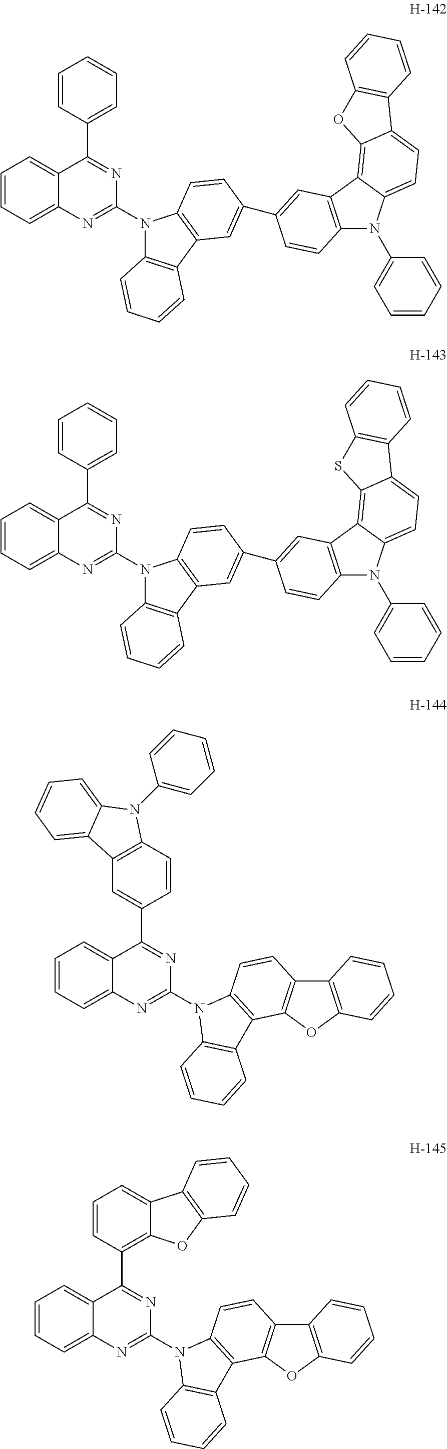 [SMILES: c1ccc(-c2nc(-n3c4ccccc4c4cc(-c5ccc6c(c5)c5c7oc8ccccc8c7ccc5n6-c5ccccc5)ccc43)nc3ccccc23)cc1 ; c1ccc(-c2nc(-n3c4ccccc4c4cc(-c5ccc6c(c5)c5c7sc8ccccc8c7ccc5n6-c5ccccc5)ccc43)nc3ccccc23)cc1 ; c1ccc(-n2c3ccccc3c3cc(-c4nc(-n5c6ccccc6c6c7oc8ccccc8c7ccc65)nc5ccccc45)ccc32)cc1 ; c1ccc2c(-c3cccc4c3oc3ccccc34)nc(-n3c4ccccc4c4c5oc6ccccc6c5ccc43)nc2c1]

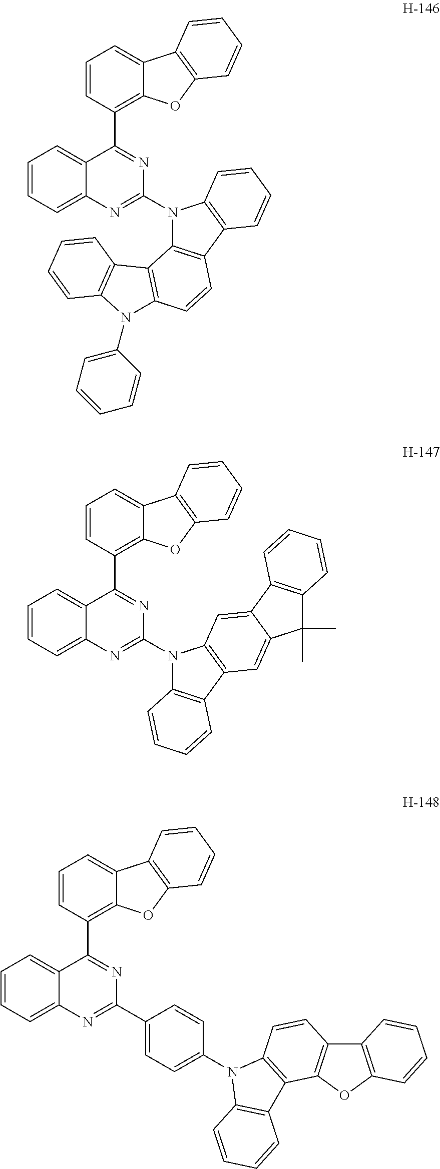 [SMILES: c1ccc(-n2c3ccccc3c3c2ccc2c4ccccc4n(-c4nc(-c5cccc6c5oc5ccccc56)c5ccccc5n4)c23)cc1 ; CC1(C)c2ccccc2-c2cc3c(cc21)c1ccccc1n3-c1nc(-c2cccc3c2oc2ccccc23)c2ccccc2n1 ; c1ccc2c(-c3cccc4c3oc3ccccc34)nc(-c3ccc(-n4c5ccccc5c5c6oc7ccccc7c6ccc54)cc3)nc2c1]

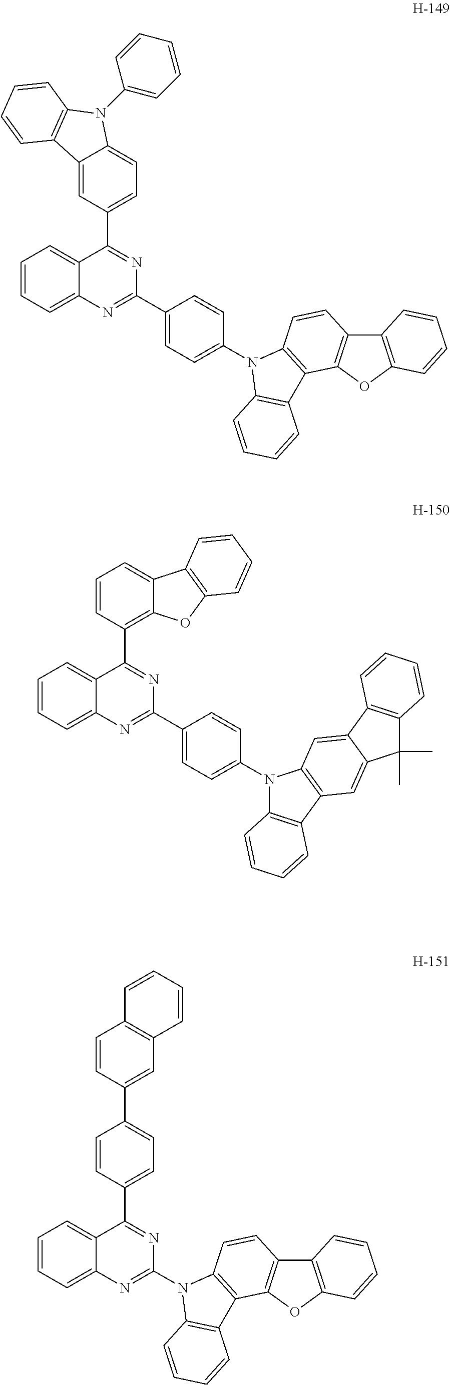 [SMILES: c1ccc(-n2c3ccccc3c3cc(-c4nc(-c5ccc(-n6c7ccccc7c7c8oc9ccccc9c8ccc76)cc5)nc5ccccc45)ccc32)cc1 ; CC1(C)c2ccccc2-c2cc3c(cc21)c1ccccc1n3-c1ccc(-c2nc(-c3cccc4c3oc3ccccc34)c3ccccc3n2)cc1 ; c1ccc2cc(-c3ccc(-c4nc(-n5c6ccccc6c6c7oc8ccccc8c7ccc65)nc5ccccc45)cc3)ccc2c1]

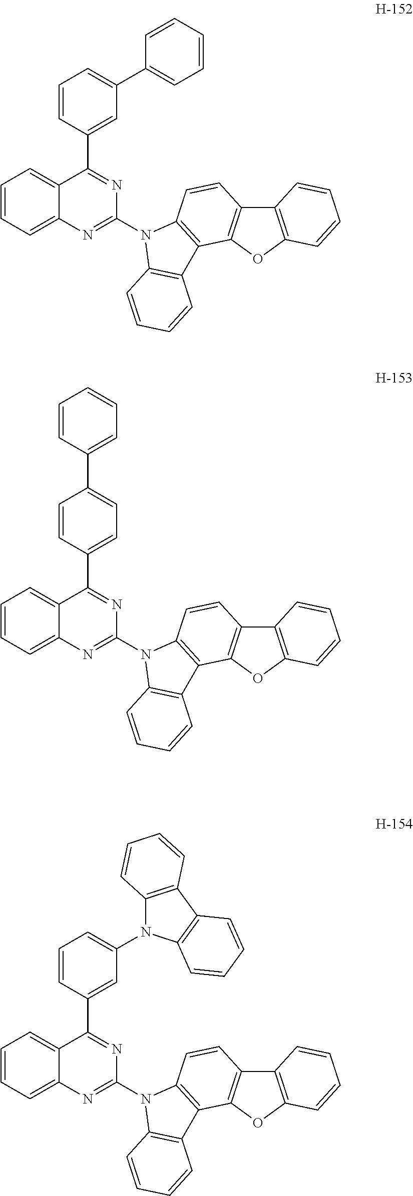 [SMILES: c1ccc(-c2cccc(-c3nc(-n4c5ccccc5c5c6oc7ccccc7c6ccc54)nc4ccccc34)c2)cc1 ; c1ccc(-c2ccc(-c3nc(-n4c5ccccc5c5c6oc7ccccc7c6ccc54)nc4ccccc34)cc2)cc1 ; c1cc(-c2nc(-n3c4ccccc4c4c5oc6ccccc6c5ccc43)nc3ccccc23)cc(-n2c3ccccc3c3ccccc32)c1]

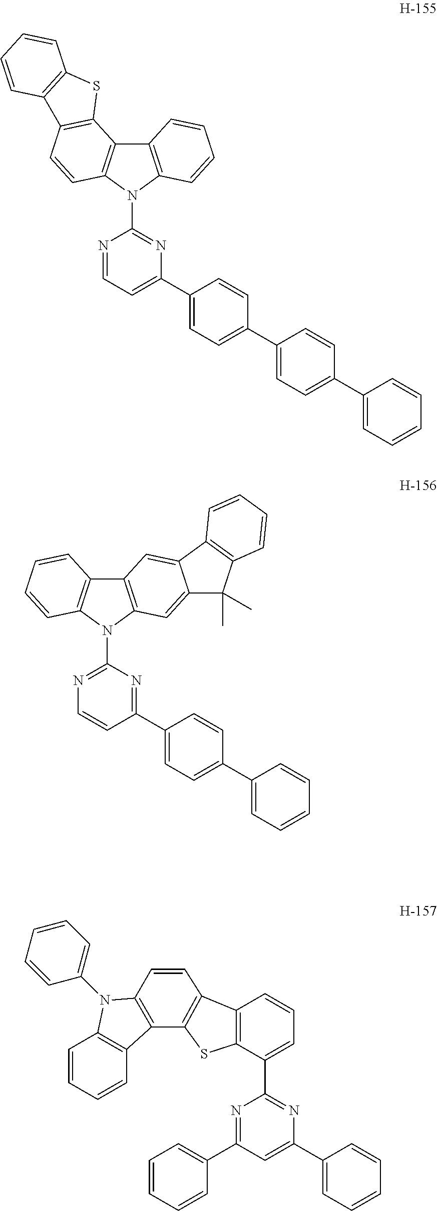 [SMILES: c1ccc(-c2ccc(-c3ccc(-c4ccnc(-n5c6ccccc6c6c7sc8ccccc8c7ccc65)n4)cc3)cc2)cc1 ; CC1(C)c2ccccc2-c2cc3c4ccccc4n(-c4nccc(-c5ccc(-c6ccccc6)cc5)n4)c3cc21 ; c1ccc(-c2cc(-c3ccccc3)nc(-c3cccc4c3sc3c4ccc4c3c3ccccc3n4-c3ccccc3)n2)cc1]

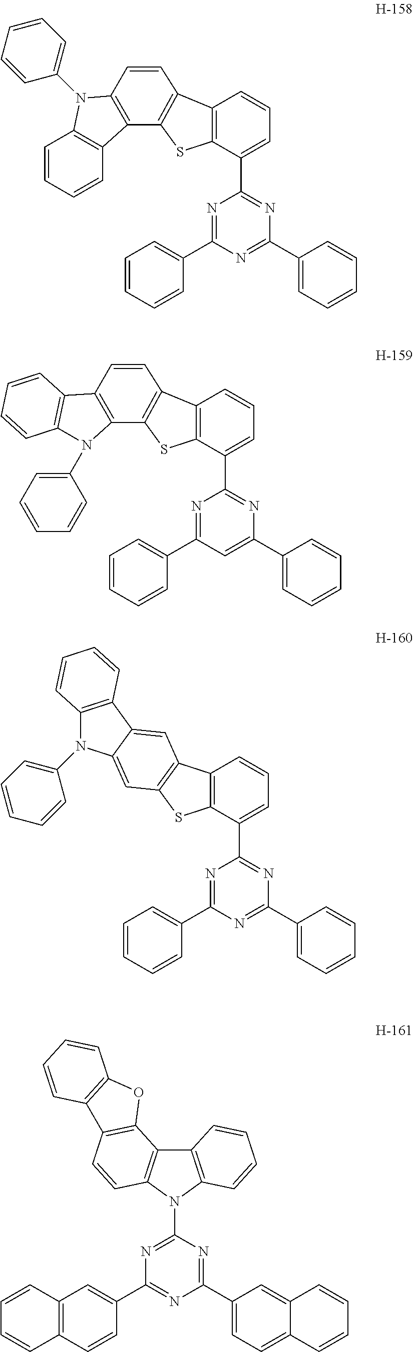 [SMILES: c1ccc(-c2nc(-c3ccccc3)nc(-c3cccc4c3sc3c4ccc4c3c3ccccc3n4-c3ccccc3)n2)cc1 ; c1ccc(-c2cc(-c3ccccc3)nc(-c3cccc4c3sc3c4ccc4c5ccccc5n(-c5ccccc5)c43)n2)cc1 ; c1ccc(-c2nc(-c3ccccc3)nc(-c3cccc4c3sc3cc5c(cc34)c3ccccc3n5-c3ccccc3)n2)cc1 ; c1ccc2cc(-c3nc(-c4ccc5ccccc5c4)nc(-n4c5ccccc5c5c6oc7ccccc7c6ccc54)n3)ccc2c1]

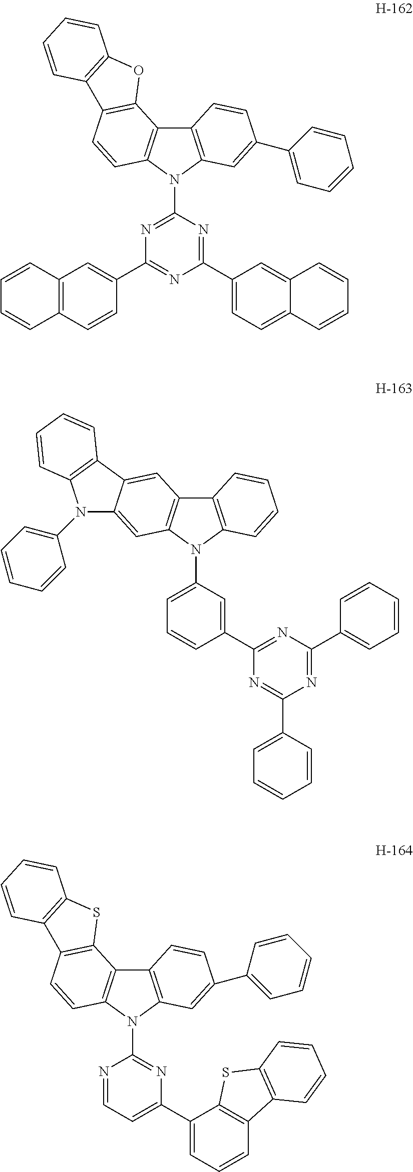 [SMILES: c1ccc(-c2ccc3c4c5oc6ccccc6c5ccc4n(-c4nc(-c5ccc6ccccc6c5)nc(-c5ccc6ccccc6c5)n4)c3c2)cc1 ; c1ccc(-c2nc(-c3ccccc3)nc(-c3cccc(-n4c5ccccc5c5cc6c7ccccc7n(-c7ccccc7)c6cc54)c3)n2)cc1 ; c1ccc(-c2ccc3c4c5sc6ccccc6c5ccc4n(-c4nccc(-c5cccc6c5sc5ccccc56)n4)c3c2)cc1]

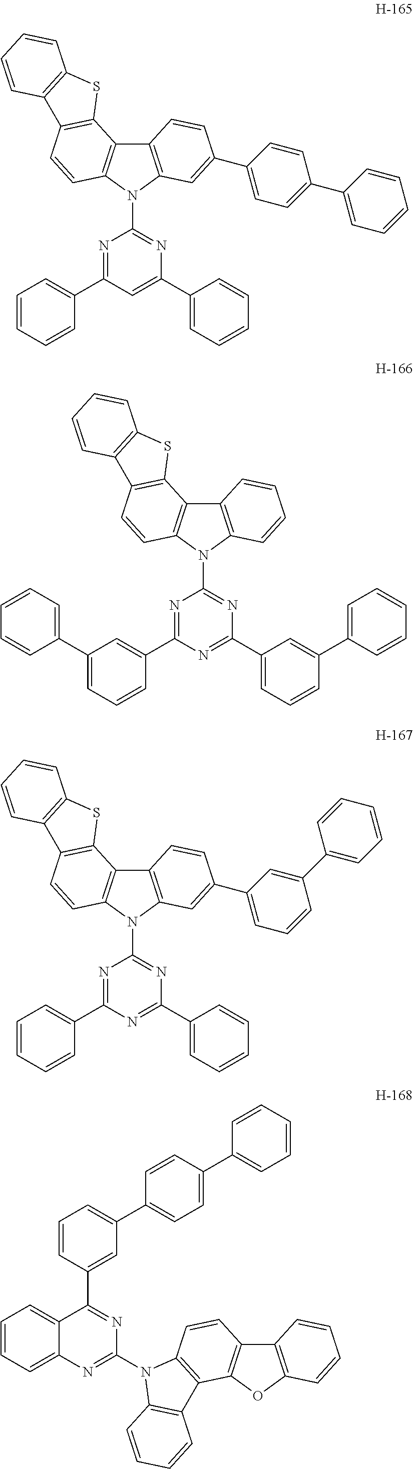 [SMILES: c1ccc(-c2ccc(-c3ccc4c5c6sc7ccccc7c6ccc5n(-c5nc(-c6ccccc6)cc(-c6ccccc6)n5)c4c3)cc2)cc1 ; c1ccc(-c2cccc(-c3nc(-c4cccc(-c5ccccc5)c4)nc(-n4c5ccccc5c5c6sc7ccccc7c6ccc54)n3)c2)cc1 ; c1ccc(-c2cccc(-c3ccc4c5c6sc7ccccc7c6ccc5n(-c5nc(-c6ccccc6)nc(-c6ccccc6)n5)c4c3)c2)cc1 ; c1ccc(-c2ccc(-c3cccc(-c4nc(-n5c6ccccc6c6c7oc8ccccc8c7ccc65)nc5ccccc45)c3)cc2)cc1]

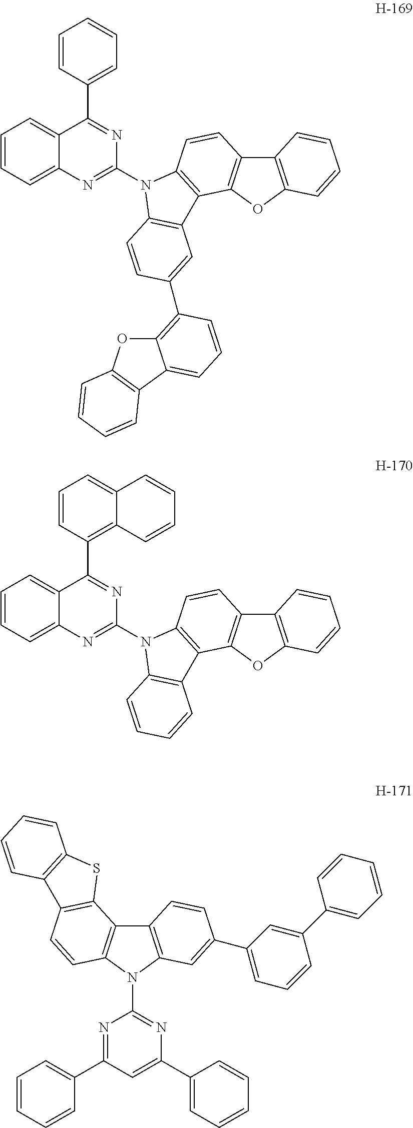

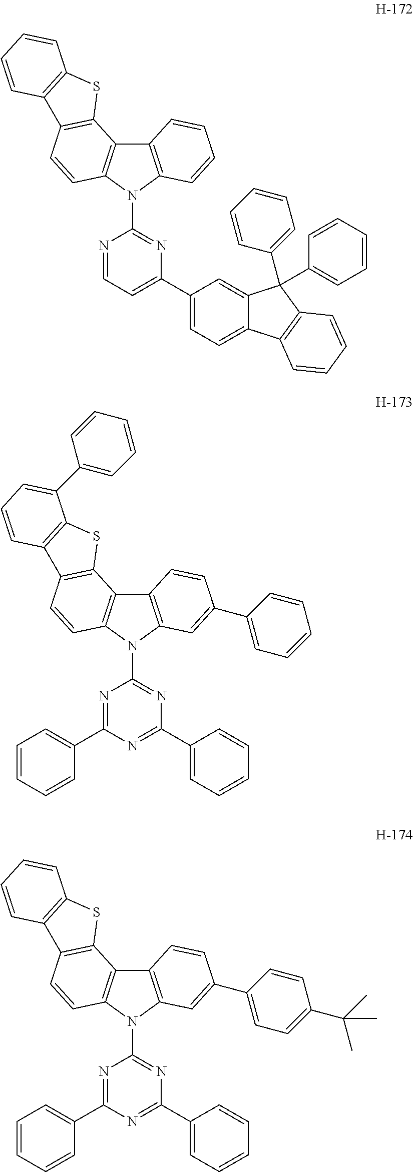 [SMILES: c1ccc(C2(c3ccccc3)c3ccccc3-c3ccc(-c4ccnc(-n5c6ccccc6c6c7sc8ccccc8c7ccc65)n4)cc32)cc1 ; c1ccc(-c2ccc3c4c5sc6c(-c7ccccc7)cccc6c5ccc4n(-c4nc(-c5ccccc5)nc(-c5ccccc5)n4)c3c2)cc1 ; CC(C)(C)c1ccc(-c2ccc3c4c5sc6ccccc6c5ccc4n(-c4nc(-c5ccccc5)nc(-c5ccccc5)n4)c3c2)cc1]

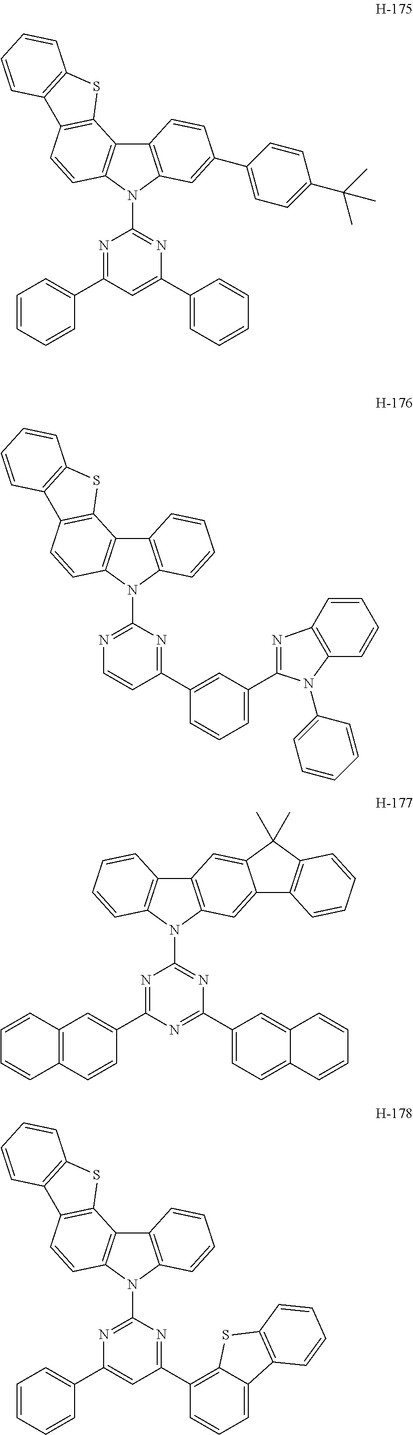

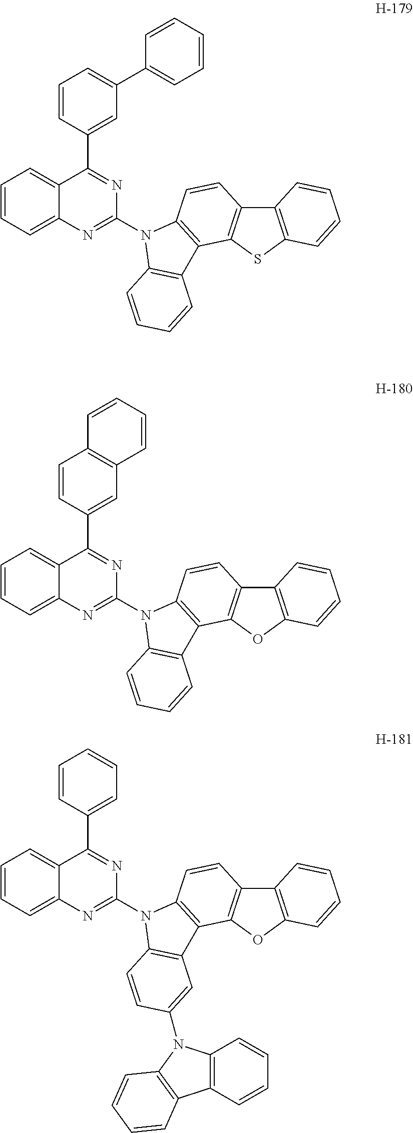 [SMILES: c1ccc(-c2cccc(-c3nc(-n4c5ccccc5c5c6sc7ccccc7c6ccc54)nc4ccccc34)c2)cc1 ; c1ccc2cc(-c3nc(-n4c5ccccc5c5c6oc7ccccc7c6ccc54)nc4ccccc34)ccc2c1 ; c1ccc(-c2nc(-n3c4ccc(-n5c6ccccc6c6ccccc65)cc4c4c5oc6ccccc6c5ccc43)nc3ccccc23)cc1]

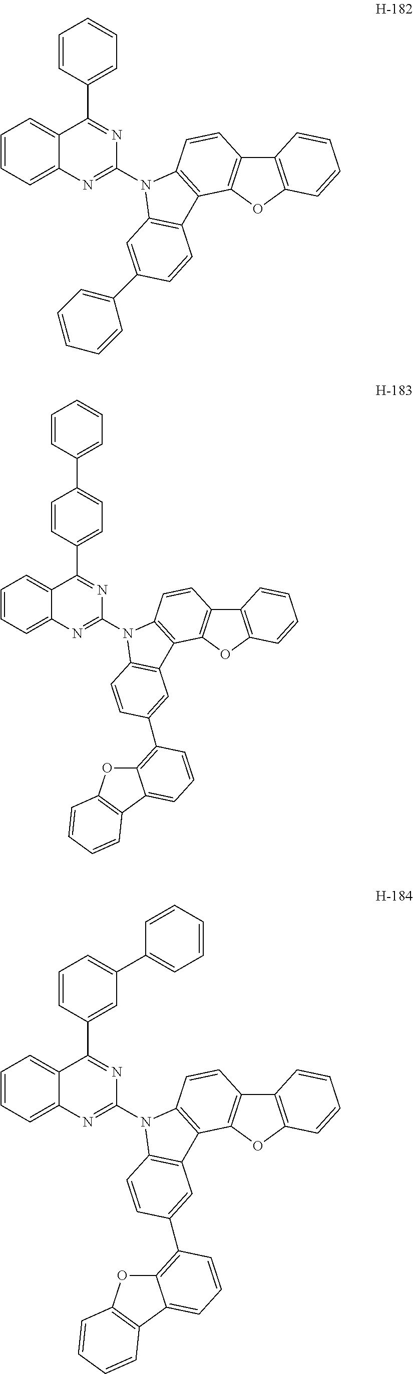 [SMILES: c1ccc(-c2ccc3c4c5oc6ccccc6c5ccc4n(-c4nc(-c5ccccc5)c5ccccc5n4)c3c2)cc1 ; c1ccc(-c2ccc(-c3nc(-n4c5ccc(-c6cccc7c6oc6ccccc67)cc5c5c6oc7ccccc7c6ccc54)nc4ccccc34)cc2)cc1 ; c1ccc(-c2cccc(-c3nc(-n4c5ccc(-c6cccc7c6oc6ccccc67)cc5c5c6oc7ccccc7c6ccc54)nc4ccccc34)c2)cc1]

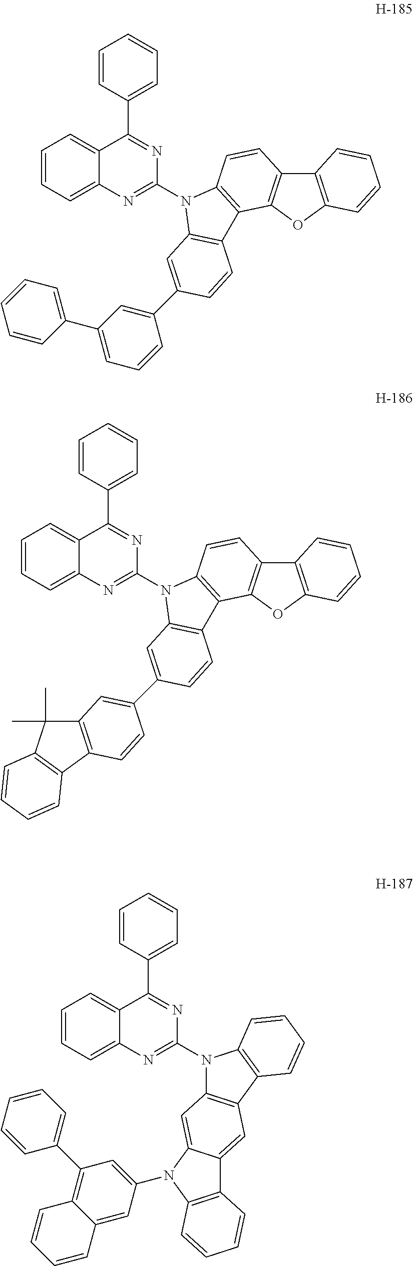 [SMILES: c1ccc(-c2cccc(-c3ccc4c5c6oc7ccccc7c6ccc5n(-c5nc(-c6ccccc6)c6ccccc6n5)c4c3)c2)cc1 ; CC1(C)c2ccccc2-c2ccc(-c3ccc4c5c6oc7ccccc7c6ccc5n(-c5nc(-c6ccccc6)c6ccccc6n5)c4c3)cc21 ; c1ccc(-c2cc(-n3c4ccccc4c4cc5c6ccccc6n(-c6nc(-c7ccccc7)c7ccccc7n6)c5cc43)cc3ccccc23)cc1]

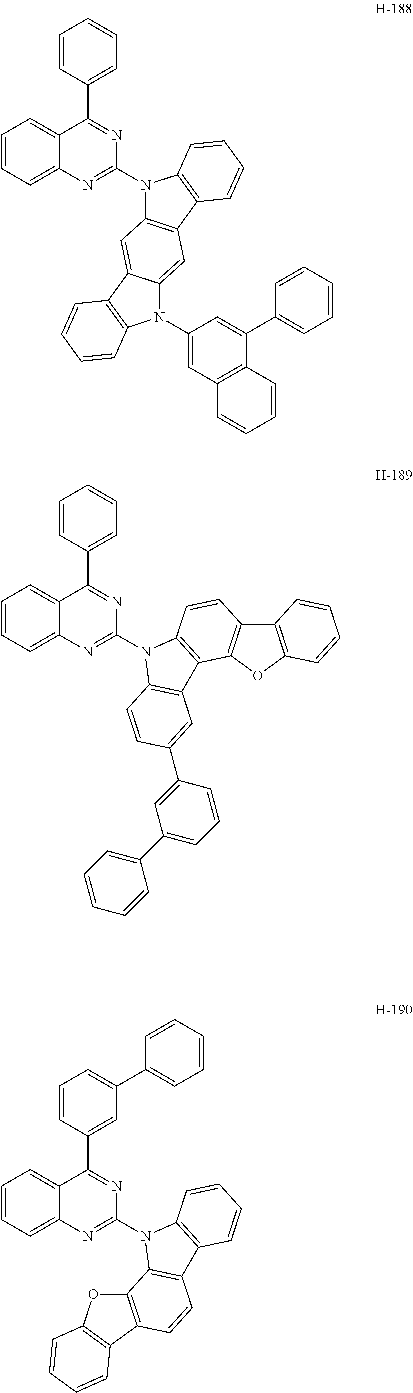 [SMILES: c1ccc(-c2cc(-n3c4ccccc4c4cc5c(cc43)c3ccccc3n5-c3nc(-c4ccccc4)c4ccccc4n3)cc3ccccc23)cc1 ; c1ccc(-c2cccc(-c3ccc4c(c3)c3c5oc6ccccc6c5ccc3n4-c3nc(-c4ccccc4)c4ccccc4n3)c2)cc1 ; c1ccc(-c2cccc(-c3nc(-n4c5ccccc5c5ccc6c7ccccc7oc6c54)nc4ccccc34)c2)cc1]

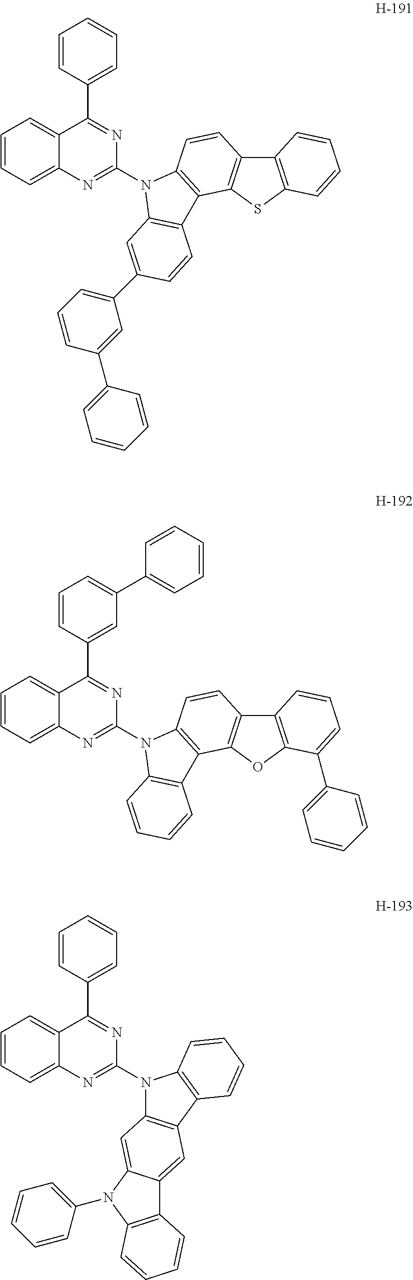 [SMILES: c1ccc(-c2cccc(-c3ccc4c5c6sc7ccccc7c6ccc5n(-c5nc(-c6ccccc6)c6ccccc6n5)c4c3)c2)cc1 ; c1ccc(-c2cccc(-c3nc(-n4c5ccccc5c5c6oc7c(-c8ccccc8)cccc7c6ccc54)nc4ccccc34)c2)cc1 ; c1ccc(-c2nc(-n3c4ccccc4c4cc5c6ccccc6n(-c6ccccc6)c5cc43)nc3ccccc23)cc1]

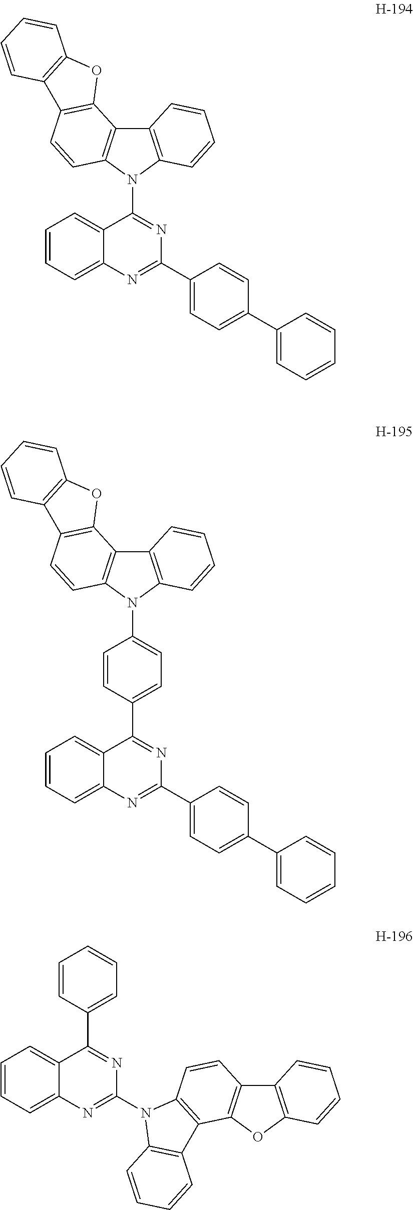 [SMILES: c1ccc(-c2ccc(-c3nc(-n4c5ccccc5c5c6oc7ccccc7c6ccc54)c4ccccc4n3)cc2)cc1 ; c1ccc(-c2ccc(-c3nc(-c4ccc(-n5c6ccccc6c6c7oc8ccccc8c7ccc65)cc4)c4ccccc4n3)cc2)cc1 ; c1ccc(-c2nc(-n3c4ccccc4c4c5oc6ccccc6c5ccc43)nc3ccccc23)cc1]

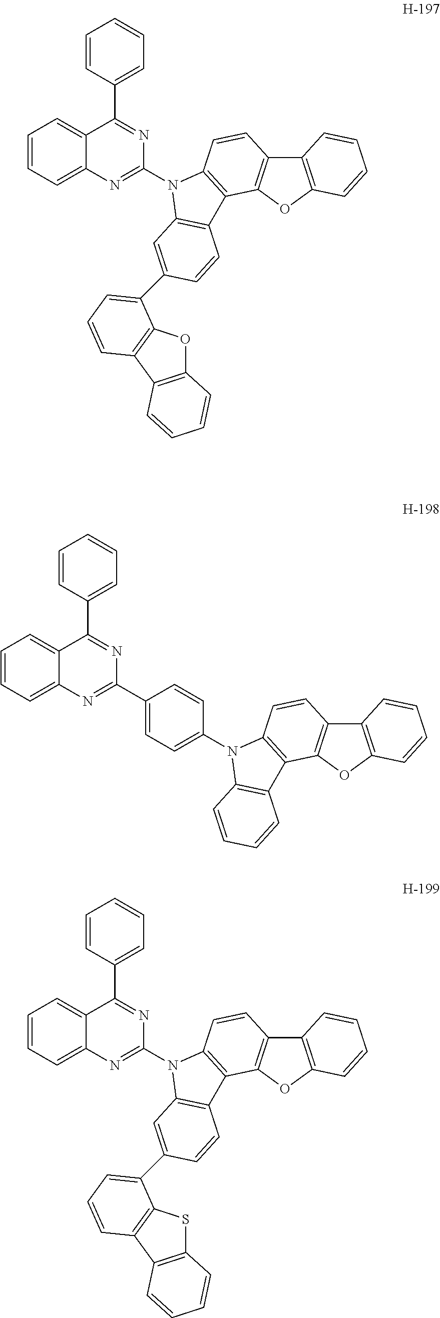 [SMILES: c1ccc(-c2nc(-n3c4cc(-c5cccc6c5oc5ccccc56)ccc4c4c5oc6ccccc6c5ccc43)nc3ccccc23)cc1 ; c1ccc(-c2nc(-c3ccc(-n4c5ccccc5c5c6oc7ccccc7c6ccc54)cc3)nc3ccccc23)cc1 ; c1ccc(-c2nc(-n3c4cc(-c5cccc6c5sc5ccccc56)ccc4c4c5oc6ccccc6c5ccc43)nc3ccccc23)cc1]

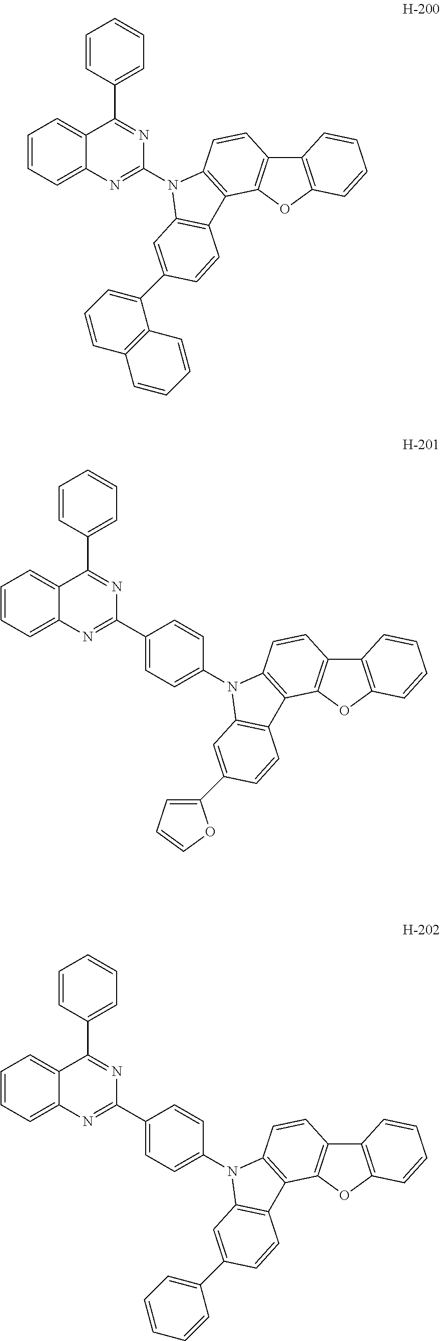 [SMILES: c1ccc(-c2nc(-n3c4cc(-c5cccc6ccccc56)ccc4c4c5oc6ccccc6c5ccc43)nc3ccccc23)cc1 ; c1ccc(-c2nc(-c3ccc(-n4c5cc(-c6ccco6)ccc5c5c6oc7ccccc7c6ccc54)cc3)nc3ccccc23)cc1 ; c1ccc(-c2ccc3c4c5oc6ccccc6c5ccc4n(-c4ccc(-c5nc(-c6ccccc6)c6ccccc6n5)cc4)c3c2)cc1]

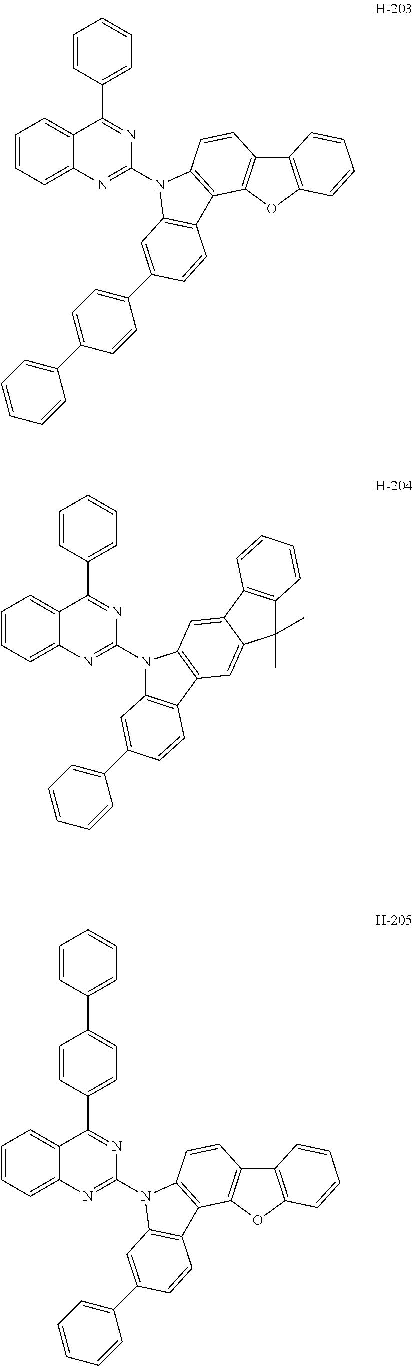 [SMILES: c1ccc(-c2ccc(-c3ccc4c5c6oc7ccccc7c6ccc5n(-c5nc(-c6ccccc6)c6ccccc6n5)c4c3)cc2)cc1 ; CC1(C)c2ccccc2-c2cc3c(cc21)c1ccc(-c2ccccc2)cc1n3-c1nc(-c2ccccc2)c2ccccc2n1 ; c1ccc(-c2ccc(-c3nc(-n4c5cc(-c6ccccc6)ccc5c5c6oc7ccccc7c6ccc54)nc4ccccc34)cc2)cc1]

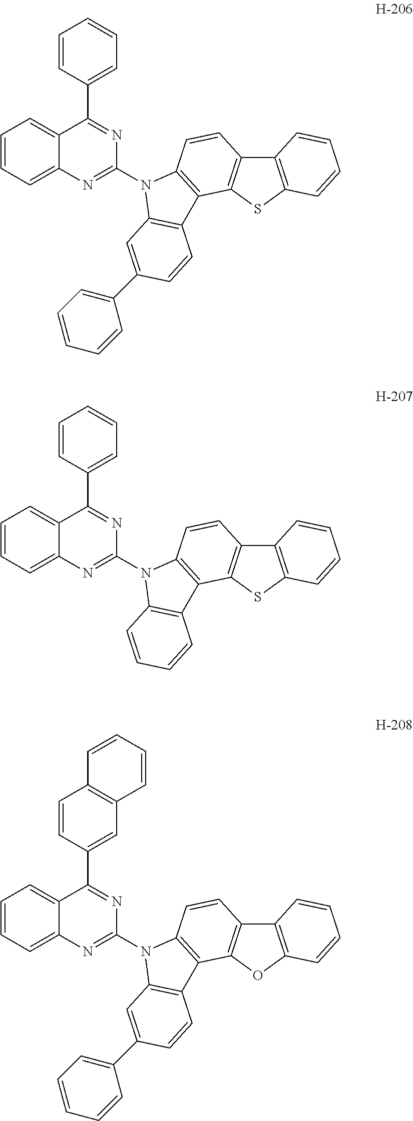 [SMILES: c1ccc(-c2ccc3c4c5sc6ccccc6c5ccc4n(-c4nc(-c5ccccc5)c5ccccc5n4)c3c2)cc1 ; c1ccc(-c2nc(-n3c4ccccc4c4c5sc6ccccc6c5ccc43)nc3ccccc23)cc1 ; c1ccc(-c2ccc3c4c5oc6ccccc6c5ccc4n(-c4nc(-c5ccc6ccccc6c5)c5ccccc5n4)c3c2)cc1]

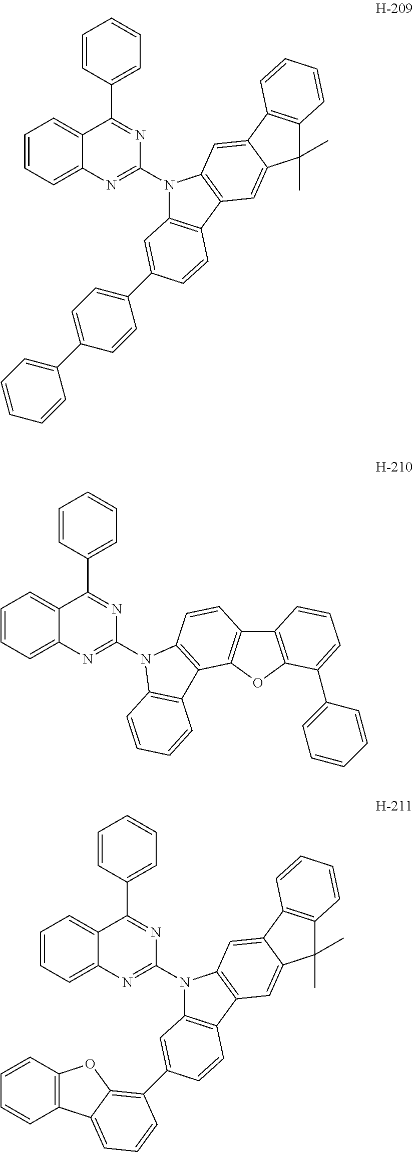 [SMILES: CC1(C)c2ccccc2-c2cc3c(cc21)c1ccc(-c2ccc(-c4ccccc4)cc2)cc1n3-c1nc(-c2ccccc2)c2ccccc2n1 ; c1ccc(-c2nc(-n3c4ccccc4c4c5oc6c(-c7ccccc7)cccc6c5ccc43)nc3ccccc23)cc1 ; CC1(C)c2ccccc2-c2cc3c(cc21)c1ccc(-c2cccc4c2oc2ccccc24)cc1n3-c1nc(-c2ccccc2)c2ccccc2n1]

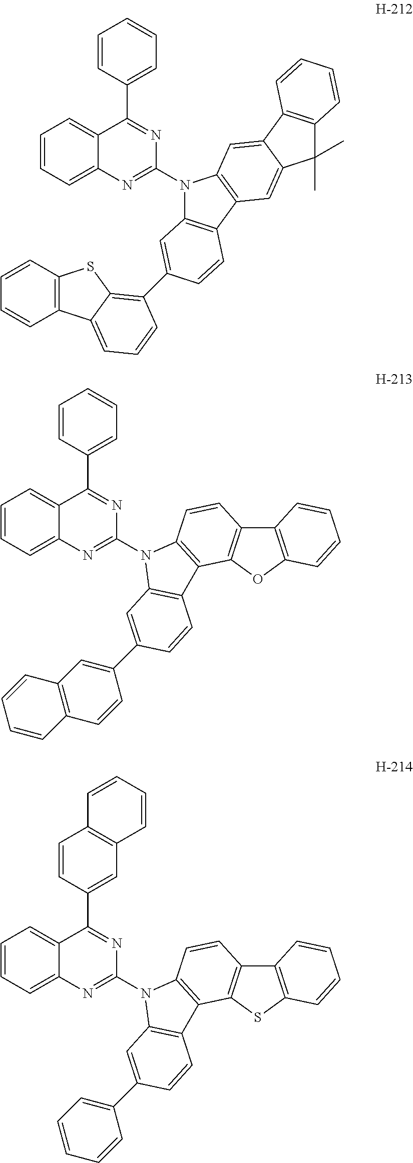

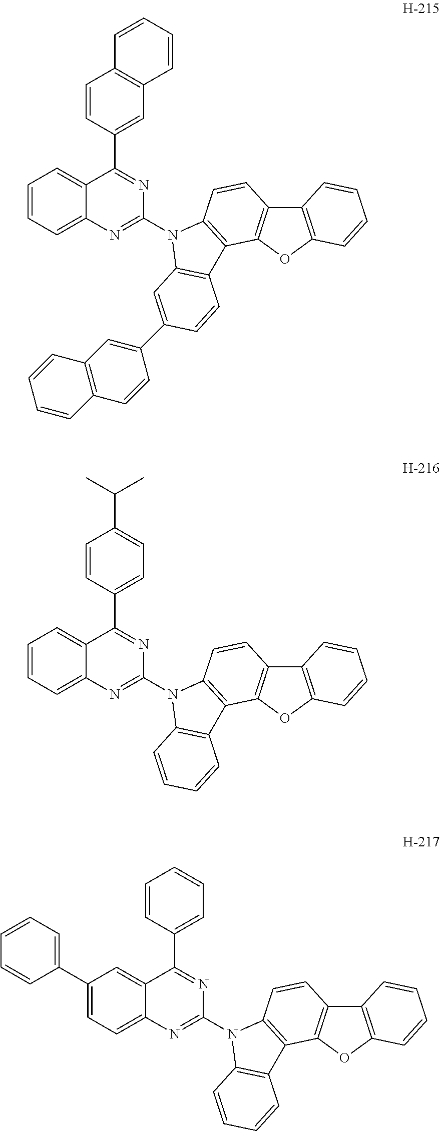 [SMILES: c1ccc2cc(-c3ccc4c5c6oc7ccccc7c6ccc5n(-c5nc(-c6ccc7ccccc7c6)c6ccccc6n5)c4c3)ccc2c1 ; CC(C)c1ccc(-c2nc(-n3c4ccccc4c4c5oc6ccccc6c5ccc43)nc3ccccc23)cc1 ; c1ccc(-c2ccc3nc(-n4c5ccccc5c5c6oc7ccccc7c6ccc54)nc(-c4ccccc4)c3c2)cc1]

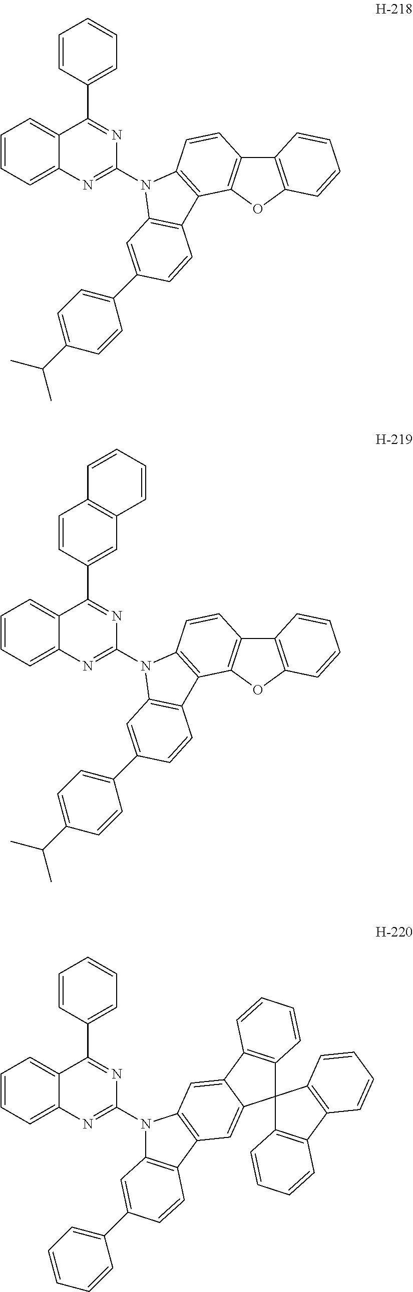 [SMILES: CC(C)c1ccc(-c2ccc3c4c5oc6ccccc6c5ccc4n(-c4nc(-c5ccccc5)c5ccccc5n4)c3c2)cc1 ; CC(C)c1ccc(-c2ccc3c4c5oc6ccccc6c5ccc4n(-c4nc(-c5ccc6ccccc6c5)c5ccccc5n4)c3c2)cc1 ; c1ccc(-c2ccc3c4cc5c(cc4n(-c4nc(-c6ccccc6)c6ccccc6n4)c3c2)-c2ccccc2C52c3ccccc3-c3ccccc32)cc1]

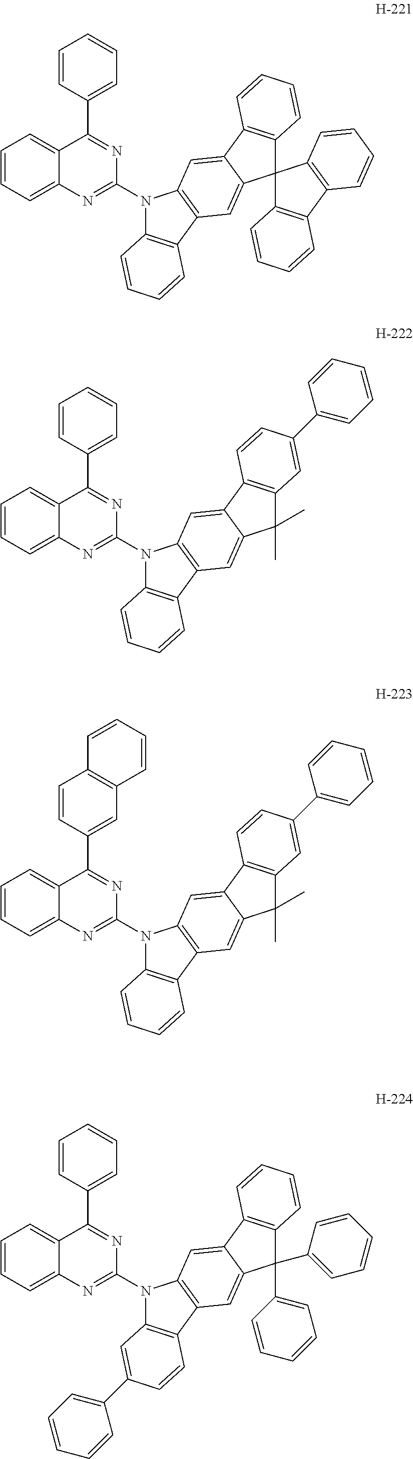 [SMILES: c1ccc(-c2nc(-n3c4ccccc4c4cc5c(cc43)-c3ccccc3C53c4ccccc4-c4ccccc43)nc3ccccc23)cc1 ; CC1(C)c2cc(-c3ccccc3)ccc2-c2cc3c(cc21)c1ccccc1n3-c1nc(-c2ccccc2)c2ccccc2n1 ; CC1(C)c2cc(-c3ccccc3)ccc2-c2cc3c(cc21)c1ccccc1n3-c1nc(-c2ccc3ccccc3c2)c2ccccc2n1 ; c1ccc(-c2ccc3c4cc5c(cc4n(-c4nc(-c6ccccc6)c6ccccc6n4)c3c2)-c2ccccc2C5(c2ccccc2)c2ccccc2)cc1]

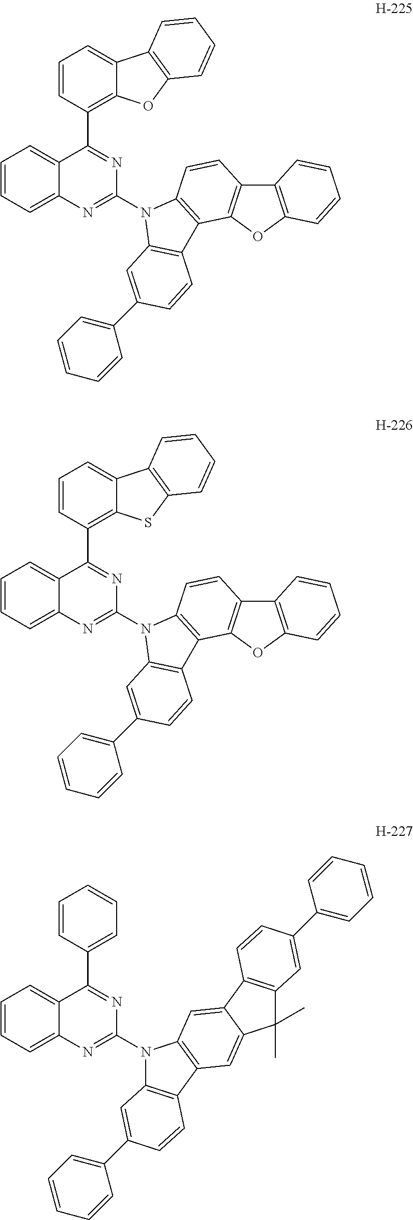 [SMILES: c1ccc(-c2ccc3c4c5oc6ccccc6c5ccc4n(-c4nc(-c5cccc6c5oc5ccccc56)c5ccccc5n4)c3c2)cc1 ; c1ccc(-c2ccc3c4c5oc6ccccc6c5ccc4n(-c4nc(-c5cccc6c5sc5ccccc56)c5ccccc5n4)c3c2)cc1 ; CC1(C)c2cc(-c3ccccc3)ccc2-c2cc3c(cc21)c1ccc(-c2ccccc2)cc1n3-c1nc(-c2ccccc2)c2ccccc2n1]

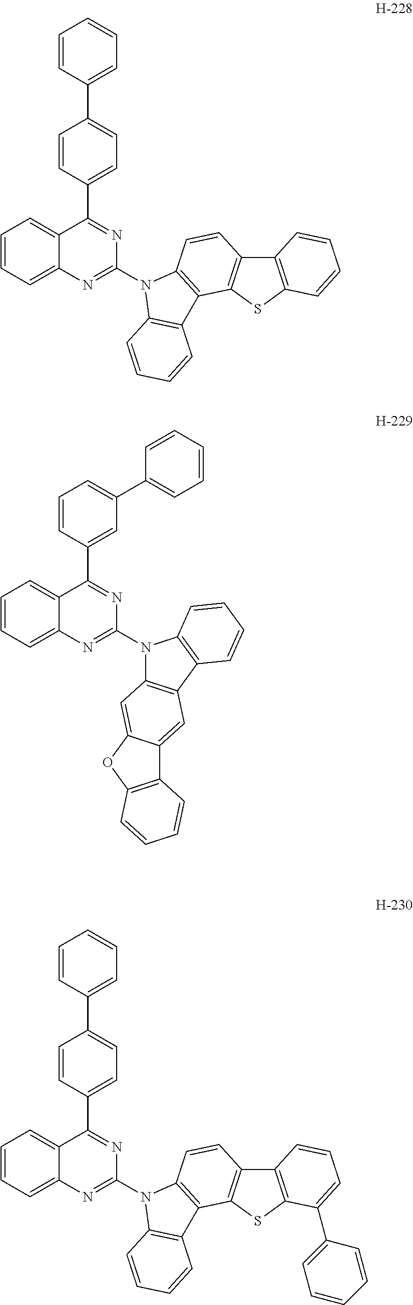 [SMILES: c1ccc(-c2ccc(-c3nc(-n4c5ccccc5c5c6sc7ccccc7c6ccc54)nc4ccccc34)cc2)cc1 ; c1ccc(-c2cccc(-c3nc(-n4c5ccccc5c5cc6c(cc54)oc4ccccc46)nc4ccccc34)c2)cc1 ; c1ccc(-c2ccc(-c3nc(-n4c5ccccc5c5c6sc7c(-c8ccccc8)cccc7c6ccc54)nc4ccccc34)cc2)cc1]

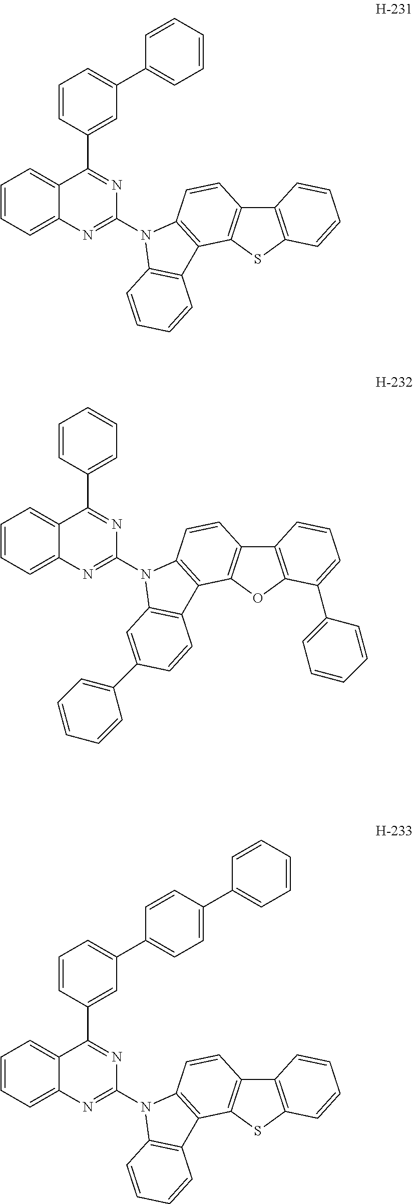 [SMILES: c1ccc(-c2cccc(-c3nc(-n4c5ccccc5c5c6sc7ccccc7c6ccc54)nc4ccccc34)c2)cc1 ; c1ccc(-c2ccc3c4c5oc6c(-c7ccccc7)cccc6c5ccc4n(-c4nc(-c5ccccc5)c5ccccc5n4)c3c2)cc1 ; c1ccc(-c2ccc(-c3cccc(-c4nc(-n5c6ccccc6c6c7sc8ccccc8c7ccc65)nc5ccccc45)c3)cc2)cc1]

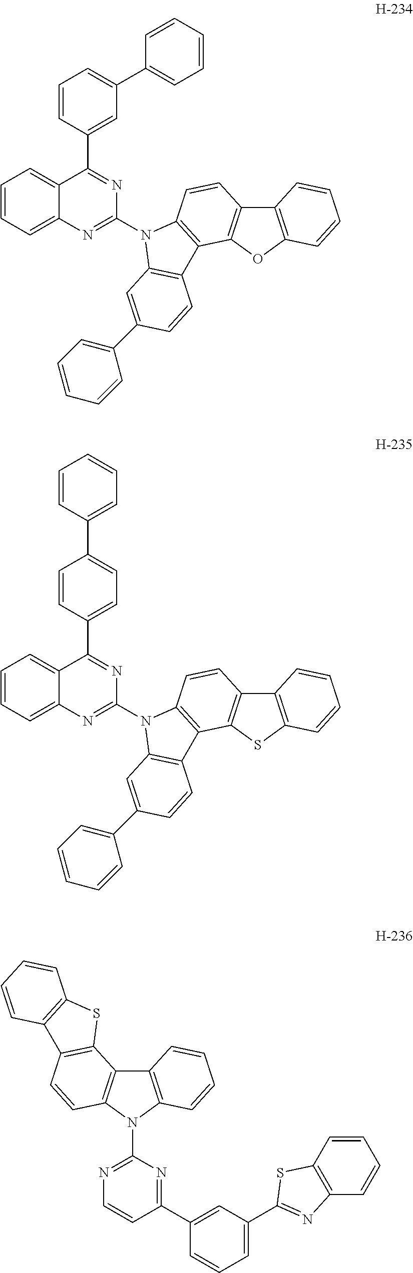 [SMILES: c1ccc(-c2cccc(-c3nc(-n4c5cc(-c6ccccc6)ccc5c5c6oc7ccccc7c6ccc54)nc4ccccc34)c2)cc1 ; c1ccc(-c2ccc(-c3nc(-n4c5cc(-c6ccccc6)ccc5c5c6sc7ccccc7c6ccc54)nc4ccccc34)cc2)cc1 ; c1cc(-c2ccnc(-n3c4ccccc4c4c5sc6ccccc6c5ccc43)n2)cc(-c2nc3ccccc3s2)c1]

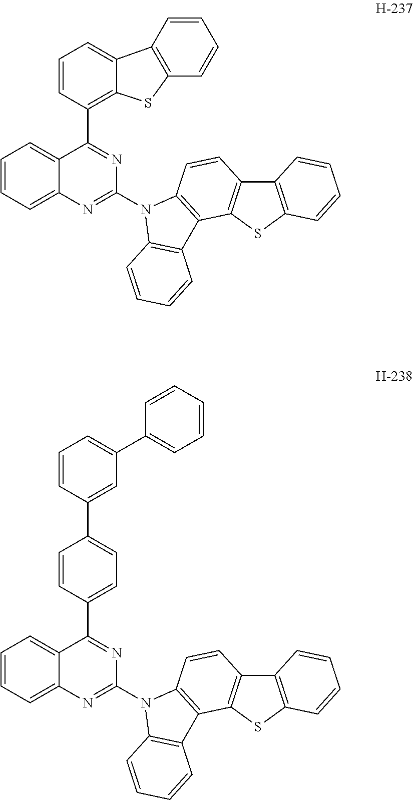 [SMILES: c1ccc2c(-c3cccc4c3sc3ccccc34)nc(-n3c4ccccc4c4c5sc6ccccc6c5ccc43)nc2c1 ; c1ccc(-c2cccc(-c3ccc(-c4nc(-n5c6ccccc6c6c7sc8ccccc8c7ccc65)nc5ccccc45)cc3)c2)cc1]

Herein, “(C1-C30)alkyl(ene)” is meant to be a linear or branched alkyl(ene) having 1 to 30 carbon atoms, in which the number of carbon atoms is preferably 1 to 20, more preferably 1 to 10, and includes methyl, ethyl, n-propyl, isopropyl, n-butyl, isobutyl, tert-butyl, etc.; “(C2-C30) alkenyl” is meant to be a linear or branched alkenyl having 2 to 30 carbon atoms, in which the number of carbon atoms is preferably 2 to 20, more preferably 2 to 10, and includes vinyl, 1-propenyl, 2-propenyl, 1-butenyl, 2-butenyl, 3-butenyl, 2-methylbut-2-enyl, etc.; “(C2-C30)alkynyl” is a linear or branched alkynyl having 2 to 30 carbon atoms, in which the number of carbon atoms is preferably 2 to 20, more preferably 2 to 10, and includes ethynyl, 1-propynyl, 2-propynyl, 1-butynyl, 2-butynyl, 3-butynyl, 1-methylpent-2-ynyl, etc.; “(C3-C30)cycloalkyl” is a mono- or polycyclic hydrocarbon having 3 to 30 carbon atoms, in which the number of carbon atoms is preferably 3 to 20, more preferably 3 to 7, and includes cyclopropyl, cyclobutyl, cyclopentyl, cyclohexyl, etc.; “3- to 7-membered heterocycloalkyl” is a cycloalkyl having at least one heteroatom selected from B, N, O, S, P(═O), Si and P, preferably O, S and N, and 3 to 7 ring backbone atoms, and includes tetrahydrofuran, pyrrolidine, thiolan, tetrahydropyran, etc.; “(C6-C30)aryl(ene)” is a monocyclic or fused ring derived from an aromatic hydrocarbon having 6 to 30 carbon atoms, in which the number of carbon atoms is preferably 6 to 20, more preferably 6 to 15, and includes phenyl, biphenyl, terphenyl, naphthyl, fluorenyl, phenanthrenyl, anthracenyl, indenyl, triphenylenyl, pyrenyl, tetracenyl, perylenyl, chrysenyl, naphthacenyl, fluoranthenyl, etc.; “3- to 30-membered heteroaryl(ene)” is an aryl group having at least one, preferably 1 to 4 heteroatom selected from the group consisting of B, N, O, S, P(═O), Si and P, and 3 to 30 ring backbone atoms; is a monocyclic ring, or a fused ring condensed with at least one benzene ring; has preferably 5 to 20, more preferably 5 to 15 ring backbone atoms; may be partially saturated; may be one formed by linking at least one heteroaryl or aryl group to a heteroaryl group via a single bond(s); and includes a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “halogen” includes F, Cl, Br and I.

Herein, “substituted” in the expression “substituted or unsubstituted” means that a hydrogen atom in a certain functional group is replaced with another atom or group, i.e., a substituent.

The substituents of the substituted alkyl(ene), the substituted aryl(ene), the substituted heteroaryl(ene), the substituted cycloalkyl, the substituted alkoxy, the substituted trialkylsilyl, the substituted triarylsilyl, and the substituted heterocycloalkyl in the above formulae each independently are preferably at least one selected from the group consisting of deuterium; a halogen; a (C1-C30)alkyl unsubstituted or substituted with a halogen; a (C6-C30)aryl unsubstituted or substituted with a 3- to 30-membered heteroaryl; a 3- to 30-membered heteroaryl unsubstituted or substituted with a (C6-C30)aryl; a 5- to 7-membered heterocycloalkyl; a 5- to 7-membered heterocycloalkyl fused with at least one (C6-C30)aromatic ring; a (C3-C30)cycloalkyl; a (C6-C30)cycloalkyl fused with at least one (C6-C30)aromatic ring; RₐR_{b}R_{c}Si—; a (C2-C30)alkenyl; a (C2-C30)alkynyl; a cyano; a carbazolyl; —NR_{d}Rₑ; —BR_{f}R_{g}; —PRₕRᵢ; —P(═O)RⱼRₖ; a (C6-C30)aryl(C1-C30)alkyl; a (C1-C30)alkyl(C6-C30)aryl; RₗZ—; RₘC(═O)—; RₘC(═O)O—; a carboxyl; a nitro; and a hydroxyl, wherein Rₐ to Rₗ each independently represent a (C1-C30)alkyl, a (C6-C30)aryl, or a 3- to 30-membered heteroaryl; or are linked to an adjacent substituent(s) to form a mono- or polycyclic, (C3-C30)alicyclic or aromatic ring whose carbon atom(s) may be replaced with at least one hetero atom selected from the group consisting of nitrogen, oxygen and sulfur; Z represents S or O; and Rₘ represents a (C1-C30)alkyl, a (C1-C30)alkoxy, a (C6-C30)aryl, or a (C6-C30)aryloxy.

Specifically, said organic electroluminescent device comprises a first electrode; a second electrode; and at least one organic layer between said first and second electrodes. Said organic layer comprises a light-emitting layer, and said light-emitting layer comprises a combination of one or more dopant compounds represented by formula 1, and one or more host compounds represented by formula 2.

Said light-emitting layer is a layer which emits light, and it may be a single layer, or it may be a multi layer of which two or more layers are laminated.

The doping concentration, the proportion of the dopant compound to the host compound may be preferably less than 20 wt %.

Another embodiment of the present invention provides a dopant and host combination of one or more dopant compounds represented by formula 1, and one or more host compounds represented by formula 2, and an organic EL device comprising the dopant and host combination.

Still another embodiment of the present invention provides an organic layer consisting of the combination of one or more dopant compounds represented by formula 1, and one or more host compounds represented by formula 2. Said organic layer comprises plural layers. Said dopant compound and said host compound can be comprised in the same layer, or can be comprised in different layers. In addition, the present invention provides an organic EL device comprising the organic layer.

In the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

Hereinafter, the compound, the preparation method of the compound, and the luminescent properties of the device will be explained in detail with reference to the following examples. However, these are just for exemplifying the embodiment of the present invention, so the scope of the present invention cannot be limited thereto.

### Example 1

### Preparation of Compound D-1

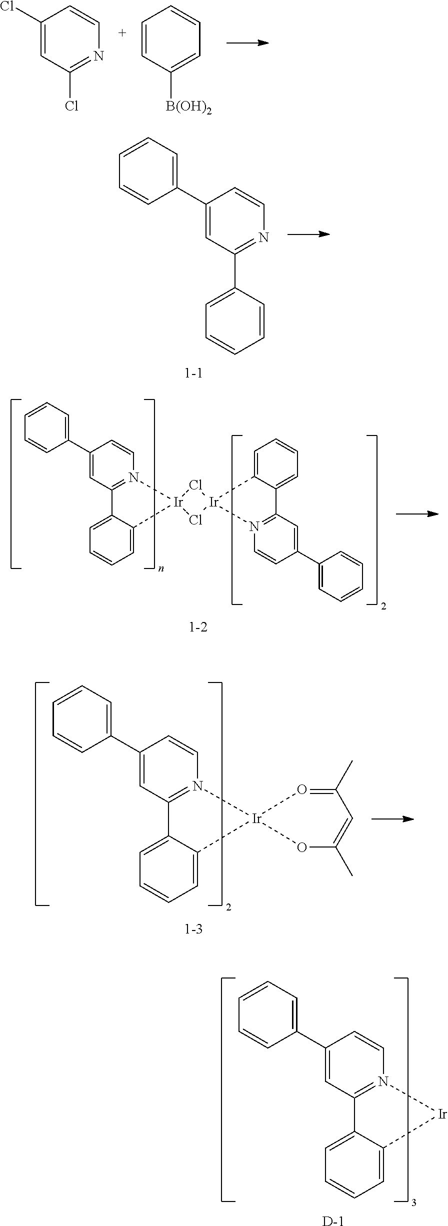

Preparation of Compound 1-1

After adding 2,4-dichloropyridine 5 g (34 mmol), phenyl boronic acid 16 g (135 mmol), Pd(PPh₃)₄ 3.9 g (2.4 mmol), K₂CO₃ 23 g (135 mmol), toluene 100 mL, ethanol 50 mL, and H₂O 50 mL in a flask, the mixture was stirred at 120° C. for 6 hours. Then, the reaction mixture was dried, and separated with a column to obtain compound 1-1 6.4 g (82%).

Preparation of Compound 1-2

After adding compound 1-1 4 g (17 mmol), IrCl₃ 2.3 g (7.8 mmol), 2-ethoxyethanol 60 mL, and H₂O 20 mL (2-ethoxyethanol/H₂O=3/1) in a flask, the mixture was stirred at 120° C. for 24 hours under reflux. After completing the reaction, the mixture was washed using H₂O/MeOH/Hex, and dried to obtain compound 1-2 3.0 g (56%).

Preparation of Compound 1-3

After adding compound 1-2 3.0 g (2.2 mmol), 2,4-pentanedion 0.6 g (6.5 mmol), Na₂CO₃ 1.4 g (13 mmol), and 2-ethoxyethanol 10 mL in a flask, the mixture was stirred at 110° C. for 12 hours. After completing the reaction, the produced solid was dried, and separated with a column to obtain compound 1-3 3 g (75%).

Preparation of Compound D-1

After adding compound 1-3 2.44 g (3.25 mmol), and compound 1-1 1.5 g (6.49 mmol) in a flask, glycerol was added to the mixture, and stirred for 16 hours under reflux. After the reaction, the produced solid was filtered, dried, and separated with a column to obtain compound D-1 2.5 g (87%).

### Example 2

### Preparation of Compound D-2 and D-8

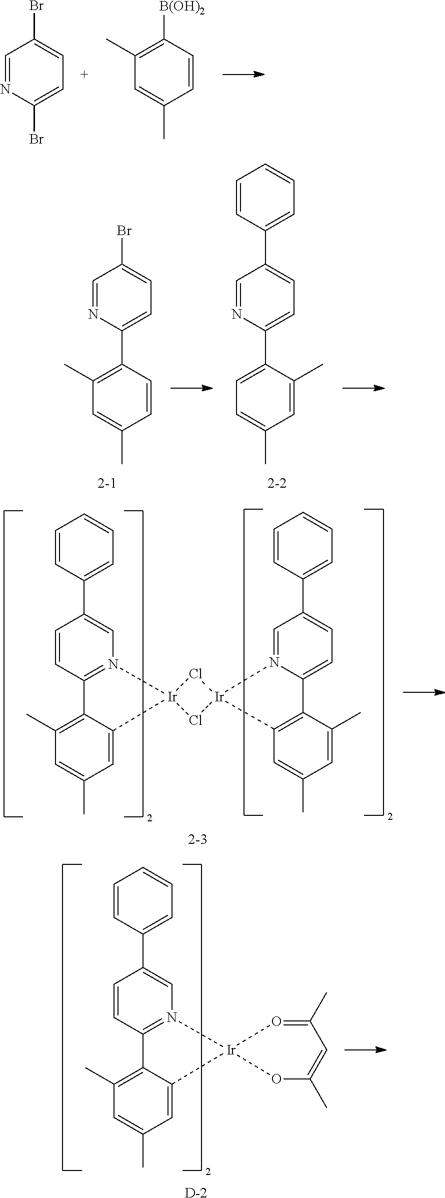

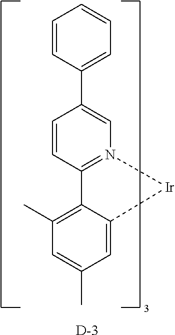

Preparation of Compound 2-1

After adding 2,5-dibromopyridine 20 g (84 mmol), 2,4-dimethylphenyl boronic acid 15 g (101 mmol), Pd(PPh₃)₄ 4 g (3.4 mmol), Na₂CO₃ 27 g (253 mmol), toluene 240 mL, and H₂O 120 mL in a flask, the mixture was stirred at 100° C. for 12 hours. Then, the reaction mixture was extracted with ethylacetate (EA), and the moisture was removed using MgSO₄, and distilled under reduced pressure. Then, the reaction mixture was dried, and separated with a column to obtain compound 2-1 18 g (70%).

Preparation of Compound 2-2

Compound 2-2 18 g (99%) was prepared by using compound 2-1 18 g (70 mmol), and phenyl boronic acid 13 g (105 mmol) in a flask in the same manner as the synthetic method of compound 1-1.

Preparation of Compound 2-3 Compound 2-3 13 g (72%) was prepared by using compound 2-2 14 g (54 mmol), and IrCl₃ 7.5 g (24.3 mmol) in a flask in the same manner as the synthetic method of compound 1-2.

Preparation of Compound D-2

Compound D-2 2.4 g (74%) was prepared by using compound 2-3 3 g (2 mmol) in a flask in the same manner as the synthetic method of compound 1-3.

Preparation of Compound D-8

Compound D-8 1.5 g (50%) was prepared by using compound D-2 2.4 g (3 mmol) in a flask in the same manner as the synthetic method of compound D-1.

### Example 3

### Preparation of Compound D-9 and D-10

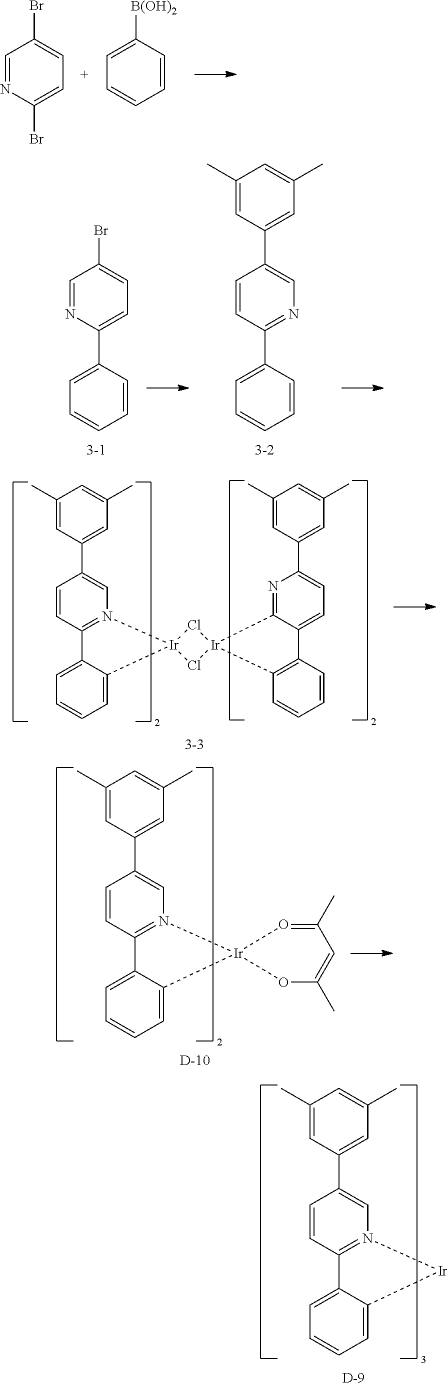

Preparation of Compound 3-1

Compound 3-1 16 g (79%) was prepared by using 2,5-dibromopyridine 20 g (84 mmol), and phenyl boronic acid 12 g (101 mmol) in a flask in the same manner as the synthetic method of compound 2-1.

Preparation of Compound 3-2

Compound 3-2 17 g (97%) was prepared by using compound 3-1 16 g (67 mmol), and 3,5-dimethylphenyl boronic acid 15 g (101 mmol) in a flask in the same manner as the synthetic method of compound 2-2.

Preparation of Compound 3-3

Compound 3-3 6 g (65%) was prepared by using compound 3-2 7 g (27 mmol), and IrCl₃ 3.7 g (12 mmol) in a flask in the same manner as the synthetic method of compound 2-3.

Preparation of Compound D-10

Compound D-10 5 g (81%) was prepared by using compound 3-3 6 g (4 mmol), and 2,4-pentanedion 1.2 g (12 mmol) in a flask in the same manner as the synthetic method of compound D-2.

Preparation of Compound D-9

Compound D-9 1.6 g (45%) was prepared by using compound D-10 3 g (3.7 mmol), and compound 3-2 2 g (7.4 mmol) in a flask in the same manner as the synthetic method of compound D-8.

### Example 4

### Preparation of Compound D-11 and D-12

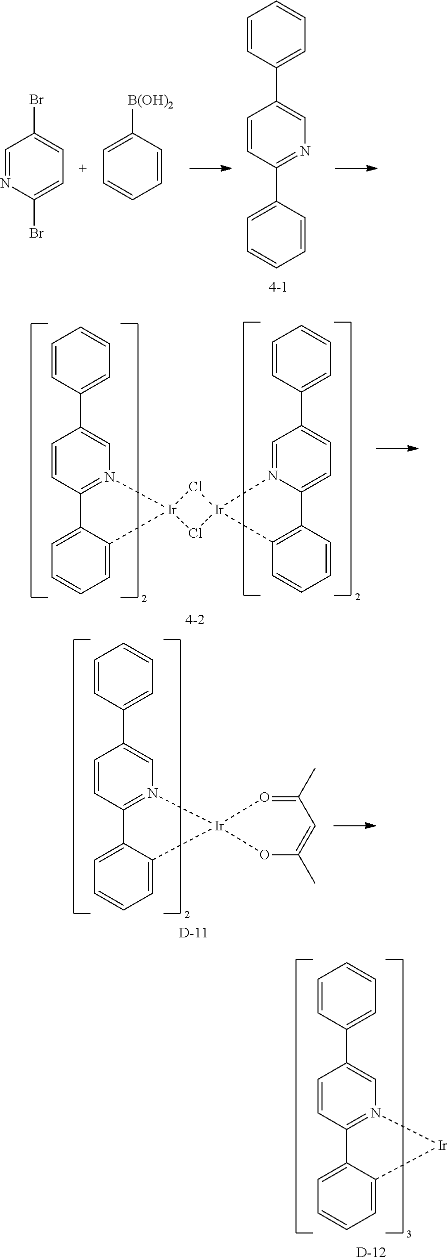

Preparation of Compound 4-1

Compound 4-1 60 g (87%) was prepared by using 2,5-dibromopyridine 70 g (295.5 mmol), and phenyl boronic acid 83 g (679.6 mmol) in a flask in the same manner as the synthetic method of compound 1-1.

Preparation of Compound 4-2

Compound 4-2 44 g (92%) was prepared by using compound 4-1 40 g (380.5 mmol), and IrCl₃ 23.5 g (173 mmol) in a flask in the same manner as the synthetic method of compound 1-2.

Preparation of Compound D-11

Compound D-11 42 g (87.4%) was prepared by using compound 4-2 44 g (48 mmol), and 2,4-pentanedion 9.6 g (96 mmol) in a flask in the same manner as the synthetic method of compound 1-3.

Preparation of Compound D-12

Compound D-12 20 g (38%) was prepared by using compound D-11 42 g (80.5 mmol), and compound 4-1 20 g (161 mmol) in a flask in the same manner as the synthetic method of compound D-1.

### Example 5

### Preparation of Compound H-33

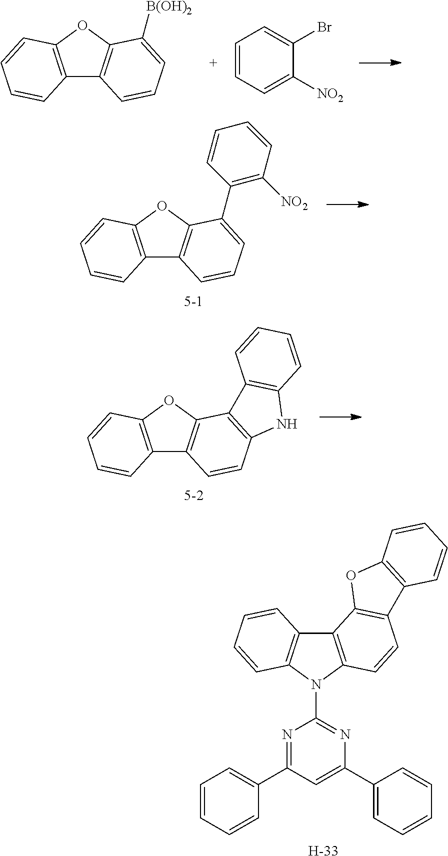

Preparation of Compound 5-1

After mixing 1-bromo-2-nitrobenzene 39 g (0.19 mol), dibenzo[b,d]furan-4-yl boronic acid 45 g (0.21 mol), Pd(PPh₃)₄ 11.1 g (0.0096 mol), 2 M K₂CO₃ aqueous solution 290 mL, EtOH 290 mL, and toluene 580 mL, the mixture was stirred while heating at 120° C. for 4 hours. After completing the reaction, the mixture was washed with distilled water, extracted with EA, and the organic layer was dried with anhydrous MgSO₄. Then, solvent was removed with a rotary evaporator, and the remaining product was purified using column chromatography to obtain compound 5-1 47 g (85%).

Preparation of Compound 5-2

After mixing compound 5-1 47 g (0.16 mol), triethylphosphite 600 mL, and 1,2-dichlorobenzene 300 mL, the mixture was stirred at 150° C. for 12 hours. After completing the reaction, unreacted triethylphosphite and 1,2-dichlorobenzene was removed using a distillation apparatus, and the remaining product was washed with distilled water, extracted with EA, and the organic layer was dried with anhydrous MgSO₄. Then, solvent was removed with a rotary evaporator, and the remaining product was purified using column chromatography to obtain compound 5-2 39 g (81%).

Preparation of Compound H-33

After dissolving NaH 1.9 mg (42.1 mmol) in dimethylformamide (DMF), the mixture was stirred. Then, compound 5-2 7 g (27.2 mmol) was dissolved in DMF, and added to the NaH solution which was being stirred. Then, the mixture was stirred for 1 hour. After dissolving 2-chloro-4,6-diphenylpyrimidine 8.7 g (32.6 mmol) in DMF, the mixture was stirred, and the reactant which was stirred for 1 hour was added to the mixture, and the mixture was stirred at room temperature for 24 hours. After completing the reaction, the produced solid was filtered, washed with ethylacetate, and purified using column chromatography to obtain compound H-33 3.5 g (25%).

### Example 6

### Preparation of Compound H-43

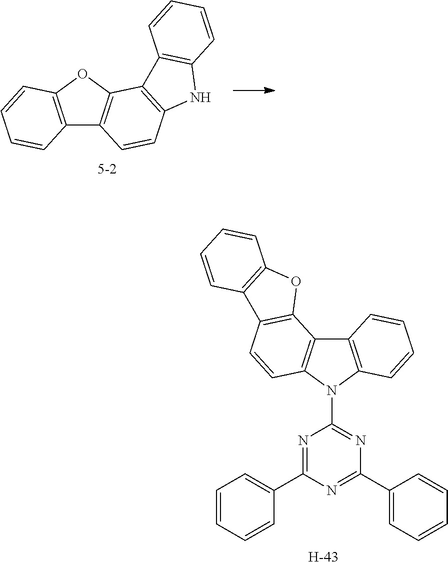

Compound H-43 11.3 g (78%) was prepared by using compound 5-2 7 g (27.2 mmol), and 2-chloro-4,6-diphenyl-1,3,5-triazine 8.2 g (32.6 mmol) in the same manner as the synthetic method of compound H-33.

### Example 7

### Preparation of Compound H-45

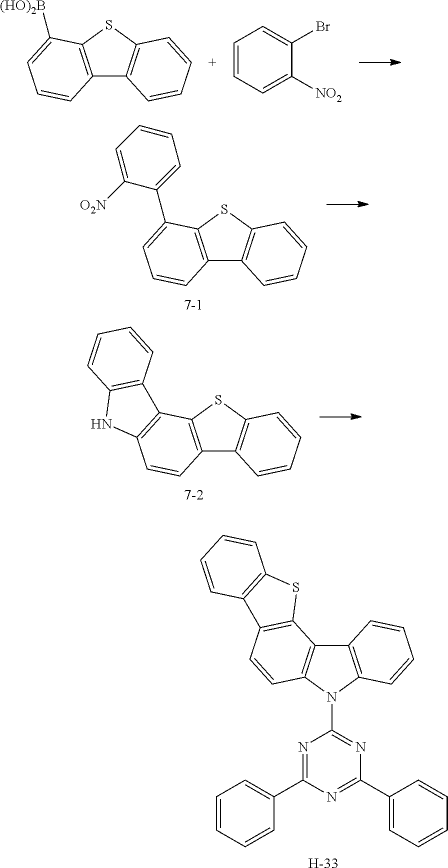

Preparation of Compound 7-1

Compound 7-1 10 g (32.74 mmol, 74.68%) was prepared by using dibenzo[b,d]thiophen-4-yl boronic acid 10 g (43.84 mmol) in the same manner as the synthetic method of compound 5-1.

Preparation of Compound 7-2

Compound 7-2 7 g (25.60 mmol, 78.19%) was prepared by using compound 7-1 10 g (32.74 mmol) in the same manner as the synthetic method of compound 5-2.

Preparation of Compound H-45

Compound H-45 5.6 g (40%) was prepared by using compound 7-2 7 g (25.6 mmol), and 2-chloro-4,6-diphenyl-1,3,5-triazine 8.7 g (32.6 mmol) in the same manner as the synthetic method of compound H-33.

### Example 8

### Preparation of Compound H-67

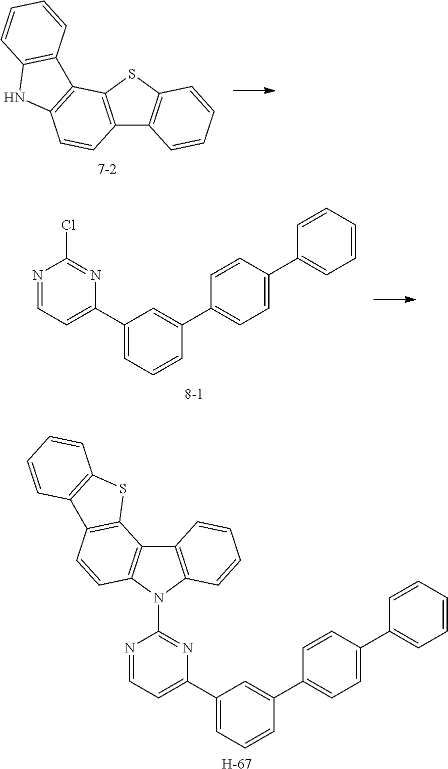

Compound H-67 5.3 g (49%) was prepared by using compound 7-2 7 g (25.6 mmol), and compound 8-1 8.2 g (32.6 mmol) in the same manner as the synthetic method of compound H-33.

### Example 9

### Preparation of Compound H-99

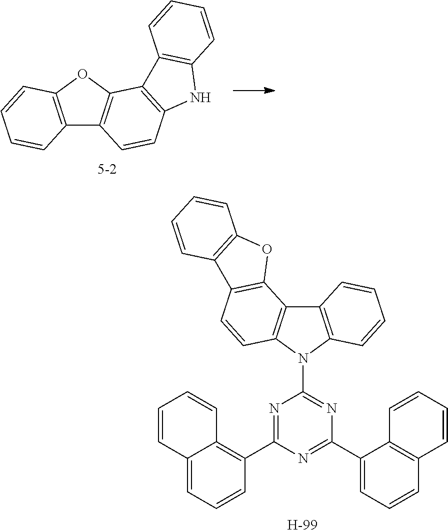

Compound H-99 8.6 g (46%) was prepared by using compound 5-2 7 g (27.2 mmol), and 2-chloro-4,6-di(naphthalen-1-yl)-1,3,5-triazine 15.2 g (32.6 mmol) in the same manner as the synthetic method of compound H-33.

### Example 10

### Preparation of Compound H-118

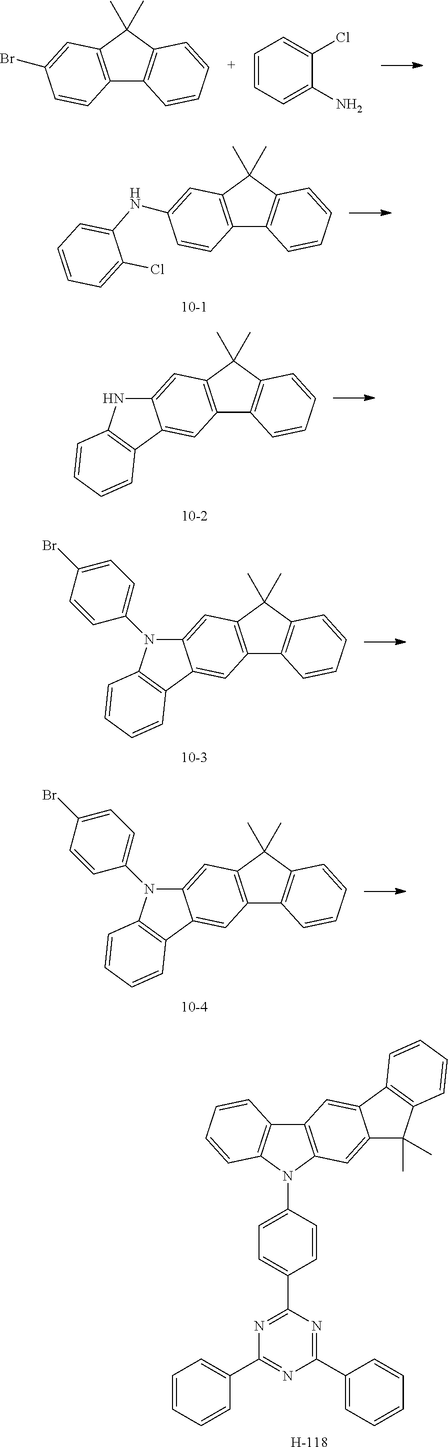

Preparation of Compound 10-1

After mixing 2-bromo-9,9-dimethyl-9H-fluorene 80 g (291 mmol), 2-chlorobenzeneamine 45 mL (437 mmol), Pd(OAc)₂ 2.6 g (12 mmol), P(t-Bu)₃ 12 mL (24 mmol), NaOt-Bu 70 g (728 mmol), and toluene 800 mL, the mixture was stirred while heating at 120° C. for 9 hours. After completing the reaction, the mixture was cooled to room temperature, extracted with ethylacetate 1.5 L, and the obtained organic layer was washed with distilled water 400 mL. Then, solvent was removed under reduced pressure, and the obtained solid was washed with hexane, filtered, and dried. Then, the obtained product was separated using silica gel column chromatography and recrystallization to obtain compound 10-1 70 g (75%).

Preparation of Compound 10-2

After mixing compound 10-1 70 g (218 mmol), Pd(OAc)₂ 2.4 g (11 mmol), PCy₃HBF₄ 8 g (22 mmol), Na₂CO₃ 70 g (654 mmol), and dimethylacetamide (DMA) 1.2 L, the mixture was stirred at 190° C. for 3 hours. After completing the reaction, the mixture was extracted with ethylacetate 1 L, the obtained organic layer was washed with distilled water 200 mL, and dried with anhydrous MgSO₄. Then, the organic solvent was removed under reduced pressure. Then, the obtained solid was separated using silica gel column chromatography and recrystallization to obtain compound 10-2 22 g (36%).

Preparation of Compound 10-3

After mixing compound 10-2 15 g (53 mmol), 1,4-dibromobenzene 32 mL (265 mmol), Pd(OAc)₂ 1.2 g (5 mmol), P(t-Bu)₃ 30 mL (64 mmol), NaOt-Bu 25 g (265 mmol), and toluene 300 mL, the mixture was stirred at 120° C. for 24 hours. After completing the reaction, the mixture was cooled to room temperature, extracted with ethylacetate 1.5 L, and the obtained organic layer was washed with distilled water 400 mL. Then, solvent was removed under reduced pressure, and the obtained solid was washed with hexane, filtered, and dried. Then, the obtained product was separated using silica gel column chromatography and recrystallization to obtain compound 10-3 7 g (30%).

Preparation of Compound 10-4

After dissolving compound 10-3 7 g (16 mmol) in tetrahydrofuran (THF) 100 mL, n-BuLi (2.5 M in hexane) 10 mL (24 mmol) was added to the mixture at −78° C. Then, the mixture was stirred at −78° C. for 1 hour, and B(Oi-Pr)₃ 6 mL (24 mmol) was added to the mixture. Then, the mixture was stirred for 2 hours, and the reaction was completed with aqueous ammonium chloride solution 20 mL. Then, the mixture was extracted with ethylacetate 500 mL, the obtained organic layer was washed with distilled water 200 mL, dried with anhydrous MgSO₄, and the organic solvent was removed under reduced pressure. Then, the obtained solid was separated by recrystallization to obtain compound 10-4 5 g (75%).

Preparation of Compound H-118

After mixing 2-chloro-4,6-diphenyl-1,3,5-triazine 6.5 g (0.03 mol), compound 10-4 19.2 g (0.036 mol), Pd(PPh₃)₄ 1.6 g (0.001 mol), K₂CO₃ 11 g (0.08 mol), toluene 140 mL, EtOH 35 mL, and H₂O 40 mL in a flask, the mixture was stirred at 120° C. for 12 hours. After completing the reaction, the mixture was extracted using ethylacetate, the organic layer was dried with MgSO₄, filtered, and the solvent was removed under reduced pressure. Then, the remaining product was separated with a column to obtain compound H-118 5.7 g (27%).

The detailed data of the dopant compounds prepared in Examples 1 to 4, and the dopant compounds easily prepared using Examples 1 to 4 are shown in table 1 below.

TABLE 1

| | | Melting Point | UV spectrum | PL spectrum |
|---|---|---|---|---|
| Compound | Yield (%) | (° C.) | (nm) | (nm) |
| D-1 | 87 | 273 | 308 | 459 |
| D-2 | 82 | 360 | 334 | 550 |
| D-3 | 81 | 154 | 308 | 541 |
| D-5 | 62 | 265 | 312 | 534 |
| D-7 | 35 | 297 | 298 | 568 |
| D-8 | 34 | over 400 | 320 | 556 |
| D-9 | 81 | 360 | 326 | 541 |
| D-10 | 45 | N/A | N/A | N/A |
| D-11 | 92 | N/A | N/A | N/A |
| D-12 | 61 | 360 | 326 | 541 |
| D-18 | 36 | 360 | 334 | 550 |
| D-32 | 36 | over 400 | 296 | 542 |
| D-33 | 42 | 380 | 296 | 547 |
| D-34 | 78 | over 400 | 308 | 545 |
| D-35 | 82 | 358 | 356 | 545 |
| D-36 | 14 | 360 | 288 | 561 |

The detailed data of the host compounds prepared in Examples 5 to 10, and the host compounds easily prepared using Examples 5 to 10 are shown in table 2 below.

TABLE 2

| | Yield | Melting Point | UV spectrum | PL spectrum | |
|---|---|---|---|---|---|
| Compound | (%) | (° C.) | (nm) | (nm) | Mass |
| H-33 | 25 | 260 | 358 | 471 | 488.5 |
| H-34 | 30 | 259 | 336 | 463 | 686.9 |
| H-36 | 26 | 350 | 356 | 429 | 581.7 |
| H-38 | 19 | 329 | 340 | 420 | 580.7 |
| H-41 | 46 | 225 | 338 | 482 | 504.3 |
| H-43 | 78 | 312 | 344 | 385 | 489.5 |
| H-44 | 67 | 249 | 324 | 458 | 610.7 |
| H-45 | 40 | 324 | 352 | 482 | 505.7 |
| H-46 | 16 | 339 | 322 | 411 | 580.7 |
| H-48 | 65 | 253 | 354 | 480 | 564 |
| H-49 | 50 | 275 | 340 | 498 | 538 |
| H-50 | 57 | 288 | 322 | 492 | 554 |
| H-52 | 60 | 250 | 334 | 428 | 680 |
| H-53 | 66 | 278 | 345 | 501 | 578 |
| H-55 | 45 | 255 | 334 | 451 | 581.7 |
| H-57 | 89 | 275 | 320 | 456 | 580.7 |
| H-58 | 72 | 267 | 334 | 459 | 610.7 |
| H-60 | 46 | 270 | 344 | 471 | 593.7 |
| H-63 | 42 | 288 | 370 | 475 | 745.9 |
| H-64 | 28 | 323 | N/A | N/A | 746.8 |
| H-65 | 39 | 320 | 325 | 516 | 581.7 |
| H-66 | 38 | 198 | 317 | 461 | 504.6 |
| H-67 | 49 | 274 | 322 | 491 | 580.7 |
| H-70 | 76 | 266 | 370 | 489 | 614 |
| H-80 | 23 | 270 | 324 | 456 | 763 |
| H-84 | 49 | 284 | 368 | 474 | 669.8 |
| H-85 | 60 | 212 | 368 | 433 | 640 |
| H-86 | 31 | 289 | 384 | 436 | 690 |
| H-88 | 34 | 294 | N/A | N/A | 656.8 |
| H-89 | 26 | 245 | 300 | 460 | 656.8 |
| H-91 | 42 | 328 | 343 | 481 | 656.8 |
| H-92 | 32 | 294 | 296 | 467 | 655.2 |
| H-94 | 52 | 241 | 294 | 464 | 581.7 |
| H-95 | 30 | 293 | 344 | 469 | 669.8 |
| H-96 | 23 | 238 | 362 | 429 | 593.7 |
| H-97 | 60 | 280 | 294 | 468 | 593.7 |
| H-99 | 46 | 324 | 324 | 495 | 589.7 |
| H-100 | 82 | 250 | 356 | 448 | 669.8 |
| H-104 | 44 | 357 | 322 | 460 | 655.8 |
| H-109 | 48 | 278 | 344 | 395 | 580.7 |
| H-112 | 48 | 221 | 334 | 396 | 656.8 |
| H-118 | 27 | 240 | 308 | 451 | 590.7 |
| H-120 | 57 | 261 | 344 | 431 | 593.7 |
| H-121 | 70 | 255 | 356 | 521 | 564 |
| H-122 | 12 | 218 | 358 | 445 | 640 |
| H-123 | 67 | 261 | 344 | 521 | 614 |
| H-124 | 47 | 315.4 | 314 | 530 | 779 |
| H-130 | 16 | 347 | 324 | 525 | 669.9 |
| H-131 | 34 | 410 | 258 | 324 | 670.8 |
| H-132 | 36 | 300 | 258 | 487 | 686.9 |
| H-135 | 74 | 375 | 340 | 473 | 687.8 |
| H-139 | 23 | 300 | 336 | 458 | 580.7 |
| H-141 | 36 | 299 | 332 | 386 | 805 |
| H-144 | 62 | 294 | 336 | 479 | 627 |
| H-145 | 69 | 269 | 324 | 496 | 552 |
| H-146 | 55 | 254 | 304 | 532 | 627 |
| H-147 | 89 | 277 | 336 | 481 | 578 |
| H-148 | 60 | 306 | 334 | 427 | 628 |
| H-149 | 22 | 200 | 392 | 421 | 703 |
| H-150 | 50 | 243 | 332 | 424 | 654 |
| H-151 | 51 | 291 | 346 | 505 | 588 |
| H-152 | 49 | 222 | 344 | 497 | 538 |
| H-153 | 77 | 271 | 308 | 431 | 614 |
| H-154 | 38 | 251 | 282 | 519 | 627 |
| H-164 | 24 | 275 | 344 | 467 | 610.8 |
| H-168 | 55 | 242 | 344 | 497 | 614 |
| H-169 | 53 | 275 | 310 | 495 | 628 |
| H-170 | 75 | 247 | 360 | 483 | 512 |
| H-173 | 50 | 305 | 350 | 502 | 656.8 |
| H-174 | 66 | 305 | 306 | 407 | 637.8 |
| H-175 | 22 | 238 | 304 | 465 | 636.8 |
| H-176 | 27 | 274 | 308 | 463 | 620.7 |
| H-179 | 71 | 173 | 292 | 509 | 554 |
| H-180 | 79 | 255 | 338 | 503 | 512 |
| H-181 | 49 | 309 | 304 | 427 | 536 |
| H-182 | 49 | 292 | 290 | 511 | 538 |
| H-183 | 51 | 256 | 310 | 504 | 703 |
| H-184 | 77 | 253 | 308 | 486 | 703 |
| H-185 | 80 | 231 | 308 | 487 | 614 |
| H-186 | 55 | 274 | 312 | 497 | 654 |
| H-187 | 48 | 336 | 350 | 508 | 665 |
| H-189 | 69 | 242 | 310 | 493 | 614 |
| H-190 | 57 | 190 | 307 | 390 | 538 |
| H-191 | 47 | 246 | 346 | 497 | 614 |
| H-192 | 80 | 247 | 308 | 487 | 630 |
| H-194 | 47 | 197 | 362 | 469 | 538 |
| H-195 | 24 | 291 | 376 | 447 | 614 |
| H-196 | 80 | 227 | 344 | 489 | 462 |
| H-197 | 59 | 283 | 368 | 495 | 628 |
| H-198 | 26 | 247 | 386 | 429 | 538 |
| H-199 | 38 | 285 | 310 | 490 | 644 |
| H-200 | 70 | 249 | 310 | 483 | 588 |
| H-202 | 25 | 255 | 384 | 423 | 613 |
| H-203 | 40 | 327 | 310 | 490 | 614 |
| H-204 | 38 | 280 | 346 | 484 | 564 |
| H-205 | 68 | 298 | 310 | 496 | 613 |
| H-206 | 46 | 288 | 310 | 487 | 554 |
| H-207 | 46 | 247 | 356 | 485 | 478 |
| H-208 | 45 | 267 | 390 | 501 | 588 |
| H-209 | 37 | 321 | 384 | 491 | 640 |
| H-210 | 33 | 267 | 344 | 497 | 538 |
| H-211 | 47 | 301 | 344 | 483 | 653 |
| H-212 | 35 | 289 | 372 | 479 | 670 |
| H-213 | 75 | 276 | 344 | 489 | 588 |
| H-214 | 72 | 265 | 350 | 386 | 604 |
| H-215 | 69 | 258 | 324 | 501 | 637 |
| H-216 | 11 | 217 | 356 | 489 | 504 |
| H-217 | 57 | 257 | 342 | 491 | 538 |
| H-218 | 49 | 290 | 308 | 498 | 580 |
| H-219 | 63 | 275 | 308 | 505 | 630 |
| H-220 | 63 | 289 | 344 | 479 | 685 |
| H-221 | 22 | 235 | 336 | 521 | 668 |
| H-222 | 47 | 298 | 376 | 482 | 563 |
| H-223 | 49 | 256 | 372 | 487 | 614 |
| H-225 | 60 | 328 | 358 | 490 | 628 |
| H-226 | 65 | 330.5 | 360 | 507 | 644 |
| H-227 | 55 | 340 | 324 | 484 | 640 |
| H-229 | 57 | 227 | 342 | 487 | 538 |

### Device Example 1

### Production of an OLED Device Using the Organic Electroluminescent Compound According to the Present Invention

An OLED device was produced using the light emitting material according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N¹,N^{1′}-([1,1′-biphenyl]-4,4′-diyl)bis(N¹-(naphthalen-1-yl)-N⁴,N⁴-diphenylbenzen-1,4-diamine) was introduced into a cell of said vacuum vapor depositing apparatus, and then the pressure in the chamber of said apparatus was controlled to 10⁻⁶ torr. Thereafter, an electric current was applied to the cell to evaporate the above introduced material, thereby forming a hole injection layer having a thickness of 120 nm on the ITO substrate. Then, N4,N4,N4′,N4′-tetra([1,1′-biphenyl]-4-yl)-[1,1′-biphenyl]-4,4′-diamine was introduced into another cell of said vacuum vapor depositing apparatus, and was evaporated by applying an electric current to the cell, thereby forming a hole transport layer having a thickness of 20 nm on the hole injection layer. Thereafter, compound H-43 was introduced into one cell of the vacuum vapor depositing apparatus, as a host material, and compound D-9 was introduced into another cell as a dopant. The two materials were evaporated at different rates and were deposited in a doping amount of 12 wt % based on the total amount of the host and dopant to form a light-emitting layer having a thickness of 40 nm on the hole transport layer. Then, 2-(4-(9,10-di(naphthalen-2-yl)anthracen-2-yl)phenyl)-1-phenyl-1H-benzo[d]imidazole was introduced into one cell and lithium quinolate was introduced into another cell. The two materials were evaporated at the same rate and were deposited in a doping amount of 50 wt % each to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed a yellow-green emission having a luminance of 1470 cd/m² and a current density of 2.5 mA/cm².

### Device Example 2

### Production of an OLED Device Using the Organic Electroluminescent Compound According to the Present Invention

An OLED device was produced in the same manner as in Device Example 1, except for using compound H-45 as a host, and using compound D-12 as a dopant of the light emitting material.

The produced OLED device showed a yellow-green emission having a luminance of 3062 cd/m² and a current density of 5.07 mA/cm².

### Device Example 3

### Production of an OLED Device Using the Organic Electroluminescent Compound According to the Present Invention

An OLED device was produced in the same manner as in Device Example 1, except for using compound H-99 as a host, and using compound D-18 as a dopant of the light emitting material.

The produced OLED device showed a yellow-green emission having a luminance of 4305 cd/m² and a current density of 8.61 mA/cm².

### Device Example 4

### Production of an OLED Device Using the Organic Electroluminescent Compound According to the Present Invention

An OLED device was produced in the same manner as in Device Example 1, except for using compound H-67 as a host, and using compound D-9 as a dopant of the light emitting material.

The produced OLED device showed a yellow-green emission having a luminance of 1647 cd/m² and a current density of 2.86 mA/cm².

### Device Example 5

### Production of an OLED Device Using the Organic Electroluminescent Compound According to the Present Invention

An OLED device was produced in the same manner as in Device Example 1, except for using compound H-33 as a host, and using compound D-12 as a dopant of the light emitting material.

The produced OLED device showed a yellow-green emission having a luminance of 1164 cd/m² and a current density of 1.94 mA/cm².

### Device Example 6

### Production of an OLED Device Using the Organic Electroluminescent Compound According to the Present Invention

An OLED device was produced in the same manner as in Device Example 1, except for using compound H-118 as a host, and using compound D-18 as a dopant of the light emitting material.

The produced OLED device showed a yellow-green emission having a luminance of 5554 cd/m² and a current density of 15.6 mA/cm².

### Device Example 7

### Production of an OLED Device Using the Organic Electroluminescent Compound According to the Present Invention

An OLED device was produced in the same manner as in Device Example 1, except for using compound H-208 as a host, and using compound D-34 as a dopant of the light emitting material.

The produced OLED device showed a yellow-green emission having a luminance of 53100 cd/m² and a current density of 5.8 mA/cm².

As shown above, the organic EL device of the present invention contains a specific combination of a dopant compound and a host compound, and thus emits yellow-green light, and provides excellent current efficiency.

In addition, the organic electroluminescent compounds according to the present invention have high efficiency in transporting electrons to prevent crystallization during a device fabrication. Furthermore, the compounds have good layer formability and improve the current characteristic of the device. Therefore, they can produce an organic electroluminescent device having lowered driving voltages and enhanced power efficiency and operational lifespan.

In general, an organic EL device can emit white light by mixing 3 colors, i.e., red, green, and blue. On the other hand, when using the dopant compound and the host compound according to the present invention, it is possible to emit white color by bicolor combination with blue light.

1. A combination of one or more dopant compound represented by the following formula 1, and one or more host compound represented by the following formula 2: 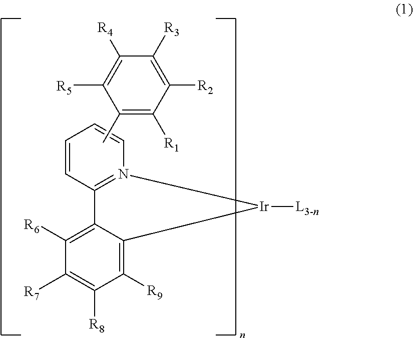
wherein
L is selected from the following structures: 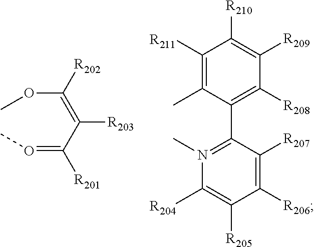
R₁ to R₉ each independently represent hydrogen, deuterium, a halogen, a substituted or unsubstituted (C1-C30)alkyl, a substituted or unsubstituted (C3-C30)cycloalkyl, a cyano, or a substituted or unsubstituted (C1-C30)alkoxy;
R₂₀₁ to R₂₁₁ each independently represent hydrogen, deuterium, a halogen, a substituted or unsubstituted (C1-C30)alkyl, or a substituted or unsubstituted (C3-C30)cycloalkyl; and
n represents an integer of 1 to 3; 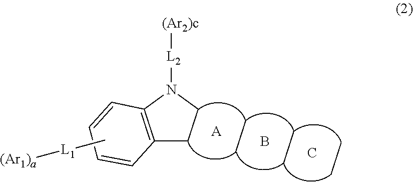
wherein
ring A and ring C each independently represent an aromatic ring represented by the following formula 1a;
ring B represents a 5-membered ring represented by the following formula 1b; 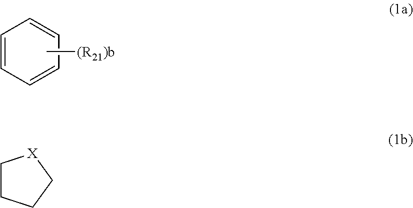
L₁ and L₂ each independently represent a single bond, a substituted or unsubstituted (C6-C30)arylene, or a substituted or unsubstituted 5- to 30-membered heteroarylene;
Ar₁ and Ar₂ each independently represent hydrogen, deuterium, a halogen, a cyano, a nitro, a hydroxyl, a substituted or unsubstituted (C1-C30)alkyl, a substituted or unsubstituted (C1-C30)alkoxy, a substituted or unsubstituted (C3-C30)cycloalkyl, a substituted or unsubstituted (C6-C30)aryl, a substituted or unsubstituted tri(C1-C30)alkylsilyl, a substituted or unsubstituted tri(C6-C30)arylsilyl, or a substituted or unsubstituted 5- to 30-membered heteroaryl; or are linked to an adjacent substituent(s) to form a mono- or polycyclic, (C3-C30)alicyclic or aromatic ring whose carbon atom(s) may be replaced with at least one hetero atom selected from nitrogen, oxygen and sulfur;
R₂₁ represents hydrogen, deuterium, a halogen, a substituted or unsubstituted (C1-C30)alkyl, a substituted or unsubstituted (C6-C30)aryl, a substituted or unsubstituted 5- to 30-membered heteroaryl, —NR₁₁R₁₂, —SiR₁₃R₁₄R₁₅, or are linked to an adjacent substituent(s) to form a mono- or polycyclic, (C3-C30)alicyclic or aromatic ring whose carbon atom(s) may be replaced with at least one hetero atom selected from nitrogen, oxygen and sulfur;
X represents —O—, —S—, —N(R₂₂)—, —C(R₂₃)(R₂₄)— or —Si(R₂₅)(R₂₆)—;
R₁₁ to R₁₅ and R₂₂ to R₂₆ each independently represent hydrogen, deuterium, a halogen, a substituted or unsubstituted (C1-C30)alkyl, a substituted or unsubstituted (C6-C30)aryl, or a substituted or unsubstituted 5- to 30-membered heteroaryl; or are linked to an adjacent substituent(s) to form a mono- or polycyclic, (C3-C30)alicyclic or aromatic ring whose carbon atom(s) may be replaced with at least one hetero atom selected from nitrogen, oxygen and sulfur;
a and c each independently represent an integer of 0 to 4; where a or c is an integer of 2 or more, each of Ar₁, and each of Ar₂ are same or different; and
b represents an integer of 0 to 2; where b is 2, each of R₂₁ are same or different.

2. The combination according to claim 1, wherein the compound represented by formula 1 is represented by formula 3 or 4: 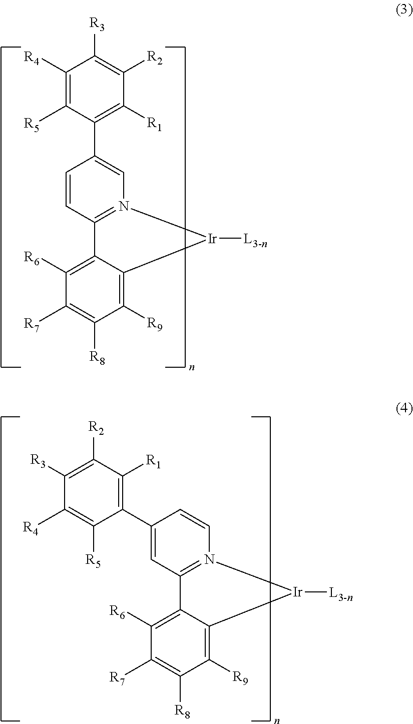
wherein R₁ to R₉, L, and n are as defined in claim 1.

3. The combination according to claim 1, wherein the compound represented by formula 2 is represented by any one of the following formulae 5 to 10: 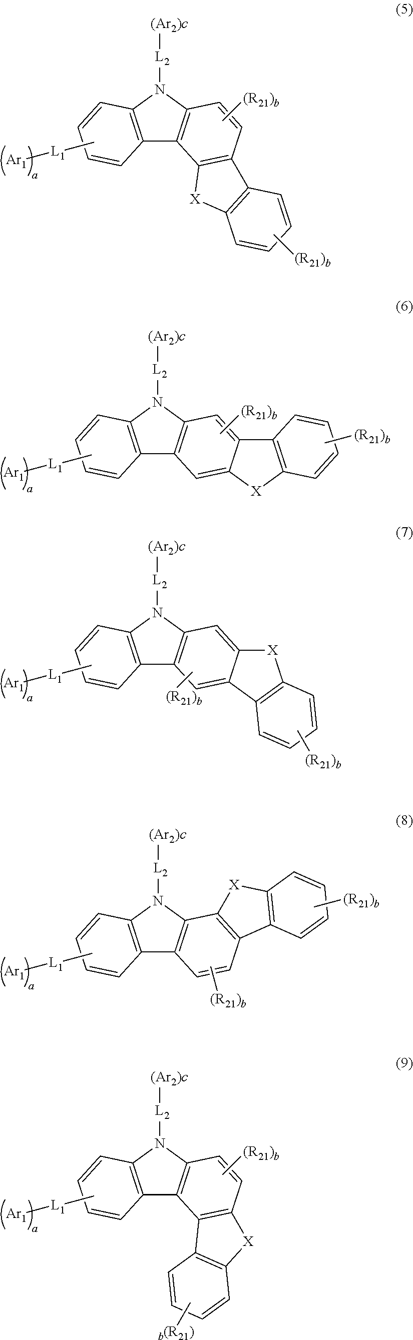 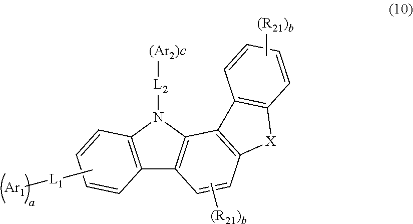
wherein L₁, L₂, Ar₁, Ar₂, R₂₁, X, a, b and c are as defined in claim 1.

4. The combination according to claim 1, wherein in formula 1, R₁ to R₉ each independently represent hydrogen, deuterium, a (C1-C10)alkyl unsubstituted or substituted with a halogen, an unsubstituted (C3-C7)cycloalkyl, or a (C1-C10)alkoxy unsubstituted or substituted with a halogen; and
R₂₀₁ to R₂₁₁ each independently represent hydrogen, or an unsubstituted (C1-C10)alkyl.

5. The combination according to claim 1, wherein in formula 2, L₁ and L₂ each independently represent a single bond, a substituted or unsubstituted (C6-C20)arylene, or a substituted or unsubstituted 5- to 22-membered heteroarylene;
Ar₁ and Ar₂ each independently represent hydrogen, a substituted or unsubstituted (C1-C6)alkyl, a substituted or unsubstituted (C6-C20)aryl, a substituted or unsubstituted tri(C1-C6)alkylsilyl, a substituted or unsubstituted tri(C6-C12)arylsilyl, or a substituted or unsubstituted 5- to 22-membered heteroaryl;
R₂₁ represents hydrogen, a substituted or unsubstituted (C6-C20)aryl, or a substituted or unsubstituted 5- to 22-membered heteroaryl; and
R₁₁ to R₁₅ and R₂₂ to R₂₆ each independently represent hydrogen, a substituted or unsubstituted (C1-C6)alkyl, a substituted or unsubstituted (C6-C20)aryl, or a substituted or unsubstituted 5- to 22-membered heteroaryl; or are linked to an adjacent substituent(s) to form a mono- or polycyclic, (C3-C30)alicyclic or aromatic ring.

6. The combination according to claim 1, wherein the compound represented by formula 1 is selected from the group consisting of:

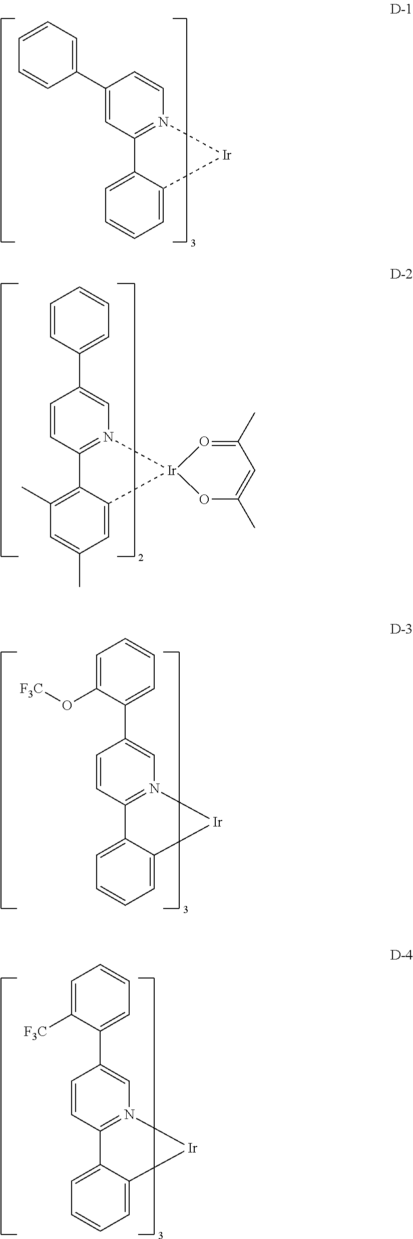

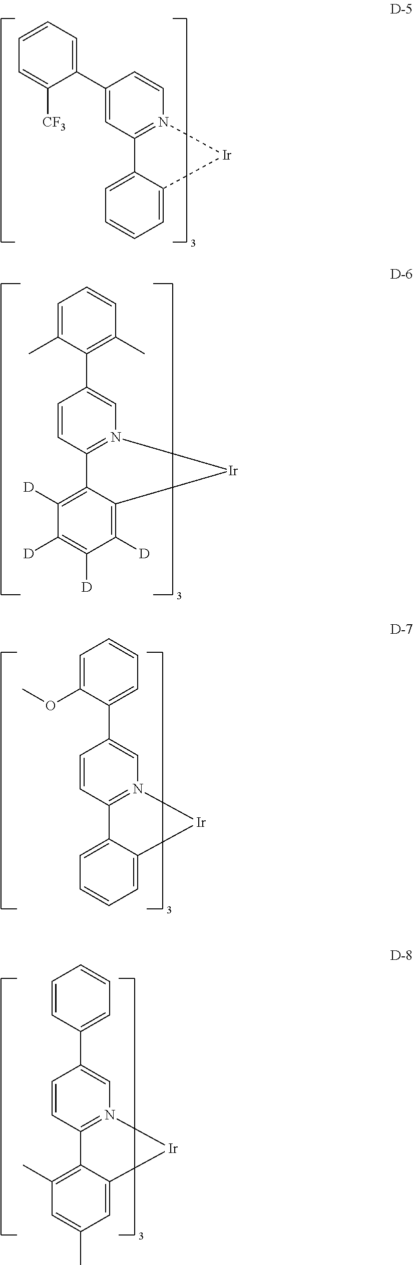

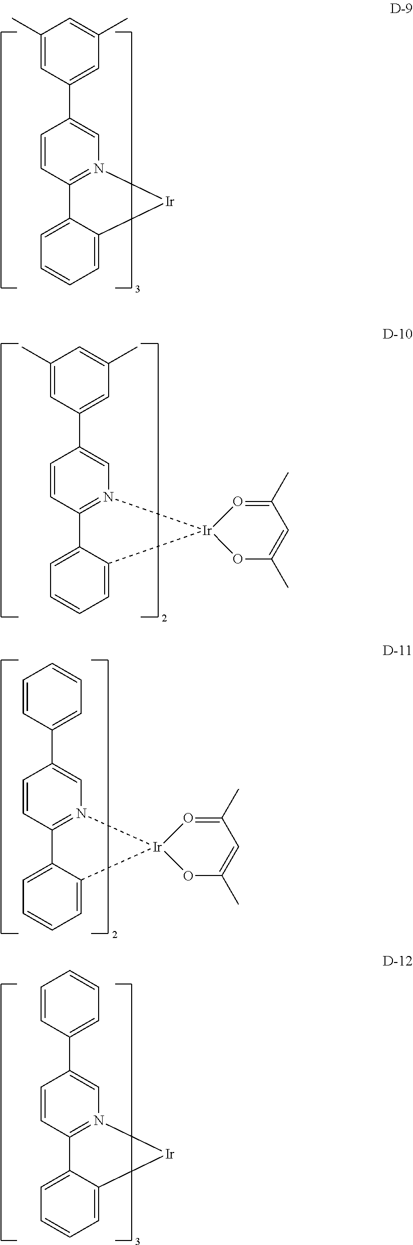

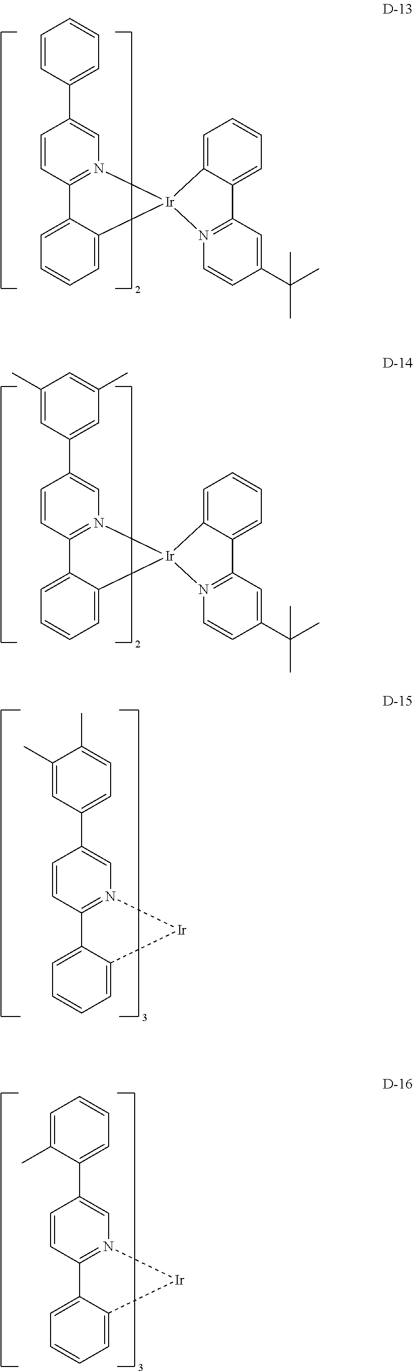

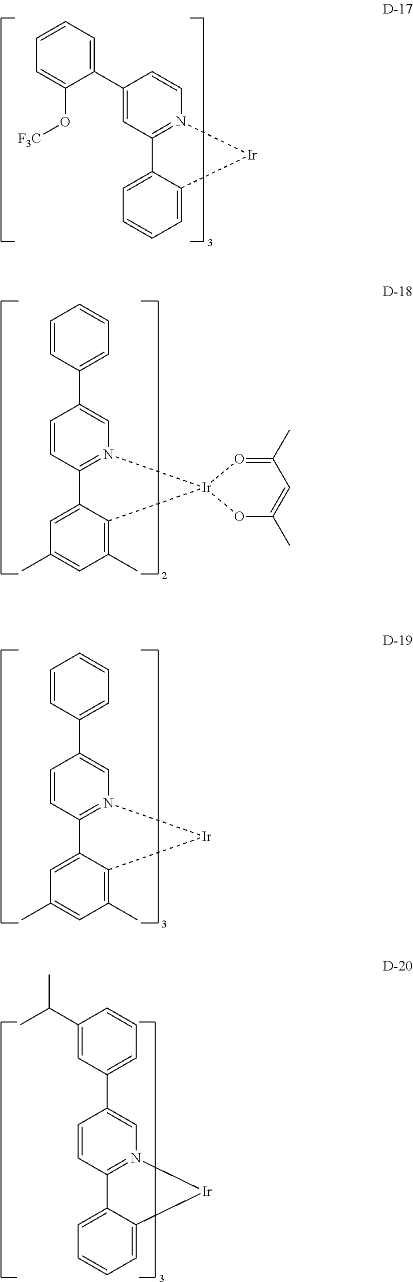

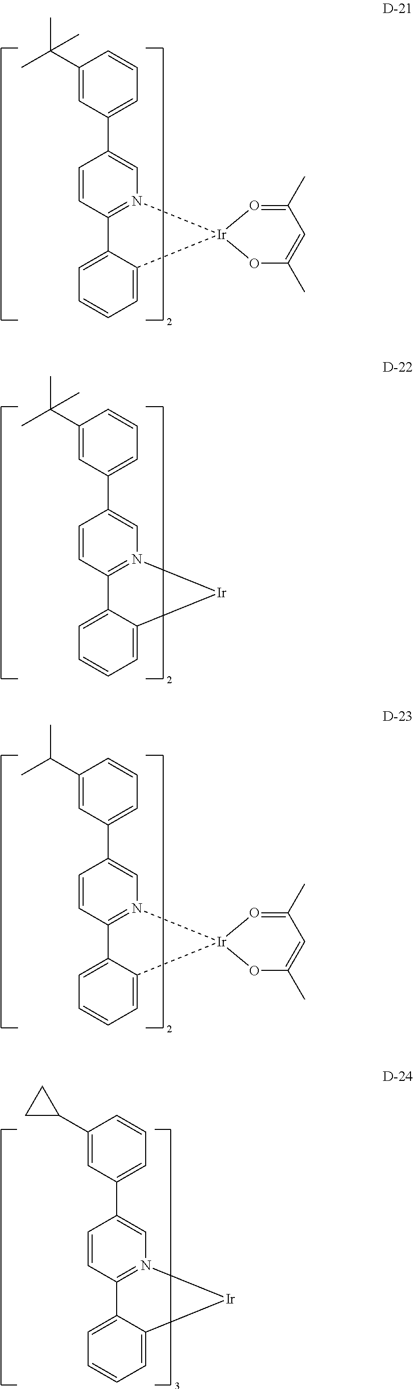

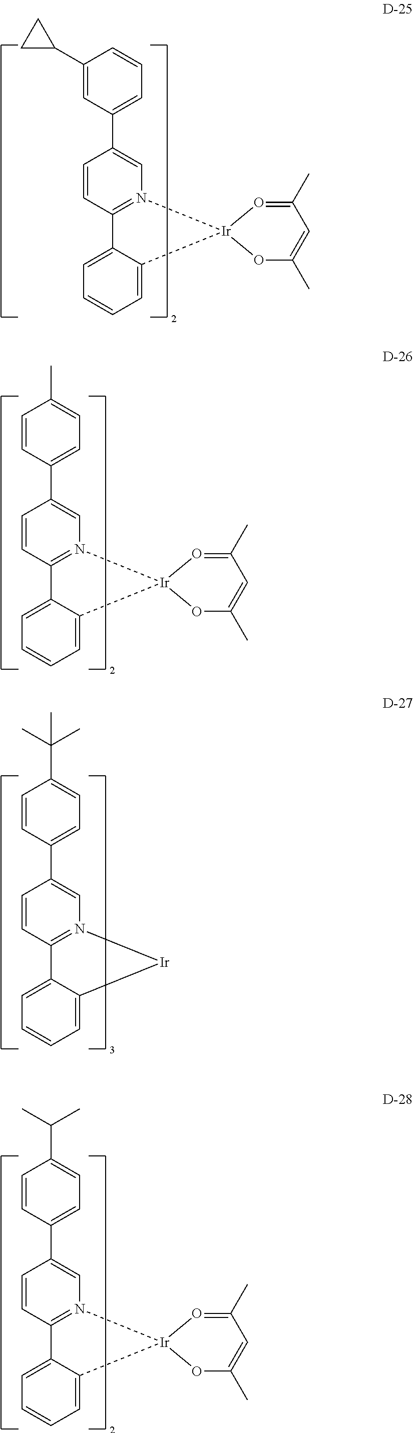

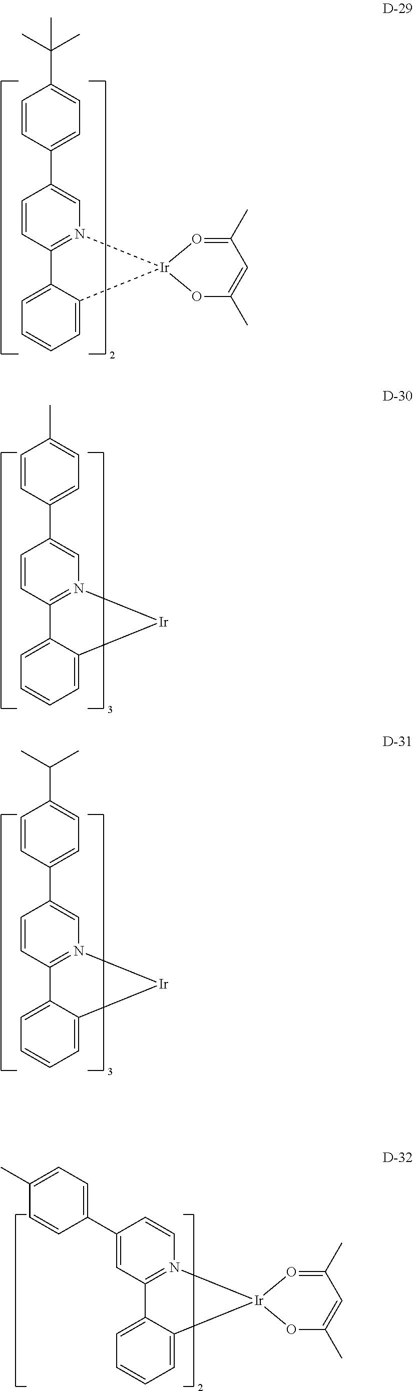

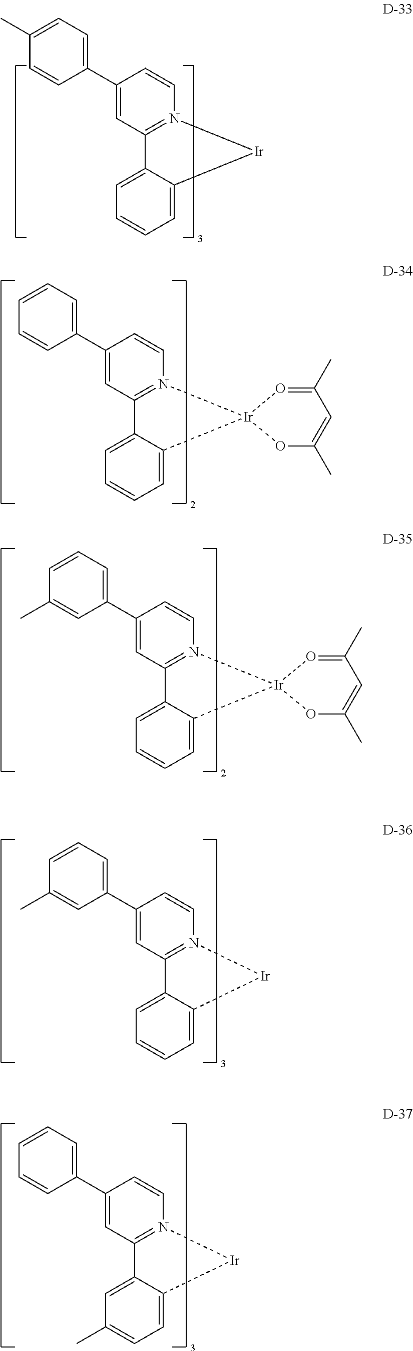

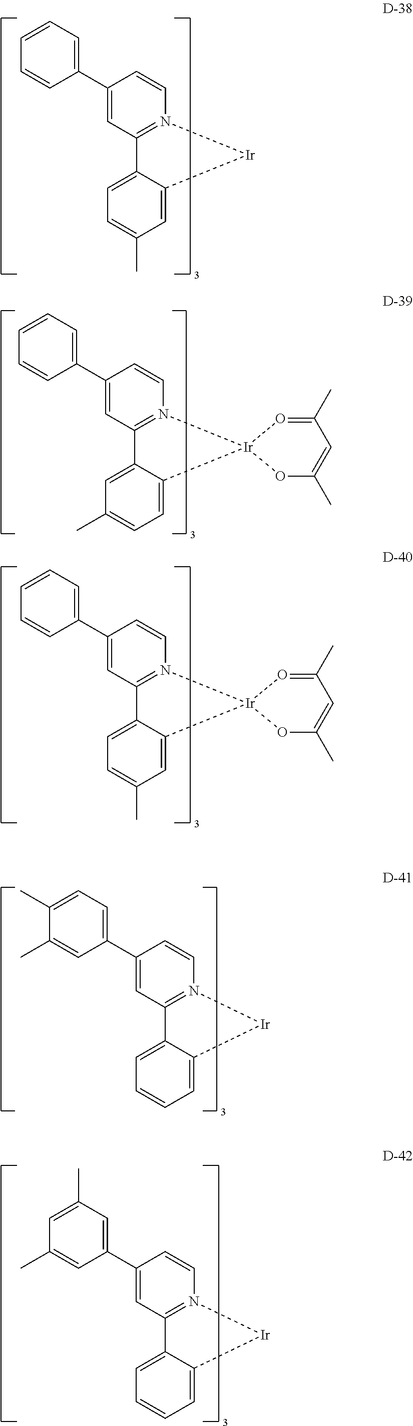

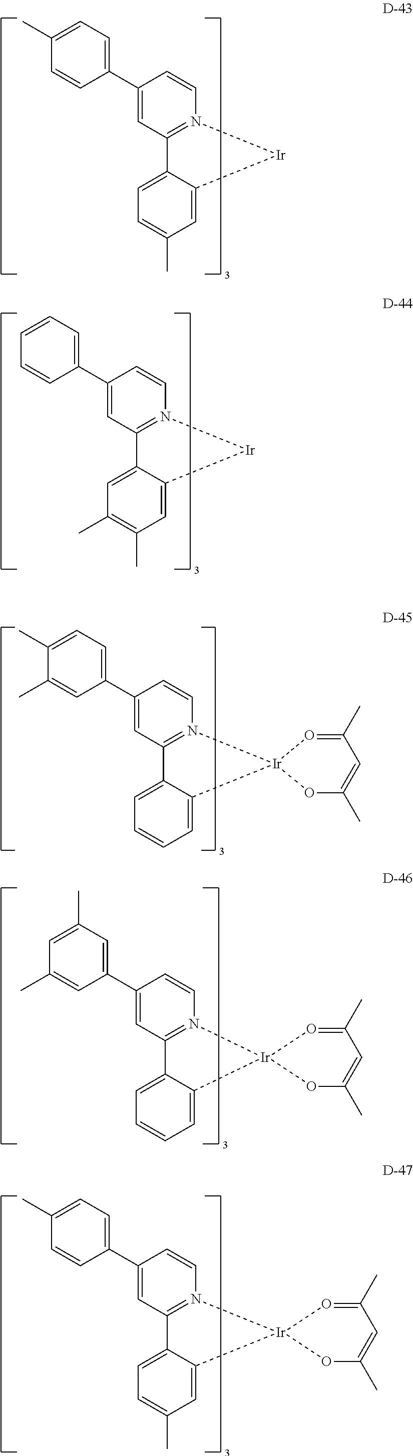

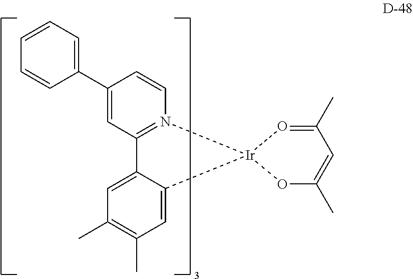

7. The combination according to claim 1, wherein the compound represented by formula 2 is selected from the group consisting of:

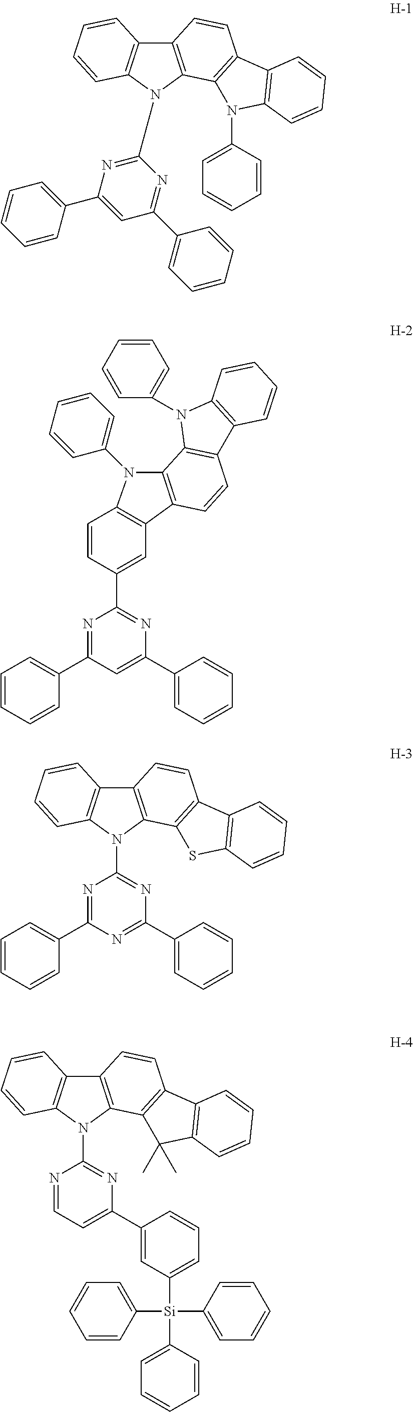 [SMILES: c1ccc(-c2cc(-c3ccccc3)nc(-n3c4ccccc4c4ccc5c6ccccc6n(-c6ccccc6)c5c43)n2)cc1 ; c1ccc(-c2cc(-c3ccccc3)nc(-c3ccc4c(c3)c3ccc5c6ccccc6n(-c6ccccc6)c5c3n4-c3ccccc3)n2)cc1 ; c1ccc(-c2nc(-c3ccccc3)nc(-n3c4ccccc4c4ccc5c6ccccc6sc5c43)n2)cc1 ; CC1(C)c2ccccc2-c2ccc3c4ccccc4n(-c4nccc(-c5cccc([Si](c6ccccc6)(c6ccccc6)c6ccccc6)c5)n4)c3c21]

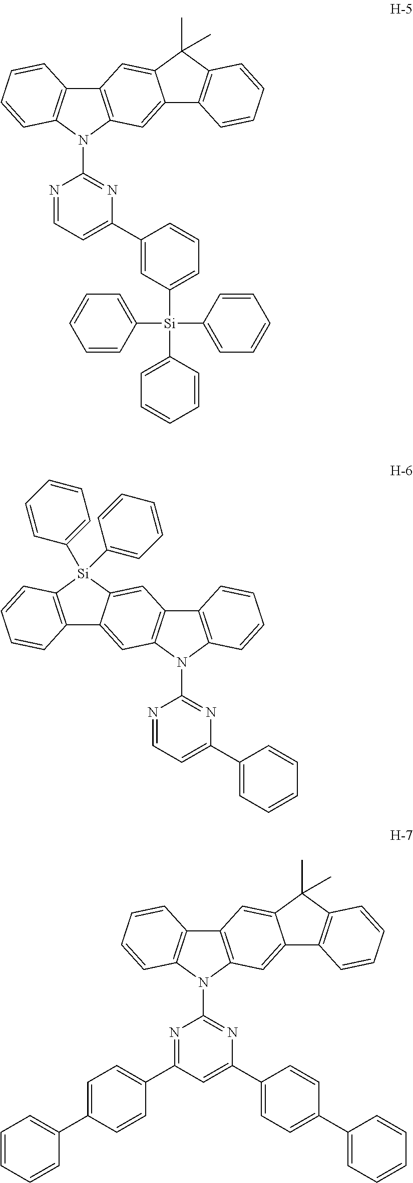 [SMILES: CC1(C)c2ccccc2-c2cc3c(cc21)c1ccccc1n3-c1nccc(-c2cccc([Si](c3ccccc3)(c3ccccc3)c3ccccc3)c2)n1 ; c1ccc(-c2ccnc(-n3c4ccccc4c4cc5c(cc43)-c3ccccc3[Si]5(c3ccccc3)c3ccccc3)n2)cc1 ; CC1(C)c2ccccc2-c2cc3c(cc21)c1ccccc1n3-c1nc(-c2ccc(-c3ccccc3)cc2)cc(-c2ccc(-c3ccccc3)cc2)n1]

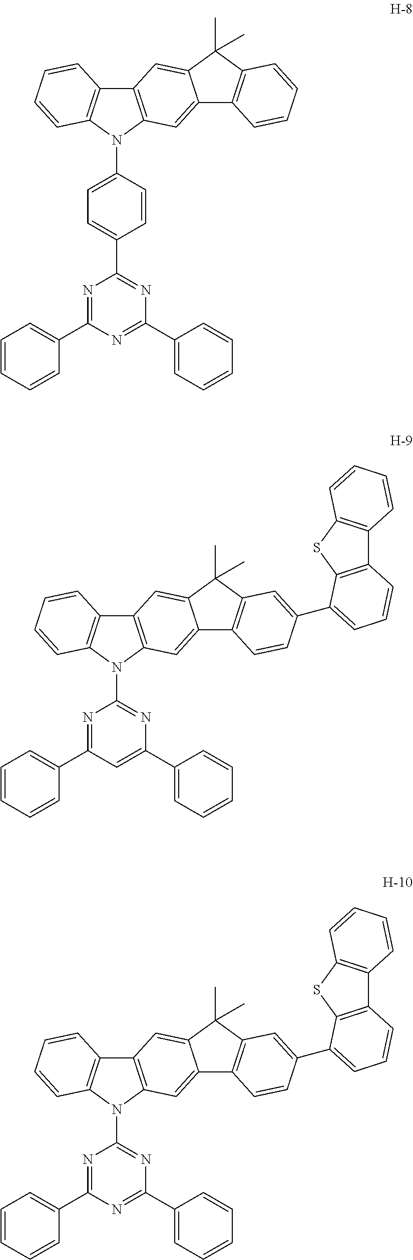 [SMILES: CC1(C)c2ccccc2-c2cc3c(cc21)c1ccccc1n3-c1ccc(-c2nc(-c3ccccc3)nc(-c3ccccc3)n2)cc1 ; CC1(C)c2cc(-c3cccc4c3sc3ccccc34)ccc2-c2cc3c(cc21)c1ccccc1n3-c1nc(-c2ccccc2)cc(-c2ccccc2)n1 ; CC1(C)c2cc(-c3cccc4c3sc3ccccc34)ccc2-c2cc3c(cc21)c1ccccc1n3-c1nc(-c2ccccc2)nc(-c2ccccc2)n1]

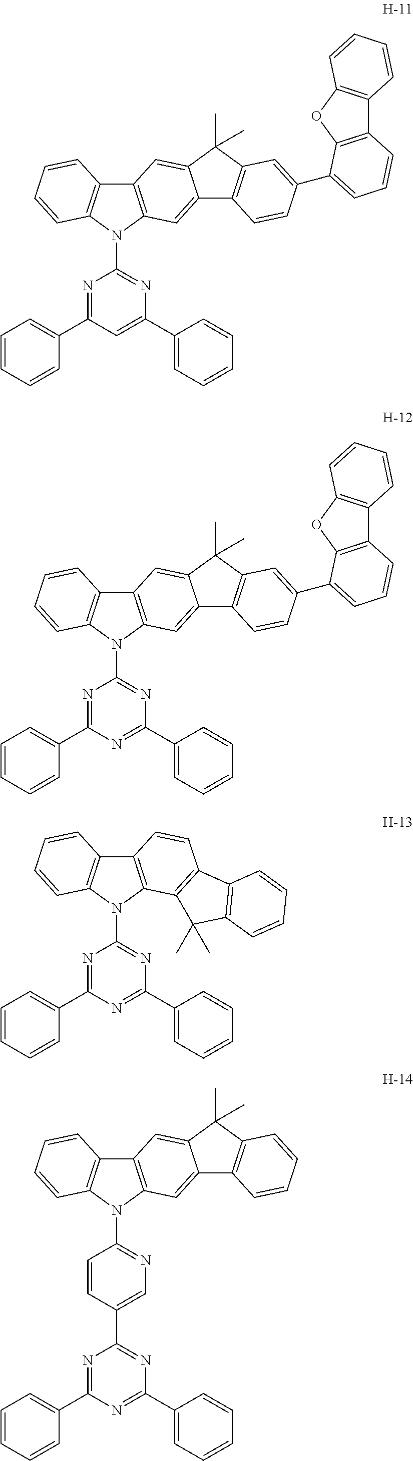

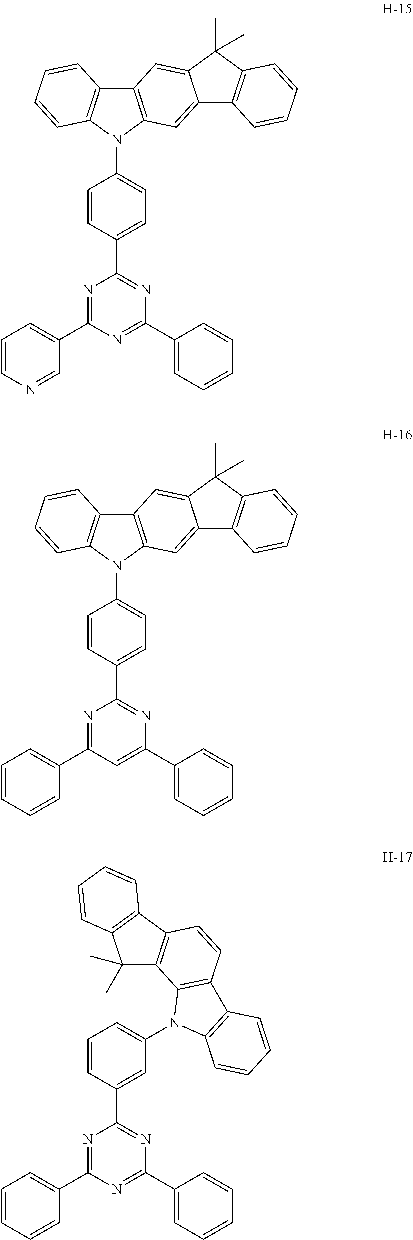 [SMILES: CC1(C)c2ccccc2-c2cc3c(cc21)c1ccccc1n3-c1ccc(-c2nc(-c3ccccc3)nc(-c3cccnc3)n2)cc1 ; CC1(C)c2ccccc2-c2cc3c(cc21)c1ccccc1n3-c1ccc(-c2nc(-c3ccccc3)cc(-c3ccccc3)n2)cc1 ; CC1(C)c2ccccc2-c2ccc3c4ccccc4n(-c4cccc(-c5nc(-c6ccccc6)nc(-c6ccccc6)n5)c4)c3c21]

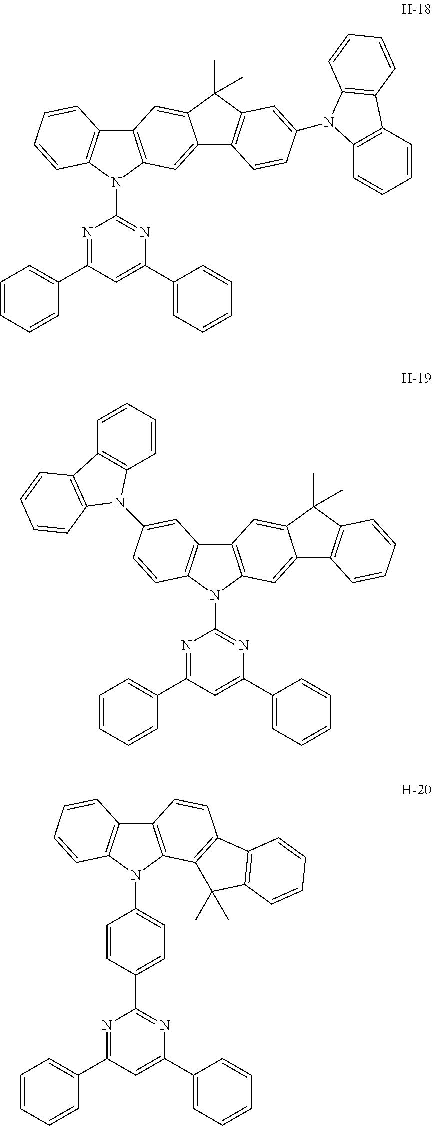 [SMILES: CC1(C)c2cc(-n3c4ccccc4c4ccccc43)ccc2-c2cc3c(cc21)c1ccccc1n3-c1nc(-c2ccccc2)cc(-c2ccccc2)n1 ; CC1(C)c2ccccc2-c2cc3c(cc21)c1cc(-n2c4ccccc4c4ccccc42)ccc1n3-c1nc(-c2ccccc2)cc(-c2ccccc2)n1 ; CC1(C)c2ccccc2-c2ccc3c4ccccc4n(-c4ccc(-c5nc(-c6ccccc6)cc(-c6ccccc6)n5)cc4)c3c21]

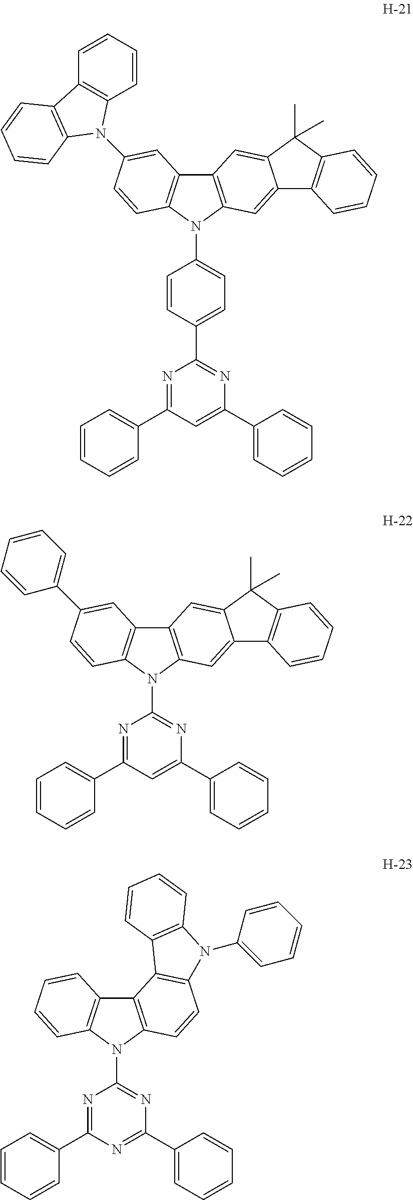 [SMILES: CC1(C)c2ccccc2-c2cc3c(cc21)c1cc(-n2c4ccccc4c4ccccc42)ccc1n3-c1ccc(-c2nc(-c3ccccc3)cc(-c3ccccc3)n2)cc1 ; CC1(C)c2ccccc2-c2cc3c(cc21)c1cc(-c2ccccc2)ccc1n3-c1nc(-c2ccccc2)cc(-c2ccccc2)n1 ; c1ccc(-c2nc(-c3ccccc3)nc(-n3c4ccccc4c4c5c6ccccc6n(-c6ccccc6)c5ccc43)n2)cc1]

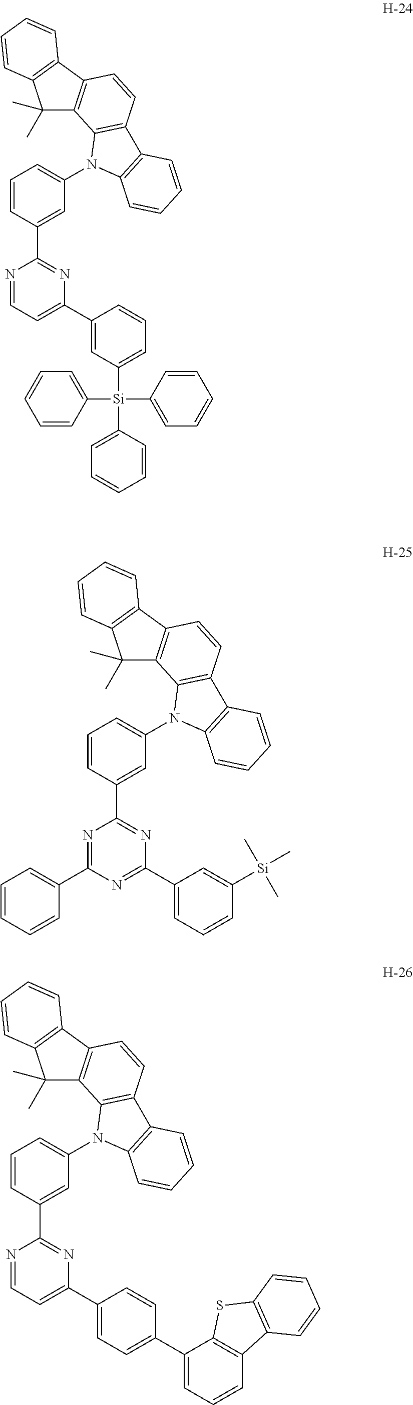 [SMILES: CC1(C)c2ccccc2-c2ccc3c4ccccc4n(-c4cccc(-c5nccc(-c6cccc([Si](c7ccccc7)(c7ccccc7)c7ccccc7)c6)n5)c4)c3c21 ; CC1(C)c2ccccc2-c2ccc3c4ccccc4n(-c4cccc(-c5nc(-c6ccccc6)nc(-c6cccc([Si](C)(C)C)c6)n5)c4)c3c21 ; CC1(C)c2ccccc2-c2ccc3c4ccccc4n(-c4cccc(-c5nccc(-c6ccc(-c7cccc8c7sc7ccccc78)cc6)n5)c4)c3c21]

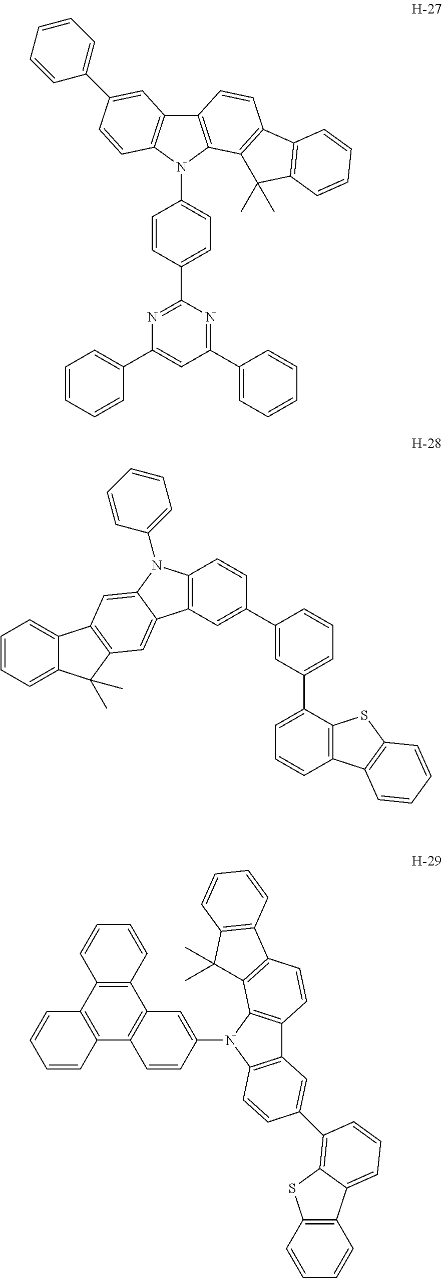 [SMILES: CC1(C)c2ccccc2-c2ccc3c4cc(-c5ccccc5)ccc4n(-c4ccc(-c5nc(-c6ccccc6)cc(-c6ccccc6)n5)cc4)c3c21 ; CC1(C)c2ccccc2-c2cc3c(cc21)c1cc(-c2cccc(-c4cccc5c4sc4ccccc45)c2)ccc1n3-c1ccccc1 ; CC1(C)c2ccccc2-c2ccc3c4cc(-c5cccc6c5sc5ccccc56)ccc4n(-c4ccc5c6ccccc6c6ccccc6c5c4)c3c21]

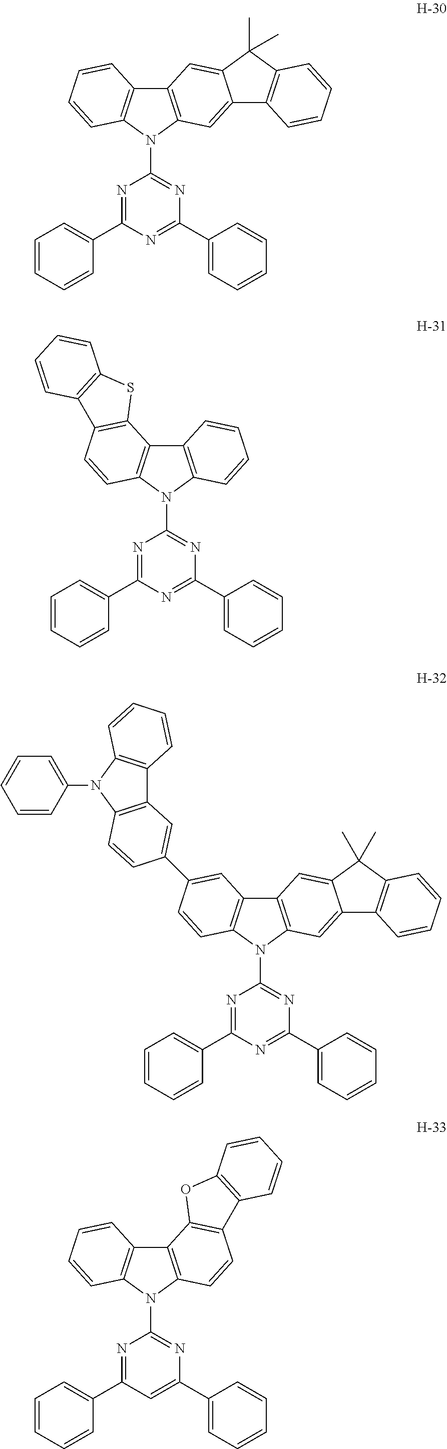

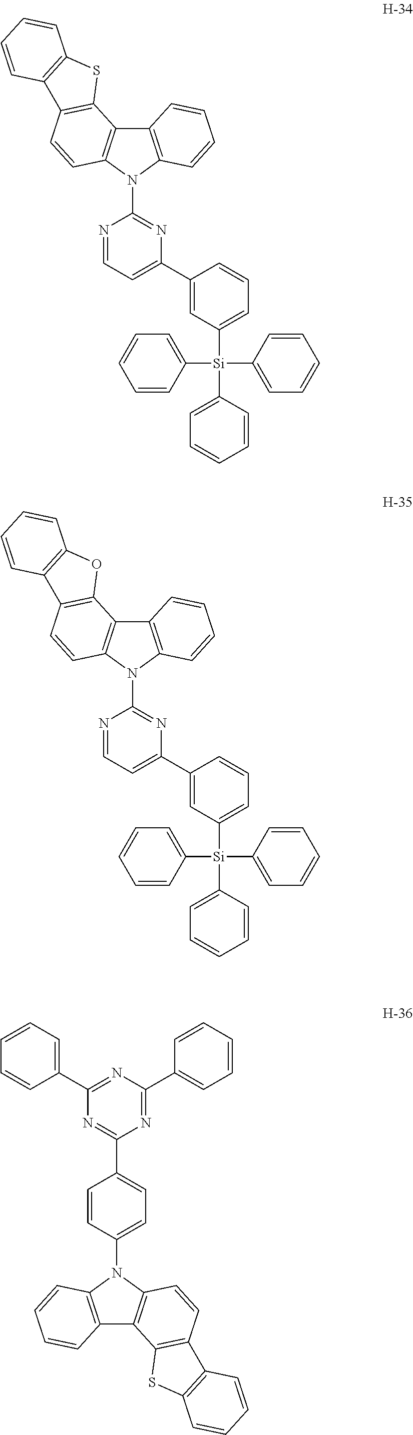 [SMILES: c1ccc([Si](c2ccccc2)(c2ccccc2)c2cccc(-c3ccnc(-n4c5ccccc5c5c6sc7ccccc7c6ccc54)n3)c2)cc1 ; c1ccc([Si](c2ccccc2)(c2ccccc2)c2cccc(-c3ccnc(-n4c5ccccc5c5c6oc7ccccc7c6ccc54)n3)c2)cc1 ; c1ccc(-c2nc(-c3ccccc3)nc(-c3ccc(-n4c5ccccc5c5c6sc7ccccc7c6ccc54)cc3)n2)cc1]

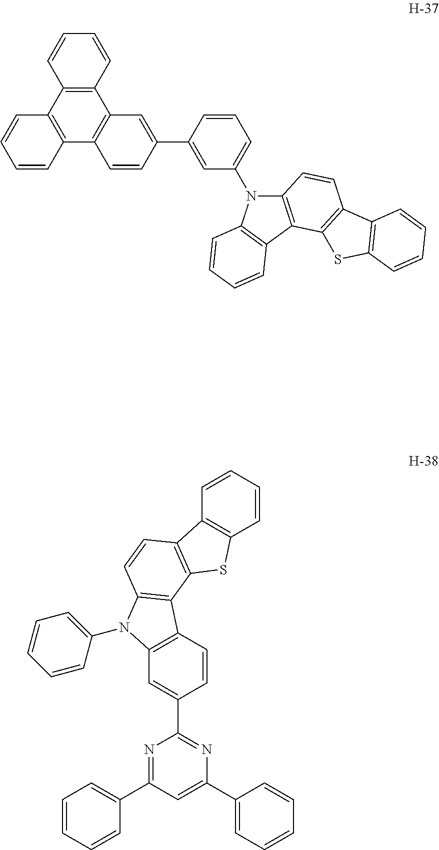 [SMILES: c1cc(-c2ccc3c4ccccc4c4ccccc4c3c2)cc(-n2c3ccccc3c3c4sc5ccccc5c4ccc32)c1 ; c1ccc(-c2cc(-c3ccccc3)nc(-c3ccc4c5c6sc7ccccc7c6ccc5n(-c5ccccc5)c4c3)n2)cc1]

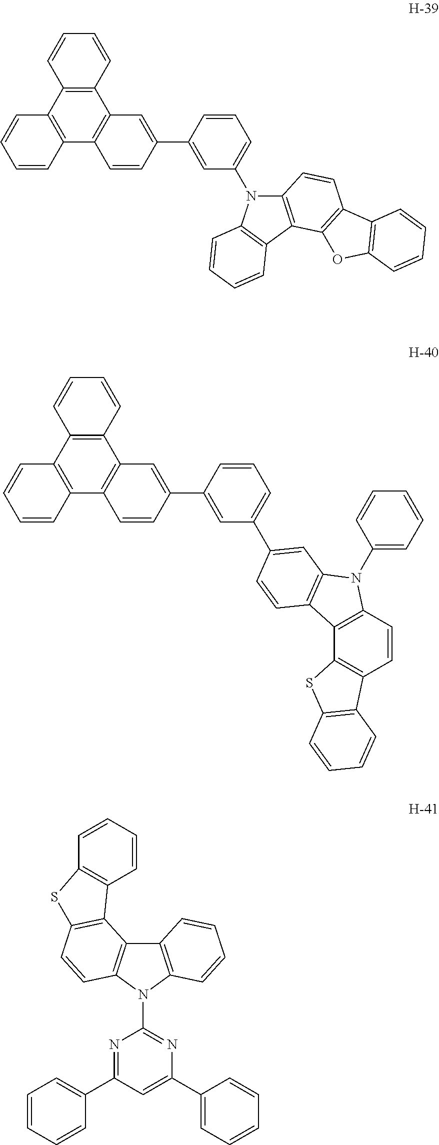 [SMILES: c1cc(-c2ccc3c4ccccc4c4ccccc4c3c2)cc(-n2c3ccccc3c3c4oc5ccccc5c4ccc32)c1 ; c1ccc(-n2c3cc(-c4cccc(-c5ccc6c7ccccc7c7ccccc7c6c5)c4)ccc3c3c4sc5ccccc5c4ccc32)cc1 ; c1ccc(-c2cc(-c3ccccc3)nc(-n3c4ccccc4c4c5c(ccc43)sc3ccccc35)n2)cc1]

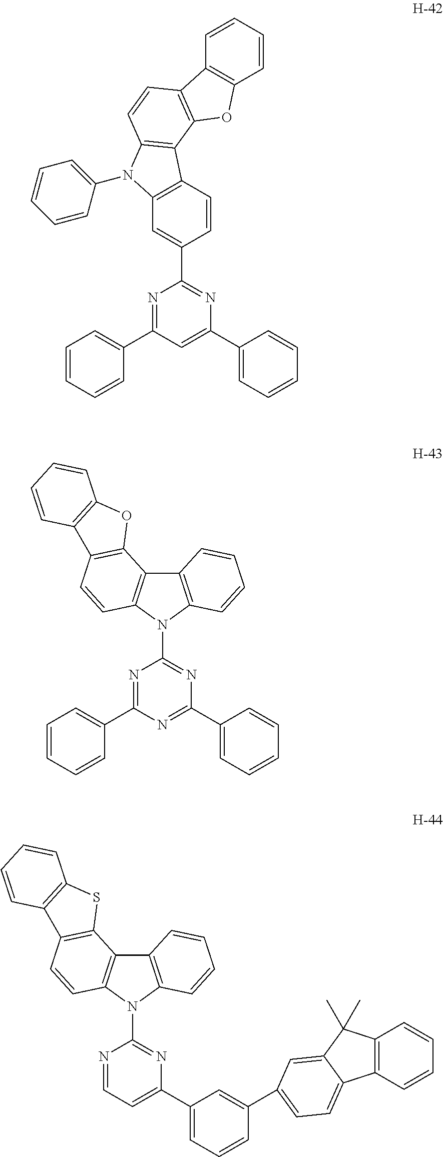 [SMILES: c1ccc(-c2cc(-c3ccccc3)nc(-c3ccc4c5c6oc7ccccc7c6ccc5n(-c5ccccc5)c4c3)n2)cc1 ; c1ccc(-c2nc(-c3ccccc3)nc(-n3c4ccccc4c4c5oc6ccccc6c5ccc43)n2)cc1 ; CC1(C)c2ccccc2-c2ccc(-c3cccc(-c4ccnc(-n5c6ccccc6c6c7sc8ccccc8c7ccc65)n4)c3)cc21]

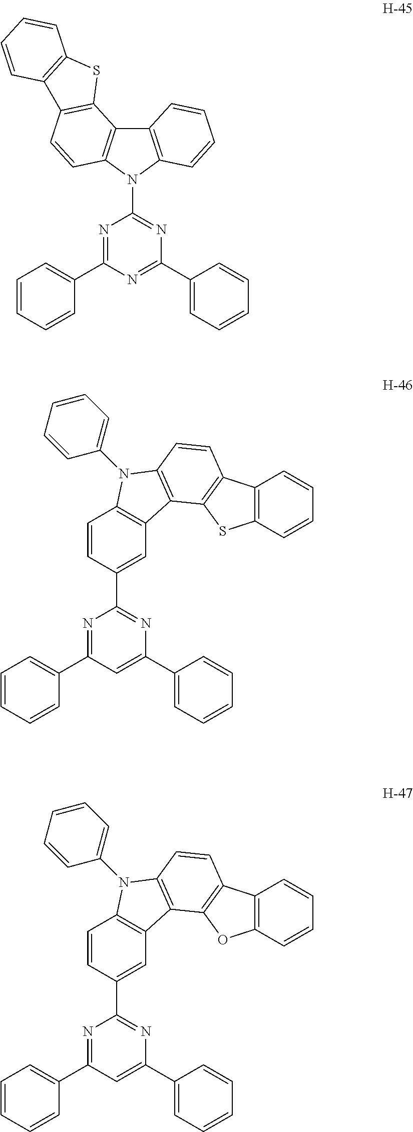 [SMILES: c1ccc(-c2nc(-c3ccccc3)nc(-n3c4ccccc4c4c5sc6ccccc6c5ccc43)n2)cc1 ; c1ccc(-c2cc(-c3ccccc3)nc(-c3ccc4c(c3)c3c5sc6ccccc6c5ccc3n4-c3ccccc3)n2)cc1 ; c1ccc(-c2cc(-c3ccccc3)nc(-c3ccc4c(c3)c3c5oc6ccccc6c5ccc3n4-c3ccccc3)n2)cc1]

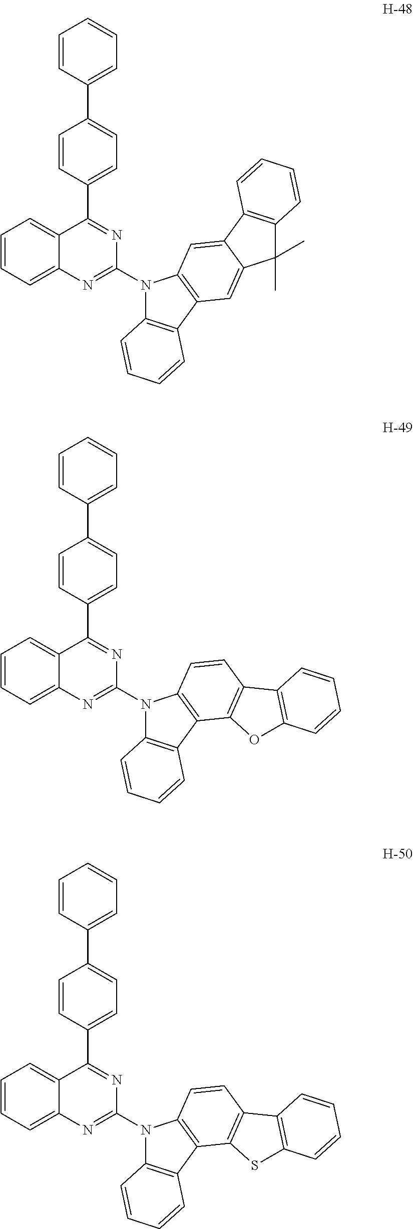 [SMILES: CC1(C)c2ccccc2-c2cc3c(cc21)c1ccccc1n3-c1nc(-c2ccc(-c3ccccc3)cc2)c2ccccc2n1 ; c1ccc(-c2ccc(-c3nc(-n4c5ccccc5c5c6oc7ccccc7c6ccc54)nc4ccccc34)cc2)cc1 ; c1ccc(-c2ccc(-c3nc(-n4c5ccccc5c5c6sc7ccccc7c6ccc54)nc4ccccc34)cc2)cc1]

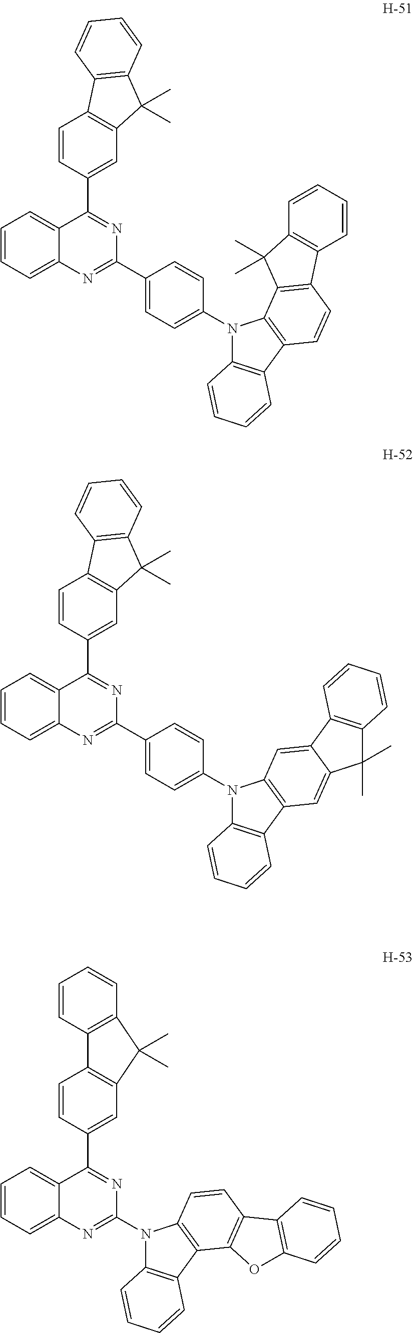 [SMILES: CC1(C)c2ccccc2-c2ccc(-c3nc(-c4ccc(-n5c6ccccc6c6ccc7c(c65)C(C)(C)c5ccccc5-7)cc4)nc4ccccc34)cc21 ; CC1(C)c2ccccc2-c2ccc(-c3nc(-c4ccc(-n5c6ccccc6c6cc7c(cc65)-c5ccccc5C7(C)C)cc4)nc4ccccc34)cc21 ; CC1(C)c2ccccc2-c2ccc(-c3nc(-n4c5ccccc5c5c6oc7ccccc7c6ccc54)nc4ccccc34)cc21]

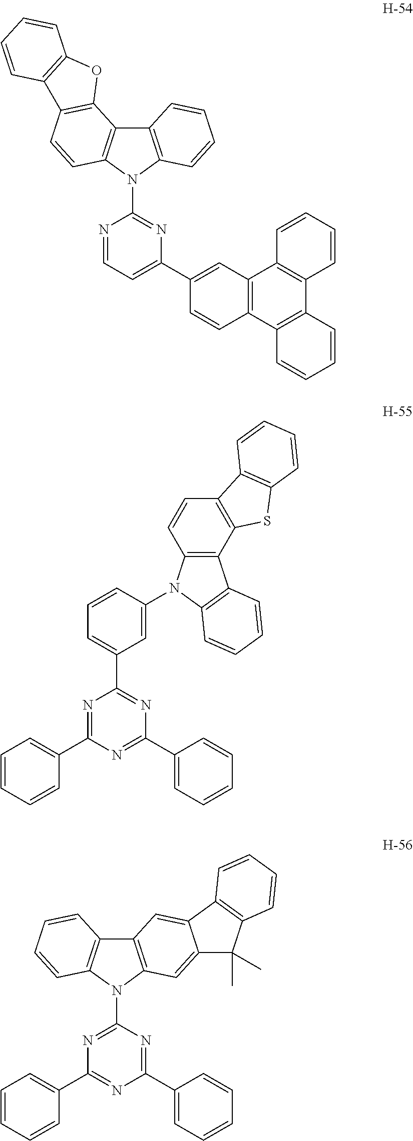 [SMILES: c1ccc2c(c1)oc1c2ccc2c1c1ccccc1n2-c1nccc(-c2ccc3c4ccccc4c4ccccc4c3c2)n1 ; c1ccc(-c2nc(-c3ccccc3)nc(-c3cccc(-n4c5ccccc5c5c6sc7ccccc7c6ccc54)c3)n2)cc1 ; CC1(C)c2ccccc2-c2cc3c4ccccc4n(-c4nc(-c5ccccc5)nc(-c5ccccc5)n4)c3cc21]

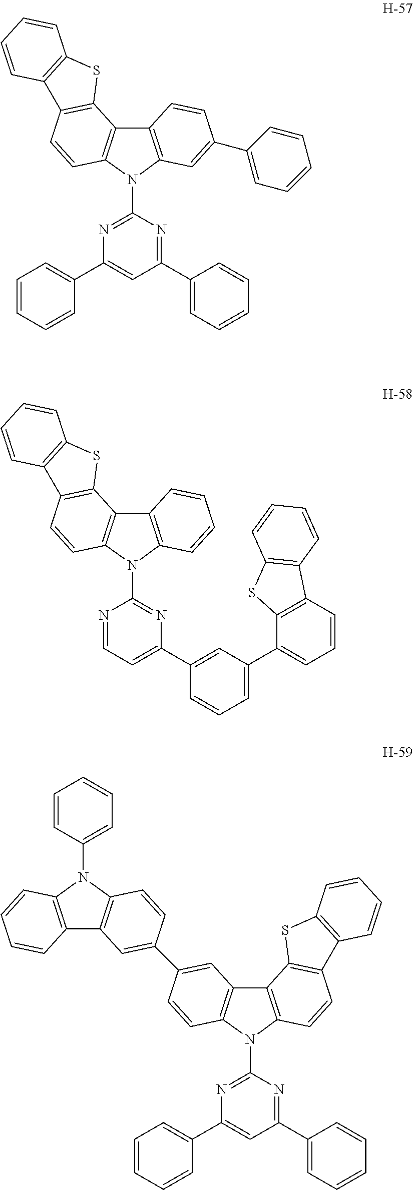 [SMILES: c1ccc(-c2ccc3c4c5sc6ccccc6c5ccc4n(-c4nc(-c5ccccc5)cc(-c5ccccc5)n4)c3c2)cc1 ; c1cc(-c2ccnc(-n3c4ccccc4c4c5sc6ccccc6c5ccc43)n2)cc(-c2cccc3c2sc2ccccc23)c1 ; c1ccc(-c2cc(-c3ccccc3)nc(-n3c4ccc(-c5ccc6c(c5)c5ccccc5n6-c5ccccc5)cc4c4c5sc6ccccc6c5ccc43)n2)cc1]

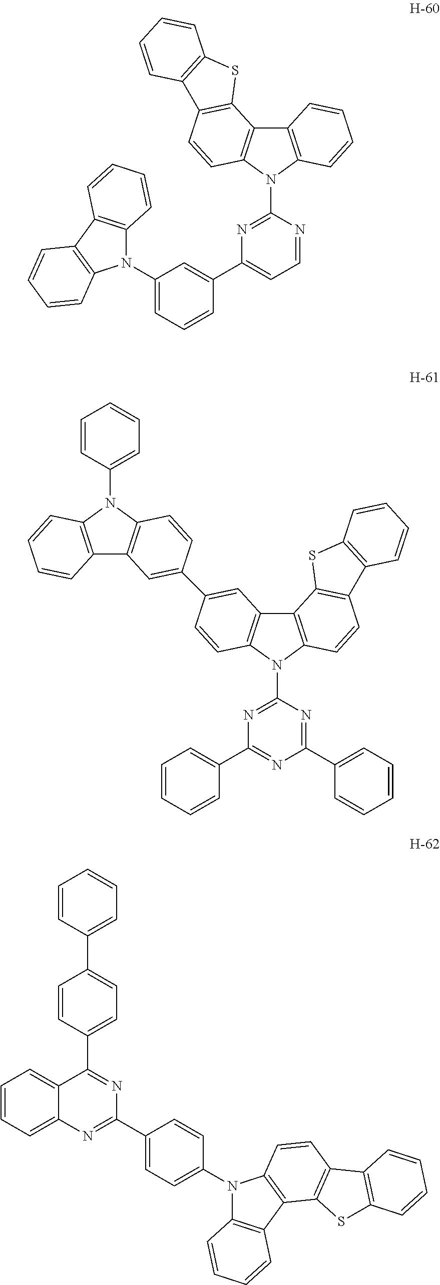 [SMILES: c1cc(-c2ccnc(-n3c4ccccc4c4c5sc6ccccc6c5ccc43)n2)cc(-n2c3ccccc3c3ccccc32)c1 ; c1ccc(-c2nc(-c3ccccc3)nc(-n3c4ccc(-c5ccc6c(c5)c5ccccc5n6-c5ccccc5)cc4c4c5sc6ccccc6c5ccc43)n2)cc1 ; c1ccc(-c2ccc(-c3nc(-c4ccc(-n5c6ccccc6c6c7sc8ccccc8c7ccc65)cc4)nc4ccccc34)cc2)cc1]

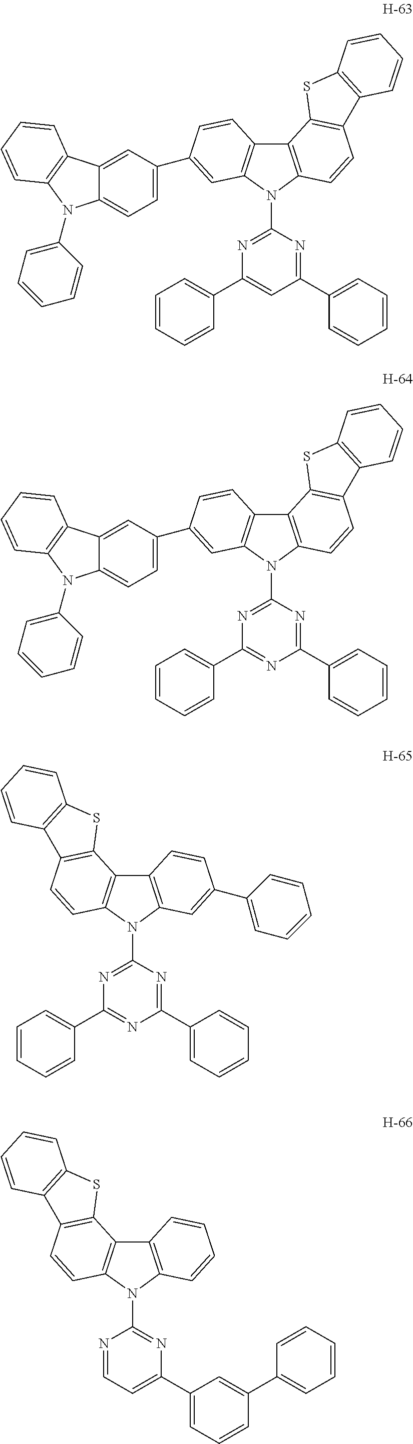 [SMILES: c1ccc(-c2cc(-c3ccccc3)nc(-n3c4cc(-c5ccc6c(c5)c5ccccc5n6-c5ccccc5)ccc4c4c5sc6ccccc6c5ccc43)n2)cc1 ; c1ccc(-c2nc(-c3ccccc3)nc(-n3c4cc(-c5ccc6c(c5)c5ccccc5n6-c5ccccc5)ccc4c4c5sc6ccccc6c5ccc43)n2)cc1 ; c1ccc(-c2ccc3c4c5sc6ccccc6c5ccc4n(-c4nc(-c5ccccc5)nc(-c5ccccc5)n4)c3c2)cc1 ; c1ccc(-c2cccc(-c3ccnc(-n4c5ccccc5c5c6sc7ccccc7c6ccc54)n3)c2)cc1]

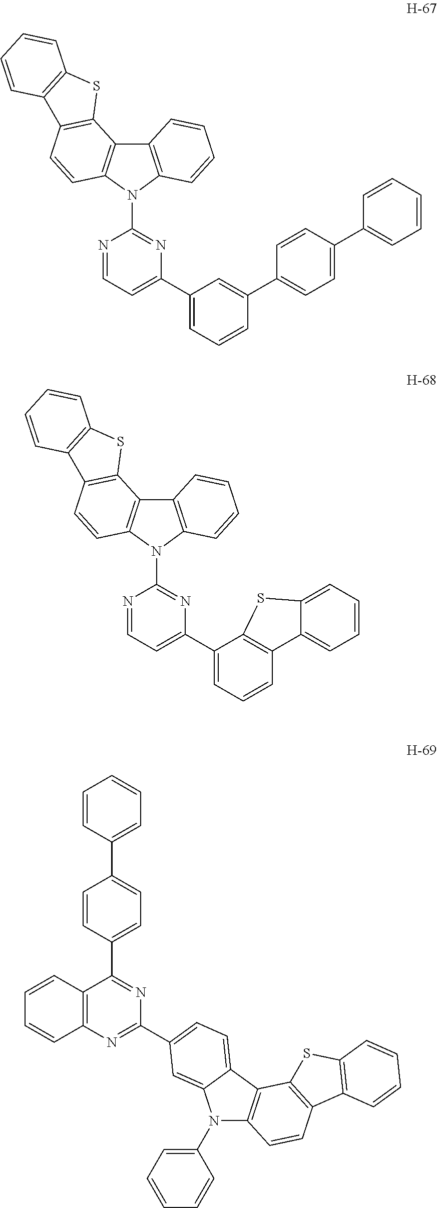 [SMILES: c1ccc(-c2ccc(-c3cccc(-c4ccnc(-n5c6ccccc6c6c7sc8ccccc8c7ccc65)n4)c3)cc2)cc1 ; c1ccc2c(c1)sc1c(-c3ccnc(-n4c5ccccc5c5c6sc7ccccc7c6ccc54)n3)cccc12 ; c1ccc(-c2ccc(-c3nc(-c4ccc5c6c7sc8ccccc8c7ccc6n(-c6ccccc6)c5c4)nc4ccccc34)cc2)cc1]

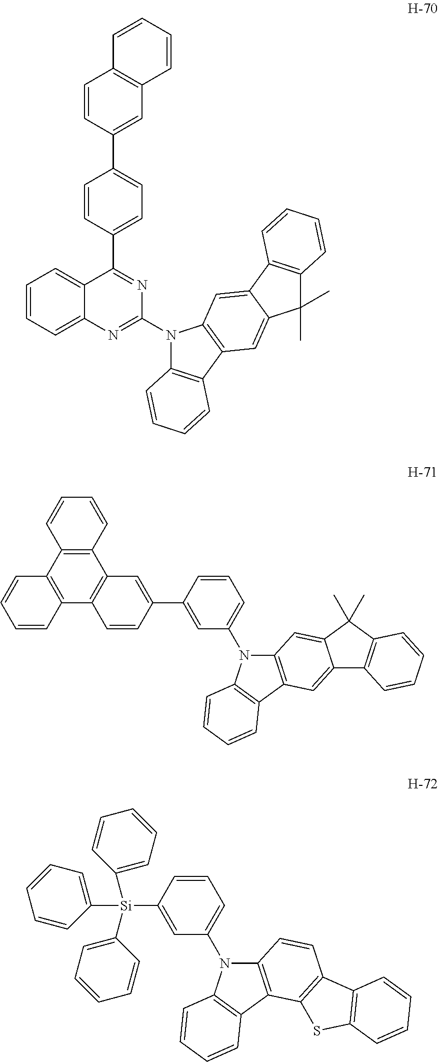 [SMILES: CC1(C)c2ccccc2-c2cc3c(cc21)c1ccccc1n3-c1nc(-c2ccc(-c3ccc4ccccc4c3)cc2)c2ccccc2n1 ; CC1(C)c2ccccc2-c2cc3c4ccccc4n(-c4cccc(-c5ccc6c7ccccc7c7ccccc7c6c5)c4)c3cc21 ; c1ccc([Si](c2ccccc2)(c2ccccc2)c2cccc(-n3c4ccccc4c4c5sc6ccccc6c5ccc43)c2)cc1]

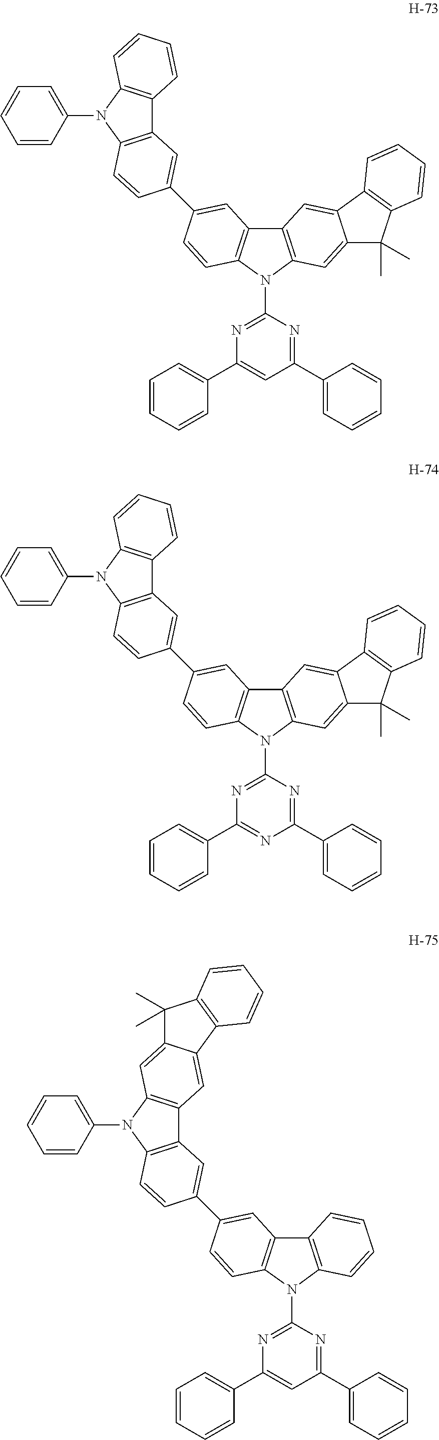 [SMILES: CC1(C)c2ccccc2-c2cc3c4cc(-c5ccc6c(c5)c5ccccc5n6-c5ccccc5)ccc4n(-c4nc(-c5ccccc5)cc(-c5ccccc5)n4)c3cc21 ; CC1(C)c2ccccc2-c2cc3c4cc(-c5ccc6c(c5)c5ccccc5n6-c5ccccc5)ccc4n(-c4nc(-c5ccccc5)nc(-c5ccccc5)n4)c3cc21 ; CC1(C)c2ccccc2-c2cc3c4cc(-c5ccc6c(c5)c5ccccc5n6-c5nc(-c6ccccc6)cc(-c6ccccc6)n5)ccc4n(-c4ccccc4)c3cc21]

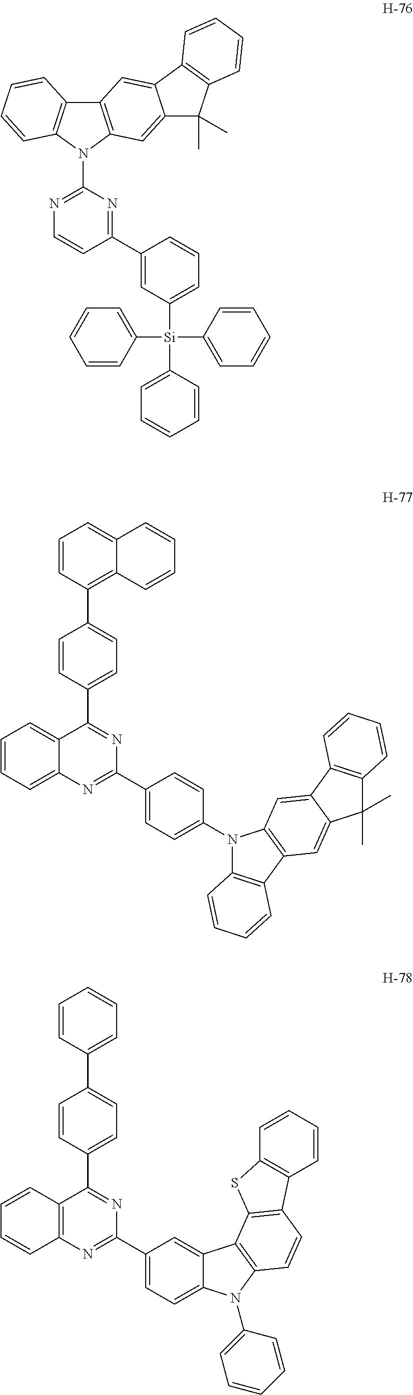 [SMILES: CC1(C)c2ccccc2-c2cc3c4ccccc4n(-c4nccc(-c5cccc([Si](c6ccccc6)(c6ccccc6)c6ccccc6)c5)n4)c3cc21 ; CC1(C)c2ccccc2-c2cc3c(cc21)c1ccccc1n3-c1ccc(-c2nc(-c3ccc(-c4cccc5ccccc45)cc3)c3ccccc3n2)cc1 ; c1ccc(-c2ccc(-c3nc(-c4ccc5c(c4)c4c6sc7ccccc7c6ccc4n5-c4ccccc4)nc4ccccc34)cc2)cc1]

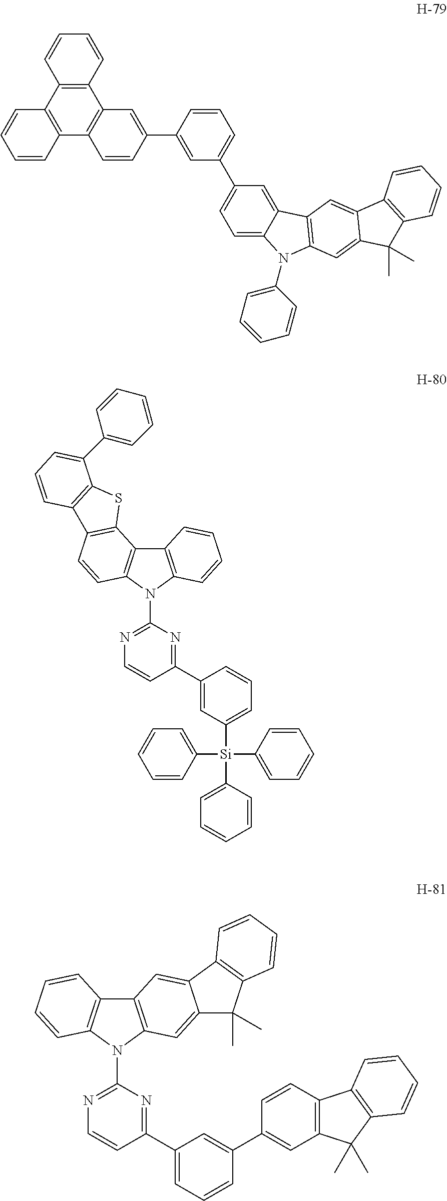 [SMILES: CC1(C)c2ccccc2-c2cc3c4cc(-c5cccc(-c6ccc7c8ccccc8c8ccccc8c7c6)c5)ccc4n(-c4ccccc4)c3cc21 ; c1ccc(-c2cccc3c2sc2c3ccc3c2c2ccccc2n3-c2nccc(-c3cccc([Si](c4ccccc4)(c4ccccc4)c4ccccc4)c3)n2)cc1 ; CC1(C)c2ccccc2-c2ccc(-c3cccc(-c4ccnc(-n5c6ccccc6c6cc7c(cc65)C(C)(C)c5ccccc5-7)n4)c3)cc21]

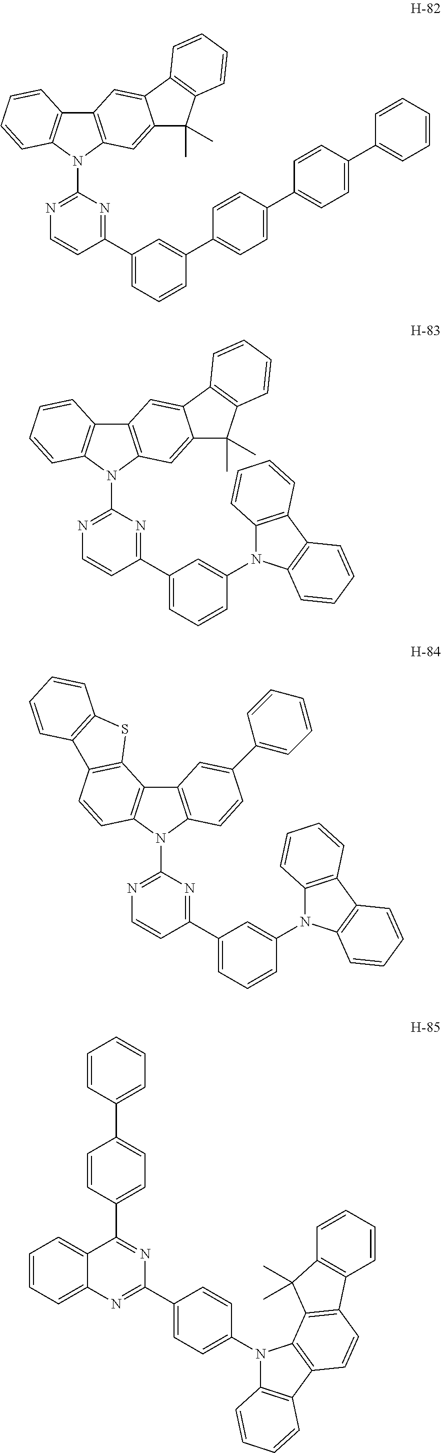 [SMILES: CC1(C)c2ccccc2-c2cc3c4ccccc4n(-c4nccc(-c5cccc(-c6ccc(-c7ccc(-c8ccccc8)cc7)cc6)c5)n4)c3cc21 ; CC1(C)c2ccccc2-c2cc3c4ccccc4n(-c4nccc(-c5cccc(-n6c7ccccc7c7ccccc76)c5)n4)c3cc21 ; c1ccc(-c2ccc3c(c2)c2c4sc5ccccc5c4ccc2n3-c2nccc(-c3cccc(-n4c5ccccc5c5ccccc54)c3)n2)cc1 ; CC1(C)c2ccccc2-c2ccc3c4ccccc4n(-c4ccc(-c5nc(-c6ccc(-c7ccccc7)cc6)c6ccccc6n5)cc4)c3c21]

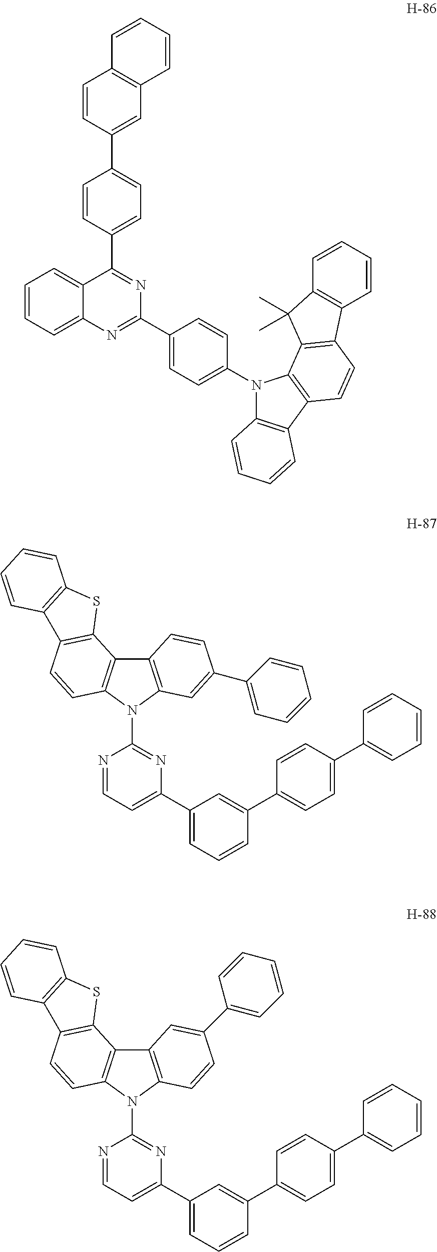 [SMILES: CC1(C)c2ccccc2-c2ccc3c4ccccc4n(-c4ccc(-c5nc(-c6ccc(-c7ccc8ccccc8c7)cc6)c6ccccc6n5)cc4)c3c21 ; c1ccc(-c2ccc(-c3cccc(-c4ccnc(-n5c6cc(-c7ccccc7)ccc6c6c7sc8ccccc8c7ccc65)n4)c3)cc2)cc1 ; c1ccc(-c2ccc(-c3cccc(-c4ccnc(-n5c6ccc(-c7ccccc7)cc6c6c7sc8ccccc8c7ccc65)n4)c3)cc2)cc1]

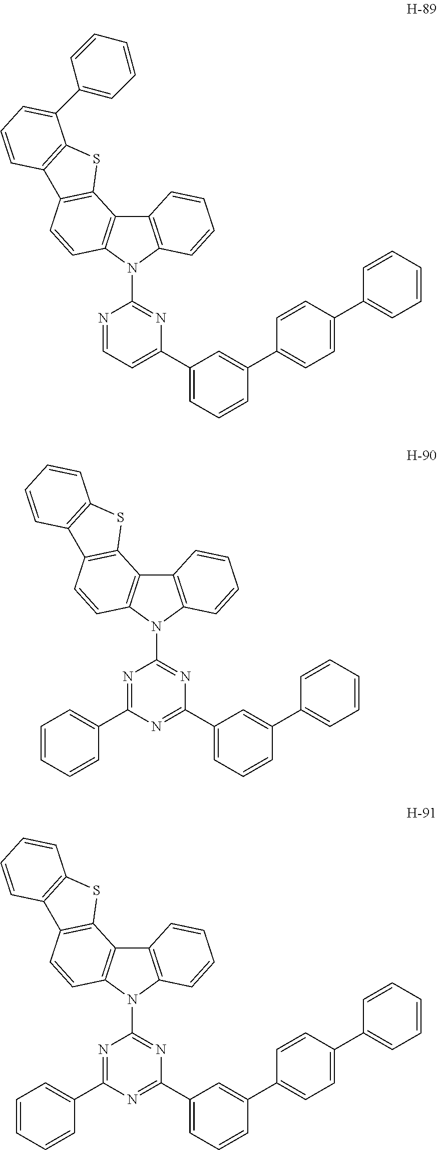 [SMILES: c1ccc(-c2ccc(-c3cccc(-c4ccnc(-n5c6ccccc6c6c7sc8c(-c9ccccc9)cccc8c7ccc65)n4)c3)cc2)cc1 ; c1ccc(-c2cccc(-c3nc(-c4ccccc4)nc(-n4c5ccccc5c5c6sc7ccccc7c6ccc54)n3)c2)cc1 ; c1ccc(-c2ccc(-c3cccc(-c4nc(-c5ccccc5)nc(-n5c6ccccc6c6c7sc8ccccc8c7ccc65)n4)c3)cc2)cc1]

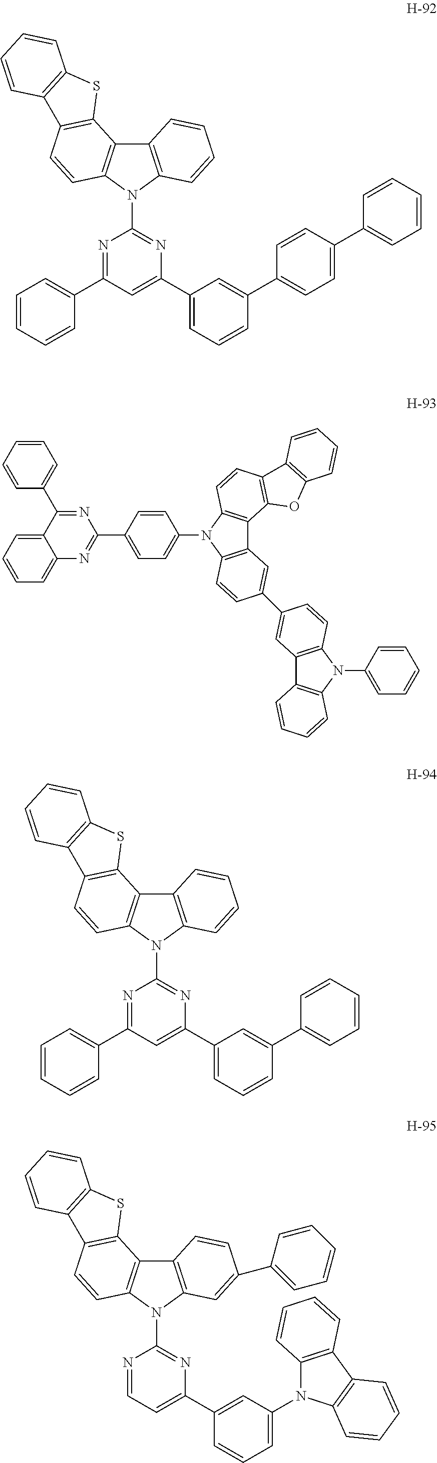 [SMILES: c1ccc(-c2ccc(-c3cccc(-c4cc(-c5ccccc5)nc(-n5c6ccccc6c6c7sc8ccccc8c7ccc65)n4)c3)cc2)cc1 ; c1ccc(-c2nc(-c3ccc(-n4c5ccc(-c6ccc7c(c6)c6ccccc6n7-c6ccccc6)cc5c5c6oc7ccccc7c6ccc54)cc3)nc3ccccc23)cc1 ; c1ccc(-c2cccc(-c3cc(-c4ccccc4)nc(-n4c5ccccc5c5c6sc7ccccc7c6ccc54)n3)c2)cc1 ; c1ccc(-c2ccc3c4c5sc6ccccc6c5ccc4n(-c4nccc(-c5cccc(-n6c7ccccc7c7ccccc76)c5)n4)c3c2)cc1]

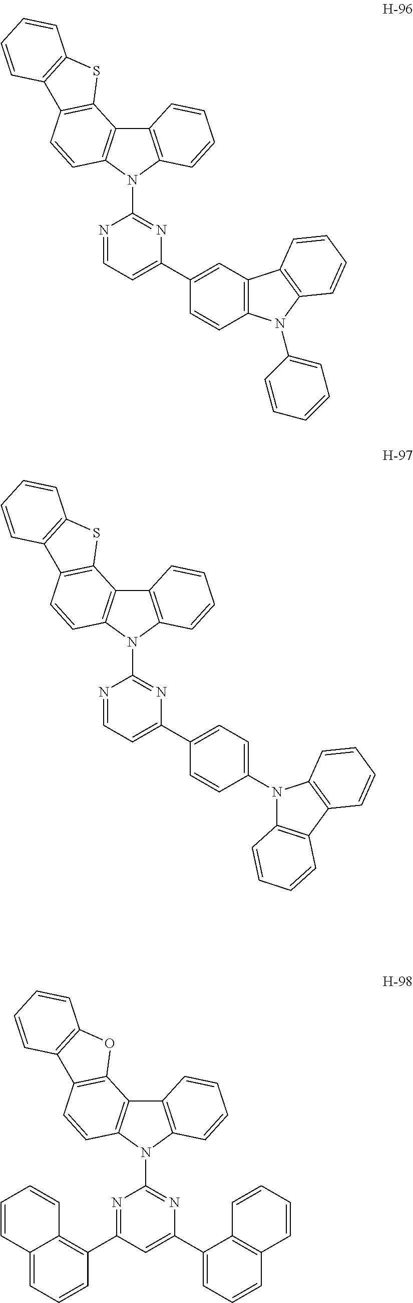 [SMILES: c1ccc(-n2c3ccccc3c3cc(-c4ccnc(-n5c6ccccc6c6c7sc8ccccc8c7ccc65)n4)ccc32)cc1 ; c1ccc2c(c1)sc1c2ccc2c1c1ccccc1n2-c1nccc(-c2ccc(-n3c4ccccc4c4ccccc43)cc2)n1 ; c1ccc2c(-c3cc(-c4cccc5ccccc45)nc(-n4c5ccccc5c5c6oc7ccccc7c6ccc54)n3)cccc2c1]

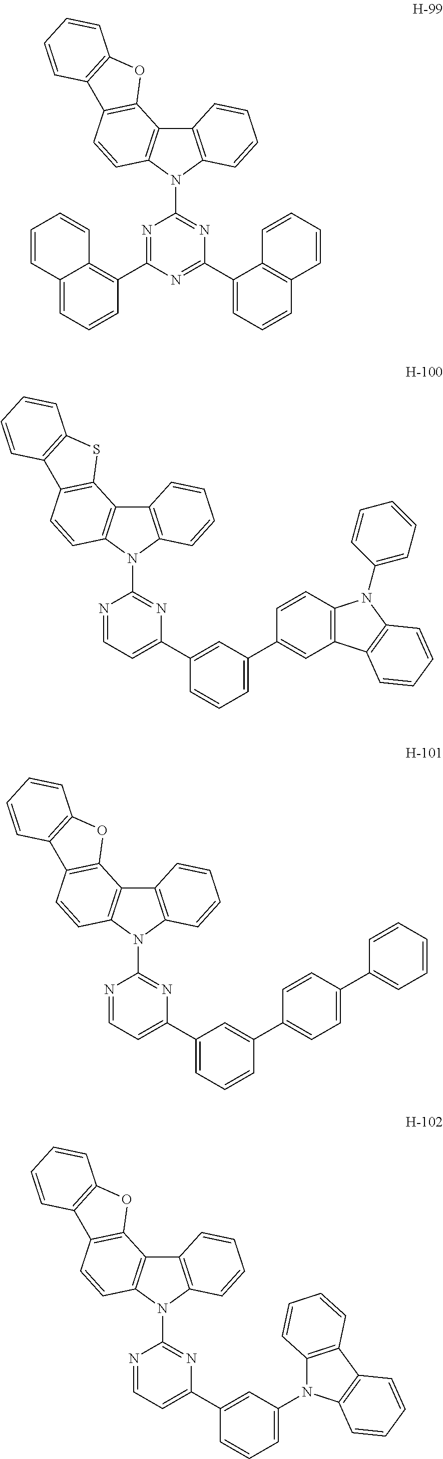 [SMILES: c1ccc2c(-c3nc(-c4cccc5ccccc45)nc(-n4c5ccccc5c5c6oc7ccccc7c6ccc54)n3)cccc2c1 ; c1ccc(-n2c3ccccc3c3cc(-c4cccc(-c5ccnc(-n6c7ccccc7c7c8sc9ccccc9c8ccc76)n5)c4)ccc32)cc1 ; c1ccc(-c2ccc(-c3cccc(-c4ccnc(-n5c6ccccc6c6c7oc8ccccc8c7ccc65)n4)c3)cc2)cc1 ; c1cc(-c2ccnc(-n3c4ccccc4c4c5oc6ccccc6c5ccc43)n2)cc(-n2c3ccccc3c3ccccc32)c1]

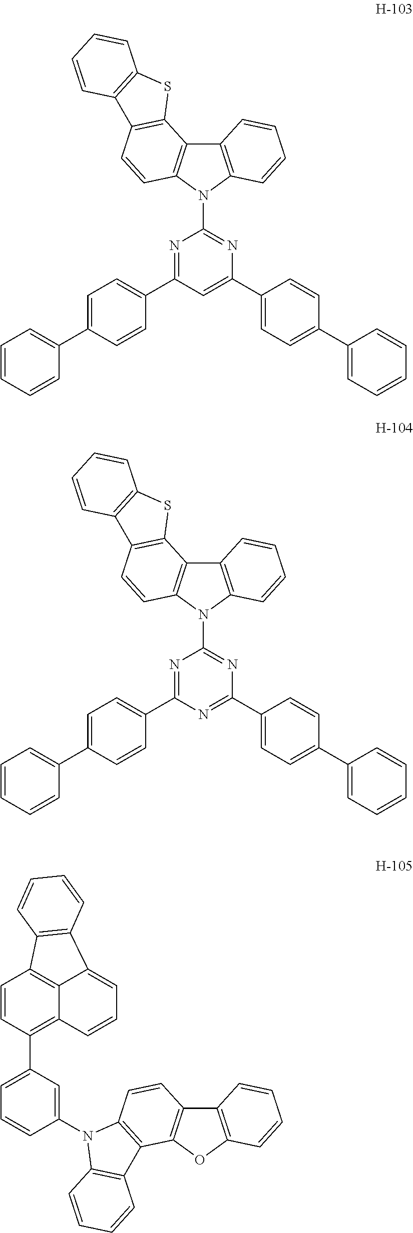 [SMILES: c1ccc(-c2ccc(-c3cc(-c4ccc(-c5ccccc5)cc4)nc(-n4c5ccccc5c5c6sc7ccccc7c6ccc54)n3)cc2)cc1 ; c1ccc(-c2ccc(-c3nc(-c4ccc(-c5ccccc5)cc4)nc(-n4c5ccccc5c5c6sc7ccccc7c6ccc54)n3)cc2)cc1 ; c1cc(-c2ccc3c4c(cccc24)-c2ccccc2-3)cc(-n2c3ccccc3c3c4oc5ccccc5c4ccc32)c1]

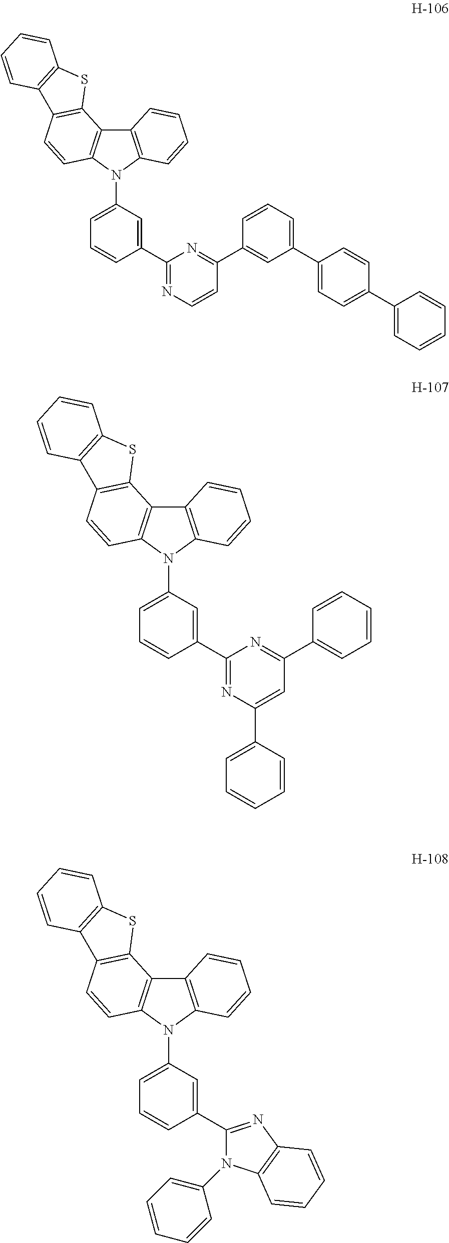 [SMILES: c1ccc(-c2ccc(-c3cccc(-c4ccnc(-c5cccc(-n6c7ccccc7c7c8sc9ccccc9c8ccc76)c5)n4)c3)cc2)cc1 ; c1ccc(-c2cc(-c3ccccc3)nc(-c3cccc(-n4c5ccccc5c5c6sc7ccccc7c6ccc54)c3)n2)cc1 ; c1ccc(-n2c(-c3cccc(-n4c5ccccc5c5c6sc7ccccc7c6ccc54)c3)nc3ccccc32)cc1]

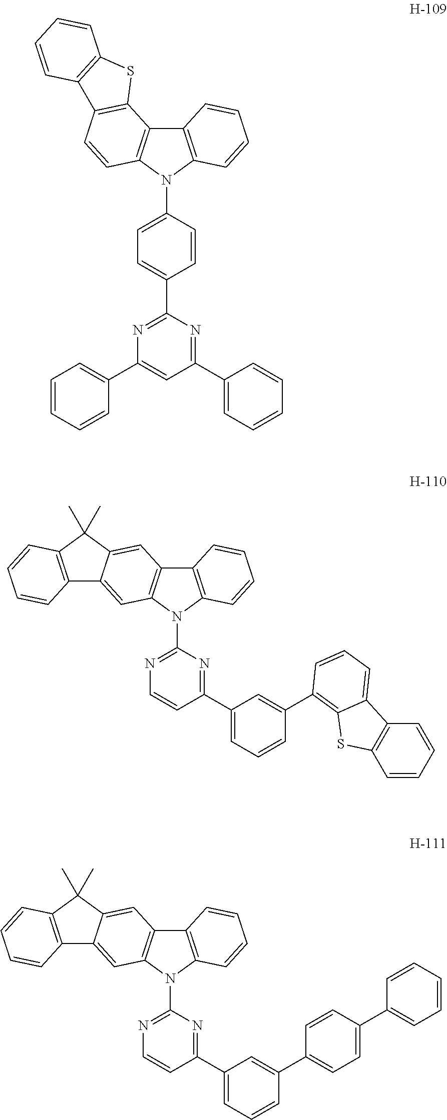 [SMILES: c1ccc(-c2cc(-c3ccccc3)nc(-c3ccc(-n4c5ccccc5c5c6sc7ccccc7c6ccc54)cc3)n2)cc1 ; CC1(C)c2ccccc2-c2cc3c(cc21)c1ccccc1n3-c1nccc(-c2cccc(-c3cccc4c3sc3ccccc34)c2)n1 ; CC1(C)c2ccccc2-c2cc3c(cc21)c1ccccc1n3-c1nccc(-c2cccc(-c3ccc(-c4ccccc4)cc3)c2)n1]

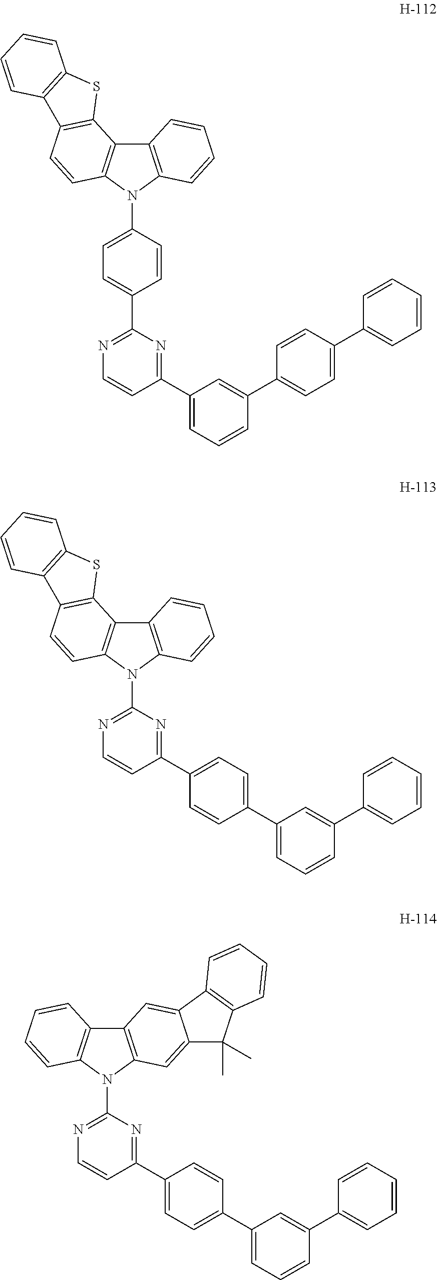 [SMILES: c1ccc(-c2ccc(-c3cccc(-c4ccnc(-c5ccc(-n6c7ccccc7c7c8sc9ccccc9c8ccc76)cc5)n4)c3)cc2)cc1 ; c1ccc(-c2cccc(-c3ccc(-c4ccnc(-n5c6ccccc6c6c7sc8ccccc8c7ccc65)n4)cc3)c2)cc1 ; CC1(C)c2ccccc2-c2cc3c4ccccc4n(-c4nccc(-c5ccc(-c6cccc(-c7ccccc7)c6)cc5)n4)c3cc21]

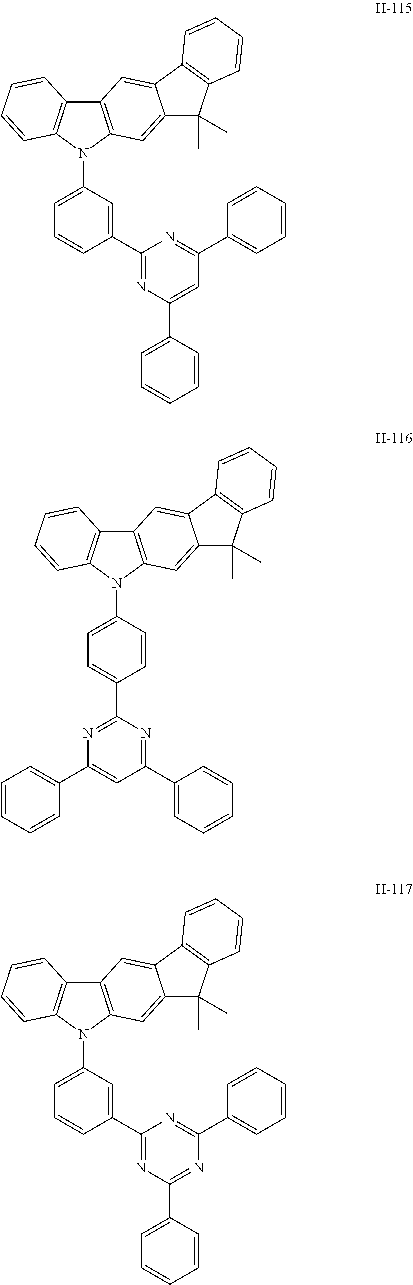 [SMILES: CC1(C)c2ccccc2-c2cc3c4ccccc4n(-c4cccc(-c5nc(-c6ccccc6)cc(-c6ccccc6)n5)c4)c3cc21 ; CC1(C)c2ccccc2-c2cc3c4ccccc4n(-c4ccc(-c5nc(-c6ccccc6)cc(-c6ccccc6)n5)cc4)c3cc21 ; CC1(C)c2ccccc2-c2cc3c4ccccc4n(-c4cccc(-c5nc(-c6ccccc6)nc(-c6ccccc6)n5)c4)c3cc21]

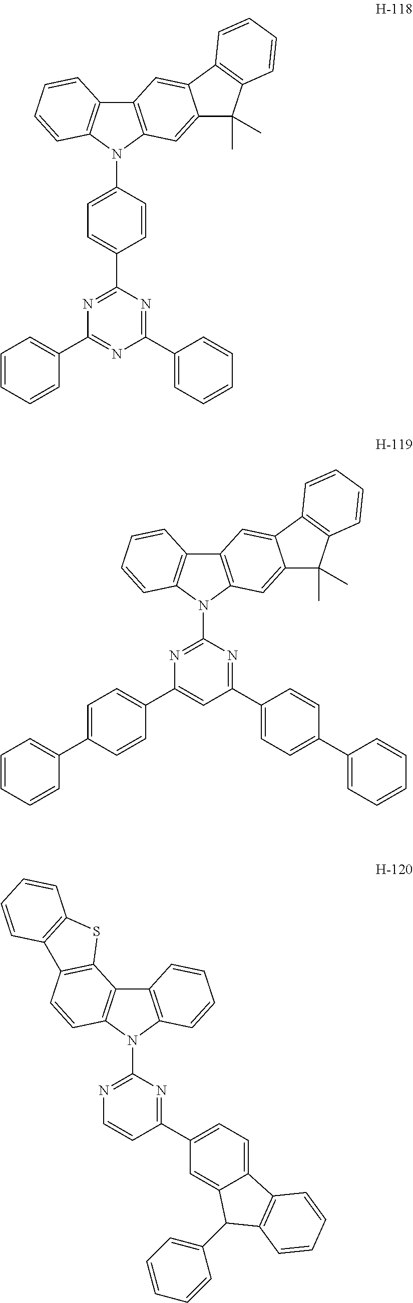 [SMILES: CC1(C)c2ccccc2-c2cc3c4ccccc4n(-c4ccc(-c5nc(-c6ccccc6)nc(-c6ccccc6)n5)cc4)c3cc21 ; CC1(C)c2ccccc2-c2cc3c4ccccc4n(-c4nc(-c5ccc(-c6ccccc6)cc5)cc(-c5ccc(-c6ccccc6)cc5)n4)c3cc21 ; c1ccc(C2c3ccccc3-c3ccc(-c4ccnc(-n5c6ccccc6c6c7sc8ccccc8c7ccc65)n4)cc32)cc1]

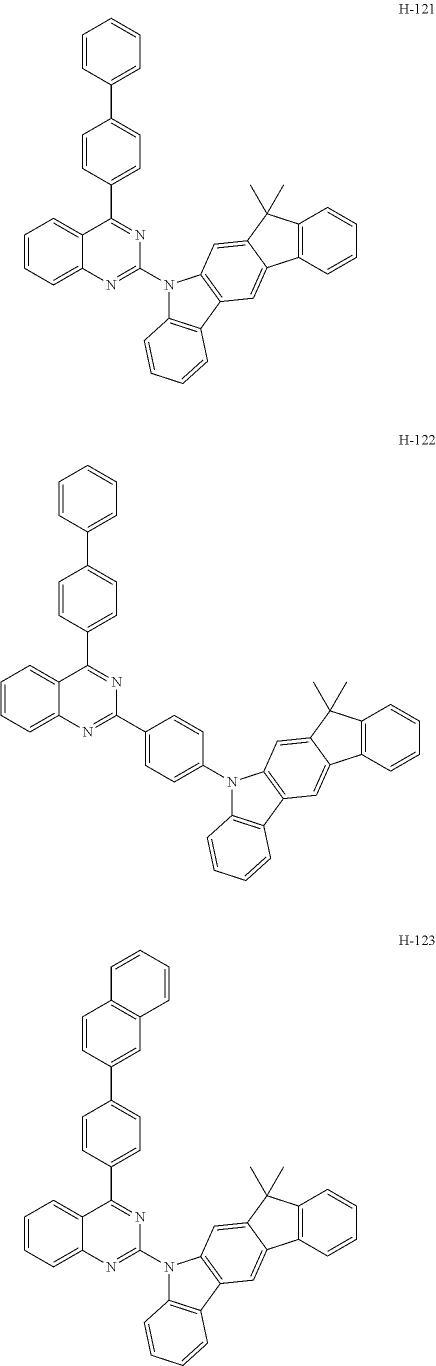 [SMILES: CC1(C)c2ccccc2-c2cc3c4ccccc4n(-c4nc(-c5ccc(-c6ccccc6)cc5)c5ccccc5n4)c3cc21 ; CC1(C)c2ccccc2-c2cc3c4ccccc4n(-c4ccc(-c5nc(-c6ccc(-c7ccccc7)cc6)c6ccccc6n5)cc4)c3cc21 ; CC1(C)c2ccccc2-c2cc3c4ccccc4n(-c4nc(-c5ccc(-c6ccc7ccccc7c6)cc5)c5ccccc5n4)c3cc21]

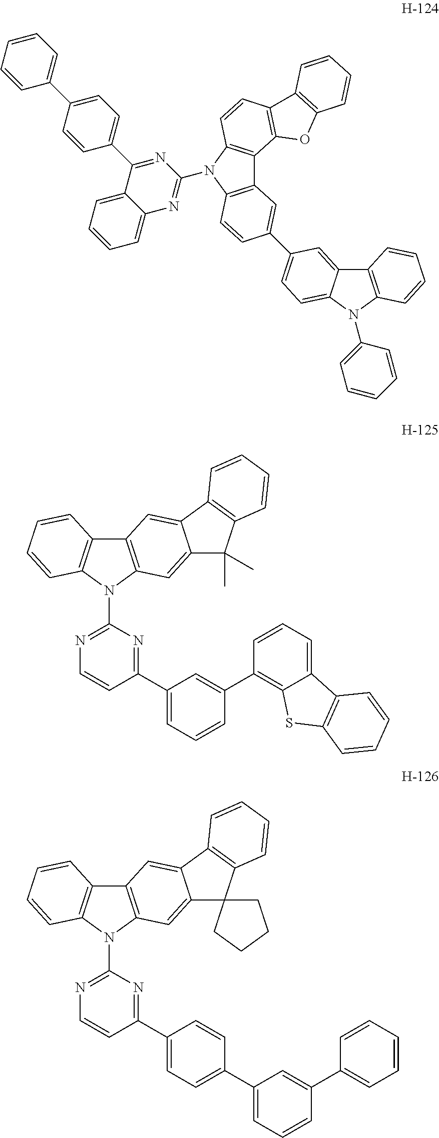 [SMILES: c1ccc(-c2ccc(-c3nc(-n4c5ccc(-c6ccc7c(c6)c6ccccc6n7-c6ccccc6)cc5c5c6oc7ccccc7c6ccc54)nc4ccccc34)cc2)cc1 ; CC1(C)c2ccccc2-c2cc3c4ccccc4n(-c4nccc(-c5cccc(-c6cccc7c6sc6ccccc67)c5)n4)c3cc21 ; c1ccc(-c2cccc(-c3ccc(-c4ccnc(-n5c6ccccc6c6cc7c(cc65)C5(CCCC5)c5ccccc5-7)n4)cc3)c2)cc1]

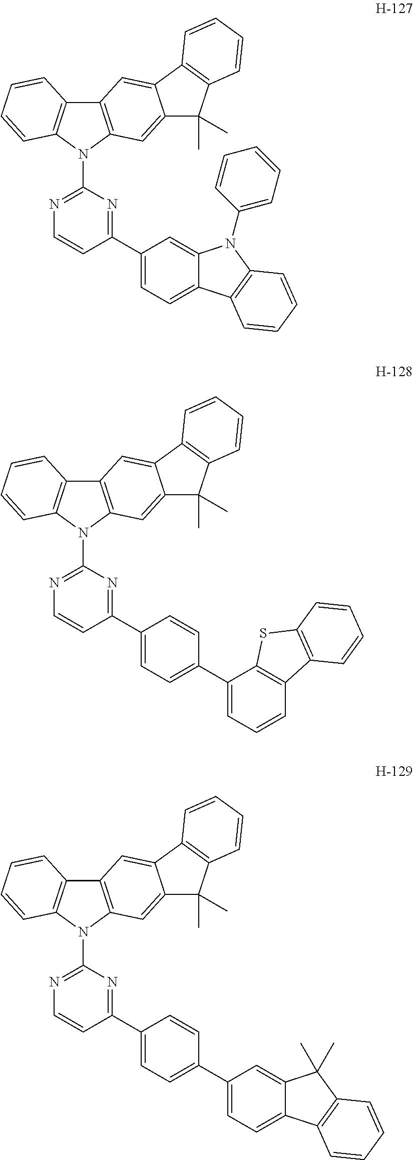 [SMILES: CC1(C)c2ccccc2-c2cc3c4ccccc4n(-c4nccc(-c5ccc6c7ccccc7n(-c7ccccc7)c6c5)n4)c3cc21 ; CC1(C)c2ccccc2-c2cc3c4ccccc4n(-c4nccc(-c5ccc(-c6cccc7c6sc6ccccc67)cc5)n4)c3cc21 ; CC1(C)c2ccccc2-c2ccc(-c3ccc(-c4ccnc(-n5c6ccccc6c6cc7c(cc65)C(C)(C)c5ccccc5-7)n4)cc3)cc21]

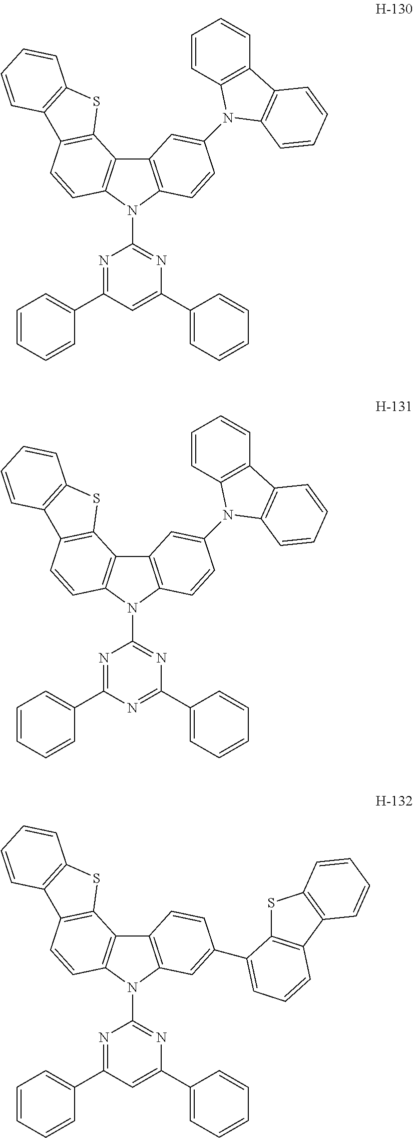 [SMILES: c1ccc(-c2cc(-c3ccccc3)nc(-n3c4ccc(-n5c6ccccc6c6ccccc65)cc4c4c5sc6ccccc6c5ccc43)n2)cc1 ; c1ccc(-c2nc(-c3ccccc3)nc(-n3c4ccc(-n5c6ccccc6c6ccccc65)cc4c4c5sc6ccccc6c5ccc43)n2)cc1 ; c1ccc(-c2cc(-c3ccccc3)nc(-n3c4cc(-c5cccc6c5sc5ccccc56)ccc4c4c5sc6ccccc6c5ccc43)n2)cc1]

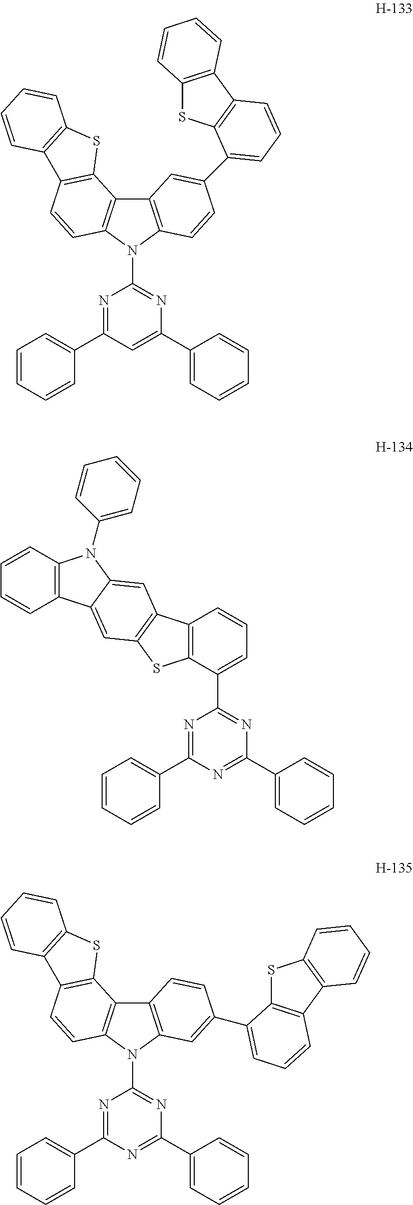 [SMILES: c1ccc(-c2cc(-c3ccccc3)nc(-n3c4ccc(-c5cccc6c5sc5ccccc56)cc4c4c5sc6ccccc6c5ccc43)n2)cc1 ; c1ccc(-c2nc(-c3ccccc3)nc(-c3cccc4c3sc3cc5c6ccccc6n(-c6ccccc6)c5cc34)n2)cc1 ; c1ccc(-c2nc(-c3ccccc3)nc(-n3c4cc(-c5cccc6c5sc5ccccc56)ccc4c4c5sc6ccccc6c5ccc43)n2)cc1]

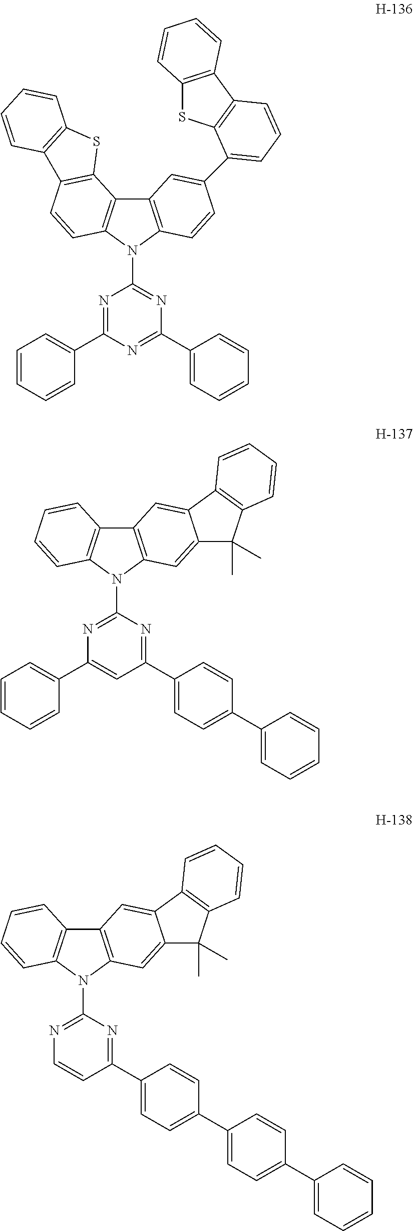 [SMILES: c1ccc(-c2nc(-c3ccccc3)nc(-n3c4ccc(-c5cccc6c5sc5ccccc56)cc4c4c5sc6ccccc6c5ccc43)n2)cc1 ; CC1(C)c2ccccc2-c2cc3c4ccccc4n(-c4nc(-c5ccccc5)cc(-c5ccc(-c6ccccc6)cc5)n4)c3cc21 ; CC1(C)c2ccccc2-c2cc3c4ccccc4n(-c4nccc(-c5ccc(-c6ccc(-c7ccccc7)cc6)cc5)n4)c3cc21]

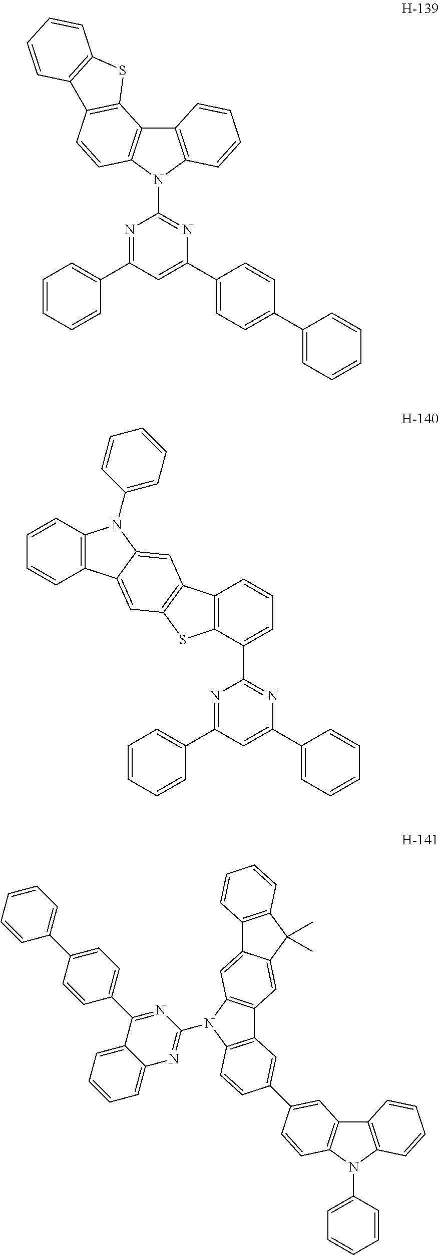 [SMILES: c1ccc(-c2ccc(-c3cc(-c4ccccc4)nc(-n4c5ccccc5c5c6sc7ccccc7c6ccc54)n3)cc2)cc1 ; c1ccc(-c2cc(-c3ccccc3)nc(-c3cccc4c3sc3cc5c6ccccc6n(-c6ccccc6)c5cc34)n2)cc1 ; CC1(C)c2ccccc2-c2cc3c(cc21)c1cc(-c2ccc4c(c2)c2ccccc2n4-c2ccccc2)ccc1n3-c1nc(-c2ccc(-c3ccccc3)cc2)c2ccccc2n1]

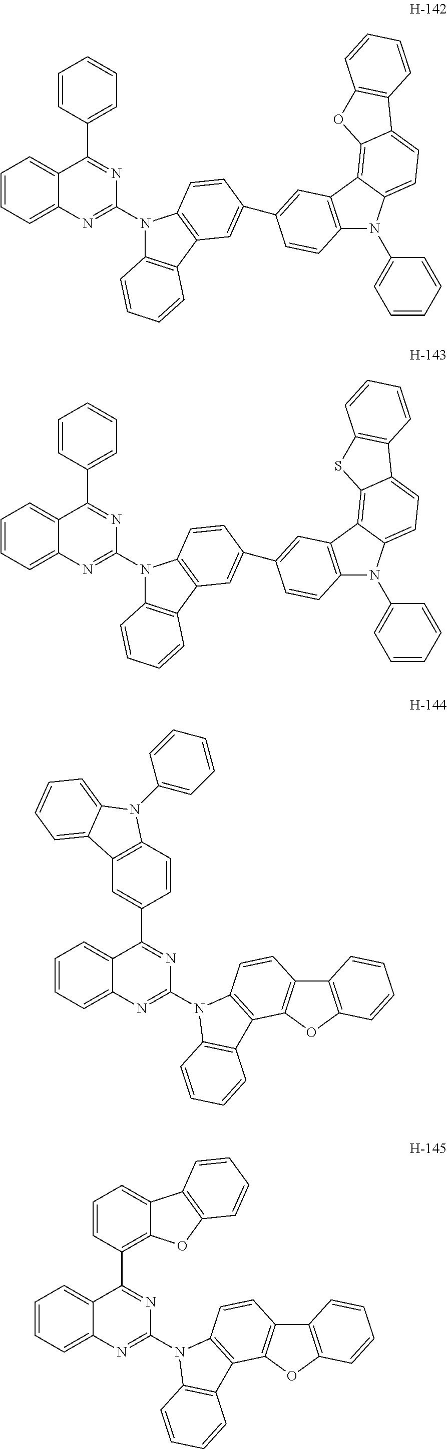 [SMILES: c1ccc(-c2nc(-n3c4ccccc4c4cc(-c5ccc6c(c5)c5c7oc8ccccc8c7ccc5n6-c5ccccc5)ccc43)nc3ccccc23)cc1 ; c1ccc(-c2nc(-n3c4ccccc4c4cc(-c5ccc6c(c5)c5c7sc8ccccc8c7ccc5n6-c5ccccc5)ccc43)nc3ccccc23)cc1 ; c1ccc(-n2c3ccccc3c3cc(-c4nc(-n5c6ccccc6c6c7oc8ccccc8c7ccc65)nc5ccccc45)ccc32)cc1 ; c1ccc2c(-c3cccc4c3oc3ccccc34)nc(-n3c4ccccc4c4c5oc6ccccc6c5ccc43)nc2c1]

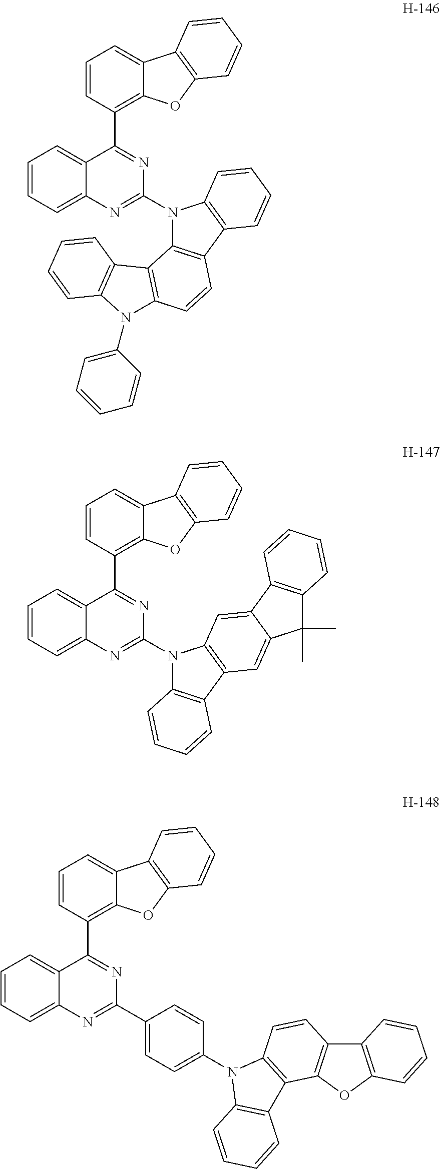 [SMILES: c1ccc(-n2c3ccccc3c3c2ccc2c4ccccc4n(-c4nc(-c5cccc6c5oc5ccccc56)c5ccccc5n4)c23)cc1 ; CC1(C)c2ccccc2-c2cc3c(cc21)c1ccccc1n3-c1nc(-c2cccc3c2oc2ccccc23)c2ccccc2n1 ; c1ccc2c(-c3cccc4c3oc3ccccc34)nc(-c3ccc(-n4c5ccccc5c5c6oc7ccccc7c6ccc54)cc3)nc2c1]

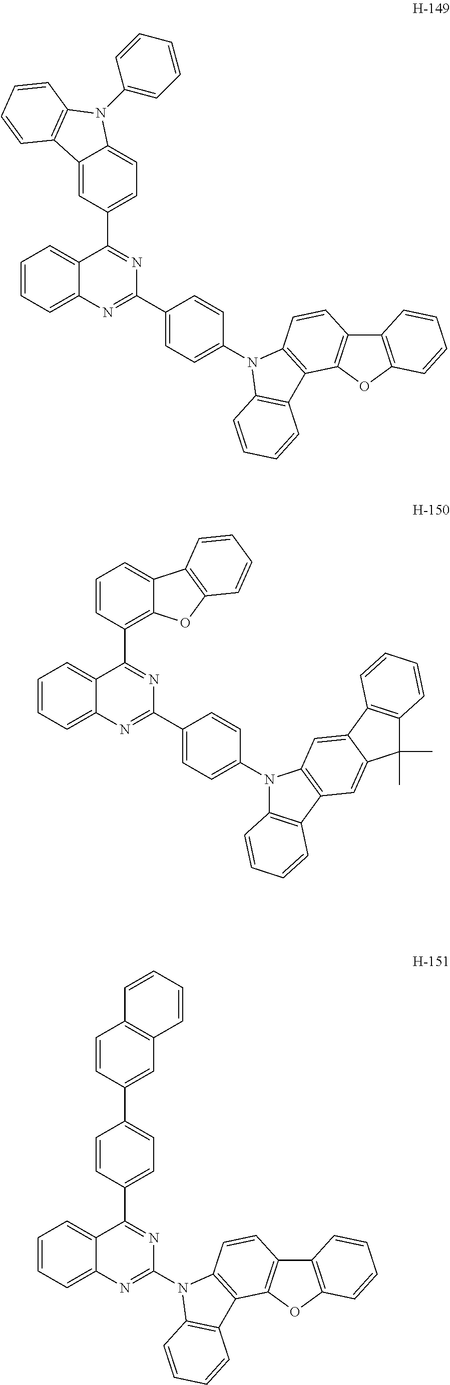 [SMILES: c1ccc(-n2c3ccccc3c3cc(-c4nc(-c5ccc(-n6c7ccccc7c7c8oc9ccccc9c8ccc76)cc5)nc5ccccc45)ccc32)cc1 ; CC1(C)c2ccccc2-c2cc3c(cc21)c1ccccc1n3-c1ccc(-c2nc(-c3cccc4c3oc3ccccc34)c3ccccc3n2)cc1 ; c1ccc2cc(-c3ccc(-c4nc(-n5c6ccccc6c6c7oc8ccccc8c7ccc65)nc5ccccc45)cc3)ccc2c1]

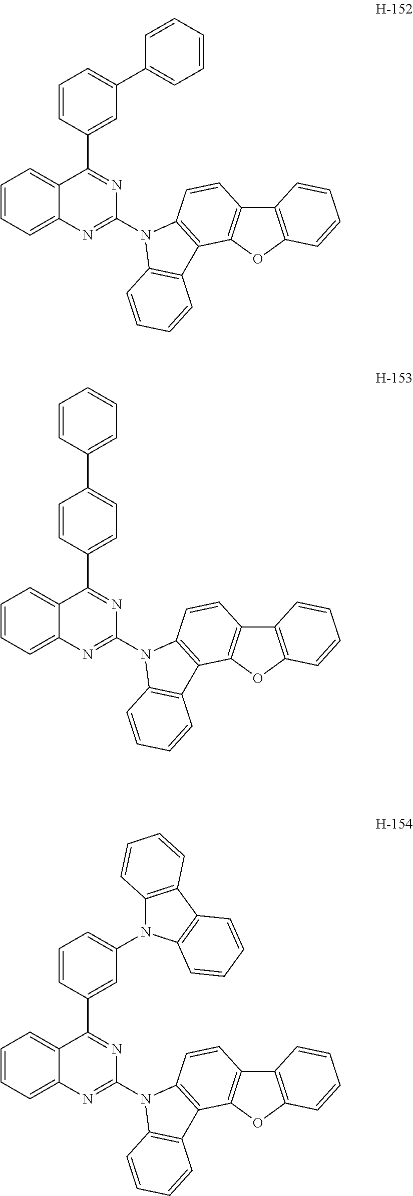 [SMILES: c1ccc(-c2cccc(-c3nc(-n4c5ccccc5c5c6oc7ccccc7c6ccc54)nc4ccccc34)c2)cc1 ; c1ccc(-c2ccc(-c3nc(-n4c5ccccc5c5c6oc7ccccc7c6ccc54)nc4ccccc34)cc2)cc1 ; c1cc(-c2nc(-n3c4ccccc4c4c5oc6ccccc6c5ccc43)nc3ccccc23)cc(-n2c3ccccc3c3ccccc32)c1]

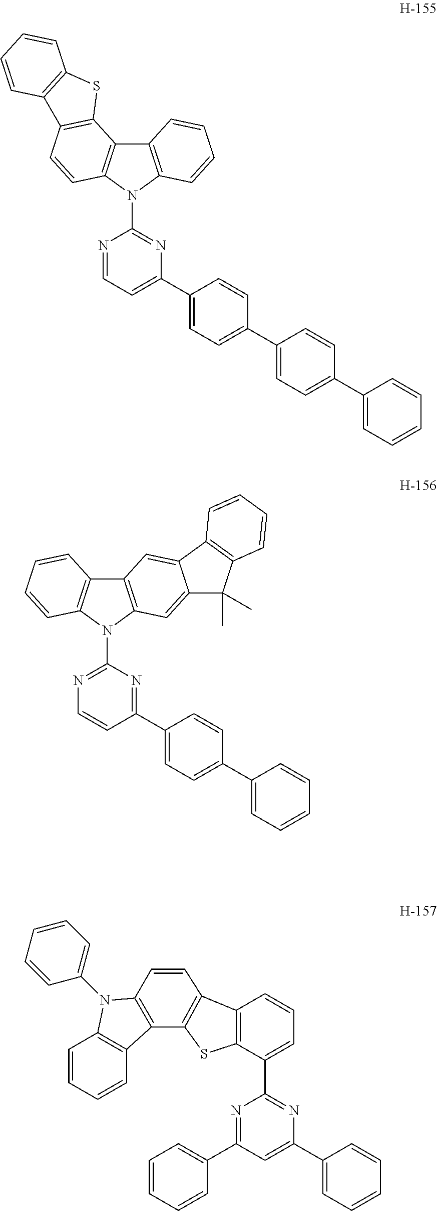 [SMILES: c1ccc(-c2ccc(-c3ccc(-c4ccnc(-n5c6ccccc6c6c7sc8ccccc8c7ccc65)n4)cc3)cc2)cc1 ; CC1(C)c2ccccc2-c2cc3c4ccccc4n(-c4nccc(-c5ccc(-c6ccccc6)cc5)n4)c3cc21 ; c1ccc(-c2cc(-c3ccccc3)nc(-c3cccc4c3sc3c4ccc4c3c3ccccc3n4-c3ccccc3)n2)cc1]

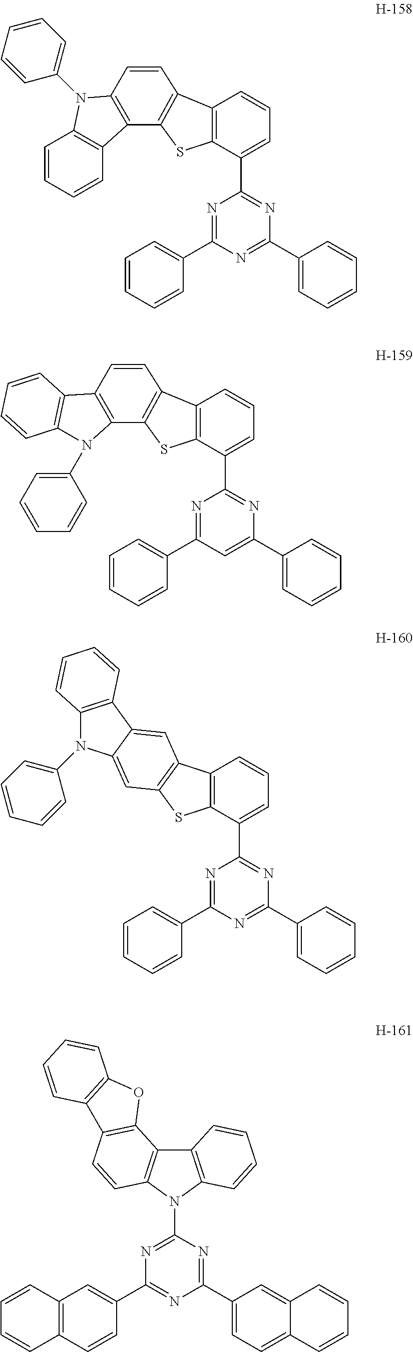 [SMILES: c1ccc(-c2nc(-c3ccccc3)nc(-c3cccc4c3sc3c4ccc4c3c3ccccc3n4-c3ccccc3)n2)cc1 ; c1ccc(-c2cc(-c3ccccc3)nc(-c3cccc4c3sc3c4ccc4c5ccccc5n(-c5ccccc5)c43)n2)cc1 ; c1ccc(-c2nc(-c3ccccc3)nc(-c3cccc4c3sc3cc5c(cc34)c3ccccc3n5-c3ccccc3)n2)cc1 ; c1ccc2cc(-c3nc(-c4ccc5ccccc5c4)nc(-n4c5ccccc5c5c6oc7ccccc7c6ccc54)n3)ccc2c1]

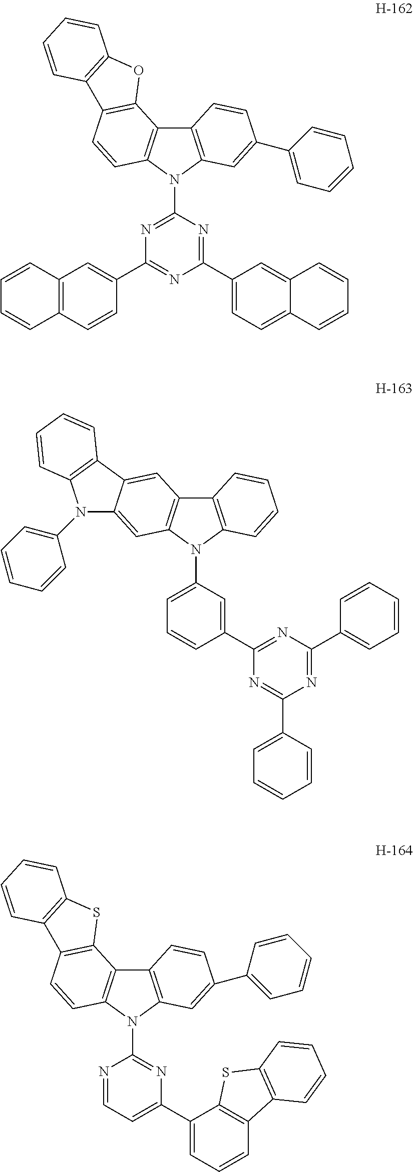 [SMILES: c1ccc(-c2ccc3c4c5oc6ccccc6c5ccc4n(-c4nc(-c5ccc6ccccc6c5)nc(-c5ccc6ccccc6c5)n4)c3c2)cc1 ; c1ccc(-c2nc(-c3ccccc3)nc(-c3cccc(-n4c5ccccc5c5cc6c7ccccc7n(-c7ccccc7)c6cc54)c3)n2)cc1 ; c1ccc(-c2ccc3c4c5sc6ccccc6c5ccc4n(-c4nccc(-c5cccc6c5sc5ccccc56)n4)c3c2)cc1]

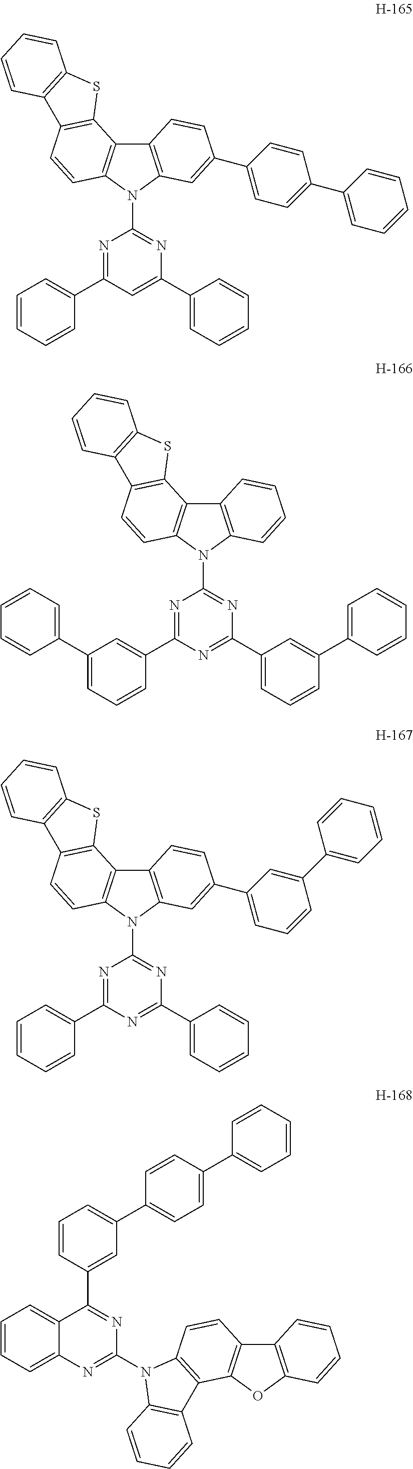 [SMILES: c1ccc(-c2ccc(-c3ccc4c5c6sc7ccccc7c6ccc5n(-c5nc(-c6ccccc6)cc(-c6ccccc6)n5)c4c3)cc2)cc1 ; c1ccc(-c2cccc(-c3nc(-c4cccc(-c5ccccc5)c4)nc(-n4c5ccccc5c5c6sc7ccccc7c6ccc54)n3)c2)cc1 ; c1ccc(-c2cccc(-c3ccc4c5c6sc7ccccc7c6ccc5n(-c5nc(-c6ccccc6)nc(-c6ccccc6)n5)c4c3)c2)cc1 ; c1ccc(-c2ccc(-c3cccc(-c4nc(-n5c6ccccc6c6c7oc8ccccc8c7ccc65)nc5ccccc45)c3)cc2)cc1]

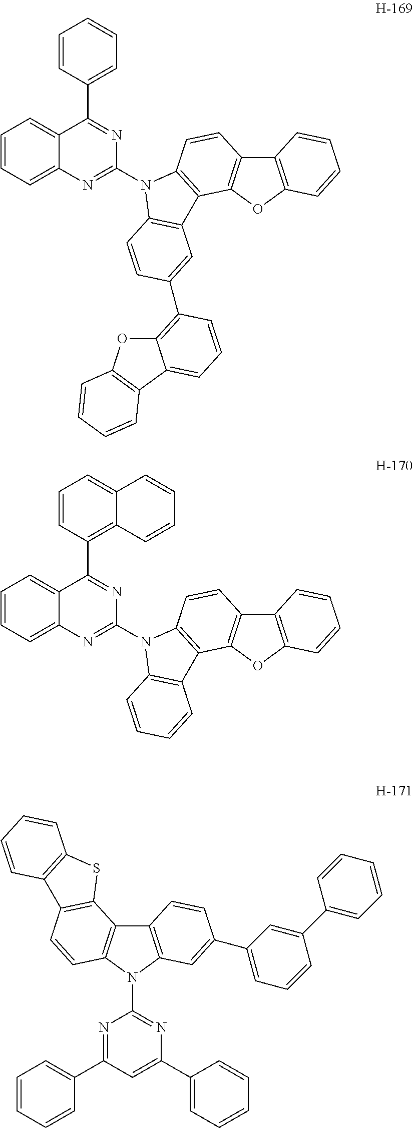

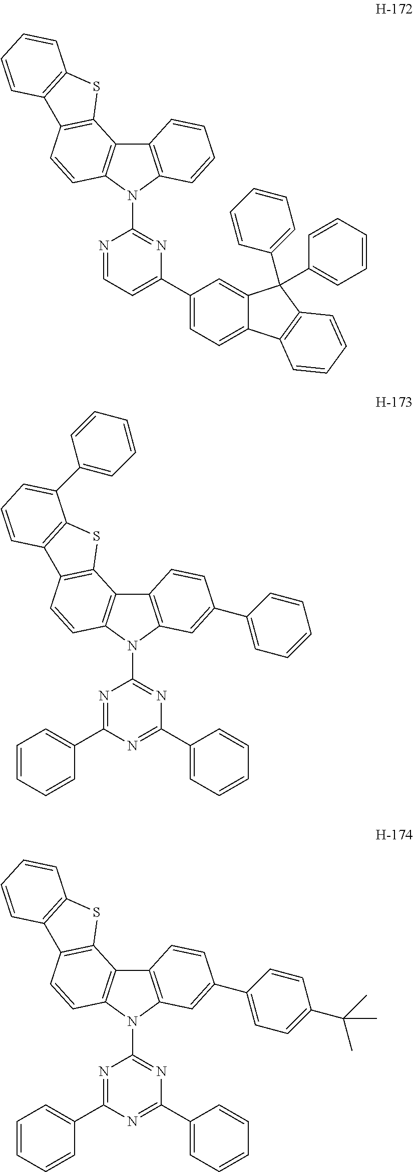 [SMILES: c1ccc(C2(c3ccccc3)c3ccccc3-c3ccc(-c4ccnc(-n5c6ccccc6c6c7sc8ccccc8c7ccc65)n4)cc32)cc1 ; c1ccc(-c2ccc3c4c5sc6c(-c7ccccc7)cccc6c5ccc4n(-c4nc(-c5ccccc5)nc(-c5ccccc5)n4)c3c2)cc1 ; CC(C)(C)c1ccc(-c2ccc3c4c5sc6ccccc6c5ccc4n(-c4nc(-c5ccccc5)nc(-c5ccccc5)n4)c3c2)cc1]

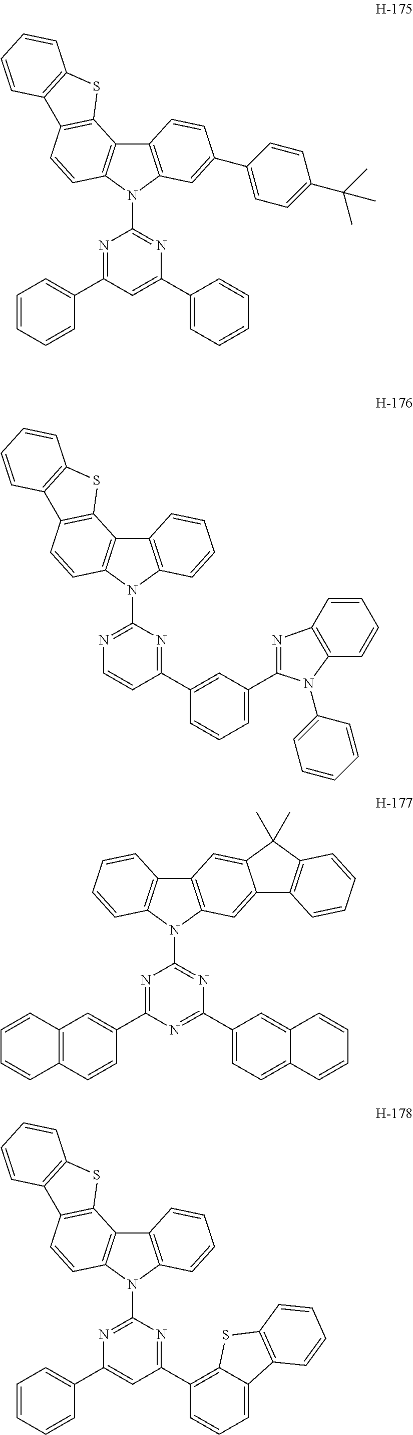

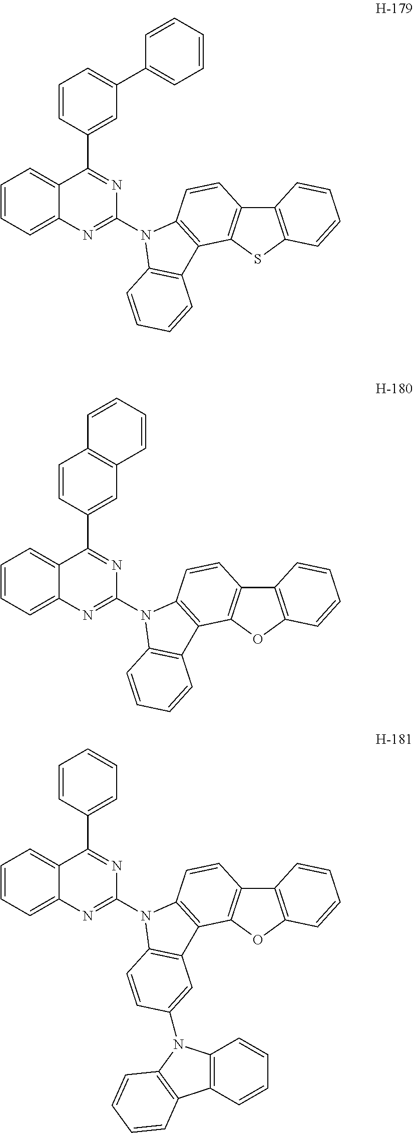 [SMILES: c1ccc(-c2cccc(-c3nc(-n4c5ccccc5c5c6sc7ccccc7c6ccc54)nc4ccccc34)c2)cc1 ; c1ccc2cc(-c3nc(-n4c5ccccc5c5c6oc7ccccc7c6ccc54)nc4ccccc34)ccc2c1 ; c1ccc(-c2nc(-n3c4ccc(-n5c6ccccc6c6ccccc65)cc4c4c5oc6ccccc6c5ccc43)nc3ccccc23)cc1]

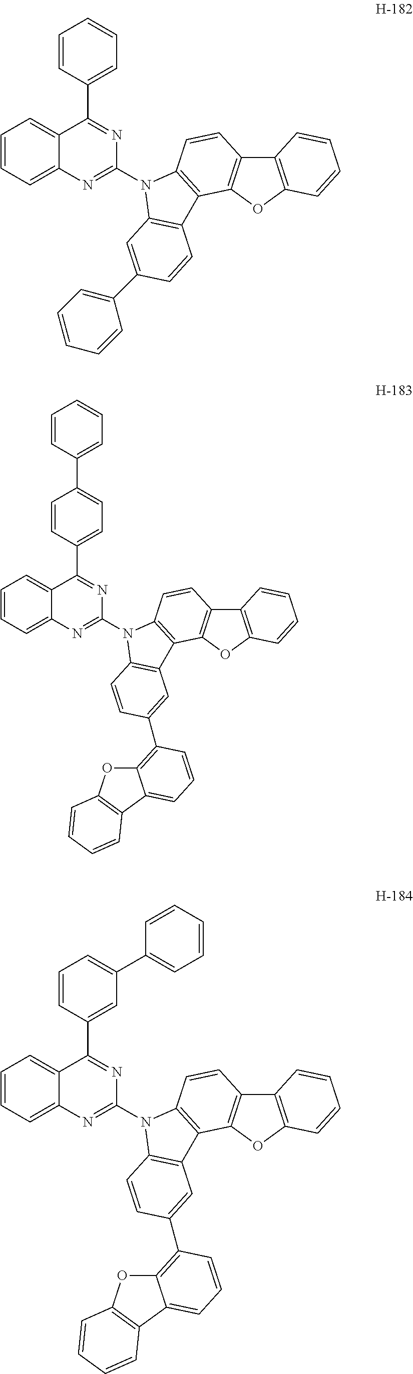 [SMILES: c1ccc(-c2ccc3c4c5oc6ccccc6c5ccc4n(-c4nc(-c5ccccc5)c5ccccc5n4)c3c2)cc1 ; c1ccc(-c2ccc(-c3nc(-n4c5ccc(-c6cccc7c6oc6ccccc67)cc5c5c6oc7ccccc7c6ccc54)nc4ccccc34)cc2)cc1 ; c1ccc(-c2cccc(-c3nc(-n4c5ccc(-c6cccc7c6oc6ccccc67)cc5c5c6oc7ccccc7c6ccc54)nc4ccccc34)c2)cc1]

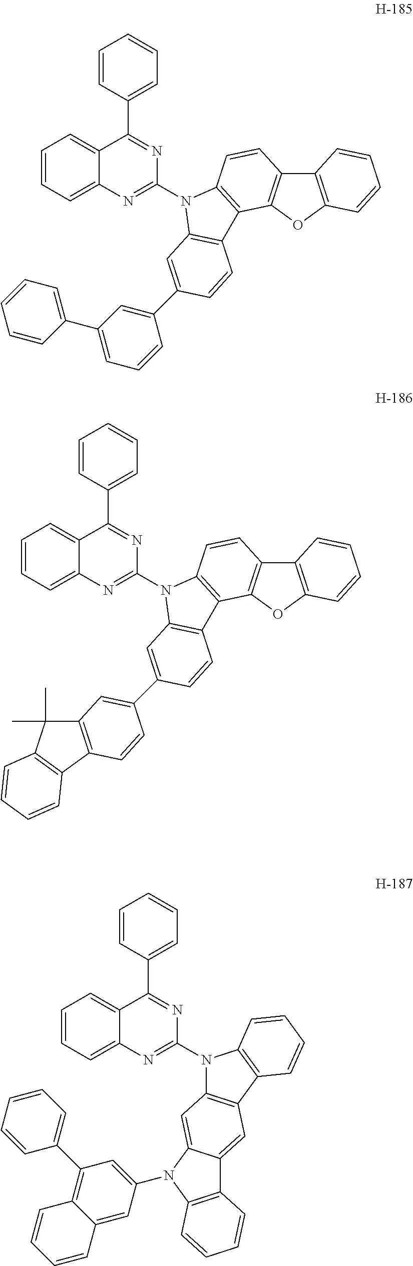 [SMILES: c1ccc(-c2cccc(-c3ccc4c5c6oc7ccccc7c6ccc5n(-c5nc(-c6ccccc6)c6ccccc6n5)c4c3)c2)cc1 ; CC1(C)c2ccccc2-c2ccc(-c3ccc4c5c6oc7ccccc7c6ccc5n(-c5nc(-c6ccccc6)c6ccccc6n5)c4c3)cc21 ; c1ccc(-c2cc(-n3c4ccccc4c4cc5c6ccccc6n(-c6nc(-c7ccccc7)c7ccccc7n6)c5cc43)cc3ccccc23)cc1]

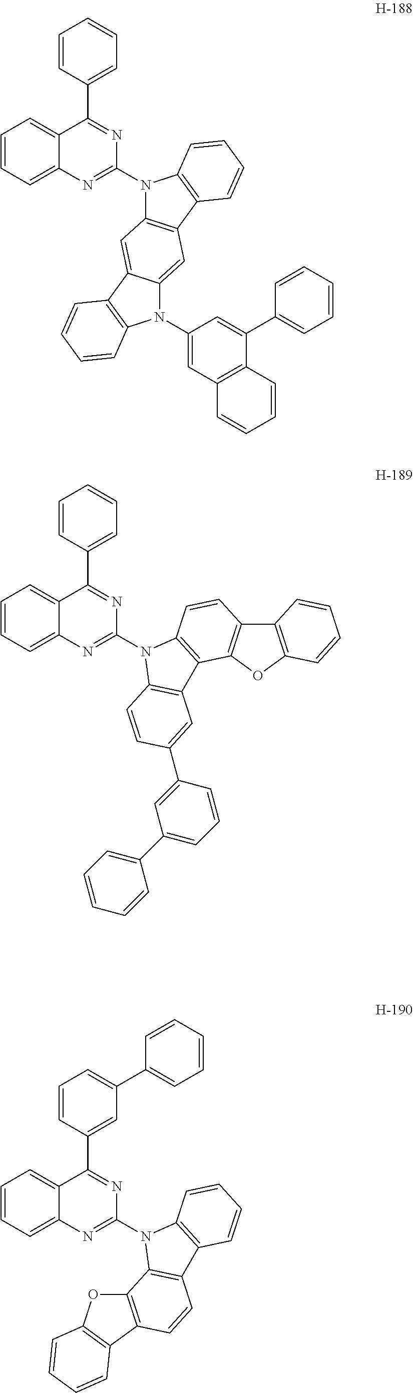 [SMILES: c1ccc(-c2cc(-n3c4ccccc4c4cc5c(cc43)c3ccccc3n5-c3nc(-c4ccccc4)c4ccccc4n3)cc3ccccc23)cc1 ; c1ccc(-c2cccc(-c3ccc4c(c3)c3c5oc6ccccc6c5ccc3n4-c3nc(-c4ccccc4)c4ccccc4n3)c2)cc1 ; c1ccc(-c2cccc(-c3nc(-n4c5ccccc5c5ccc6c7ccccc7oc6c54)nc4ccccc34)c2)cc1]

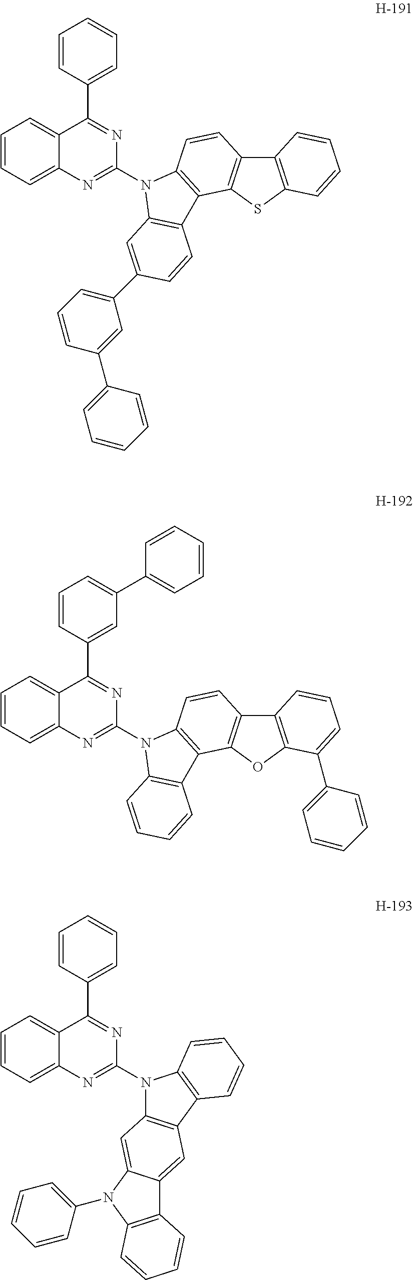 [SMILES: c1ccc(-c2cccc(-c3ccc4c5c6sc7ccccc7c6ccc5n(-c5nc(-c6ccccc6)c6ccccc6n5)c4c3)c2)cc1 ; c1ccc(-c2cccc(-c3nc(-n4c5ccccc5c5c6oc7c(-c8ccccc8)cccc7c6ccc54)nc4ccccc34)c2)cc1 ; c1ccc(-c2nc(-n3c4ccccc4c4cc5c6ccccc6n(-c6ccccc6)c5cc43)nc3ccccc23)cc1]

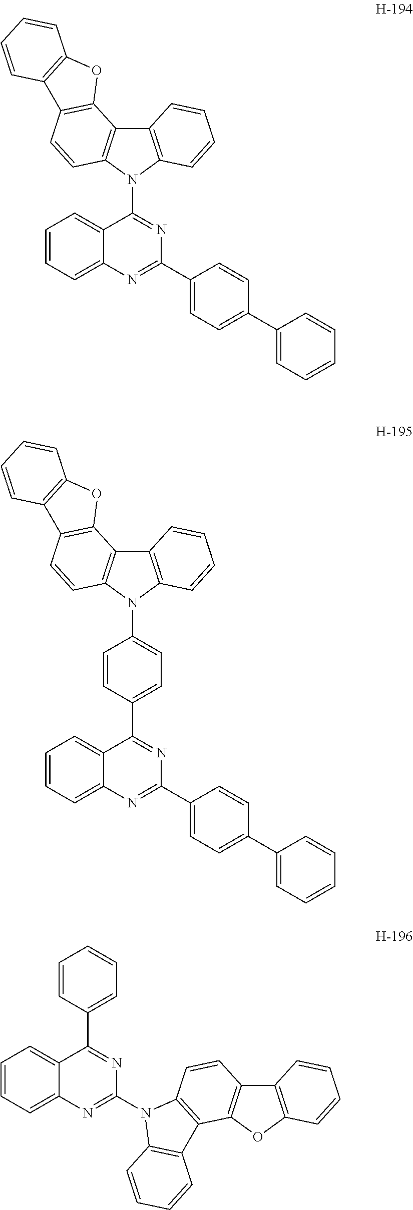 [SMILES: c1ccc(-c2ccc(-c3nc(-n4c5ccccc5c5c6oc7ccccc7c6ccc54)c4ccccc4n3)cc2)cc1 ; c1ccc(-c2ccc(-c3nc(-c4ccc(-n5c6ccccc6c6c7oc8ccccc8c7ccc65)cc4)c4ccccc4n3)cc2)cc1 ; c1ccc(-c2nc(-n3c4ccccc4c4c5oc6ccccc6c5ccc43)nc3ccccc23)cc1]

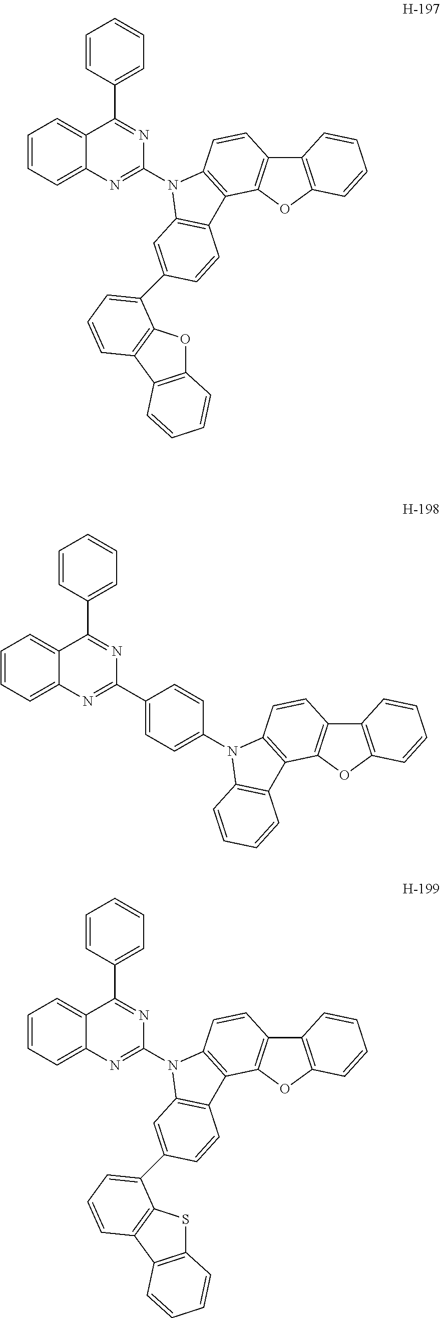 [SMILES: c1ccc(-c2nc(-n3c4cc(-c5cccc6c5oc5ccccc56)ccc4c4c5oc6ccccc6c5ccc43)nc3ccccc23)cc1 ; c1ccc(-c2nc(-c3ccc(-n4c5ccccc5c5c6oc7ccccc7c6ccc54)cc3)nc3ccccc23)cc1 ; c1ccc(-c2nc(-n3c4cc(-c5cccc6c5sc5ccccc56)ccc4c4c5oc6ccccc6c5ccc43)nc3ccccc23)cc1]

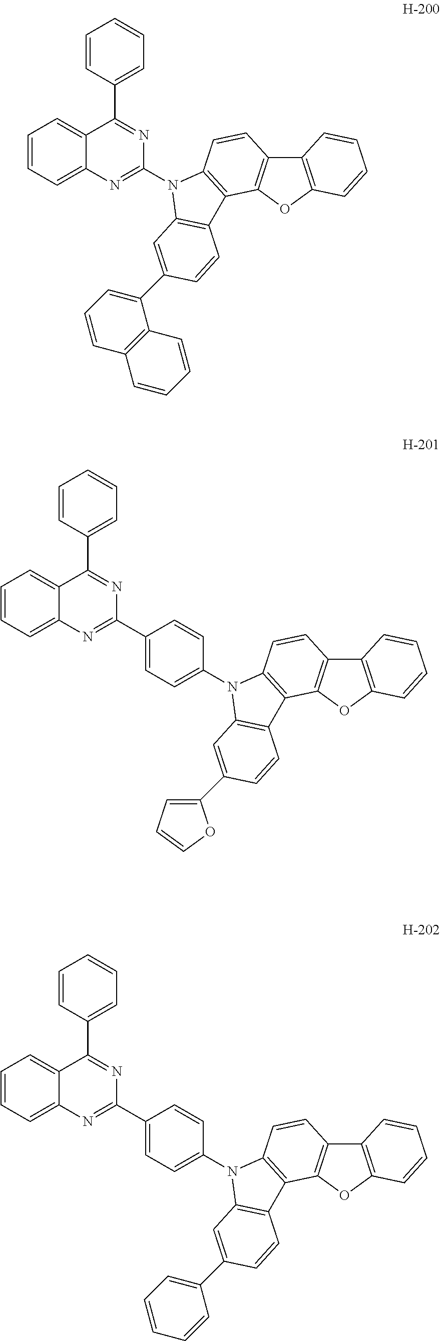 [SMILES: c1ccc(-c2nc(-n3c4cc(-c5cccc6ccccc56)ccc4c4c5oc6ccccc6c5ccc43)nc3ccccc23)cc1 ; c1ccc(-c2nc(-c3ccc(-n4c5cc(-c6ccco6)ccc5c5c6oc7ccccc7c6ccc54)cc3)nc3ccccc23)cc1 ; c1ccc(-c2ccc3c4c5oc6ccccc6c5ccc4n(-c4ccc(-c5nc(-c6ccccc6)c6ccccc6n5)cc4)c3c2)cc1]

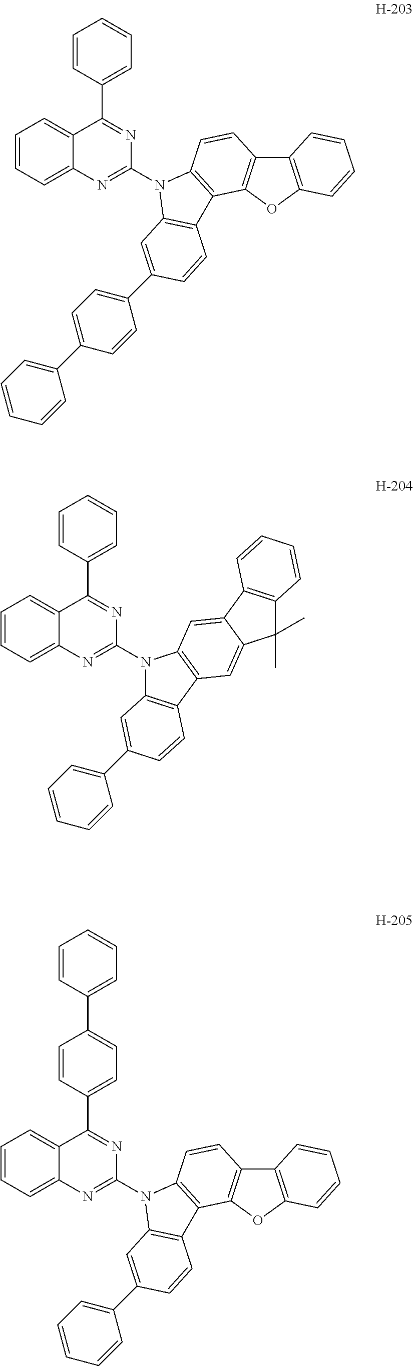 [SMILES: c1ccc(-c2ccc(-c3ccc4c5c6oc7ccccc7c6ccc5n(-c5nc(-c6ccccc6)c6ccccc6n5)c4c3)cc2)cc1 ; CC1(C)c2ccccc2-c2cc3c(cc21)c1ccc(-c2ccccc2)cc1n3-c1nc(-c2ccccc2)c2ccccc2n1 ; c1ccc(-c2ccc(-c3nc(-n4c5cc(-c6ccccc6)ccc5c5c6oc7ccccc7c6ccc54)nc4ccccc34)cc2)cc1]

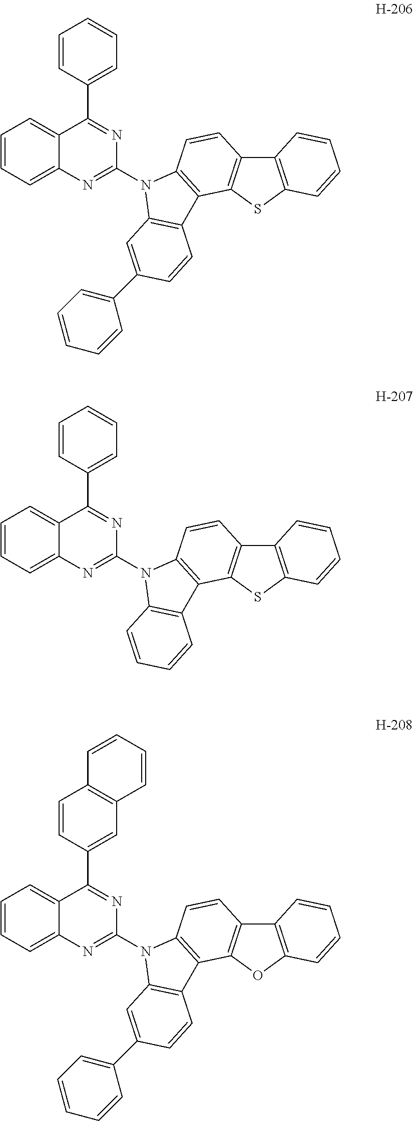 [SMILES: c1ccc(-c2ccc3c4c5sc6ccccc6c5ccc4n(-c4nc(-c5ccccc5)c5ccccc5n4)c3c2)cc1 ; c1ccc(-c2nc(-n3c4ccccc4c4c5sc6ccccc6c5ccc43)nc3ccccc23)cc1 ; c1ccc(-c2ccc3c4c5oc6ccccc6c5ccc4n(-c4nc(-c5ccc6ccccc6c5)c5ccccc5n4)c3c2)cc1]

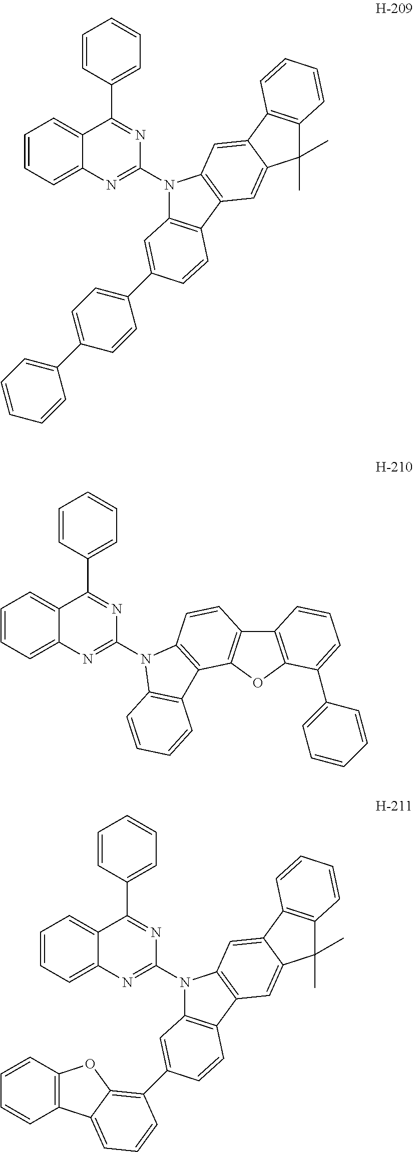 [SMILES: CC1(C)c2ccccc2-c2cc3c(cc21)c1ccc(-c2ccc(-c4ccccc4)cc2)cc1n3-c1nc(-c2ccccc2)c2ccccc2n1 ; c1ccc(-c2nc(-n3c4ccccc4c4c5oc6c(-c7ccccc7)cccc6c5ccc43)nc3ccccc23)cc1 ; CC1(C)c2ccccc2-c2cc3c(cc21)c1ccc(-c2cccc4c2oc2ccccc24)cc1n3-c1nc(-c2ccccc2)c2ccccc2n1]

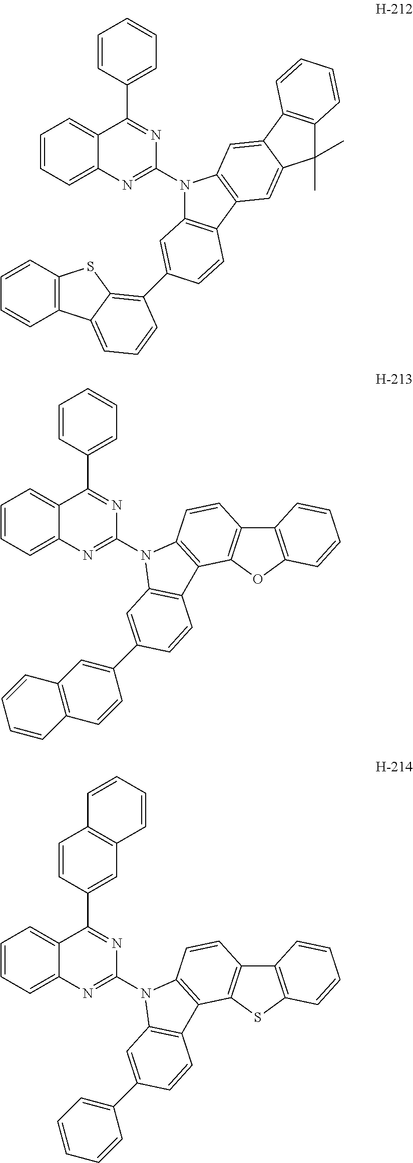

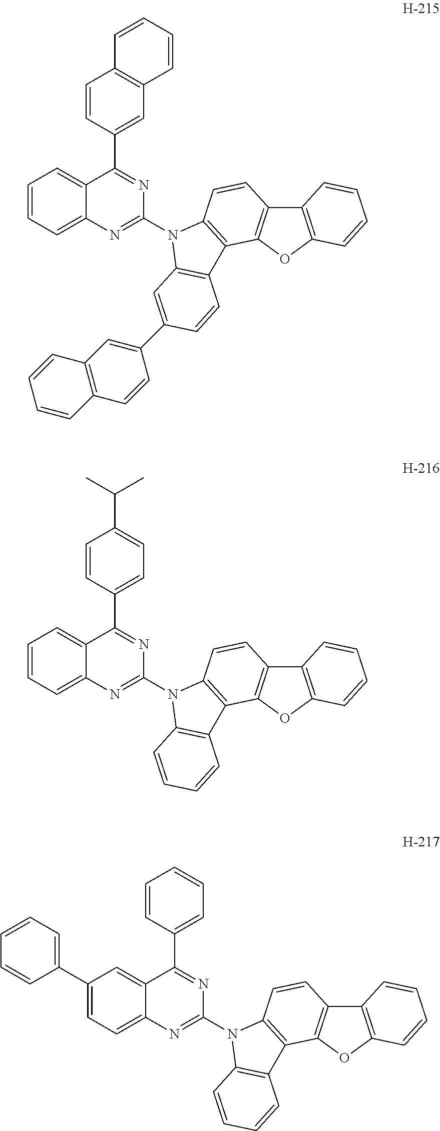 [SMILES: c1ccc2cc(-c3ccc4c5c6oc7ccccc7c6ccc5n(-c5nc(-c6ccc7ccccc7c6)c6ccccc6n5)c4c3)ccc2c1 ; CC(C)c1ccc(-c2nc(-n3c4ccccc4c4c5oc6ccccc6c5ccc43)nc3ccccc23)cc1 ; c1ccc(-c2ccc3nc(-n4c5ccccc5c5c6oc7ccccc7c6ccc54)nc(-c4ccccc4)c3c2)cc1]

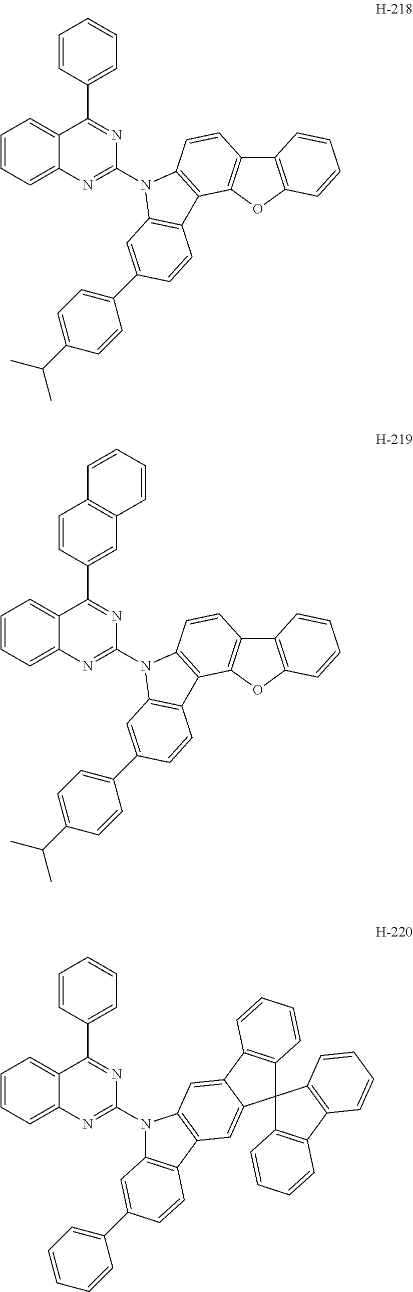 [SMILES: CC(C)c1ccc(-c2ccc3c4c5oc6ccccc6c5ccc4n(-c4nc(-c5ccccc5)c5ccccc5n4)c3c2)cc1 ; CC(C)c1ccc(-c2ccc3c4c5oc6ccccc6c5ccc4n(-c4nc(-c5ccc6ccccc6c5)c5ccccc5n4)c3c2)cc1 ; c1ccc(-c2ccc3c4cc5c(cc4n(-c4nc(-c6ccccc6)c6ccccc6n4)c3c2)-c2ccccc2C52c3ccccc3-c3ccccc32)cc1]

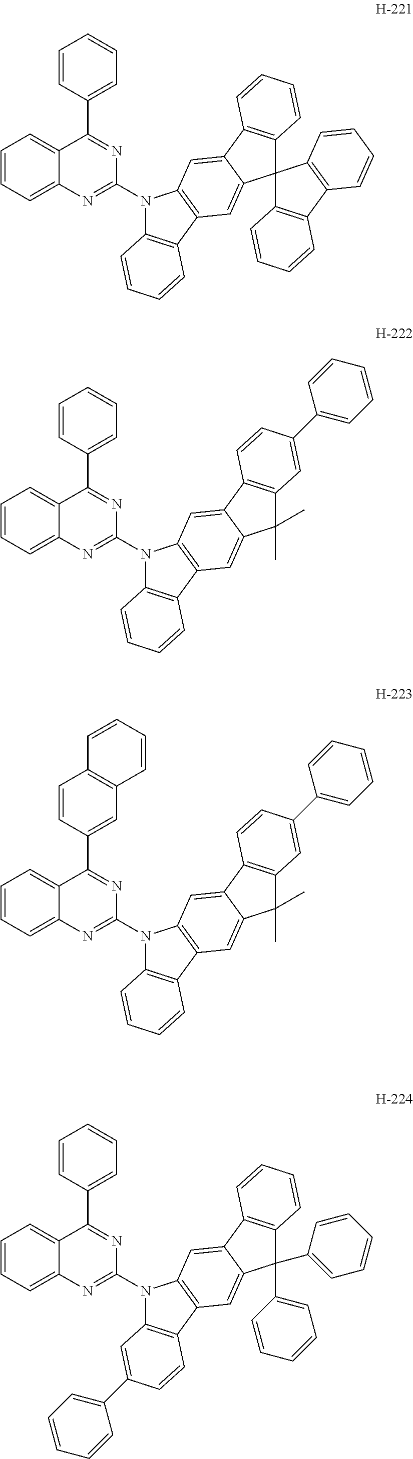 [SMILES: c1ccc(-c2nc(-n3c4ccccc4c4cc5c(cc43)-c3ccccc3C53c4ccccc4-c4ccccc43)nc3ccccc23)cc1 ; CC1(C)c2cc(-c3ccccc3)ccc2-c2cc3c(cc21)c1ccccc1n3-c1nc(-c2ccccc2)c2ccccc2n1 ; CC1(C)c2cc(-c3ccccc3)ccc2-c2cc3c(cc21)c1ccccc1n3-c1nc(-c2ccc3ccccc3c2)c2ccccc2n1 ; c1ccc(-c2ccc3c4cc5c(cc4n(-c4nc(-c6ccccc6)c6ccccc6n4)c3c2)-c2ccccc2C5(c2ccccc2)c2ccccc2)cc1]

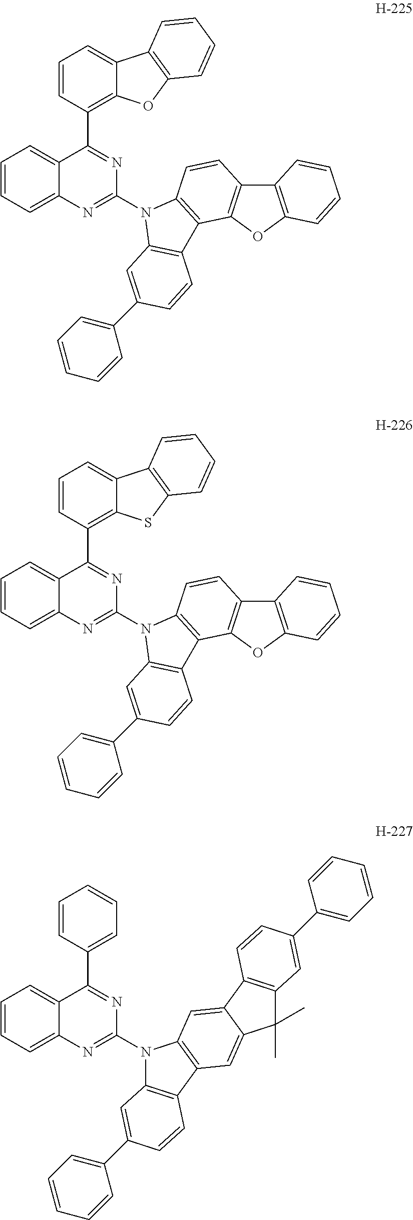 [SMILES: c1ccc(-c2ccc3c4c5oc6ccccc6c5ccc4n(-c4nc(-c5cccc6c5oc5ccccc56)c5ccccc5n4)c3c2)cc1 ; c1ccc(-c2ccc3c4c5oc6ccccc6c5ccc4n(-c4nc(-c5cccc6c5sc5ccccc56)c5ccccc5n4)c3c2)cc1 ; CC1(C)c2cc(-c3ccccc3)ccc2-c2cc3c(cc21)c1ccc(-c2ccccc2)cc1n3-c1nc(-c2ccccc2)c2ccccc2n1]

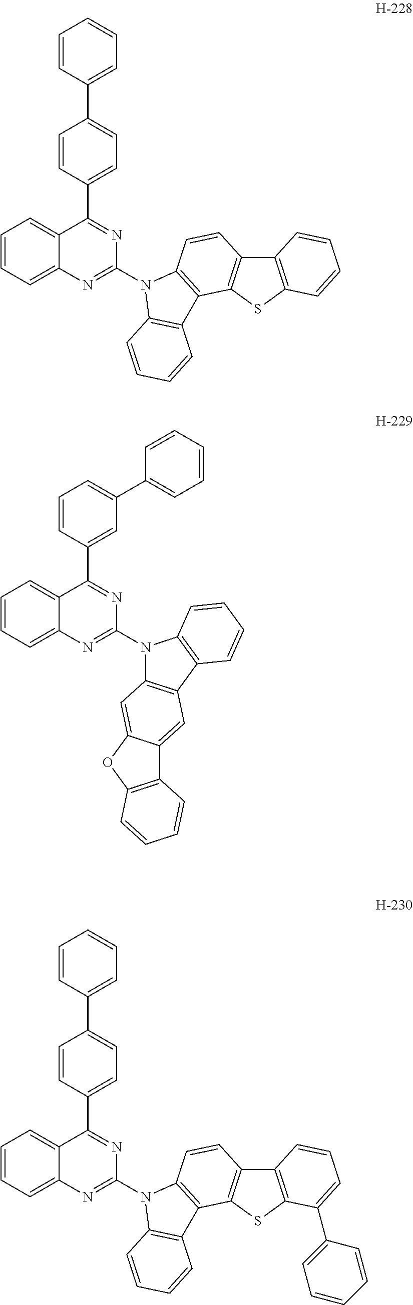 [SMILES: c1ccc(-c2ccc(-c3nc(-n4c5ccccc5c5c6sc7ccccc7c6ccc54)nc4ccccc34)cc2)cc1 ; c1ccc(-c2cccc(-c3nc(-n4c5ccccc5c5cc6c(cc54)oc4ccccc46)nc4ccccc34)c2)cc1 ; c1ccc(-c2ccc(-c3nc(-n4c5ccccc5c5c6sc7c(-c8ccccc8)cccc7c6ccc54)nc4ccccc34)cc2)cc1]

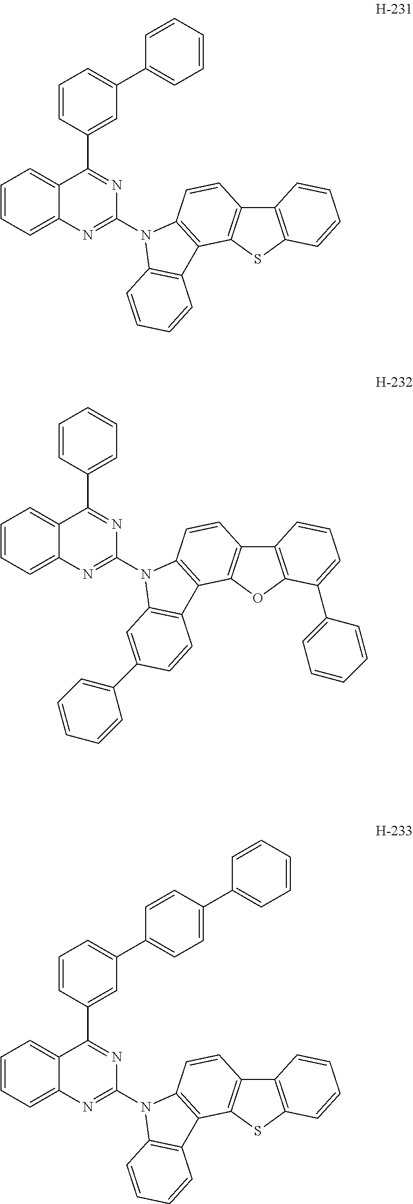 [SMILES: c1ccc(-c2cccc(-c3nc(-n4c5ccccc5c5c6sc7ccccc7c6ccc54)nc4ccccc34)c2)cc1 ; c1ccc(-c2ccc3c4c5oc6c(-c7ccccc7)cccc6c5ccc4n(-c4nc(-c5ccccc5)c5ccccc5n4)c3c2)cc1 ; c1ccc(-c2ccc(-c3cccc(-c4nc(-n5c6ccccc6c6c7sc8ccccc8c7ccc65)nc5ccccc45)c3)cc2)cc1]

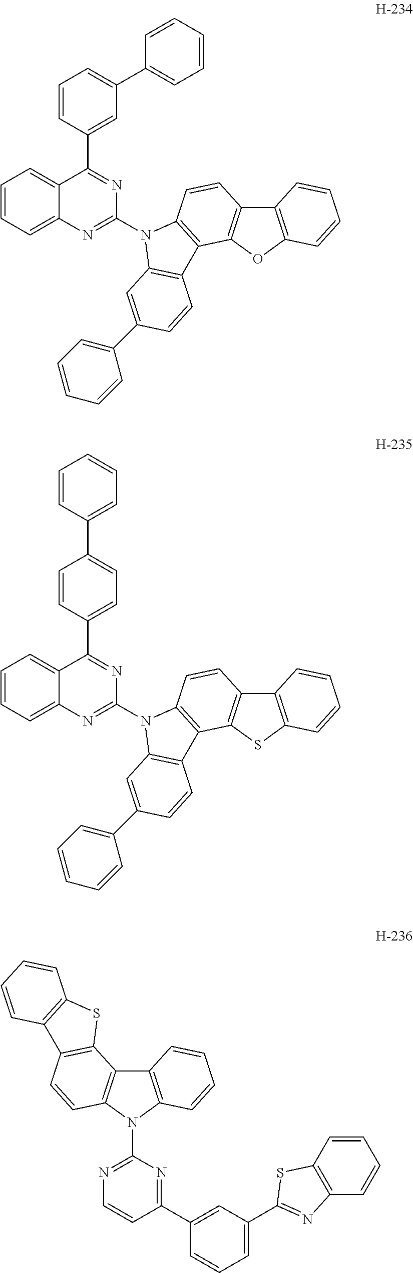 [SMILES: c1ccc(-c2cccc(-c3nc(-n4c5cc(-c6ccccc6)ccc5c5c6oc7ccccc7c6ccc54)nc4ccccc34)c2)cc1 ; c1ccc(-c2ccc(-c3nc(-n4c5cc(-c6ccccc6)ccc5c5c6sc7ccccc7c6ccc54)nc4ccccc34)cc2)cc1 ; c1cc(-c2ccnc(-n3c4ccccc4c4c5sc6ccccc6c5ccc43)n2)cc(-c2nc3ccccc3s2)c1]

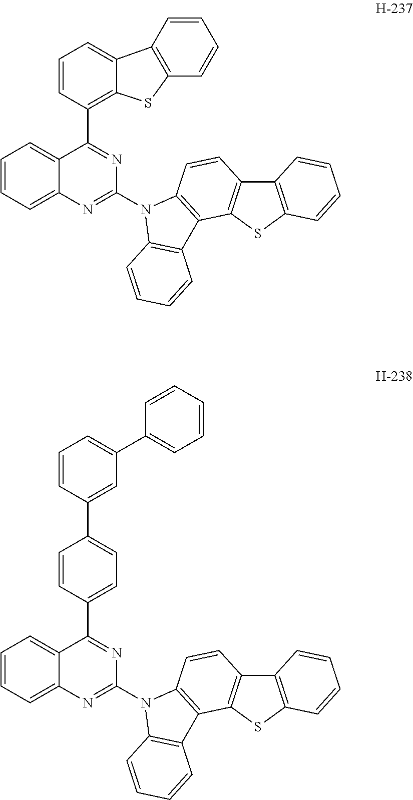 [SMILES: c1ccc2c(-c3cccc4c3sc3ccccc34)nc(-n3c4ccccc4c4c5sc6ccccc6c5ccc43)nc2c1 ; c1ccc(-c2cccc(-c3ccc(-c4nc(-n5c6ccccc6c6c7sc8ccccc8c7ccc65)nc5ccccc45)cc3)c2)cc1]

8. An organic electroluminescent device which comprises the combination according to claim 1, and emits yellow-green light.
